(19) United States
(12) Patent Application Publication
(10) Pub. No.: US 2025/0261441 A1
(43) Pub. Date: Aug. 14, 2025

(54) MONOLITHICALLY INTEGRATED LATERAL BIPOLAR DEVICE WITH SELF-ALIGNED DOPED REGIONS

(71) Applicant: Analog Devices International Unlimited Company, Limerick (IE)

(72) Inventor: Edward John Coyne, Athenry (IE)

(21) Appl. No.: 19/096,578

(22) Filed: Mar. 31, 2025

Related U.S. Application Data
(63) Continuation of application No. 18/840,056, filed on Aug. 20, 2024.
(60) Provisional application No. 63/268,585, filed on Feb. 25, 2022.
(60) Provisional application No. 63/268,590, filed on Feb. 25, 2022.
(60) Provisional application No. 63/268,588, filed on Feb. 25, 2022.
(60) Provisional application No. 63/268,587, filed on Feb. 25, 2022.
(60) Provisional application No. 63/268,519, filed on Feb. 25, 2022.

(51) Int. Cl. H10D 84/40; H10D 84/01

(52) U.S. Cl. CPC H10D 84/401; H10D 84/0109

(57) ABSTRACT

An integrated circuit device comprises a metal-oxide-semiconductor (MOS) transistor comprising a gate stack formed over a channel region thereof and a bipolar junction transistor (BJT) comprising a layer stack formed over a collector region thereof. Some features of the MOS transistor and the BJT are co-fabricated such that they have common physical characteristics.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application is a continuation of U.S. patent application Ser. No. 18/840,056, filed Aug. 20, 2024, which is a national phase under 35 U.S.C. § 371 of International Application No. PCT/EP2023/054624, filed Feb. 23, 2023, which claims the benefit of priority to U.S. Provisional Application No. 63/268,585, filed Feb. 25, 2022, U.S. Provisional Application No. 63/268,590, filed Feb. 25, 2022, U.S. Provisional Application No. 63/268,588, filed Feb. 25, 2022, U.S. Provisional Application No. 63/268,587, filed Feb. 25, 2022, and U.S. Provisional Application No. 63/268,519 filed Feb. 25, 2022. The entire content of each of the applications referenced in this paragraph is hereby incorporated by reference herein for all purposes and made a part of this specification.

### BACKGROUND

### Technical Field

The disclosed technology relates generally to integrated circuits and more particularly to monolithically integrated high performance transistors and high voltage devices.

### Description of Related Art

Some integrated circuit (IC) devices include a combination of one or more different types of semiconductor devices, such as complementary metal oxide semiconductor (CMOS) devices, bipolar devices and double diffused metal oxide semiconductor (DMOS) devices. Bipolar-CMOS-DMOS (BCDMOS) devices refer to IC devices that include features of each of bipolar, CMOS and DMOS devices, and can combine characteristics thereof. For example, bipolar devices can provide precise analog functions, CMOS devices can provide digital design and DMOS devices can provide power and high-voltage elements. The combination of these different device technologies can bring a combination of these and other advantages including high speed and high voltage operation, improved reliability, reduced electromagnetic interference and smaller chip area. BCDMOS devices find application in a broad range of products and applications in the fields of power management, analog data acquisition and power actuators, to name a few.

### SUMMARY

In one aspect, an integrated circuit (IC) device comprises a metal-oxide-semiconductor (MOS) transistor comprising a gate stack formed over a channel region thereof and a bipolar junction transistor (BJT) comprising a layer stack formed over a collector region thereof. The gate stack and the layer stack have one or more corresponding layers having a common physical dimension.

In another aspect, an integrated circuit (IC) device comprises a metal-oxide-semiconductor (MOS) transistor comprising a gate stack formed over a channel region thereof and a bipolar junction transistor (BJT) comprising a layer stack formed over a collector region thereof. The gate stack and the layer stack have corresponding spacer structures formed on sidewalls thereof having a common physical dimension.

In another aspect, an integrated circuit (IC) device comprises a metal-oxide-semiconductor (MOS) transistor comprising a gate stack formed over a channel region thereof and a bipolar junction transistor (BJT) comprising a layer stack formed over a collector region thereof. The MOS transistor and the BJT have corresponding implanted diffusion regions having a common implanted dopant profile.

In another aspect, an integrated circuit (IC) device comprises a metal-oxide-semiconductor (MOS) transistor and a bipolar junction transistor (BJT) formed in a common semiconductor substrate. The BJT comprises a collector region electrically connected to a high voltage potential divider substrate region in series and physically separated therefrom by an isolation structure. The BJT further comprises a layer stack comprising a conductive field plate formed over the collector region.

In another aspect, an integrated circuit (IC) device comprises a metal-oxide-semiconductor (MOS) transistor and a bipolar junction transistor (BJT) formed in a common semiconductor substrate. The BJT comprises a collector region electrically connected to a high voltage potential divider substrate region in series and physically separated therefrom by an isolation structure. The collector region and the high voltage potential divider substrate region are electrically connected through one or more metallization levels formed above a major surface of the common semiconductor substrate.

In another aspect, an integrated circuit (IC) device comprises a metal-oxide-semiconductor (MOS) transistor and a bipolar junction transistor (BJT) formed in a common semiconductor substrate. The BJT comprises a collector region electrically connected to a high voltage potential divider substrate region in series and physically separated therefrom by an isolation structure. The high voltage potential divider substrate region is configured to drop>50% of a combined voltage applied across the BJT and the high voltage potential divider substrate region.

In another aspect, an integrated circuit (IC) device comprises a metal-oxide-semiconductor (MOS) transistor and a lateral double-diffused metal-oxide-semiconductor (LDMOS) transistor formed in a common semiconductor substrate. The LDMOS transistor comprises an extended drain drift region that is physically separated from a channel region of the LDMOS transistor by an isolation structure. A gate stack of the MOS transistor and a gate stack of the LDMOS transistor have one or more corresponding layers having a common physical dimension.

In another aspect, an integrated circuit (IC) device comprises a metal-oxide-semiconductor (MOS) transistor and a lateral double-diffused metal-oxide-semiconductor (LDMOS) transistor formed in a common semiconductor substrate. The LDMOS transistor comprises an extended drain drift region that is physically separated from a channel region of the LDMOS transistor by an isolation structure. The MOS transistor and the LDMOS transistor have implanted diffusion regions having a common implanted dopant profile.

In another aspect, an integrated circuit (IC) device comprises a metal-oxide-semiconductor (MOS) transistor and a lateral double-diffused metal-oxide-semiconductor (LDMOS) transistor formed in a common semiconductor substrate. The LDMOS transistor comprises an extended drain drift region that is physically separated from a channel region of the LDMOS transistor by an isolation structure. The extended drain drift region comprising a conductive field plate formed thereover.

In another aspect, an integrated circuit (IC) device comprises a metal-oxide-semiconductor (MOS) transistor and one or both of a bipolar junction transistor (BJT) and a lateral double-diffused metal-oxide-semiconductor (LDMOS) transistor formed in a common silicon substrate. The IC device additionally comprises a high voltage potential divider region formed above a major surface of the common semiconductor substrate and integrated in a back-end-of-line (BEOL) of the IC device. The high voltage potential divider region is formed of a wide bandgap semiconductor material.

In another aspect, an integrated circuit (IC) device comprises a metal-oxide-semiconductor (MOS) transistor and one or both of a bipolar junction transistor (BJT) and a lateral double-diffused metal-oxide-semiconductor (LDMOS) transistor formed in a common silicon substrate. The IC device additionally comprises a high voltage potential divider region formed above a major surface of the common semiconductor substrate and integrated in a back-end-of-line (BEOL) of the IC device. The high voltage potential divider region comprises a major portion comprising a lightly doped semiconductor region.

In another aspect, an integrated circuit (IC) device comprises a metal-oxide-semiconductor (MOS) transistor and one or both of a bipolar junction transistor (BJT) and a lateral double-diffused metal-oxide-semiconductor (LDMOS) transistor formed in a common silicon substrate. The IC device additionally comprises a high voltage potential divider region formed above a major surface of the common semiconductor substrate and integrated in a back-end-of-line (BEOL) of the IC device. In operation, the high voltage potential divider region is configured to drop a higher voltage relative to at least the MOS transistor.

In another aspect, a lateral bipolar junction transistor (BJT), comprises an emitter region formed in a base well, a lightly doped collector region separated in a lateral direction from the base well by a drift region doped with a dopant of a same type at a lower dopant concentration relative to the lightly doped collector region. The lateral BJT additionally comprises a layer stack formed on the drift region where a boundary of the base well or the emitter region is aligned, in a vertical direction crossing the lateral direction, with an edge of the layer stack.

In another aspect, a lateral bipolar junction transistor (BJT), comprises an emitter region formed in a base well, a lightly doped collector region separated in a lateral direction from the base well by a drift region doped with a dopant of a same type at a lower dopant concentration relative to the lightly doped collector region. The lateral BJT additionally comprises a layer stack formed on the drift region having a spacer formed on a sidewall thereof, where a base length of the lateral BJT, extending in the lateral direction between the emitter region and the drift region, is defined by a lateral width of a bottom portion of the spacer formed on a sidewall of the layer stack.

In another aspect, a lateral bipolar junction transistor (BJT) comprises an emitter region formed in a base well, and a heavily doped collector region separated in a lateral direction from the base well by a drift region doped with a dopant of a same type at a lower dopant concentration relative to the heavily doped collector region. The lateral BJT additionally comprises a layer stack formed at least on a first lateral section of the drift region, the layer stack including a conductive reduced surface field (RESURF) layer.

In another aspect, an integrated circuit (IC) device, comprises a metal-oxide-semiconductor (MOS) transistor comprising a heavily doped (HD) drain region, a gate stack, a drain region extension extending in a lateral direction from the HD drain region to an edge of the gate stack, and at least one drain field plate extending over at least 20% of a length of the drain region extension. Additionally the integrated circuit (IC) device comprises, a bipolar junction transistor (BJT) comprising a heavily doped (HD) collector region, a layer stack, a drift region extension extending in the lateral direction from the HD collector region to an edge of the layer stack, and at least one field plate extending over at least 20% of the drift region extension where at least one drain field plate and at least one field plate have at least one common physical dimension.

In another aspect, an integrated circuit (IC) device, comprises, a metal-oxide-semiconductor (MOS) transistor comprising a heavily doped (HD) drain region, a gate stack, a drain region extension extending in a lateral direction from the HD drain region to an edge of the gate stack, and a thick dielectric layer extending over the drain region extension. Additionally the integrated circuit (IC) device comprises a bipolar junction transistor (BJT) comprising a heavily doped (HD) collector region, a layer stack, a drift region extension extending in the lateral direction from the HD collector region to an edge of the layer stack, and a thick isolating dielectric layer extending over the drift region extension, where the thick dielectric layer and the thick isolating dielectric layer have at least one common physical dimension.

In another aspect, an integrated circuit (IC) device comprises a metal-oxide-semiconductor (MOS) transistor comprising a heavily doped (HD) drain region, and a gate stack and a drain region extension extending in a lateral direction from the HD drain region to an edge of the gate stack, the gate stack comprising a gate layer extending over a gate dielectric layer and a portion of the drain region extension. Additionally the integrated circuit (IC) device, comprises a bipolar junction transistor (BJT) comprising a heavily doped (HD) collector region, a layer stack and a drift region extension extending in the lateral direction from the HD collector region to an edge of the layer stack, and a reduced surface field (RESURF) layer extending over a RESURF dielectric layer and a portion of the drift region extension, where the gate layer and the RESURF layer have least one common physical dimension.

In another aspect, a bipolar junction transistor (BJT) formed in a substrate, the BJT comprises a base well, an emitter region formed in the base well, a heavily doped (HD) collector region separated in a lateral direction from the base well by a drift region, and a first conductive field plate disposed over a first lateral section of the drift region spanning greater than 20% of a length of the drift region in the lateral direction, where the emitter region, the drift region, and the HD collector region have a same polarity that is opposite to a polarity of the base well.

In another aspect, a bipolar junction transistor (BJT) formed in a substrate, the BJT comprises a base well, an emitter region formed in the base well; and a heavily doped (HD) collector region separated in a lateral direction from the base well by a drift region having the HD collector region formed therein. The drift region has a lower dopant concentration relative to that of the HD collector region and of the base well and the emitter region, the drift region, and the HD collector region have a same polarity that is opposite to a polarity of the base well.

In another aspect, a bipolar junction transistor (BJT) formed in a substrate, the BJT comprises a base well, an emitter formed in the base well, a heavily doped (HD) collector region separated in a lateral direction from the base well by a drift region, and a thick dielectric layer disposed on a first lateral section of the drift region. The first lateral section is longer than 20% of a length of the drift region in the lateral direction, and the emitter region, drift region, and the HD collector region have a same polarity opposite to a polarity of the base well.

In another aspect, an integrated circuit (IC) device configured for voltage reduction between an input and an output, where the IC device comprises an isolated substrate region formed in a semiconductor substrate while being electrically isolated therefrom in vertical and lateral directions, the isolated substrate region having formed therein a plurality of alternatingly doped regions arranged laterally in a lateral direction and alternatingly doped with dopants of opposite types. The alternatingly doped regions comprises an input drift region and an output drift region each doped with a dopant of a first type, where the input drift region is connected to the input and the output drift region is connected to the output, an inter-gate region and a substrate region of the isolated substrate region each doped with a dopant of a second type, where the inter-gate region is laterally interposed between the input and output drift regions. The heavily doped first gate region formed within the inter-gate region where the input drift region is elongated to have a first lateral length along the lateral direction that is longer than a second lateral length of the inter-gate region by at least a factor of two.

In another aspect, an integrated circuit (IC) device configured for voltage reduction between an input and an output where the IC device comprises an isolated substrate region formed in a substrate while being electrically isolated therefrom in vertical and lateral directions, the isolated substrate region having formed therein a plurality of alternatingly doped regions arranged laterally in a lateral direction and alternatingly doped with dopants of opposite types. The alternatingly doped regions comprises an input drift region and an output drift region each doped with a dopant of a first type, where the input drift region is connected to the input and the output drift region is connected to the output, and an inter-gate region and a substrate region of the isolated substrate region each doped with a dopant of a second type, where the inter-gate region is laterally interposed between the input and output drift regions. The inter-gate region has a dopant concentration that is lower than that of the input drift region, the output drift region and the substrate region, and a heavily doped first gate region formed within the inter-gate region.

In another aspect, an integrated circuit (IC) device configured for voltage reduction between an input and an output, where the IC device comprises an isolated substrate region formed in a substrate while being electrically isolated therefrom in vertical and lateral directions, the isolated substrate region having formed therein a plurality of alternatingly doped regions arranged laterally in a lateral direction and alternatingly doped with dopants of opposite types. The alternatingly doped regions comprise an input drift region and an output drift region each doped with a dopant of a first type, where the input drift region is connected to the input and the output drift region is connected to the output, an inter-gate region and a substrate region of the isolated substrate region each doped with a dopant of a second type. The inter-gate region is laterally interposed between the input and output drift regions. Additionally the integrated circuit (IC) device comprises a dielectric layer covering the input drift region and at least one conductive field plate extending above the dielectric layer along the lateral direction, and a heavily doped (HD) first gate region formed within the inter-gate region.

In another aspect, an integrated circuit (IC) device comprises at least one low voltage active semiconductor device formed in a first substrate region of a semiconductor substrate; and a depletion field effect potential divider (DFE-PD) formed in a second substrate region of the semiconductor substrate and configured to reduce a high voltage input signal received from a high voltage node to generate a low voltage output signal, and to provide the low voltage output signal to the low voltage active semiconductor device as an input signal thereto. The low voltage active semiconductor device and the DFE-PD are physically separated while being electrically connected in series, and the first and the second substrate regions are electrically separated by an isolation structure.

In another aspect, an integrated circuit (IC) device, comprises at least one low voltage active semiconductor device formed in a first substrate region of a semiconductor substrate; and a depletion field effect potential divider (DFE-PD) formed in a second substrate region of the semiconductor substrate and configured to reduce a high voltage input signal received from a high voltage node to generate a low voltage output signal, and to provide the low voltage output signal to the low voltage active semiconductor device as an input signal thereto. The DFE-PD comprises a plurality of alternatingly doped regions arranged laterally in a lateral direction and alternatingly doped with dopants of opposite types. The alternatingly doped regions comprises an input drift region and an output drift region each doped with a dopant of a first type, where the input drift region is connected to the input and the output drift region is connected to the output, and an inter-gate region laterally interposed between the input and output drift regions, where the inter-gate region and the second substrate region are doped with a dopant of a second type, and a heavily doped first gate region formed within the inter-gate region.

In another aspect, an integrated circuit (IC) device, comprises at least one low voltage active device formed in a semiconductor substrate; and a depletion field effect potential divider (DFE-PD) formed above a major surface of the semiconductor substrate and separated therefrom by a dielectric layer, the DFE-PD configured to scale a high voltage input signal received from a high voltage node to a low voltage output signal, and to provide a low voltage signal to the low voltage active device as an input signal thereto. The DFE-PD comprises a doped semiconductor region extending along a lateral direction parallel to the major surface of the substrate between a heavily doped (HD) input region and a heavily doped (HD) output region, and a depletion control region formed within the doped semiconductor region and oppositely doped relatively to a remainder of the doped semiconductor region where the DFE-PD and the low voltage active device are electrically connected by an electrical connection.

In another aspect, an integrated circuit (IC) device, comprises at least one low voltage active device formed in a semiconductor substrate; and a depletion field effect potential divider (DFE-PD) formed above a major surface of the semiconductor substrate and separated therefrom by a dielectric layer, the DFE-PD configured to scale a high voltage input signal received from a high voltage node to a low voltage output signal, and to provide a low voltage signal to the low voltage active device as an input signal thereto. The DFE-PD comprises a doped semiconductor region laterally extending along a lateral direction parallel to the major surface of the substrate between a heavily doped (HD) input region that receives the low voltage output signal and a heavily doped (HD) output region that outputs the low voltage signal. Additionally, The DFE-PD comprises a depletion control region formed within the doped semiconductor region and oppositely doped relatively to a remainder of the doped semiconductor region, and at least one conductive field plate laterally extending over the doped semiconductor region and electrically connected to the low voltage active device by an electrical connection formed at least partly above the semiconductor substrate.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. Moreover, those in skilled in the art will understand that the drawings are not to scale. Wherever possible, like elements have been indicated by identical numbers. The detailed description of embodiments and the embodiments set forth in the drawings present various descriptions of specific embodiments of the invention. However, the invention can be embodied in a multitude of different ways. It will be understood that certain embodiments can include more elements than illustrated in a drawing and/or a subset of the elements illustrated in a drawing. Further, some embodiments can incorporate any suitable combination of features from two or more drawings. The present disclosure is not limited to specific methods and apparatus disclosed herein.

Embodiments of the present disclosure will now be described, by way of example only, with reference to the following patent diagrams wherein:

FIG. 1A schematically illustrates a multi-die electronic platform that includes bipolar, CMOS, and DMOS devices mounted as multiple dies on a single substrate.

FIG. 1B is a block diagram illustrating the monolithically integrated BCDMOS (or superset) design concept.

FIG. 2 schematically illustrates a side cross-sectional view of a bipolar-CMOS (BiCMOS) integrated circuit (IC) in accordance with certain embodiments disclosed herein.

FIG. 3A schematically illustrates a side cross-sectional view of an MOS transistor with extended drain drift region and field plates.

FIG. 3B schematically illustrates a side cross-sectional view of a lateral bipolar junction transistor (BJT) with extended drift region and field plates, in accordance with certain embodiments disclosed herein.

FIG. 4A schematically illustrates a side cross-sectional view of a MOS transistor with extended drain region and close up views of the source region (left) and the extended drain region (right).

FIG. 4B schematically illustrates a side cross-sectional view of a lateral bipolar junction transistor (L-BJT) with an extended drift region and close up views of the base/emitter regions (left) and extended collector region (right), in accordance with certain embodiments disclosed herein.

FIG. 5A schematically illustrates a side cross-sectional view of a laterally isolated potential divider (PD) electrically connected to a MOSFET in accordance with certain embodiments disclosed herein.

FIG. 5B schematically illustrates a side cross-sectional view of a laterally isolated PD electrically connected to a vertical bipolar junction transistor (V-BJT) in accordance with certain embodiments disclosed herein.

FIG. 5C schematically illustrates a side cross-sectional view of a laterally isolated potential divider electrically connected to a lateral bipolar junction transistor (L-BJT) in accordance with certain embodiments disclosed herein.

FIG. 6A schematically illustrates a three dimensional (3D) view of a vertically isolated PD in accordance with certain embodiments disclosed herein.

FIG. 6B schematically illustrates a 3D view of a PD fabricated in the backend-of-the-line (BEOL) of an IC with respect to a substrate that includes BCDMOS devices electrically connected to the PD.

FIG. 7A schematically illustrates a side cross-sectional view of an example L-BJT in accordance with certain embodiments disclosed herein.

FIG. 7B schematically illustrates a side cross-sectional view of a MOS transistor.

FIG. 7C schematically illustrates a side cross-sectional view of another disclosed embodiment of L-BJT.

FIG. 7D schematically illustrates a side cross-sectional view of an LDMOS transistor.

FIG. 8A schematically illustrates a 3D view of another disclosed embodiment of L-BJT.

FIG. 8B schematically illustrates a top view of the L-BJT shown in FIG. 8A.

FIG. 8C schematically illustrates a side cross-sectional view of another embodiment of L-BJT.

FIG. 8D schematically illustrates a top view of the L-BJT shown in FIG. 8C.

FIG. 9A schematically illustrates a side cross-sectional view of an L-BJT having a dedicated base spacer in accordance with certain embodiments disclosed herein.

FIG. 9B schematically illustrates a side cross-sectional view of an L-BJT having an elongated emitter region in accordance with certain embodiments disclosed herein.

FIG. 9C schematically illustrates a side cross-sectional view of an L-BJT having a vertical emitter section in accordance with certain embodiments disclosed herein.

FIG. 9D schematically illustrates a side cross-sectional view of an L-BJT having an elongated emitter region and a vertical emitter section in accordance with certain embodiments disclosed herein.

FIG. 9E schematically illustrates a side cross-sectional view a vertically and laterally isolated L-BJT in accordance with certain embodiments disclosed herein.

FIG. 9F schematically illustrates a side cross-sectional view of an L-BJT having a thermally diffused base region in accordance with certain embodiments disclosed herein.

FIGS. 10A-10E schematically illustrate selected fabrication steps for fabricating an L-BJT in accordance with certain embodiments disclosed herein.

FIG. 10F schematically illustrates a fabrication step for fabricating an L-BJT having an elongated emitter region in accordance with certain embodiments disclosed herein.

FIGS. 11A-11E schematically illustrate selected fabrication steps for fabricating an L-BJT in accordance with certain other embodiments disclosed herein.

FIG. 11F schematically illustrates a fabrication step for fabricating an L-BJT having an elongated emitter region in accordance with certain other embodiments disclosed herein.

FIGS. 12A-12C schematically illustrate selected fabrication steps for fabricating an L-BJT having a vertical emitter section in accordance with certain embodiments disclosed herein.

FIGS. 12D-12F schematically illustrate selected fabrication steps for fabricating an L-BJT having a vertical emitter section region in accordance with certain other embodiments disclosed herein.

FIGS. 13A-13E schematically illustrate selected fabrication steps for fabricating an L-BJT having a thermally diffused base region in accordance with certain embodiments disclosed herein.

FIGS. 14A-14E schematically illustrate selected fabrication steps for fabricating an L-BJT having a thermally diffused base region in accordance with certain embodiments disclosed herein.

FIG. 15A schematically illustrates a cross-sectional view of the L-BJT shown in FIG. 9D and variation of the voltage and electric field along its drift region.

FIG. 15B schematically illustrates a cross-sectional view of the L-BJT shown in FIG. 7C and variation of the voltage and electric field along its drift region.

FIG. 16A schematically illustrates a cross-sectional view of an embodiment of an L-BJT having an extended drift region with three field plates, and a schematic dopant profile thereof.

FIG. 16B schematically illustrates a cross-sectional view of the L-BJT shown in FIG. 16A and variation of the electric field along its extended drift region.

FIG. 16C schematically illustrates a cross-sectional view of an L-BJT having an extended drift region with four field plates thereover, and variation of the voltage and electric field along its extended drift region.

FIG. 17 schematically illustrates a graph illustrating approximate operating voltages supported by several L-BJT designs as a function of the length of the corresponding drift regions.

FIG. 18 schematically illustrates a side cross-sectional view of an L-BJT having an extended drift region that is fully isolated using a buried oxide layer and trench isolation.

FIG. 19 schematically illustrates a side cross-sectional view an L-BJT with isolated extended drift region fully isolated using trench isolation.

FIG. 20 schematically illustrates the depletion region of the L-BJT shown in FIG. 19 at three different magnitudes of input voltages.

FIG. 21 schematically illustrates an L-BJT with an extended drift region and vertically separated drift region extension.

FIG. 22A schematically illustrates a cross-sectional view of a semiconductor device structure configured for voltage reduction with output saturation, and the corresponding voltage transfer function in an open ended output configuration.

FIG. 22B schematically illustrates a cross-sectional view of another semiconductor device structure configured for voltage reduction, without output saturation and with slope change, and the corresponding voltage transfer function in an open ended output configuration.

FIG. 22C schematically illustrates a cross-sectional view of another semiconductor device structure configured for linear or near linear voltage reduction with non-zero punch-through voltage, and the corresponding voltage transfer function in an open ended output configuration.

FIG. 22D schematically illustrates a cross-sectional view of another semiconductor device structure configured for linear or near linear voltage reduction with zero punch-through voltage, and the corresponding voltage transfer function in an open ended output configuration.

FIG. 22C schematically illustrates a cross-sectional view of another semiconductor device structure for voltage reduction with, non-zero punch-through voltage, and the corresponding voltage transfer function in an open ended output configuration.

FIGS. 23A-23B schematically illustrate voltage transformation through an inter-gate region and the distribution and evolution of electric charge and electric field in the inter-gate region.

FIGS. 24A-24B schematically illustrate a long (A) and a short (B) inter-gate region showing the impact of the length an inter-gate region on the slope of the corresponding voltage transformation.

FIG. 25A schematically illustrates a cross-sectional view of a depletion field effect potential divider (DFE-PD) with an extended drift region.

FIG. 25B is plot of voltage variation along the DFE-PD shown in FIG. 25A for various values of the input voltage.

FIG. 26A is plot of output voltage generated by a DFE-PD as a function of the input voltage provided to DFE-PD.

FIG. 26B is plot of output current per unit length for a DFE-PD as a function of the input voltage provided to DFE-PD.

FIG. 27A schematically illustrates a cross-sectional view of a DFE-PD with a gate region on the input side.

FIG. 27B schematically illustrates a cross-sectional view of a DFE-PD with a gate region on the input side and the output side.

FIG. 28A schematically illustrates a side cross-sectional view of a DFE-PD having field plates on input region fabricated on a substrate and voltage variation along the DFE-PD for several values of the input voltage.

FIG. 28B is plot of output voltage generated by a DFE-PD as a function of the input voltage provided to DFE-PD.

FIG. 28C is plot of output current per unit length for a DFE-PD as a function of the input voltage provided to DFE-PD.

FIG. 28D schematically illustrates the evolution of the depletion regions in the drift, depletion control, and output regions of the DFE-PD shown in FIG. 28A, as a function of input voltage.

FIG. 29 schematically illustrates a side cross-sectional view of another DFE-PD having field plates on input and output regions.

FIG. 30A schematically illustrates a cross-sectional view of a laterally isolated DFE-PD electrically connected to a lateral bipolar junction transistor (L-BJT) in accordance with certain embodiments disclosed herein.

FIG. 30B schematically illustrates a cross-sectional view of a laterally isolated DFE-PD electrically connected to a MOS transistor in accordance with certain embodiments disclosed herein.

FIG. 31 schematically illustrates a cross-sectional view of an example high voltage device including electrical connections between a DFE-PD and an L-BJT, fabricated on a common substrate, where the DFE-PD and the L-BJT are electrically connected, while being laterally isolated from each other and vertically isolated from the substrate by a buried dielectric layer.

FIG. 32 schematically illustrates a cross-sectional view of an example high voltage device including electrical connections between a DFE-PD and an L-BJT, fabricated on a common substrate, where the DFE-PD and L-BJT are electrically connected, while being laterally isolated from each other and vertically isolated and confined by a buried dielectric layer.

FIG. 33 schematically illustrates a cross-sectional view of an example high voltage device including a DFE-PD that is vertically separated from the substrate and directly connected to an L-BJT.

FIG. 34 schematically illustrates a cross-sectional view of an example high voltage device including a DFE-PD that is vertically separated from the substrate and is electrically connected to an L-BJT via conductive lines.

FIG. 35 schematically illustrates a cross-sectional view of an example high voltage device including a DFE-PD that is laterally and vertically isolated from the substrate and is electrically connected to an L-BJT via conductive lines.

FIG. 36 schematically illustrates a cross-sectional view of another example high voltage device including a DFE-PD that is vertically isolated from the substrate and is electrically connected to an L-BJT via conductive lines.

FIG. 37 schematically illustrates a cross-sectional view of another example high voltage device including a DFE-PD that is vertically isolated from the substrate and is electrically connected to one or more MOS transistors and BJTs via conductive lines.

FIG. 38A-38B illustrate an equivalent circuit to a DFE-PD.

### DETAILED DESCRIPTION

### Introduction: Overview of BDCMOS Process Architecture Platform

Different types of semiconductor devices with distinct characteristics and uses include bipolar, complementary metal oxide (CMOS), and double diffused MOS (DMOS) devices. For example, bipolar devices (e.g., bipolar transistors) can provide precise and high speed analog functionalities, CMOS devices can provide high speed and high density digital functionalities, and DMOS devices can support high power and high-voltage operations. Conventional high performance bipolar and CMOS devices operate at relatively low voltages (<5 Volts) while DMOS devices can operate at high voltage (up to 400 Volts). Many applications can benefit from functionalities provided by a monolithically fabricated circuit or device that includes a combination of these devices integrated and interconnected on a single substrate (or chip). An integrated circuit (IC) device that includes a combination of monolithically fabricated bipolar junction device and CMOS devices may be referred to as a BiCMOS device or platform. In some cases, a BiCMOS device or platform that include MOS and DMOS transistors or low and high voltage CMOS devices, may be referred to as a bipolar-CMOS-DMOS (BCDMOS) device or platform.

However, because bipolar, CMOS, and DMOS devices employ different structural features and design rules, and may need to operate at different voltage levels, fabrication (e.g., monolithic fabrication) of a BiCMOS or BCDMOS device on a common substrate, or a monolithic circuit having BCDMOS devices on a single chip, can be relatively difficult, inefficient, and costly. For example, when CMOS fabrication techniques are used for co-fabricating CMOS transistors (also referred to as MOS transistors) and BJTs having conventional designs, one or both of the BJT and MOS transistor may lose their technical and/or cost competitiveness in order to be co-fabricated on the same platform and using same or substantially the same fabrication processes.

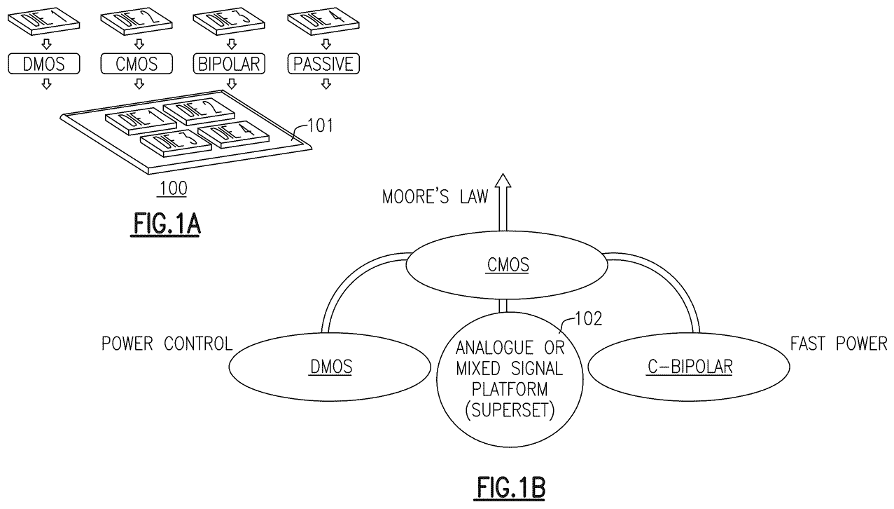

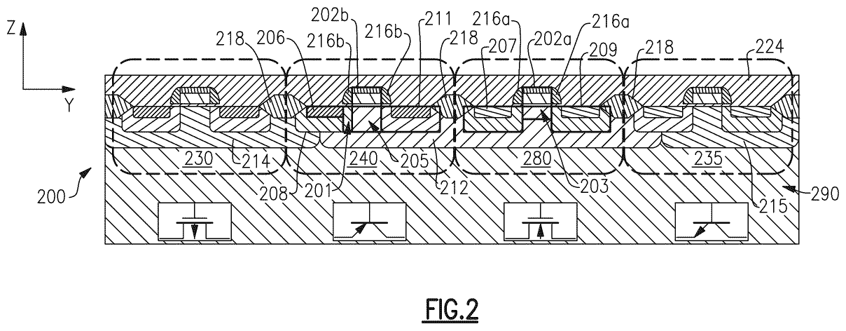

To avoid the complexities associated with monolithic BiCMOS or BCDMOS platforms, some conventional BCDMOS devices are formed by connecting bipolar, CMOS, and DMOS devices fabricated on separate chips (or dies). FIG. 1A illustrates an example traditional approach to fabricating BCDMOS devices, which includes a multi-die solution, where different devices are fabricated on separate substrates and combined into a single package or multi-die platform 100. In many existing fabrication methods, the bipolar devices, the CMOS devices, and the DMOS devices are fabricated on separate dies using different fabrication techniques and then mounted (e.g., surface bonded or soldered) on a common substrate 101. However, such approach can suffer from many disadvantages, including high cost, high package, hi complexity, inefficient area integration, multi-site manufacturing, and sometime low reliability complexity, to name a few. On the other hand, because these different devices can employ very different physical design rules and thermal budgets among other differences, integrating these devices on the same substrate can involve little synergy and lead to unacceptably long fabrication times.

Fabricating BCDMOS devices on a single chip where different devices are fabricated (e.g., monolithically fabricated) on the same semiconductor substrate, can offer advantages such as reduced area footprint, reduced fabrication cost, and large scale integration, among others, if substantial process steps can be synergized between different ones of the bipolar devices, the CMOS devices, and the DMOS devices. FIG. 1B is a block diagram illustrating the concept of monolithically fabricating an analog or mixed analog and digital platform (herein referred to as a superset 102) comprising at least three transistor having distinct functionalities (e.g., high gain, fast switching, high voltage operation, fast power and/or voltage control, and the like). The superset 102 can control electronic signals (e.g., digital and analog signals) within a wide voltage and power ranges. In some implementations, the transistor technologies may include DMOS, and CMOS, and Complimentary Bipolar (C-Bipolar) transistors. The superset 102 design concept combines various distinctive features and advantages of the different types of devices, including the high switching speed and density (number of devices per unit area) of CMOS transistors (e.g., field effect transistors or FETs), the fast analog power control supported by bipolar junction transistors (BJTs), and the high power and high voltage handling capabilities of DMOS transistors. For example, a CMOS transistor may operate between 3 and 125 Volts, a DMOS transistor may operate between 12 and 225 Volts, and a C-Bipolar transistors may operate between 3 and 36 Volts. However, because the different devices including CMOS, DMOS and bipolar devices are fabricated using very different process technologies, such strategy can still be time and cost inefficient due to, e.g., high lithography mask counts and slow factory cycle time. In addition, the process architectures and process flows that are engineered for one application, e.g., with unique voltage nodes, can be highly unadaptable for other applications.

In principle, the superset 102 can fabricated using currently available or commercialized BCDMOS fabrication platforms or a combination of BCDMOS and JFET fabrication platforms. However, fabrication of such superset based on both technologies may suffer from high fabrication cost, long cycle time, high mask count, and lithography limits among other disadvantages. While combining the existing JFET platforms with BCDMOS platforms may improve the performance of the devices used in the superset 102 (including bipolar devices), it can unavoidably disadvantageously increase the cost, cycle time, and mask count among other disadvantages, compared to BCDMOS.

While combining DMOS devices with bipolar devices on a single platform may enable high voltage (e.g., >10 Volts) operation of a BCDMOS device, many applications can benefit from or may require high voltage operation of a bipolar device (e.g., a BJT that can handle voltages above 10 Volts, 100 Volts, or even 200 Volts). However, the tradeoff between device features associated with high voltage, high gain (e.g., >100), high speed (e.g., >1 GHz), and linearity (among other parameters), imposes a limit on transistor designs (e.g., BJT designs) that can control high voltage signals at high speeds. Moreover, modifying a low voltage device for high voltage operation while keeping its overall size within an acceptable limit for large scale integration can be very challenging.

In recognition of these and other challenges with existing BDCMOS fabrication technologies, the disclosed technology provides efficient and synergistic monolithic integration of high performance and high voltage BCDMOS devices, and potential dividers that can be combined with low-voltage devices to enable processing and controlling low and high voltage signals on a single monolithically fabricated circuit. Some of the inventive devices and design methods described herein include, without limitation:
low-voltage (LV) lateral (or lateral) bipolar devices (e.g., BJTs) that can be fabricated using established tools, techniques, and concepts developed for CMOS-based devices and thereby can be monolithically fabricated with CMOS devices (e.g., MOSFETs).
Design concepts for can increase the operating voltage of LV lateral bipolar devices using established techniques and concepts developed for DCMOS-based devices and other methods.
Physically dividing low voltage (5V or less)/high performance regions and high voltage (5-400V) regions of BCDMOS process architectures to design BCDMOS devices having a high voltage region physical electrically separated from a low voltage region.
Depletion field effect (DFE) potential dividers (PDs) that can be connected in series with one or more low voltage to create high voltage devices. The DFE PDs can be fabricated using established tools, techniques, and concepts developed for CMOS-based devices and thereby can be monolithically fabricated with BCDMOS devices.
On-chip isolation structures and designs for electrically isolating high voltage and low voltage devices monolithically fabricated on a same substrate.

Various inventive aspects disclosed herein may comprise a purposeful construction of a bipolar device (e.g. a lateral BJT), where at least one feature of the bipolar device has substantially the same physical dimension as a corresponding feature of a MOS device, e.g., because the corresponding features are co-fabricated using masks or process steps that are developed for the same or similar technology node or design rule.

In various conventional BiCMOS process, BJT's are fabricated vertically to allow control over various device parameters, e.g., the vertical doping profile and the base dimensions (e.g., width and/or thickness of a base region). Such approach requires separate fabrication steps, and masks for fabricating BJTs and MOS transistors on a common substrate and significantly increases the cost, complexity, and cycle time of an IC device.

Disclosed herein is a first inventive aspect directed to a BiCMOS core process architecture that facilitates the construction of a high performance, low cost, low voltage, and fast factory cycle time BiCMOS technology platform using existing digital cell libraries and fabrication processes established for CMOS devices. Some of the device designs (e.g., lateral bipolar device designs) described herein can synergistically benefit from fabrication steps used in CMOS fabrication technologies using the same ingredients and elements. As such, bipolar device designs disclosed herein may enable exploiting the precision of CMOS processing, which has been under development for several decades, for fabrication of high performance bipolar devices (e.g., bipolar transistors). In some implementations, the disclosed bipolar devices (e.g., lateral bipolar junction transistors), can be co-fabricated with CMOS devices (e.g., MOS filed effect transistors) through a co-fabrication or parallel fabrication process flows in which one or more fabrication steps may be shared at least partly contemporaneously or simultaneously. In some implementations, the disclosed bipolar devices (e.g., lateral BJTs), can substantially be entirely fabricated independently of the MOS devices, but can still benefit from the accuracy, low cost, and reduced cycle time offered by well-developed and advanced CMOS fabrication techniques.

An example of BiCMOS platform is an IC device comprising a metal-oxide-semiconductor (MOS) transistor (e.g., a MOS field effect transistor or MOSFET) comprising a gate stack formed over a channel region thereof and a bipolar junction transistor (BJT) comprising a layer stack formed over a collector region thereof. The MOS and bipolar transistors of the disclosed IC device are constructed using some common CMOS process features. As a result, various features of the bipolar devices (e.g., BJTs) are defined using structural features and process steps used for fabricating the MOS devices (e.g., MOSFETs). In some embodiments, implantations for forming lightly and/or highly doped regions of the source and drain regions, the gate region, and the channel region of a CMOS device (e.g., a MOSFET), are used to form the emitter, the base, the collector regions of a bipolar device (e.g., a BJT). As described herein, highly or heavily doped (HD) regions, sometimes denoted as P⁺⁺ regions or N⁺⁺ regions, can have a peak doping concentration exceeding about 1×10¹⁹ cm⁻³, exceeding about 1×10²⁰ cm⁻³, or a value in a range defined by any of these values. In addition, lightly doped (LD) regions, sometimes denoted as N⁻ or P⁻ regions, can have a peak doping concentration lower than about 1×10¹⁴ cm⁻³ or about 1×10¹³ cm⁻³. In some cases, a highly or heavily doped (HD) region (e.g., a P⁺⁺ or N⁺⁺) may comprise an ohmic contact region that provides electrical connection to a region (e.g., for example a region in which the HD region is formed). For example, spacers formed on a sidewalls of the gate stack of a MOSFET, used to define a lightly-doped (LD) drain (LDD) region, is used to define the base length (L_{B}) of a BJT. In addition, gate contact layers (e.g., silicide layers) and gate layers (e.g., polycrystalline silicon layers) that form the gate stacks of CMOS devices, are used to form field plates, e.g., reduced surface field (RESURF) plates, for a bipolar device (e.g., for increasing its operating voltage). One or both of the spacers and the field plates can advantageously also serve as implant hard masks, as described below.

An example of a disclosed bipolar device that can be co-fabricated with a CMOS device is a lateral BJT (L-BJT) having an emitter region, a base region, and a collector region that are arranged in a lateral direction parallel to a main surface of a common substrate on which a MOS transistor (e.g., a MOSFET) is fabricated. An L-BJT may comprise a PNP (or NPN) transistor having laterally formed PN (or NP) and NP (or PN) junctions configured to support bipolar transistor operation based on bipolar carrier transport substantially in the lateral direction (path of the bipolar current is substantially in the lateral direction). The L-BJT arrangement results in several corresponding features between the two types of devices and allows for enhanced parallel processing of various fabrication steps between the MOSFET and the BJT. As a result, replacing the conventional vertical BJT design with L-BJT can reduce cycle time by significantly improving the synergy between CMOS and BJT fabrication process flows.

Some examples of the correspondence between the features are shown in FIG. 2. FIG. 2 illustrates a portion of an integrated circuit (IC) device 200 fabricated using a low voltage, high performance BiCMOS architecture and process flow according to embodiments. The IC device 200 can include or both of a PNP lateral bipolar junction transistor (PNP L-BJT) 240 and an n-channel MOS (NMOS) transistor 280 fabricated according to a low voltage, high performance BiCMOS process architecture according to embodiments. The IC 200 can additionally include one or both of a p-channel MOS (PMOS) transistor 230 and an NPN L-BJT 235. The PMOS transistor 230 has analogous features as the NMOS transistor 280 but with regions comprising opposite polarity types of semiconductors regions compared to corresponding regions of the n-channel NMOS transistor 280. Similarly, the NPN L-BJT 235 has analogous features as the PNP L-BJT 240 but with regions comprising opposite polarity types of semiconductors regions compared to corresponding regions of the PNP L-BJT 240. The wells (e.g., the common well 212) in which the MOS transistors 230, 280, and the L-BJTs 240 and 235 are formed, may be generated in a substrate 290 (e.g., a silicon substrate).

It will be appreciated that, as described herein, while some features may be described in reference to a particular type of MOS transistor (e.g., one of NMOS transistor 280 or PMOS transistor 235), it will be understood that analogous features, where applicable, may be present in the opposite type of MOS transistor (e.g., the other of NMOS transistor 280 or PMOS transistor 235). Similarly, while some features may be described in reference to a particular type of BJT (e.g., one of PNP L-BJT 240 or NPN L-BJT 235), it will be understood that analogous features, where applicable, may be present in the opposite type of BJT (e.g., the other of one of PNP L-BJT 240 or NPN L-BJT 235).

In some embodiments, the NMOS transistor 280 can be a field effect (FET) transistor comprising a drain region 209, a source region 207, and a gate stack 202a formed over a channel region 203 between the drain region 209 and the source region 207. The gate stack 202a includes a gate dielectric and a gate. Additionally, the NMOS transistor 280 may comprise gate spacers 216a disposed on opposing sidewalls of the gate stack 202a.

In some implementations, the PNP L-BJT 240 may comprise an emitter region 206, a base region base 201, a collector region 211, and a layer stack 202b formed over a portion of the collector region 211 thereof. The emitter region 206 has a first polarity or semiconductor type (e.g., p-type) and is formed in a base well 208 having a second polarity or semiconductor type (e.g., n-type) opposite to the first polarity or semiconductor type.

According to various embodiments described herein, source and drain regions (e.g., source and drain regions 207, 209) of a MOS transistor (e.g., NMOS transistor 280) may include heavily doped regions. In addition, emitter and collector regions (e.g., emitter region 206 and the collector region 211) of an L-BJT may be heavily doped region.

It should be understood, as used herein, polarity of a region (e.g., a semiconductor region) is determined by the polarity of the majority charge carrier in that region, which can in turn be defined by the net doping. So in a p-type region, the net doping is positive such that the majority charge carriers are holes, and in an n-type region, the net doping is negative such that the majority charge carriers are electrons. The majority carriers in a region is a charge carrier whose concentration is greater than that of the opposite charge carrier in that region, or larger than its intrinsic concentration in the absence of doping and the same temperature. As such a p-type region can have p-type dopant and n-type dopant, but the p-type dopant is present at a larger concentration than that of the n-type dopant, resulting in a larger hole concentration compared to electron concentration in that region.

In some cases, the emitter region 206 may have a higher doping concentration than the base well 208 and the base region 201. Additionally, the PNP L-BJT 240 may comprise spacers 216b disposed on the sidewalls of the layer stack 202b. In some embodiments, the layer stack 202b may serve as a reduced surface field (RESURF) plate that reduces a lateral component of the E-filed in a drift region 205 of the collector region 211. The layer stack 202b may include a dielectric layer on the substrate and a conducting layer on the dielectric layer. The emitter region 206, the base region base 201, and the collector region 211 are arrange laterally (e.g., along y-axis), such that the bipolar operation of the PNP L-BJT 240 is mainly associated with the carrier transport in the lateral direction. As a result, the base region 201 may comprise a region of the base well 208 having a lateral extension from the collector region 211 to the emitter region 206, and the base length (L_{B}) can be defined by a lateral distance from a vertical interface (e.g., along z-axis) between the base well 201 and the collector region 211, and a vertical interface between the emitter region 206 and the base well 208 closer to the collector region 211 (herein referred to as vertical emitter-base junction). Advantageously, in some embodiments, the base length (L_{B}), which can significantly affect the performance of the PNP L-BJT 240, is defined by a lateral width of a bottom or base portion of the spacers 216b (e.g., the spacer or spacer portion above the base region 201), which is in turn defined by the spacer fabrication process. Given that the dimensions of the spacers 216b (and the corresponding spacers 216a) can be accurately defined using standard CMOS fabrication processes, the base length of the PNP L-BJT 240 can be precisely controlled (or defined) by the co-fabrication process. Thus, the design and structure of an L-BJT not only enables its co-fabrication with MOS transistors on a common substrate, but also enables precise control over its base length (e.g., with a resolution of +5 nm, +3 nm, +1 nm, or sun-nanometer). Such level of control over the base length is close to that of the vertical BJTs used in conventional BiCMOS platforms that require dedicated fabrication processes that cannot be synergistically combined with the MOS transistor fabrication process. In some cases, the base length may be defined by a lateral width of a bottom portion of a spacer. The space may be formed by depositing a polysilicon layer and vertically etching the polysilicon layer to provide desired bottom thickness. As such the width of a bottom portion of the spacer (and thereby the base length) may be precisely defined by controlling the polysilicon thickness (by controlling its growth time) and the etching time.

In some examples, the entire structure of an L-BJT (base well and emitter region therein, layer stack, and the collector region) may be fabricated in and/or on a common well. In some other examples, such as PNP L-BJT 240, an L-BJT may be partially formed in a common well 212 and a second region (e.g., a second well) 214 comprising a semiconductor having opposite dopant types, and/or an opposite polarity compared to the common well 212. In such examples, the common well 212 and the second region 214 may have an interface under the base well 208 such that a first portion of the base well 208 shares an interface with the common well 210 and a second portion of the base well 208 shares an interface with the second well. In some cases, a vertical interface between the common well 212 and the second region 214 can be aligned with the vertical emitter-base junction of the PNP L-BJT 240. In some cases, the PNP L-BJT 240 may include a highly doped (HD) base region (not shown) disposed on the base well 208 to provide an ohmic contact to the base well 208 and the base region 201 therein.

Still referring to FIG. 2, in the example shown, the NMOS transistor 280 and the MOS transistor 230 are fabricated in the common well 212 and a second well 214, respectively. The PNP L-BJT 240 is partially fabricated in the common well 212 and the second well 214, and the NPN L-BJT 235 is fabricated in third well 215 and the common well 212. The second well 214 and the third well 215 have the same polarity (e.g., n-type) and the common well 212 has a polarity opposite to that of the second well 214 and the third well 215.

According to various aspects, the MOS transistors 280, 230 and the L-BJTs 240, 235 are synergistically formed using various common structural features. As a result, the gate stack 202a of the NMOS transistor 280 and the layer stack 202b of the PNP L-BJT 240 have one or more corresponding layers having a common physical dimension or material. For example, one or both of the dielectric layer and the conducting layer of the layer stack 202b may be formed simultaneously or using the same process recipes, and consequently be formed of the same materials and have the same thicknesses as the corresponding ones of the gate dielectric and the gate of the gate stack 202a. Furthermore, in some embodiments, the gate stack 202a and the layer stack 202b may be patterned using a mask designed with similar design rules, such that one or more lateral dimensions of the gate stack 202a and the layer stack 202b may be substantially the same. In addition, the gate stack 202a of the MOS 280 transistor and the layer stack 202b of the PNP L-BJT 240 have corresponding spacer structures 216a, 216b formed on sidewalls thereof having a common physical dimension. Similar to the layer stack 202b, the spacer structures 216a, 216b may be formed simultaneously or using the same process recipes, and consequently be formed of the same materials and have the same physical dimensions. Furthermore, the NMOS transistor 280 and the PNP L-BJT 240 have corresponding implanted diffusion regions having a common implanted dopant profile, e.g., as a result of being formed simultaneously or using the same implant masks and/or recipes, and consequently have the same implant profile in one or more directions.

Advantageously, the lateral arrangement of the emitter region 206, the base region 201 and the collector region 211 in a direction parallel to a main surface of the common substrate 290 allows for enhanced simultaneous or parallel processing of and/or sharing process recipes between various steps between the MOS transistors 280, 230 and the L-BJTs 240, 235.

For example, patterning including lithography and etch for defining the gate stack 202a of the NMOS transistor 280 and the layer stack 202b of the PNP L-BJT 240 can be co-processed, i.e., simultaneously processed. As a result, according to embodiments, the layer stack 202b of the PNP L-BJT 240 over a collector region 211 thereof can have a dielectric layer that is co-deposited or co-formed by oxidation with and can have the same thickness as a gate dielectric of the NMOS transistor 280. Similarly, the layer stack 202b of the PNP L-BJT 240 has a conducting layer on a dielectric that is co-deposited with and can have the same thickness as a gate electrode on a gate dielectric of the NMOS transistor 280. After co-forming the layer stack 202b of the PNP L-BJT 240 and the gate stack 202a of the NMOS transistor 280, the layer stack 202b of the PNP L-BJT 240 and the gate stack 202a of the NMOS transistor 280 can be co-patterned using shared lithography and etch processes. In some cases, the layer stack 202b of the PNP L-BJT 240 and the gate stack 202a of the NMOS transistor 280 can correspond to a length of a drift region 205 of the BJT and a channel length of the MOS transistor in the first direction, respectively.

Thus patterned or co-patterned gate stack 202b and layer stack 202b can be used as hard masks for ion implants. For example, the corresponding regions can be co-implanted using the same energy and/or dose, and can further have substantially the same dopant profile. For example, using the gate stack 202b and layer stack 202b as patterning layers, which may further include patterning layers remaining thereover, e.g., photoresist or hard masks, lightly doped (LD) source and drain regions of the n-channel NMOS transistor 280 can be co-implanted with the base well 208 of the PNP L-BJT 240. Similarly, an LD source and drain regions of the p-channel MOS transistor 230 can be co-implanted with a base well of the NPN L-BJT 235.

After the LD implants, spacers 216a, 216b, can be co-formed on sidewalls of the gate stack 202a of the NMOS transistor 280 and the layer stack of the PNP L-BJT 240. As a result, a spacer 216b of the PNP L-BJT 240 and a spacer 216a of the NMOS transistor 280 can be formed by co-depositing a spacer layer, e.g., a nitride or oxide layer, and co-etched, e.g., anisotropically co-etched to have the same lateral dimension and define one or more implanted diffusion regions for the PNP L-BJT 240 and the NMOS transistor 280 that have the same type of implant and, in some cases, a common implanted dopant profile.

Using the spacer 216b of the PNP L-BJT 240 and the spacer 216a of the NMOS transistor 280 that have been co-formed, an emitter region 206 of the PNP L-BJT 240 and source and drain (S/D) regions 207, 209 of the MOS transistor can be defined by co-implantation. The NMOS transistor 280 is an n-channel MOSFET and PNP L-BJT 240 is a PNP BJT so the S/D regions are 207, 209 and the emitter region 206 can be n-doped, e.g., co-implanted with an n-type dopant. Similarly, the S/D regions MOS transistor 230, which is an p-channel MOSFET, and the emitter region of the NPN L-BJT 235, which is an NPN BJT, are p-doped, e.g., co-implanted with a p-type dopant.

In addition, prior to forming the gate stacks (e.g., the gate stack 202a) and the layer stacks (e.g., the layer stack 202b), a common patterning layer can be used to define, by co-implantation processes, the collector regions of the BJTs and the channel regions of the MOS transistors. When the channel region is a p-doped well region (e.g., the channel region 203) of a n-channel MOS transistor (e.g., the NMOS transistor 280), it may be co-implanted with a p-type collector region (e.g., the collector region 211) of a PNP L-BJT (e.g., the PNP L-BJT 240). Similarly, when the channel region is an n-doped well region of a p-channel MOS transistor (e.g., the PMOS transistor 230), it may be co-implanted with n-type collector region of a NPN L-BJT (e.g., the NPN L-BJT 235).

Further regions of the highly doped (HD) and lightly doped (LD) collector regions of the L-BJTs can be defined by co-implantation with the corresponding HD and LD implants in the S/D regions of the MOS transistors. For a PNP L-BJT (e.g., PNP L-BJT 240), the p-type collector region (e.g., the collector region 211) comprises an HD region that is co-implanted with p-doped S/D regions of a p-channel MOS transistor (e.g., the MOS transistor 230) and the p-type emitter region 206 of the PNP. For an NPN L-BJT (e.g., the NPN L-BJT 235), the n-type collector region comprises an HD region that is co-implanted with n-doped S/D regions of an n-channel MOS transistor (e.g., NMOS transistor 280) and an n-type emitter region of the NPN L-BJT 235).

For the PNP L-BJT (e.g., the PNP L-BJT 240), the p-type collector region 211 comprises an LD doped region that is co-implanted with a p-doped LD S/D regions a p-channel MOS transistor (e.g., the MOS transistor 230) and a p-type base well of an NPN L-BJT (e.g., the NPN L-BJT 235). Similarly, for the NPN L-BJT (e.g., the NPN L-BJT 235), the n-type collector region comprises an LD doped region that is co-implanted with a n-doped LD S/D regions of an n-channel MOS transistor (e.g., the NMOS transistor 280) and a n-type base well (e.g., the base well 208 and the base region 201 therein) of an PNP L-BJT (e.g., the PNP L-BJT 240).

In the above, various corresponding structures of CMOS and L-BJT devices have been described as advantageously being adapted for co-fabrication according to embodiments, e.g., simultaneously fabricated. However, embodiments are not so limited, and the corresponding structures can be fabricated sequentially. Even when sequentially fabricated, it will be appreciated that, because of shared design rules, various process recipes, e.g., deposition, etch and implant recipes, can be synergistically used for fabricating the corresponding structures in CMOS and L-BJT devices.

Mos Transistor and L-BJT with Extended Drain and Drift Regions

As described above the design and structures described above may be used to co-fabricate L-BJTs with MOS transistors (MOSFETs) for a BiCMOS platform. In some cases, these L-BJTs may be low voltage (LV) BJTs having a maximum operating voltages less than 5 Volts. As such, the operating voltage of BiCMOS circuits fabricated based on conventional MOS transistors (e.g., MOSFETs) and the disclosed L-BJTs, may be limited while for some applications MOSFETs and BJTs operating at higher voltages (e.g., larger than 10 Volts, 100 Volts, 200 Volts, or 300 Volts) and co-fabricated on a common substrate may be desired.

To address these and other needs, a second inventive aspect described herein is directed to elevating the operating voltage of a bipolar junction device (e.g., a lateral BJT) co-fabricated with MOS transistor on a common substrate, e.g., by increasing the length of at least one drift region of the bipolar junction device. Similarly, the operating voltage of the MOS transistor (e.g., a MOSFET) may be elevated to a higher voltage range (e.g., 5-400V) by increasing the length of a channel region of the MOS transistor. In some implementations, the drift region of an L-BJT may be extended along a lateral direction, parallel to the common substrate, from an LD collector region to a base region of the L-BJT Similarly, the channel region of the MOS transistor may be extended along the lateral direction from an LD source region to an LD drain region. In some cases, including an extended gate stack over the channel region of a MOSFET, and/or an extended layer stack over the drift region of an L-BJT may further increase the operating voltage of a device, by maintaining a magnitude of a lateral component of an E-field constant along the drift or channel region.

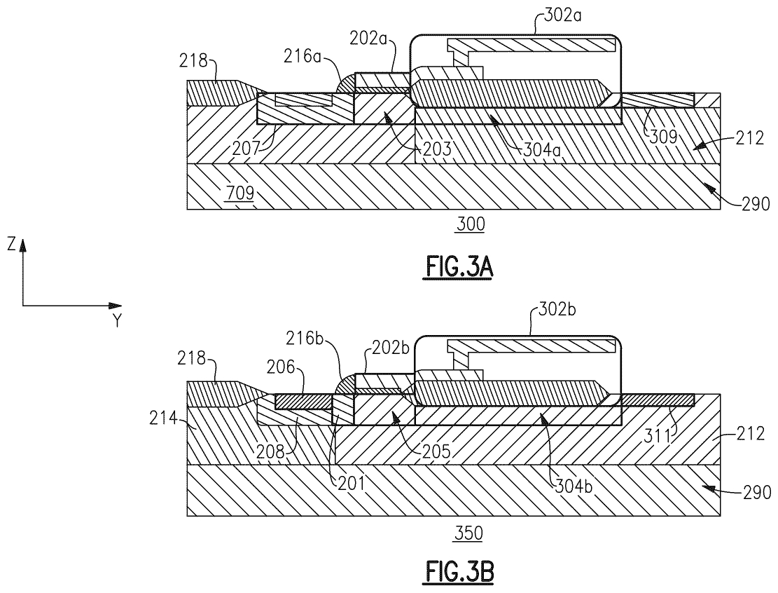

FIG. 3A schematically illustrates a side cross-sectional view of a high voltage (HV) MOSFET 300 having an extended drain region and an extended gate stack. The extended drain region comprises the channel region 203 and an extended drain region 304a. The extended gate stack comprises the gate stack 202a and a gate stack extension section 302a. Similar to MOSFET 280, the HV MOSFET 300 includes a source region 207, and a drain region 309. In some examples, the drain region 309 of the HV MOSFET 300 includes a highly doped region while the drain region 209 of the MOSFET 280 may include a highly doped and a lightly doped region.

FIG. 3B schematically illustrates a side cross-sectional view of a high voltage (HV) L-BJT 350 having an extended drift region and an extended layer stack. The extended drift region comprises the drift region 205 and a drift region extension 304b. The extended layer stack comprises the layer stack 202b and a layer stack extension section 302b. Similar to the PNP L-BJT 240, the HV L-BJT 350 includes an emitter region 206 and a base region 201 at one end of the extended drift region, and a collector region 311 at the other end of the extended drift region closer to the layer stack extension 302b. In some examples, the collector region 311 of the HV L-BJT 350 includes a highly doped region while the collector region 211 of the MOSFET 240 may include a highly doped and a lightly doped region.

In some implementations, the HV L-BJT 350 is co-fabricated with the MOSFET 300 on a common substrate 290. Advantageously, the longer drift, channel, layer stack, and gate stacks of the HV MOSFET 300 and the HV BJT 350 make their maximum operating voltage larger than the corresponding MOSFET 280 and the PNP L-BJT 240. A voltage applied on the HD drain region of the HV MOSFET 300 or the HD collector region of the HV L-BJT 350, may drop along the extended drain region and drift region, respectively. In some cases, the voltage can drop by at least 50% from the HD drain region of the HV MOSFET 300 and the HD collector region of the HV L-BJT 350 to the source region 209 and base region 201, respectively.

As used herein, a maximum operating voltage (also referred to as break down voltage) of a MOS device (e.g., a MOSFET) or a bipolar device (e.g., an L-BJT) can be a voltage above which at least one junction and/or at least one dielectric layer within the device electrically breaks down, e.g., under a reverse bias.

The HV MOSFET 300 and the HV L-BJT 350 may comprise one or more features described above with respect to the NMOS transistor 280 and the PNP L-BJT 240. As such, in some examples, one or more regions, and/or layers of the HV MOSFET 300 may be co-fabricated with the corresponding regions, and/or layers of the HV L-BJT 350 and have the same or substantially identical physical dimensions. Additionally, one or both of the extended layer stack of the HV L-BJT 350 and the extended gate stack of the HV MOSFET 300, may have the same physical dimensions and may be co-fabricated during the same fabrication step(s).

In some embodiments, at least one structure, one dimension or one doping profile of the L-BJT designs described above, may be different from those of the corresponding feature in a MOS transistor co-fabricated with the L-BJT. As a result, at least one fabrication step of the L-BJT may be a dedicated fabrication step that is not associated with a fabrication of a corresponding feature in the MOS transistor. A dedicated fabrication step may include but it is not limited to forming or doping a region (e.g., diffusing a dopant), etching a structure (e.g., a spacer), disposing a layer, and the like.

### Potential Divider

A third inventive aspect of the disclosed technology is elevating the low voltage BiCMOS platform to a higher voltage node through the use of a high voltage (HV) potential divider. This inventive aspect arises from the inventors' recognition that high voltage devices based on a BCDMOS process platform, e.g., the MOS and bipolar devices having extended drift and channel regions described above, can be conceptually divided into two regions. In some cases, a first region of the device is designed to operate at a low voltage (e.g., less than 5 Volts) and a second region of the device, which may be physically separated or at least partly isolated from the first region, is designed to provide a voltage drop from a higher voltage (e.g., 5-400 Volts) to a safe voltage level that can be applied on the first region. In some examples, the first region may include a high performance and low voltage channel portion of a MOS device (e.g., a MOSFET), or a high performance and low voltage emitter-base region of a bipolar device (e.g., an L-BJT). The second region may include an extended drift region or extended drain region that translates a high voltage provided to the HD drain region or the HD collector region into a low voltage near the source region or for base region of a MOS transistor or LBJT respectively.

In recognition of this conceptual divide between low voltage/high performance (5V or less) regions and voltage drop regions of BCDMOS process architectures, inventive aspects include a BCDMOS process architecture that can support a broad range of voltages by physically dividing the a MOS or bipolar device into a first region that supports a high performance at a low voltage and a second region that includes a potential divider (PD) that can be electrically connected or wired in series with any one of the low voltage regions or components to create a high voltage device. Both regions can be fabricated using a low cost and fast cycle time bipolar-CMOS (BiCMOS) core process and platform on the same substrate, examples of which have been described above.

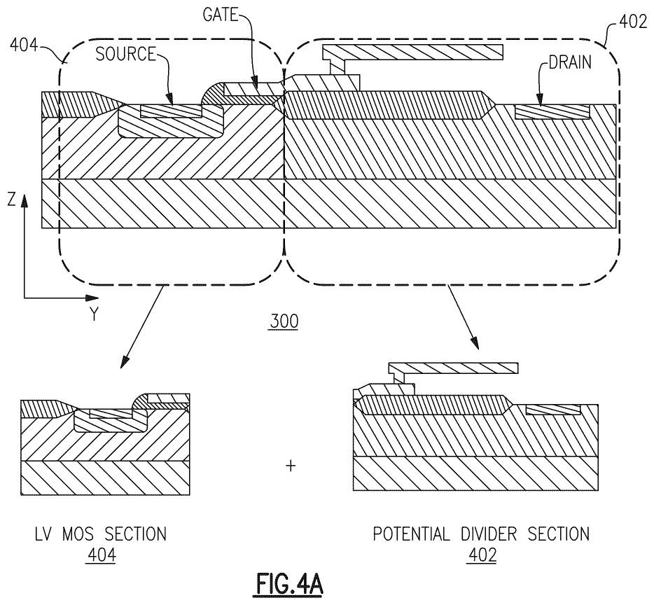

FIG. 4A schematically illustrates a side cross-sectional view of the HV MOSFET 300 with an extended drain region. A first region 404 of the HV MOSFET 300 may be a low voltage MOS section comprising the source region 207 and at a least a portion of the gate stack 202a. A second region 402 of the HV MOSFET 300 may be a PD section comprising the extended drain region and the drain region 209. FIG. 4B schematically illustrates a side cross-sectional view of the lateral bipolar junction transistor (L-BJT) 350 with extended drift region. A first region 454 of the HV L-BJT 350 maybe a low voltage bipolar section comprising the emitter and base regions and at a least a portion of the layer stack. A second region 452 of the HV L-BJT 350 may be a PD section comprising the extended drift region and the collector region.

While the operating voltage of a MOS or bipolar device can be increased (e.g., above 5 Volts) by increasing the length of a channel or drift regions, applying a high voltage on a region of an integrated device that is physically close to a region designed to handle a lower level of voltage (e.g., the first region 404 or 454), may lower the reliability of the device. For example, certain parasitic effects may couple a portion of the high voltage to the first region 404 (or first region 454) of the HV MOSFET 300 (or L-BJT 350) and cause a junction or dielectric breakdown in the first region 404 (or the first region 454). Correct

In some embodiments, physically separating the first regions 404, 454 (the low voltage sections) from the corresponding second regions 402, 452 (the potential divider sections) may improve the reliability of the corresponding device, e.g., by reducing the probability of a breakdown caused by parasitic voltage coupling between the low voltage and potential divider sections. Additionally, physically separating the first regions 404, 454 (the low voltage sections) from the corresponding second regions 402, 452 (the potential divider sections) may prevent the minority carriers generated through weak impact ionization from attacking the delicate gate oxide. Additionally, physical separation between the low voltage and potential divider sections of MOS and bipolar devices may allow using a potential divider section for coupling multiple devices of the same or different types. For example, a potential divider may receive a high voltage and provide a reduced voltage to two or more devices comprising L-BJTs and MOSFETS.

In various implementations, physical separation may comprise reducing an/or limiting electric, magnetic, or electromagnetic coupling between the first and the second regions with isolation (herein referred to as isolation). As such, physical separation can include providing a distance and/or an isolating element, layer, or structure between a low voltage section and a PD section of a device. The distance may include a lateral distance, a vertical distance, or a combination thereof. In some cases, a physical separation that provides sufficient isolation for reducing the risk of breakdown in the low voltage section, may translate to a distance that significantly increases the overall size of the device or the corresponding circuit. As such, in some implementations, one or more low voltage device sections or low voltage substrate regions may be isolated from one or more potential divider sections using one or more isolating elements, layers, or structures.

In some cases, the PD section may comprise a region of the substrate (herein referred to as PD substrate region) physically separated from a region of the substrate that includes an L-BJT and/or a MOSFET. The L-BJT comprises a collector region electrically connected to a PD substrate region in series and physically separated therefrom by an isolation structure. In some embodiments, the L-BJT further comprises a layer stack comprising a conductive field plate formed over the collector region. In some other embodiments, the collector region and the PD substrate region are electrically connected through one or more metallization levels formed above a major surface of the common semiconductor substrate. In some other embodiments, the PD substrate region is configured to drop>50% of a voltage applied across the BJT and the PD substrate region. According to embodiments, the PD substrate region, which is formed in the same common substrate but physically separated from LV regions including L-BJT and CMOS devices, may be isolated from the LV regions by one or more isolation structures, e.g., dielectric isolation structures including deep or shallow trenches filled with a dielectric material (e.g., an oxide such as silica) and/or junction or well isolation structures.

Still referring to FIGS. 4A and 4B, in some embodiments, the PD section (second regions 402, 452) described above, in the context of BJTs or MOSFETs with extended drain and drift regions, may be designed and optimized as a standalone PD device. Connecting a low voltage (LV) device or platform in series with such PD device can scale up the operating voltage of the platform without changing the structure of the device or the platform. In some cases, the PD device may be physically separated from the platform or the LV device similar according to the principles described above with respect to physical separation between the first and second regions of the HV MOSFET 300 and HV BJT 350, or the PD substrate region from a LV substrate region.

In some cases, the platform or device may include an integrated circuit (IC) device. According to various aspects, the IC device comprises a metal-oxide-semiconductor (MOS) transistor and a bipolar junction transistor (BJT) formed in a common semiconductor substrate. The PD device can be connected in series with one or more low voltage devices to provide various high voltage MOS and bipolar devices (e.g., HV DMOS, HV BJT, HV MOS, and the like). This gives the BiCMOS core process technology the ability to accommodate a broad range of application voltage nodes with relatively small or no extra cost or redesign of various device structures used for fabricating these devices.

A fourth inventive aspect is development and optimization of a versatile PD device that can be fabricated using CMOS process. In various implementations The PD device may include an input port, region, or electrode that receives a high voltage (e.g., 5-400 V), an output port, region, or electrode, that outputs a low voltage (e.g., 0-5V) and is configured to be connected to an LV device. As such the PD device is connected in series between a device that provides a high voltage signal and the LV device. In some examples, the PD includes one or more RESURF electrodes or connections configured to be connected to ground potential or the stable low potential of the LV platform or the device to which the PD provides the reduced voltage.

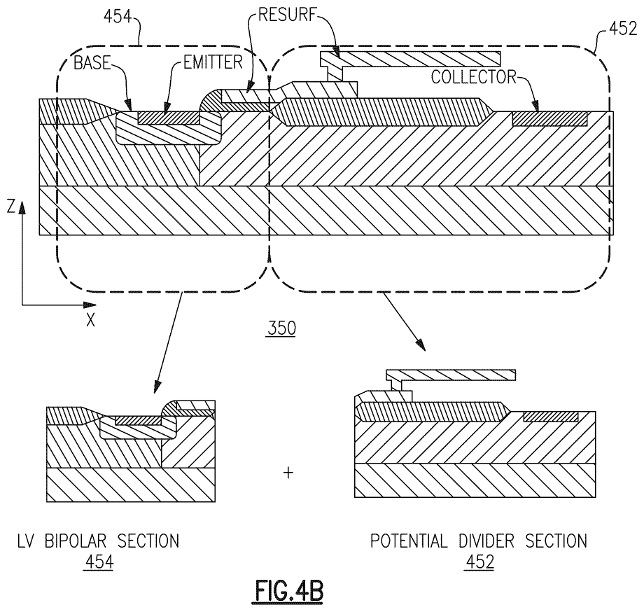

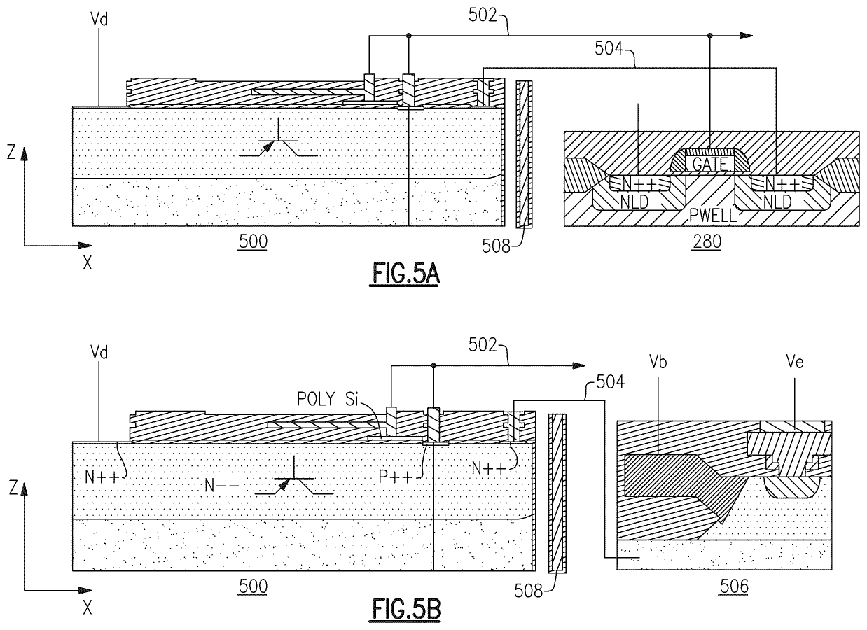

FIGS. 5A-5C illustrate example embodiments directed to MOS and bipolar junction devices connected to a potential divider (PD) 500. FIG. 5A schematically illustrates an isolated PD 500 connected to the NMOS transistor 280. The RESURF electrodes of the PD 500 are electrically connected to the gate stack of the NMOS transistor 280 and the output port of the PD 500 is electrically connected to the HD drain region of the NMOS transistor 280.

FIG. 5B schematically illustrates an isolated PD 500 connected to a vertical bipolar junction transistor (V-BJT) 506. The output port of the PD 500 is electrically connected to the collector region of the V-BJT 506. The RESURF electrodes of the PD 500 are electrically connected to the highest opposing potential, i.e., for an N-type device, a positive voltage would be applied to the PD and the resurf electrodes would be connected to the lowest potential (e.g., ground potential). In some cases, the RESURF electrodes of the PD 500 can be connected to an independent voltage source.

FIG. 5C schematically illustrates an isolated PD 500 connected to the lateral bipolar junction transistor (L-BJT) 240. The RESURF electrodes of the PD 500 are electrically connected to the layer stack of the PNP L-BJT 240 and the output port of the PD 500 is electrically connected to the HD collector region of the PNP L-BJT 240.

In various implementations an electrical connection 502 between the RESURF electrodes of the PD 500 and a gate stack, layer stack, of an LV device, and an electrical connection 504 between the output port of the PD 500 and a collector or drain region of the LV device, may comprise a connection through conductive lines in a metallization layer of an IC, which includes the PD 500 and the corresponding LV device. For example, the RESURF electrode and the output port of the PD 500 and the corresponding regions of the LV device can be connected to a common conductive line in a metalized layer above the PD 500 and the LV device, using two or more conductive vias.

When the LV device is an L-BJT (FIG. 5C), various synergistic parallel processing with MOS transistors can be performed, including definition of gate stack of the MOS transistor and the layer stack of the BJT, definition of the spacers of the MOS transistor and the BJT and the associated implanted diffusion and definition of various implanted diffusion regions. The details of the synergistic processing have been described above, and not repeated herein for brevity.

In certain embodiments described herein, the PD device can be a depletion field effect potential divider (DFE-PD) that monotonically (e.g., substantially linearly) drops the voltage from a higher input voltage at a first node (an input node) to a lower voltage at a second node (an output node). Thus, the semiconductor device is suitable for analog signal translation. The PD includes individually doped silicon regions (for example, four regions, or in certain implementations five or more regions) arranged to form a reverse biased depletion junction (first junction) at the input node and a different junction (second junction) at the output node. Charge is coupled from the first junction to the second junction to serve as a potential divider, with the ratio of charge coupling defining the ratio of the voltage scaling. In certain implementations, the full extent of the scaling can range from a direct one-to-one voltage translation to a situation in which the output voltage is independent of the input voltage, and can be fixed to be a substantially constant value.

Devices employing the above-described voltage reduction schemes can be implemented into various electronic devices. Examples of electronic devices include, but are not limited to, industrial automation/control systems, military and aerospace systems, security and surveillance systems, building technology, instrumentation and measurement systems, power management systems, data acquisition systems, radio frequency communication systems, consumer electronic products, electronic test equipment, communication infrastructure, radar systems, mobile devices (for instance, smartphones or handsets), phased array antenna systems, laptop computers, tablets, and/or wearable electronics.

### Vertical Isolation of the Potential Divider

A fifth inventive aspect includes architectures, designs, and structures for isolating the PD device (e.g., the DFE-PD) or the PD section from the LV devices or LV device sections fed by the PD device. These architectures, designs, and structures can reduce cost, complexity, and/or cycle time for fabricating high voltage BCDMOS platforms, facilitate connecting the PD device to multiple HV devices in the same or different IC layers, and/or enable inclusion of high bandgap materials in the structure of the PD device.

In some implementations, the PD device or region can be formed in the front end of line (FEOL) in the same silicon substrate according to some embodiments. In these embodiments, the BiCMOS devices can be isolated from the HV potential divider by an isolation structure such as shallow trench isolation (STI). As shown in FIGS. 5A-5C, such isolation scheme may include lateral isolation of the PD device (or a PD substrate region) from an LV device (or an LV substrate region) using a lateral isolation structure. The lateral isolation structure may comprise a trench filled with a dielectric material (e.g., silicon dioxide). In some cases, the trench can be a deep trench extended from a metalized layer, through which the PD device or section is connected to the LV devices, to a common substrate on which the LV devices are formed. In some cases, the width of the trench may be determined by the magnitude of an input voltage level provided to the PD device. In some examples, multiple lateral isolation structures may be provided at different locations in an IC to isolate the PD device from different lateral directions. In some cases, a lateral distance of the lateral isolation structure from the PD device and the LV device may be determined by the width of a trench and an input voltage level provided to the PD device.

In some embodiments, for modest voltage ranges (e.g., less than 50V) a junction boundary may be used for laterally isolation the PD device or section from the LV device or section. In some cases, the depletion with of the junction boundary (isolating junction) may be determined based on a magnitude of a voltage drop from an input node of the PD device or region to the LV device or region. In some cases, the depletion width of an isolating junction can be from 10 to 20 microns. When possible, using a junction boundary as an isolation structure (e.g., a lateral isolation structure) may reduce the fabrication cost of the IC. However, given that the depletion width of the junction boundary may scale with the magnitude of the voltage drop, this isolation scheme may consume more substrate space.

In alternative implementations, the potential divider can be formed in the backend of line (BEOL) above the substrate. In these embodiments, the BiCMOS devices can be vertically isolated from the PD by at least one intermetal or interlayer dielectric (IMD or ILD) layer, thereby obviating the need for lateral isolation at the higher voltage nodes.

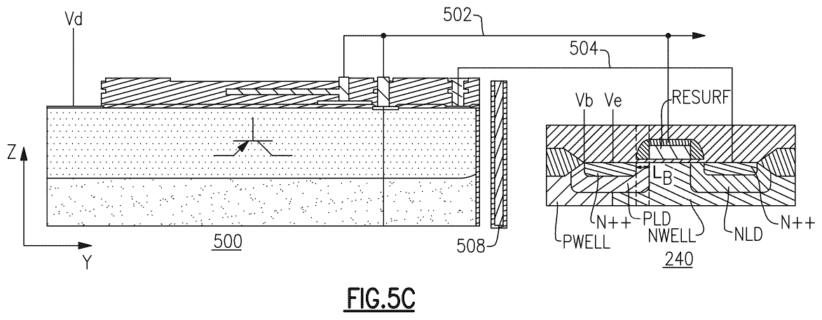

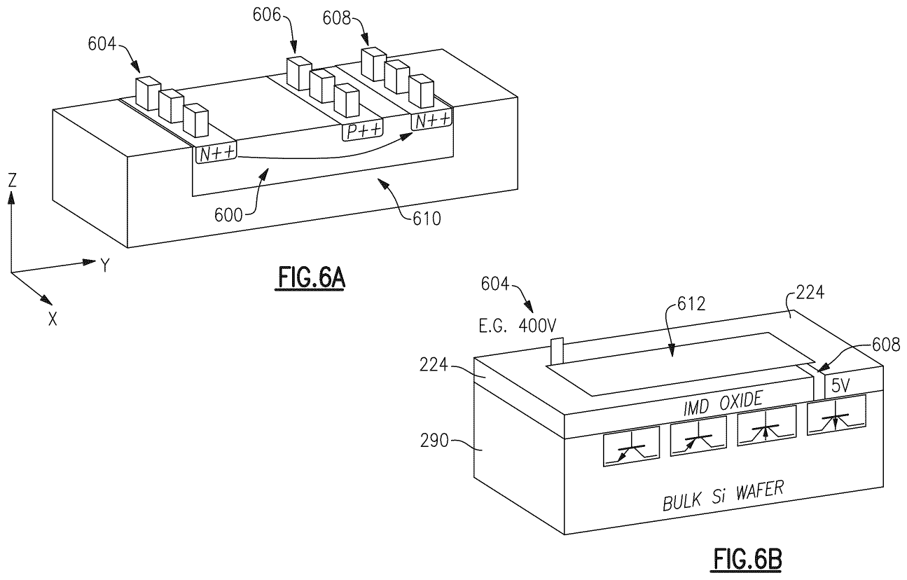

FIG. 6A schematically illustrates a vertically isolated PD 600 that may be fabricated above a substrate that includes the electronic devices that electrically connected to the PD 600 to receive a reduced voltage. Similar to the PD 500, the PD 600 includes one or more input electrodes 604, one or more RESURF electrodes 606, and one or more output electrodes 608. A dielectric structure 610 (e.g., an oxide structure), vertically isolates the PD 600 from the LV devices and regions below the dielectric structure 610. In some cases, the dielectric structure 610 may be the cladding dielectric layer 224 disposed over the substrate 290 of the corresponding IC. FIG. 6B schematically illustrates a potential divider 612 formed in the backend-of-the-line (BEOL) within the cladding dielectric layer 224. The PD 612 receives an input voltage (e.g., 5-400V) from an input electrode 604 and outputs a reduced voltage (0-5V) via the output electrode 608. The output electrode 608 can be connected to one or more input nodes or regions of the BCDMOS devices fabricated on the substrate 290.

In some implementations, vertical isolation of the PD 612 may facilitate forming one or more regions of the PD 612 using wide band gap materials. Advantageously a PD that includes a wide band gap material may improve the performance of the PD 612 to provide a better design trade-off for industry leading performance. For example, a PD device that includes a wide band gap material may reduce higher voltage levels (e.g., larger than 400 V) to a voltage level usable by LV devices.

By employing the low voltage and high performance BiCMOS devices and the PDs according to embodiments, a “superset” process architecture platform according to various embodiments may be realized. The process architecture platform according to embodiments can greatly reduce the number of masks and manufacturing cost, e.g., by as much as about 50%.

### Low Voltage, High Performance BiCMOS Process Architecture: Low Voltage-Lateral BJT

As described above, an inventive aspect of the disclosed technology is directed to a process architecture that facilitates the construction of a high performance, low cost, low voltage (5V or less), and fast cycle time BiCMOS technology platform using digital cell libraries used for fabricating CMOS devices. In a conventional BiCMOS process, BJTs are fabricated to have a vertical arrangement of emitter, base, and collector regions to allow control over vertical doping profile of each layer and in particular the base length, which in this case is a vertical distance between the junction between the base collector and the junction between the base and the emitter of the BJT. The vertical direction is a direction perpendicular to a main surface of a common substrate on which the BJT and the MOS devices are fabricated. Most fabrication steps required for fabricating a vertical BJT (V-BJT) cannot be synergistically combined with those of the MOS devices and thereby increase cost, complexity, and cycle time of a conventional BiCMOS platform compared to a CMOS platform.

In some cases, a lateral BJT (L-BJT) design uses a lateral arrangement of the emitter, base, and collector regions co-fabricated with corresponding features of MOS devices using CMOS fabrication techniques, to provide a high-performance bipolar junction device (e.g., a BJT). In some implementations, the disclosed L-BJT designs include regions with similar physical dimensions, dopants, doping profiles, doping regions, spacers, layer stacks, and other features corresponding to the same or similar features in a MOS transistor (e.g., MOSFET), providing maximum synergy between CMOS and L-BJT fabrication processes. As such, cycle time, cost, and complexity of fabricating a BiCMOS platform based on L-BJTs can be significantly reduced with respect to a BiCMOS platform fabricated based on V-BJTs.

Advantageously, the L-BJT designs described above and with more details below, provide synergy with CMOS fabrication without trading the high performance desired for a BJT on the BiCMOS platform. For example, since the base length of the L-BJT is defined using the spacer structures and the corresponding processing steps tailored and optimized over several decades in the context of MOS fabrication, very thin base regions may be fabricated with high precision to provide high gain. In other words, the structure of the L-BJT can be tailored with high precision based on features and fabrication steps of a MOS transistor, not only to provide synergy between the corresponding fabrication steps, but also to utilize the precision of the MOS fabrication process to improve the performance of BJTs in BiCMOS platforms.

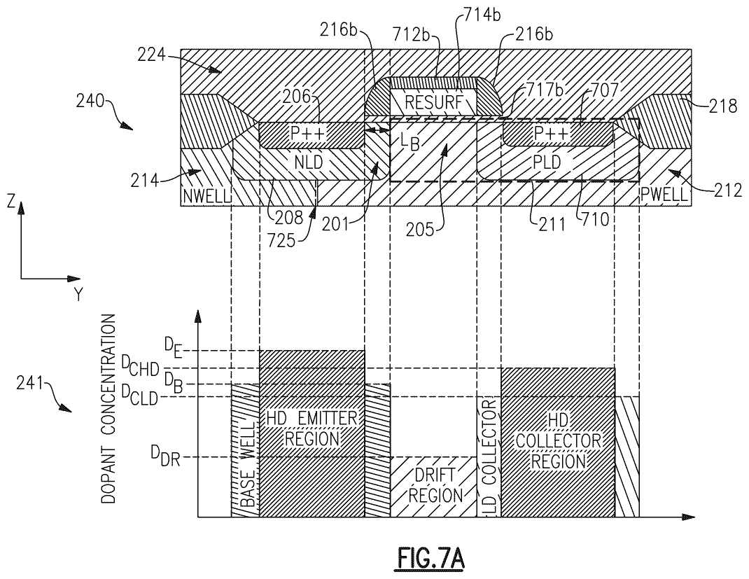

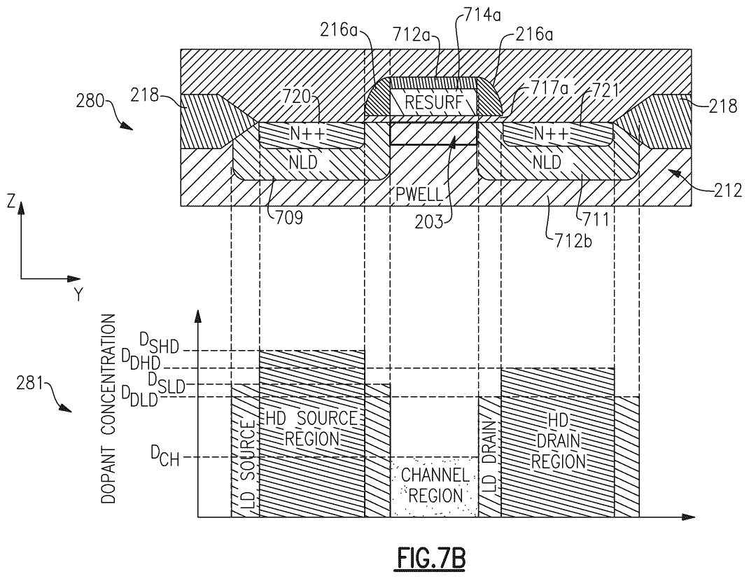

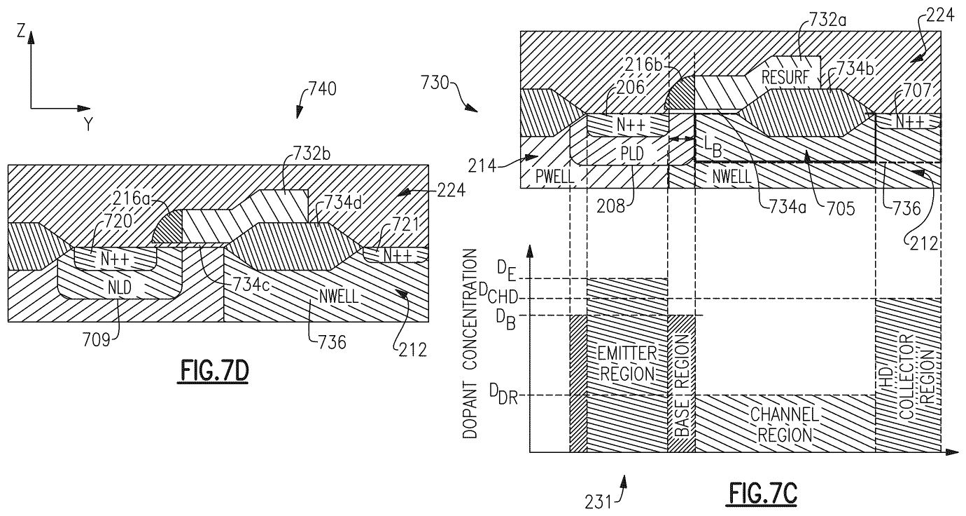

FIG. 7A illustrates a cross-sectional view of the PNP L-BJT 240 (previously described in FIG. 2) and a corresponding schematic dopant concentration distribution 241. In some implementations, the PNP L-BJT 240 may comprise an emitter region 206, a base region 201, a collector region 211, and a layer stack formed over a portion of the collector region 211. The emitter region 206 comprises a highly doped (HD) semiconductor material having a first polarity or semiconductor type (e.g., p-type or n-type) and is formed in a lightly doped (LD) base well 208 having a second polarity or semiconductor type opposite to the first polarity or semiconductor type. In some cases, the HD emitter region 206 and the LD base well 208 may comprise the same semiconductor material doped with dopants of opposite types (n-type and p-type). The collector region 211, may comprise a drift region 205, an HD collector region 707, and at least a portion of the LD collector region 710. In some examples, the collector region 211, the LD collector region 710 are formed a common well 212. The HD and LD collector regions 707, 710, and the common well 212 may comprise a same type (p-type or n-type) of semiconductor material. In some embodiments, the layer stack may comprise a reduced surface field (RESURF) dielectric layer 717b (e.g., an oxide layer such as silica), a RESURF layer 714b disposed on the RESURF dielectric layer 717b, and a RESURF contact layer 712b disposed on the RESURF layer 714b. Additionally, the PNP L-BJT 240 may comprise spacers 716b, disposed on the sidewalls of the stack layer. The RESURF layer 714b, the RESURF contact layer 712b, and the base and collector spacers 216b, may comprise different types of materials. The layer stack may be disposed on of the drift region 205 of the BJT 240.

As described above, the layer stack may be configured as a RESURF layer stack to maintain a magnitude of the lateral electric field component along the drift region 205 constant, and thereby increase the operating voltage of the PNP L-BJT 240. Equivalently, the layer stack may allow increasing a doping concentration of the drift region without reducing the operating voltage of the PNP L-BJT 240. In some cases, the RESURF layer 714b can be maintained at a RESURF potential by connecting the contact layer 714b to voltage source providing the RESURF potential. The RESURF potential can be a potential less than a potential of the HD collector region 707 (also referred to as collector potential). In some cases, the RESURF potential can be close or substantially equal to a potential of the emitter region 206. In some cases, the RESURF potential is substantially equal to the ground potential. In some cases, the operating voltage of the L-BJT may increase proportional to a difference between the RESURF potential and the collector potential. Equivalently, for a given operating voltage, the doping concentration of the base region 201 and/or the drift region 205 may be increased proportional to a difference between the RESURF potential and the collector potential.

Including the layer stack in the structure of the L-BJT provides at least a three-fold advantage over conventional BJTs (e.g., V-BJTs) used in BiCMOS platforms, including: (1) enabling co-fabrication of the emitter region 206 of the PNP L-BJT 240 with the HD source region 720 of the NMOS transistor 280, and simultaneously forming the base region 201; (2) Increasing the operating voltage of the L-BJT or increasing the doping concentration of the base region 201 and/or drift region 205; and (3) fabricating high gain L-BJT having precisely defined short base length.

In some examples, the entire structure of an L-BJT may be formed in a common well. In some other examples, such as PNP L-BJT 240, an L-BJT may be partially formed in a common well and a second region (e.g., a second well) comprising a semiconductor having opposite dopant types, and/or an opposite polarity compared to the common well. In such examples, the common well and the second region may have an interface under the base well 208 such that a first portion of the base well 208 shares an interface with the common well 212 and a second portion of the base well 208 shares an interface with the second well. In some cases, an electrical connection may be provided to the LD base region above the second well. In the example shown, the PNP L-BJT 240 is a PNP BJT having a p-type HD emitter region (P++) 206 formed in an n-type LD base well 208, and a p-type collector region comprising a p-type well 204 comprising HD and LD collector regions 207, 210, formed in the p-type well 204. As shown, in this example, the base LD region 208 is partially formed in the p-well (the common well) and an n-type well 202 that shares an interface with the p-well 204 under the LD base region.

The schematic dopant concentration distribution 241 shows relative doping levels in the PNP L-BJT 240 along the lateral direction (e.g., y-axis). A dopant concentration (D_{E}) in the emitter region can be larger than a dopant concentration (D_{B}) in the base region. A dopant concentration (D_{CHD}) in the HD collector region can be larger than a dopant concentration in the LD collector region (D_{CLD}). A dopant concentration (D_{DR}) in the drift region can be smaller than D_{B} and D_{CLD}. In some examples, D_{B} and D_{CLD} can be different or substantially equal. In some examples, D_{E} and D_{CHD} can be different or substantially equal. In some cases, D_{DR} can be from 5×10¹⁵ cm⁻³ to 5×10¹⁶ cm⁻³. D_{B} and can be from 10¹⁶ cm⁻³ to 10¹⁸ cm⁻³, and D_{E} and D_{CHD} can be larger than 10¹⁸ cm⁻³.

FIG. 7B schematically illustrates a side cross-sectional view of a NMOS transistor 280 and the corresponding dopant concentration distribution. In some embodiments, the NMOS transistor 280 can be a field effect (FET) transistor comprising a drain region, a source region, and a gate stack formed over a channel region 203 between the drain region and the source region. The source region may include a highly doped (HD) source region 220 formed in a common well 212. Similarly, the drain region of the MOSFET 280 may include a highly doped (HD) drain region 220 formed in a lightly doped drain region (LD) region 209, where the HD drain (or source) and LD drain (or source) regions comprise a semiconductor of the same type or polarity (n-type or p-type). The gate stack may comprise a gate dielectric layer 217a (e.g., an oxide layer), a gate layer 214a disposed on the gate dielectric layer 217a, and a gate contact layer 212a disposed on the gate layer 214a. Additionally, the NMOS transistor 280 may comprise gate spacers 216a disposed on the side walls of the gate stack. The gate layer 214a, the gate contact layer 212a, and the gate spacers 216a, each may comprise a different type of material.

In some cases, the HD and LD regions of the MOSFET 280 may comprise the same semiconductor materials (e.g., silicon) doped with the same dopant. The source and drain regions are formed in a well comprising a semiconductor doped with a dopant type opposite to that of the source and drain regions. In the example shown, the MOSFET 280 is an n-channel MOSFET having n-type drain and source regions formed in a p-type well, each comprising a n-type HD region (N⁺⁺) formed in an n-type LD region.

The dopant concentration distribution 281 shows relative doping concentration in the MOSFET 280 along the lateral direction (e.g., y-axis). A dopant concentration (D_{SHD}) in the HD source region can be larger than a dopant concentration (D_{SLD}) in the LD source region. Similarly, the dopant concentration (D_{DHD}) in the HD drain region can be larger than a dopant concentration (D_{DLD}) in the LD drain region. A dopant concentration (D_{CH}) in the channel region can be smaller than D_{DLD} and D_{SLD}. In some examples, D_{SHD} and D_{DHD} can be different or substantially equal. In some examples, D_{SLD} and D_{DLD} can be different or substantially equal. In some cases, D_{CH} can be from 5×10¹⁵ cm⁻³ to 5×10¹⁶ cm⁻³, D_{SLD} and D_{DLD} can be from 10¹⁶ cm⁻³ to 10¹⁸ cm⁻³, and D_{SHD} and D_{DHD} can be larger than 10¹⁸ cm⁻³.

In some implementations, with the exception of the layer stack and the gate stack, all the regions and wells of the PNP L-BJT 240 and the NMOS transistor 280 and the substrate 290 may comprise single crystalline silicon. The isolating dielectric layers 218, the gate dielectric layer, and the RESURF dielectric layer may comprise a dielectric layer (e.g., an oxide such as thermally grown or deposited silicon dioxide or other suitable dielectric layer such as a high K dielectric layer), the gate and RESURF layers may comprise polysilicon or a metal, and the gate and RESURF contact layers may comprise a silicide. In some implementations, isolating dielectric layers 218, may comprise oxide layers (e.g., silica layer) thermally grown on the surface of the substrate 290. In some other implementations, isolating dielectric layers 218, may comprise layers or regions (e.g., silica layers) fabricated by forming trenches in the substrate 290 and depositing the oxide material in the trench.

In various implementations, a highly doped (HD) region may have a doping concentration (concentration) from 10¹⁸ cm⁻³ to 10²⁰ cm⁻³, a lightly doped (LD) region may have a doping concentration (concentration) from 10¹⁶ cm⁻³ to 10¹⁸ cm⁻³, and a very lightly doped (VLD) region may have a doping concentration less than 10¹⁵ cm⁻³.

In some cases, the depth of the LD source region 709 and/or the base well 208 along a vertical direction (e.g., along z-axis) can be from 0.2 microns to 1.0 microns.

In some cases, the width of the LD source region 709 and/or the base well 208 along a lateral direction (e.g., along y-axis) can be from 0.18 microns to 2.0 microns.

In some cases, the depth of the LD drain region 711 and/or the LD collector region 710 along the vertical direction can be from 0.2 microns to 1.0 microns.

In some cases, the width of the LD drain region 711 and/or the LD collector region 710 along a lateral direction (e.g., along y-axis) can be from 0.18 microns to 2.0 microns.

In some cases, the depth of the HD source well 208 HD and/or the emitter region 206 along a vertical direction (e.g., along z-axis) can be from 0.1 microns to 0.2 microns.

In some cases, the width of the HD source well 208 and/or the HD emitter region 206 along a lateral direction (e.g., along y-axis) can be from 0.18 microns to 1.0 microns.

In some cases, the depth of the HD drain region 721 and/or the HD collector region 707 along the vertical direction can be from 0.1 microns to 0.2 microns.

In some cases, the width of the HD drain region 721 and/or the HD collector region 707 along a lateral direction (e.g., along y-axis) can be from 0.18 microns to 1.0 microns.

In some cases, a length of the channel region 203 and/or the drift region 205 along the lateral direction can be from 0.18 microns to 0.6 microns.

In some cases, a length of the RESURF layer 714b along the lateral direction (e.g., along y-axis) can be substantially equal to a length of the drift region along the lateral direction.

In some cases, the thickness of the gate layer 714a, and/or the RESURF layer 714b along a vertical direction (e.g., along z-axis) can be from 0.1 microns to 0.3 microns.

In some cases, the thickness of the gate contact layer 712a, and/or the RESURF layer 712b along a vertical direction (e.g., along z-axis) can be from 0.02 microns to 0.05 microns.

In some cases, the thickness of the gate dielectric layer 717a, and/or the RESURF dielectric layer 774b along a vertical direction (e.g., along z-axis) can be from 0.01 microns to 0.02 microns.

In some cases, a width of a bottom portion the spacers 216a and 216b (e.g., at the interface between the spaces 216a, 216b and the dielectric layers 217a, 217b, respectively), along a lateral direction can be from 0.05 microns to 0.15 microns.

In some cases, the length of the base region 201 (base length, L_{B}) extended from the drift region 205 to the HD emitter region 206 along a lateral direction (e.g., along y-axis), can be from 0.03 microns to 0.05 microns, from 0.05 microns to 0.07 microns, from 0.07 microns to 0.1 microns, from 0.1 microns to 0.13 microns, from 0.13 microns to 0.15 microns, from 0.15 microns to 0.17 microns, from 0.17 microns to 0.2 microns, or any value in range formed by these values.

In some implementations, the length of the base region 204 is substantially equal to the width of the bottom portion of the spacers 216a and 216b.

Still referring to FIGS. 7A and 7B, as the described above, the PNP L-BJT 240 and the NMOS transistor 280 can be fabricated on a common substrate by fabricating the regions and structures of the NMOS transistor 280 and the corresponding regions and structures of the PNP L-BJT 240, during same fabrication steps or same process recipes at different steps. For example, the gate stack and the spacers of one or more (MOS transistors) can be co-fabricated with the RESURF stack and the spacers 216b of the PNP L-BJT 240. Subsequently, the emitter region 206 of the PNP L-BJT 240 and the HD source regions of one or more a p-channel MOS transistors, which may be structurally identical to the n-channel NMOS transistor 280, can be co-fabricated. Advantageously, the latter fabrication step simultaneously forms of the base region 201 and the emitter region 206 of the PNP L-BJT 240.

In some examples, the gate stack of the NMOS transistor 280 and the layer stack of the PNP L-BJT 240 have at least one common physical dimension, as a result of being co-fabricated or using the same fabrication recipes. For example, the gate layer 714a may have at least one physical dimension in common with the RESURF layer 714b, and/or the gate contact layer 712a may have at least one physical dimension in common with the RESURF contact layer 712b. Similarly, the spacers 716b may have at least one physical dimension in common with the gate spacers 216a. Additionally, in some examples, the spacers may comprise the same material, the RESURF and the gate layers may comprise the same material, and the RESURF and the gate contact layers may comprise the same material.

In some cases, the LD base well 208 and the LD source region 709 may have at least one common dimension, the HD emitter region 206 and the HD drain region 721 may have at least one common dimension, and the HD source region 720 and the HD emitter region 206 may have at least one common dimension. In some examples, the LD regions and/or HD regions may comprise the same material with the same or different polarities.

In some embodiments, at least the LD collector region of an L-BJT, the LD drain region, and the LD source regions of a MOSFET may be formed in a single well (e.g., a common well). In some such cases, the HD and LD drain and source regions of the MOSFET may have a polarity and/or comprise a dopant type, different from those of the HD and LD collector regions and the HD emitter region of the L-BJT.

In some cases, the spacers 216b, and the spacers 216a may have substantially identical dimensions (e.g., within the tolerance of a corresponding fabrication process), the RESURF layer 714b and the gate layer 714a may have substantially identical dimensions, and/or the RESURF contact layer 712b and the gate contact layer 712a may have substantially identical dimensions.

In some cases, the LD base well 208 and the LD source region 709 may have substantially identical dimensions, and/or the HD emitter region 206 and the HD drain region 721 may have substantially identical dimensions.

In various implementations, the gate layer 714a, the RESURF layer 714b, the gate layer contact 712a, and the RESURF contact layer 714b may comprise one or more materials having conductivities larger than 10 Ω/sq, larger than 30 Ω/sq, larger than 50 Ω/sq, or larger than 70 Ω/sq. In some cases, the gate layer 714a, the RESURF layer 714b, the gate layer contact 712a, or the RESURF contact layer 714b may comprise doped polysilicon or silicide. The spacers may comprise a dielectric material (e.g., silica).

In various implementations, the NMOS transistor 280 and the PNP L-BJT 240 may be laterally extended between two isolating dielectric layers 218 (e.g., silica layers) grown or disposed on the substrate 290.

In some implementations, and the corresponding features of the MOSFET 280 and the PNP L-BJT 240 that have common physical dimensions may be co-fabricated during the same fabrication step(s) or using the same process recipe. As described with respect to FIG. 2, the HD emitter region 206, LD base well 208, the HD collector region 707 and LD 210 regions, the spacer 216b, the oxide layer 217b, the RESURF layer 214b, RESURF contact layer 212b of the BJT 240 are at least structurally similar to the HD source region 220, LD source region 209a, the drain HD 221 and LD 209b regions, the gate spacers 216a, the oxide layer 217, the GATE layer 214a, GATE contact layer 212a, respectively. However, unlike the HD 220 and LD source 209a source regions of the MOSFET 280, the HD emitter region 206 and the LD base well 208 are not of the same type. Despite this minor difference, these common features can be synergistically formed using same processing steps on a single substrate. In some cases, one or more regions or layers of the PNP L-BJT 240 and NMOS transistor 280 may have common physical dimensions, common doping profiles, or common material layers. For example, the layer stack 202b (the RESURF layer 214b and the RESURF contact 212b) of the PNP L-BJT 240, the layer stack of the NPN L-BJT 235, the gate stack 202a (the gate layer 214a and the gate contact layer 212a) of the NMOS transistor 280, and the gate stack of the PMOS transistor 230 may have one or more common physical dimensions including the thickness and/or comprise layers having a common material. Furthermore, the HD and LD collector regions of the NPN L-BJT 235 may have corresponding implanted diffusion regions having common implanted regions with the HD and LD drain regions 721, 720, and 709, 711 of the NMOS transistor 280.

In some implementations, D_{SLD} and D_{B} can be substantially equal, D_{DLD} and D_{CLD} can be substantially equal, D_{SHD} and D_{B} can be substantially equal, D_{DHD} and D_{CHD} can be substantially equal, and/or D_{CH} and D_{DR} can be substantially equal. In some cases, D_{DR} for PNP L-BJT 240 can be larger than D_{CH} for NMOS transistor 280.

FIG. 7C schematically illustrates a side cross-sectional view of another embodiment of an L-BJT 730. In some cases, an upper level for the operating voltages of L-BJT 730 can be larger to that of the LBT 240. Similar to the PNP L-BJT 240, the L-BJT 730 comprises laterally arranged emitter-base and base-collector junctions and may operate mainly based on carrier transport in a lateral direction parallel to a main surface of a substrate on which the L-BJT 730 is fabricated on. However, the L-BJT 730 may not have a LD collector region and may include a thick RESURF dielectric layer 734b in addition to the RESURF dielectric layer 717b. The L-BJT 730 may comprise one or more features described above with respect to the PNP L-BJT 240. The L-BJT 730 may include an HD emitter region 206 formed in an LD base region. The collector region 736 of the L-BJT 730 is a portion of the common well 212 that supports bipolar carrier transport to and from the base region 201 and may include an HD collector region 707. In some cases, a drift region 705 of the L-BJT can have length extended in the lateral direction (y-axis) from the HD collector region 707 to the base region 201. The RESURF dielectric layer of the L-BJT 730 may comprise a thin RESURF dielectric layer 734a and a thick RESURF dielectric layer 734b. Accordingly, a first portion of a RESURF layer 732a of the L-BJT 730 may disposed on the thin RESURF dielectric layer 734a and a second portion of a RESURF layer 732a may disposed on the thick RESURF dielectric layer 734b. In some cases, the RESURF layer of the L-BJT 730 can be longer than that of the L-BJT 240. A space layer 216 may be disposed on a sidewall of the RESURF layer 732a and on the thin dielectric layer 734a. Similar to formation of the base region 201 of the PNP L-BJT 240, the base region 201 of the L-BJT 730 may be formed simultaneously with formation of the HD emitter region 206 and using the spacer 216b. In some cases, the length of the drift region of the L-BJT 730 can be substantially equal to that of the PNP L-BJT 240. In some cases, the length of the drift region of the L-BJT 730 can be larger than that of the PNP L-BJT 240. In some cases, the longer length of the drift region 705 and/or the presence of the thick RESURF dielectric layer 734b, may increase an upper limit for the operating voltage of the L-BJT 730 compared to that of the PNP L-BJT 240. In some cases, extending the length of the drift region 705 may significantly increase the upper limit for the operating voltage of the L-BJT 730. Examples of L-BJTs having long drift regions, also referred to as L-BJTs with extended drift regions, are discussed below.

Similar to the PNP L-BJT 240, in some embodiments, the base well 208 of the L-BJT 730 may be partially formed in the common well 212 and a second region 214. In some cases, an interface between the collector region 212 and the second region 214 can be aligned with the emitter-base junction of the L-BJT 730. In some examples, the entire structure of an L-BJT 730 may be formed in the common well 212.

In some cases, the L-BJT 730 can be co-fabricated at least partially with MOS transistors similar to the MOS transistor 240. In some examples, the L-BJT 730 can be co-fabricated with a MOS transistor (e.g., an LDMOS) having a structure similar to the L-BJT 730. FIG. 7D schematically illustrates a side cross-sectional view of an LDMOS transistor. The LDMOS transistor 740 comprises an LD source region 709 formed in the common well 212, an HD source region 720 formed in the LD source region 709, and an HD drain region formed in the common well 212. The gate dielectric layer of the L-BJT 730 may comprise a thin gate layer 734c and a thick gate dielectric layer 734d. Accordingly, a first portion of a gate RESURF layer 732b of the MOS transistor 740 may disposed on the thin dielectric layer 734c and a second portion of the gate layer 732b may disposed on the thick gate dielectric layer 734d. The LD base region 208, the thin RESURF dielectric layer 734a, the thick RESURF dielectric layer 734 b, the RESURF layer 732a, and the HD collector region 707 of the L-BJT 730 may be co-fabricated with the corresponding layers and regions of the MOS transistor to 740 and may comprise substantially identical physical dimensions with those layers and regions.

The dopant concentration distribution 231 shows relative doping levels in the L-BJT 730 along the lateral direction (e.g., y-axis). A dopant concentration (D_{E}) in the emitter region can be larger than a dopant concentration (D_{B}) in the base region. A dopant concentration (D_{DR}) in the drift region can be smaller than D_{B} and D_{CHD}. In some cases, the relative doping levels in the LDMOS 740 along the lateral direction can be similar to th3 of the L-BJT 730. In some cases, D_{DR} for L-BJT 730 can be larger than D_{CH} for MOSFET 740.

The base well 208 of the PNP L-BJT 240 or L-BJT 730 may include one or more HD base regions having the same polarity or semiconductor type as the base well 208. The HD base regions may be used to provide electrical connection to the base well 208 and the base region 201. In some embodiments, the base regions may be aligned with the HD emitter region along a lateral direction (e.g., along x-axis) perpendicular to the lateral direction along which the emitter-base and base-collector junctions are aligned (e.g., y-axis). In some other embodiments, a base region may be aligned with the HD emitter region along a lateral direction (e.g., along y-axis) parallel to the lateral direction along which the emitter-base and base-collector junctions are aligned.

In some cases, forming the base region 208 partially in the common well 212 and a second region (e.g., a second well) with opposite polarity and aligning the interface between the collector region 212 and the second region 214 with the emitter-base junction of the L-BJT 730 or L-BJT-240, may improve the performance of the BJT.

With reference to FIGS. 2 and 7A-7D, in some embodiments, a length of the layer stack 202b along a lateral direction (e.g., along y-axis) can be longer than a length of gate stack 202a along the lateral direction. In some embodiments, a length of the HD collector region 707 along a lateral direction (e.g., along y-axis) can be smaller than a length of the HD drain region of the MOS transistor 230 along the lateral direction.

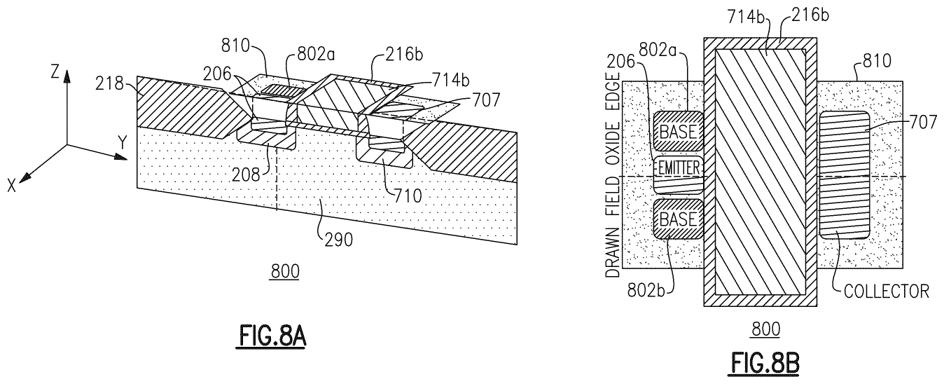

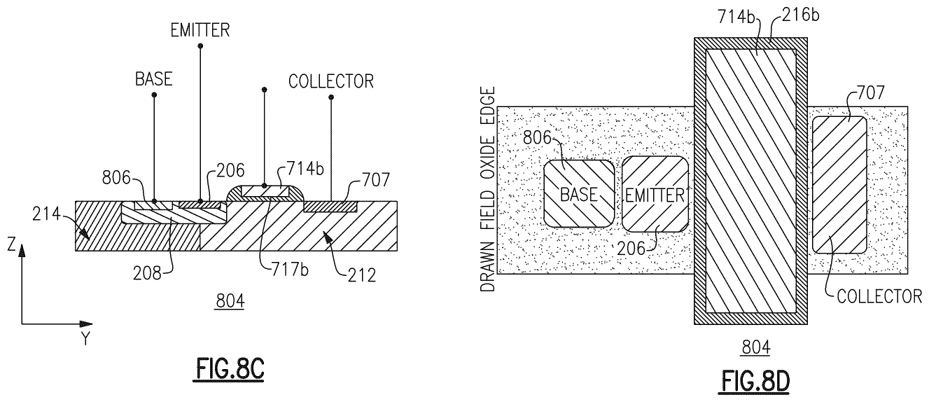

FIG. 8A shows a three-dimensional (3D) cross-sectional view of an example L-BJT 800 having an HD base region 802a disposed in the base well 208 in a corner region between the HD emitter region 206 and the spacer 216b disposed on the side wall of the layer stack 714b. FIG. 8B shows a top two-dimensional (2D) cross-sectional view of the L-BJT 800 in a plane 810 parallel to and above the top surface of the substrate 290. The base region 802a and another base region 802b are disposed in two corner regions between the HD emitter region 206 and the spacers 216b. The base region 802a, HD emitter region 206 and the base region 802b are disposed in in the vicinity of the RESURF layer 714b and are aligned in a lateral direction along x-axis.

FIG. 8C shows a 2D cross-sectional view of another example L-BJT 804 having an HD base region 806 disposed in the base well 208 near an edge of the HD emitter region 206 opposite to another edge near the spacers 216b disposed on the side walls of the RESURF layer 714b and RESURF dielectric layer 717b. The HD base region 806 and the HD emitter region 206 are separated by a gap having a width along the lateral direction from 0.1 to 1 micron. The HD base region 806 has the same polarity as the base well 208, but it has a higher doping concentration. In some examples, the doping concentration of the HD base region 806 can be larger than 10²⁰ cm³. FIG. 8D shows a top two-dimensional (2D) view of the L-BJT 804. The base region 806, the HD emitter region 206 are aligned in a lateral direction along y-axis.

In some cases, the base well 208 of L-BJT 804 may be partially disposed in the common well 212 and a second region (e.g., a second well) 214 having an opposite polarity compared to the common well 212. The HD emitter region 206, the HD collector region 707, and the common well 212 (e.g., a well shared with a MOS transistor) have the same polarity that is opposite to a polarity of the base well 208 and the HD base region 806.

While the PNP L-BJT 240 or L-BJT 804 can be co-fabricated with a MOS device on a common BiCMOS platform, in some embodiments, at least one feature, structure, doping profile of an L-BJT (e.g., the PNP L-BJT 240 and/or L-BJT 804) co-fabricated with the corresponding feature, structure, doping profile of one or more MOS devices (e.g., MOSFET 280 and/or MOSFET 230), may be purposefully adjusted, designed, or tailored to enhance the performance of the L-BJT. In some of such embodiments, such design, adjustment, or tailoring may result in sub-optimal performance of the co-fabricated MOS devices. However, the sub-optimal performance may be in an acceptable range for an IC device and the corresponding application. In some examples, purposeful adjustment of a feature, structure, or doping profile of an L-BJT may take into account its impact on the performance of the co-fabricated MOS devices and maintain it in an acceptable range for an IC device and the corresponding application.

In some implementations, a change made to a fabrication step of an L-BJT with respect to the corresponding fabrication step in a MOS transistor, may result in significant change in the performance of the co-fabricated MOS transistor, e.g., degrading its performance below an acceptable or threshold level. In some such implementations, at least one fabrication step of the an L-BJT may be a dedicated fabrication step that is not associated with a fabrication of a corresponding feature in the MOS transistors on the same substrate. A dedicated fabrication step may include but it is not limited to forming or doping a region (e.g., diffusing a dopant), etching a structure (e.g., a spacer), disposing a layer, and the like.

In some cases, the doping step of the base well 208 may of the PNP L-BJT 240 (a PNP BJT) can be a dedicated fabrication step. In some such cases, a doping profile of the base well 208 can be different from that of a corresponding drain and source regions 209, 207, of the MOSFET 280. In some examples, the location of the peak doping concentration of the doping profile of the base well 208 along the vertical direction (e.g., z-axis) can be at or near the lateral emitter-base junction.

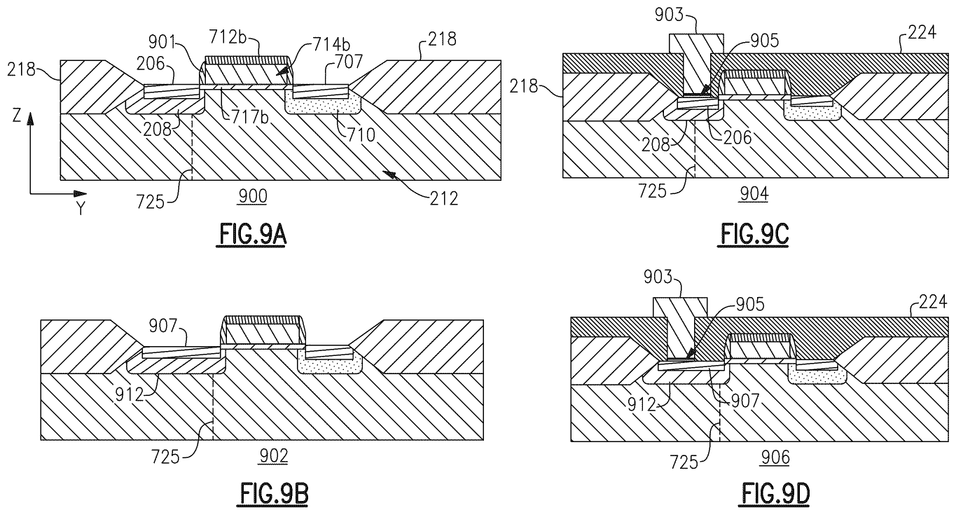

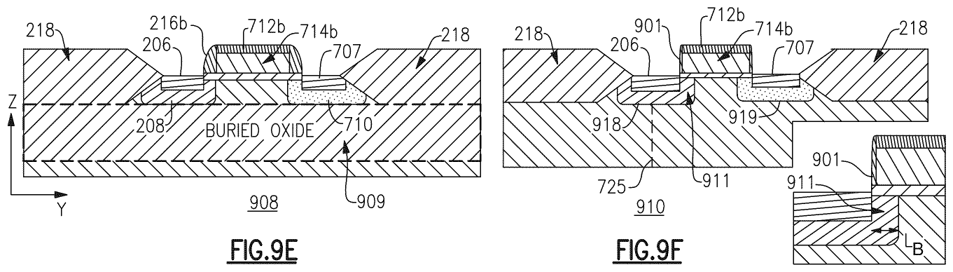

In some cases, the spacers 216b of the PNP L-BJT 240 may be fabricated (e.g., etched) using a dedicated fabrication process independent of a process used to fabricate the spacers 216a of the NMOS transistor 280. FIG. 9A illustrates a cross-sectional view of an L-BJT 900 having a spacer 901 fabricated using a dedicated process. For example, a top width, a base width, or an average width of the spacer 901 of the L-BJT 900 may be smaller than those of a MOS transistor fabricated in the same common well 212 and/or the same substrate. The base width of the spacer 909 may be a length of a base of the spacer 901. The base of the spacer 901 may comprise a portion of the spacer 901 at interface between the spacer 901 and the dielectric layer 717b. Advantageously, fabricating the spacer 901 using a dedicated fabrication process may allow forming a thin base region having a base length (L_{B}) less than 0.01p m, less than 0.05 μm, less than 0.1 μm, or less than 0.15 μm.

In some cases, the emitter region 206 of an L-BJT (e.g., the PNP L-BJT 240) may fabricated using a dedicated fabrication process independent of a process used to fabricate the HD drain or source regions of a MOS transistor on the same substrate (e.g., the MOSFET 230). FIG. 9B illustrates a cross-sectional view of an L-BJT 902 having an elongated emitter region 907 fabricated using a dedicated process. For example, a length of the emitter region 907 along the lateral direction (e.g., along y-axis) may be larger than those of HD drain and HD source regions of a MOS transistor fabricated on the same substrate. Advantageously, an L-BJT having an elongated emitter region 907 may have a lower base current and higher gain compared to an L-BJT having an emitter length limited by the lengths of the HD drain and HD source regions of a co-fabricated MOS device. Correct In some examples, a length of the base well 912 of the L-BJT 902 may be longer than the LD drain and LD source regions of the MOS transistor fabricated on the same substrate to accommodate for the elongated emitter. As such both the elongated emitter region 907 and the elongated base well 912 of the L-BJT 902 may be fabricated using a dedicated fabrication process or step. In some examples, the length of an elongated emitter region can be from 0.18 to 0.6 microns. In some examples, the length of an elongated base well can be from 0.18 to 1.0 microns.

In some cases, the emitter region of an L-BJT (e.g., the PNP L-BJT 240) may be extended in a vertical direction (e.g., along z-axis) to increase the gain of the L-BJT. In such cases, a dedicated fabrication step may be used to fabricate a vertical emitter section on the HD emitter region of the L-BJT. FIG. 9C illustrates a cross-sectional view of a L-BJT 904 having a vertical emitter section 903. In some cases, the vertical emitter section 903 may be fabricated using a dedicated fabrication process. The vertical emitter section 903 may comprise polysilicon. In some cases, the vertical emitter section 903 may be disposed on the elongated emitter region 907 of the L-BJT 902. FIG. 9D illustrates a cross-sectional view of a L-BJT 906 having an elongated emitter region 907, and elongated base well 912, and a vertical emitter section 903.

In some embodiments, a dielectric layer 905 may be formed between the emitter region 206 and the vertical emitter section 903. The dielectric layer 905 (also referred to as interfacial dielectric layer) may be naturally formed during fabrication of the vertical emitter section 903, fabricated using a separate process, or a combination of both. In either case, the thickness of the dielectric layer (along the vertical direction) may be precisely controlled. In some examples, the thickness of the interfacial dielectric layer may be from 1 μm to 200 μm. In some cases, the thickness of the dielectric layer 905 may be less than a threshold limit to allow carrier transport between the emitter region 206 and the vertical emitter section 903 via quantum tunneling. In some cases, the dielectric layer 905 may comprise silicon dioxide.

In various embodiments, the vertical emitter section 903 and the corresponding dielectric layer 905 at the base of the vertical emitter section 903, may be fabricated using a dedicated process.

In some cases, an L-BJT (e.g., the PNP L-BJT 240) can be vertically isolated from a lower region of the substrate (e.g., substrate 290) below the base well (e.g., base well 206) and/or the LD collector region of the L-BJT (e.g., LD collector region 710). In some such cases, a buried dielectric layer (e.g., a buried oxide layer) may vertically isolate the L-BJT from the bulk substrate. Such L-BJT may be fabricated, e.g., in a silicon-insulator (SOI) substrate. In some cases, the combination of the isolating layers formed on the surface of the substrate (e.g., the isolation layer 218) and the vertical isolation layer may fully isolate the L-BJT. FIG. 9E illustrates a cross-sectional view of a fully isolated L-BJT 908 that is laterally isolated by the isolation layers 218 and vertically isolated by the buried dielectric layer 909. In some examples, the buried dielectric layer 909 may be in contact with the dielectric layers 218. In some examples, a vertical gap or distance (e.g., along z-axis) between a bottom surface of the dielectric layer 218 and a top surface of the buried dielectric layer 909 can be less than 150 nm, less than 100 nm, or less than 50 nm.

In some embodiments, the base wells 208, 912 of the L-BJT designs described above with respect to FIGS. 9A-9F may be partially formed in the common well 212 and a second region (e.g., a second well) comprising a semiconductor having opposite dopant types, and/or an opposite polarity compared to the common well 212. In such examples, the common well 212 and the second region 214 may have a vertical interface 725 (shown as a dashed line) underneath the base well 208, 912. In some cases, the vertical interface 725 can be aligned with the vertical emitter-base junction of the L-BJT.

In some implementations, a base region of an L-BJT may be formed and the corresponding base length may be precisely defined by thermal diffusion of a dopants from base well under the RESURF layer. In these implementations, the base width of a spacer used to form the emitter region of the L-BJT is reduced to allow the diffusion of the dopants to a region of the substrate below the RESURF layer. FIG. 9F illustrates a cross-sectional view of the L-BJT 910 having thermally diffused base region 911 formed by thermally diffusing the dopants from the base well 208 laterally (e.g., along y-axis) underneath the RESURF layer 714b. In this case, the base length L_{B} is precisely defined by controlling the temperature of the sample after formation of the base well 208. The base width if the spacer 901 is reduced to bring the emitter region 206 closer to the edge of the RESURF later 714b to allow the dopants to thermally defuse from the base well 208 under the RESURF layer 714b. Is some cases, the fabrication of the spacer 901 and the thermal diffusion of the dopants may be performed as dedicated processes during the fabrication of the L-BJT 910 on a BiCMOS platform comprising the L-BJT 910 and one or more MOS transistors on a common substrate.

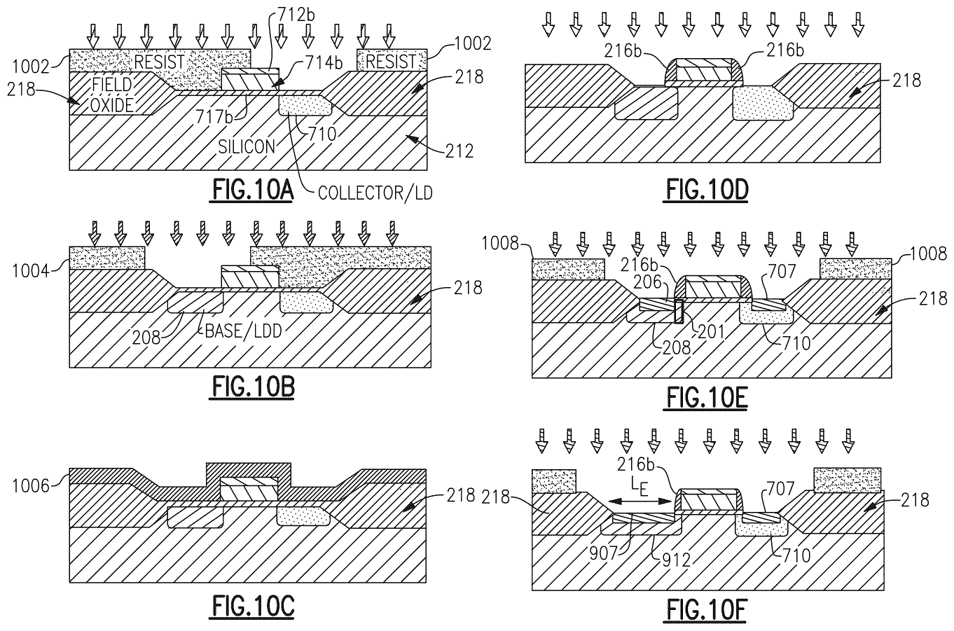

FIGS. 10A-10D schematically illustrate cross-sectional views of intermediate structures at some of the steps in the fabrication process of an L-BJT according to embodiments. FIG. 10A shows a cross-sectional view of a partially fabricated L-BJT structure during formation of the LD collector region 710. In some cases, the isolating oxide layers 218, the RESURF oxide layer 717b, the RESURF contact layer 712b, and the RESURF layer 714b, may have been fabricated using standard CMOS fabrication processes. In some examples, these features may have been co-fabricated with the corresponding features of one or more MOS transistors.

The fabrication step shown in FIG. 10A may comprise depositing a patterning layer such as a photoresist layer and lithographically patterning the photoresist layer to generate a patterned photoresist layer 1002 covering portions of the isolating dielectric layers 218 and the RESURF contact layer 712b leaving an edge of the layer stack near the collector region uncovered. After patterning the photoresist layer, the LD collector region may be formed in the common well 212, e.g., by implanting an n-type dopant (for an NPN L-BJT) or a p-type (e.g., for PNP L-BJT). The dopant selectively penetrate to a region of the common well 212 covered by the unprotected portion of the RESURF oxide layer 717b and form the LD collector region 710.

A length or width of the collector region 710 along a lateral direction may be determined by a length or width of the unprotected portion of the RESURF oxide layer 717b. A depth of the collector region 710 along a vertical direction (perpendicular to a main surface of the substrate) may be determined by the energy of the implanted dopant and a thickness of the RESURF oxide layer 717b along the vertical direction.

The fabrication step shown in FIG. 10B may comprise removing the patterned photoresist 1002 and depositing a second patterning layer such as a second photoresist layer and lithographically patterning the second photoresist layer to generate a second patterned photoresist layer 1004 covering the portions of the isolating dielectric layers 218 and the RESURF contact layer 712b leaving an edge of the layer stack near the emitter/base region uncovered. After patterning the second photoresist layer, the LD base well 208 may be formed in the common well 212, e.g., by implanting a p-type dopant (for an NPN L-BJT) or an n-type (e.g., for PNP L-BJT). The dopants selectively penetrate to a region of the common well 212 covered by the unprotected portion of the RESURF oxide layer 717b and form the base well 208. A length or width of the base well 208 along a lateral direction may be determined by a length or width of the unprotected portion of the RESURF oxide layer 717b. A depth of the base well 208 along a vertical direction (perpendicular to a main surface of the substrate) may be determined by the energy of the implanted dopant and a thickness of the RESURF oxide layer 717b along the vertical direction.

The fabrication step shown in FIG. 10C may comprise removing the patterned photoresist 1004 and depositing a dielectric layer 1006 covering all regions of the L-BJT. In some cases, the dielectric layer 1006 may be formed using a precursor such as tetraethoxysilane (TEOS) and can be deposited using a suitable process such as chemical vapor deposition (CVD), e.g., low pressure chemical vapor deposition (LPCVD). The dielectric layer 1006 may have a suitable thickness along the vertical direction between 0.1-0.3 microns across the L-BJT regions, which is correlated to the final width of the spacer layer formed therefrom, which in turn defines the base width as described above. Depending on the conformality of the process used to form the spacer, the thickness of a portion of the dielectric layer 1006 on the side walls of the layer stack may be larger by a factor of 1.5-3 (depending on the thickness of the layer stack).

The fabrication step shown in FIG. 10D may comprise etching the dielectric layer 1004 to fabricate the spacers 216b on the sidewalls of the layer stack. In some cases, the etching process can be an anisotropic or directional etching process (e.g., plasma etching) that etches the dielectric layer 1006 in a vertical direction (e.g., along z-axis). By carefully adjusting the penetration or etching depth of the etching process a portion of the dielectric layer 1006 disposed on the isolating dielectric layers 218 and a portion of the dielectric layer 1006 and the RESURF dielectric layer 717b underneath, may be completely removed exposing the HD base well 208 and the LD collector region 710. In the meantime, given the larger thickness of a portion of the dielectric layer 1006 near and at the side wall of the layer stack remains and form the spacers 216b around the layer stack. As the etching rate may decrease proportional to depth, the spacers 216b can have a tapered shape from a wide base portion of the spacer (that is in contact with the RESURF dielectric layer 717b) toward a top portion of the spacer near the RESURF contact layer 712b.

The final fabrication step shown in FIG. 10E may comprise depositing a third patterning layer such a third photoresist layer and lithographically patterning the third photoresist layer to generate a third patterned photoresist layer 1008 covering the portions of the isolating dielectric layers 218. After patterning the third photoresist layer, the HD emitter region 206 and the HD collector region 707 may be fabricated the base well 208 and the LD collector region 710, respectively. The HD emitter region 206 and the HD collector 707 region by implanting an n-type dopant (for an NPN L-BJT) or a p-type dopant (e.g., for PNP L-BJT). The layer stack of and the spacers 216b of the L-BJT naturally act as a mask for defining the HD emitter region 206 and the HD collector 707 regions. A length the HD emitter region 206 and the HD collector region 707 are determined by a lateral distance (e.g., along y-axis) between one of the isolating dielectric layers 218 and the spacers 216b. The length L_{B} of the base region 201 is substantially equal to a base width of the spacer 216b above the base region 201. Using the layer stack a mask for fabricating the base well 208, and the layer stack and the spacer 216b, as a mask for fabricating the emitter region 206, results in formation of the base region 201. As a result, the accuracy of the base length L_{B} is limited by the accuracy of the dimensions of the spacer 216b and the layer stack, and the self-alignment of the base well 208 and the emitter region 206 with the spacer 216b and the layer stack, both of which have been highly optimized given decades of development for CMOS fabrication.

The depth of the HD emitter region 206 and the HD collector region 707 along the vertical direction may be determined by the energy of the implanted dopants. After dopant implantations, the third patterned photoresist layer 1008 may be removed.

In some implementations, during one or more the fabrication steps shown in FIGS. 10A-10F, corresponding regions or structures a MOS transistor may be fabricated on the common well 212 and/or the substrate 290 on which the L-BJT and the MOS transistor are co-fabricated.

In some embodiments, the dopant implantation process in the fabrication step for the base well 208 (FIG. 10B), can be a dedicated implantation process not used for the co-fabrication of the MOS transistors. In such embodiments, a doping profile of the base well 208 can be different from a doping profile of the corresponding regions (e.g., drain or source regions) of a MOS transistor. For example, when the doping profile comprises a Gaussian profile, the peak of the Gaussian profile may be located at the lateral emitter-base interface while for a corresponding source/drain region, the peak can be below the HD/LD interface.

As mentioned above, in some embodiments, a L-BJT may have an elongated emitter region. In these embodiments, one or more masks used to define a length of the RESURF dielectric layer 717b and/or the location position of the layer stack with respect to the isolating dielectric layers 212 may include features having different dimensions for the L-BJT and the MOS transistors. FIG. 10A shows the doping implantation process for an L-BJT having elongated emitter region 907 and base well 912. As shown a lateral distance between the spacers 216b and the isolating dielectric layers in the emitter side (left) is longer than that of the collector side (right). As a result the base well 912 is longer (along a lateral direction parallel to y-axis) than the LD collector region and the HD emitter region 907 (elongated emitter region) is longer than length of the HD collector region 707 and/or the length of the drain/source regions of one or more MOS transistors or co-fabricated on a common substrate or common well. In some cases, the length of the base well of an L-BJT can be substantially equal to the length of its LD collector region but and the length of its HD emitter region can be longer than length of the HD collector region 707. In some case, an upper limit for the length of the elongated emitter 907 may be determined based at least in part on a recombination rate or diffusion length of the carrier is the emitter region. In some, examples, a lower limit for the length of an emitter or elongated emitter may be determined by a length (along y-axis) of a conductive contact electrode disposed on the emitter regions 907 or 206. For example, the length of the conductive contact electrode can be 1.5 to 2 times smaller than the length of the emitter region 907 or 206.

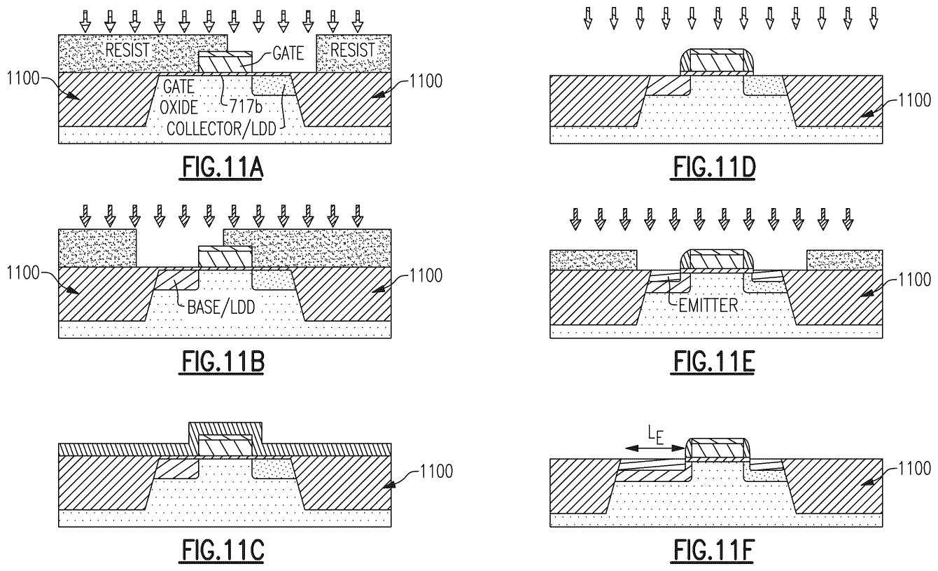

In some implementations, the isolating dielectric layers 218 may be thermally grown oxides (also referred to as locally oxidized silicon or LCOS). In some other implementations, the isolating dielectric layers surrounding an L-BJT may be fabricated by etching a trenches in the substrate 290 and/or common well 212 and depositing a dielectric material (e.g., silicon dioxide) in the trenches (also referred to as shallow trench isolation or STI). FIGS. 11A-11F schematically illustrate selected fabrication steps for an L-BJT having isolating dielectric (STI) layers 1100 disposed in trenches. In some cases, the RESURF dielectric layer 717b may be fabricated as part of dielectric deposition process used to fabricate the isolating dielectric layers 1100. In some cases, the fabrication steps shown in FIGS. 11A-11F are similar to the fabrication steps shown in FIGS. 10A-10F, respectively. The details of the similarities are not reproduced herein for brevity.

In some cases, a cladding dielectric layer 224 may be disposed on the final structures shown in FIGS. 10E, 10F, 11E, and 11F, after removing the last patterned photoresist layer. In some cases, the cladding dielectric layer 224 may comprise silicon dioxide.

Additionally, the fabrication process described with respect to FIG. 10A-10E, may include fabrication of a HD base region in above the base well 208 to provide an ohmic contact to the base region 201. As described above with respect to FIG. 8A-8C, the HD base region can be fabricated in a corner area between the emitter region 206 and the spacer 216b or near an edge of the emitter region 206 opposite to another edge near the spacer 216b. As shown in FIG. 8C, in the latter case, the base well 208 may be partially formed in the common well 212 and a second region 208 having an opposite polarity with respect to the common well 212. In some cases, the HD base regions 802a/b or 806 may be fabricated using a dedicated fabrication process during which a feature a MOS transistor is not fabricated.

In some cases, the electrical connections to the emitter, base, and collector regions, may comprise the ohmic contacts with a conductive line (e.g., an electrode). In some cases, at least one of the conductive lines may comprise polysilicon having a doping type similar to a region of L-BJT on which the polysilicon is disposed.

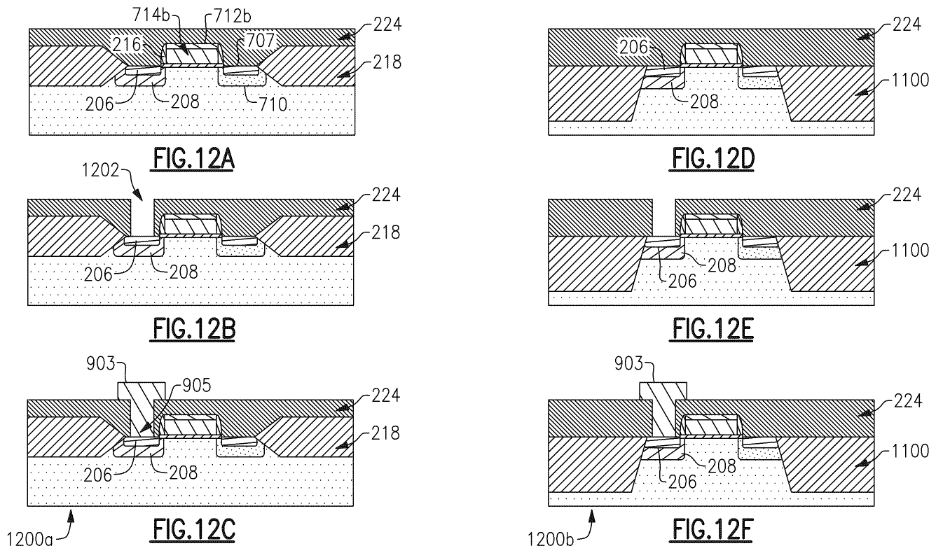

As described above in some embodiments, an emitter region of an L-BJT may be further extended by adding a vertical emitter section to the emitter region, which can further improve the gain of the L-BJT. FIG. 12A-12C schematically illustrate the fabrication process of the vertical emitter section 908 on the emitter region 206 of an L-BJT. FIG. 12A shows a cross-sectional view of a partially fabricated L-BJT structure during formation before fabricating the vertical emitter section 908. The emitter region, 206, base well 208, HD and LD collector regions 707, 710, the isolating oxide layers 218, the RESURF oxide layer 717b, the RESURF contact layer 712b, the RESURF layer 714b, and the cladding dielectric layer 224 may have been fabricated using standard CMOS fabrication processes. In some examples, these features may have been co-fabricated with the corresponding features of one or more MOS transistors. The fabrication step shown in FIG. 12B may comprise depositing a photoresist layer and lithographically patterning the photoresist layer to cover cladding dielectric layer 224 except for a region above the emitter region 206 through which a hole is etched to exposing a corresponding area of the emitter region 206. In the next fabrication step shown in FIG. 12C the vertical emitter section 908 is fabricated by depositing a semiconducting material having moderate to high conductivity. In some cases, the vertical emitter section may comprise polysilicon. In some cases, vertical emitter section may comprise polysilicon with a dopant of the same type (p or n) of a dopant used to dope the emitter region 206. In various examples, the vertical emitter section 908 may be fabricated before a metallization process that may electrically connect the base, emitter, or the collector of eth L-BJT to or more components or devices. In some cases, the vertical emitter section 908 may serve as an ohmic contact between a metallization layer and the emitter region 206.

In some examples, a thin interfacial dielectric layer 905 (e.g., oxide layer) may be grown at the base of the vertical emitter section 908 and on the emitter region 206. The thin interfacial dielectric layer 908 may increase the gain of the L-BJT by reducing the gradient of carriers in the emitter region 206 and dropping the base current. In some cases, the interfacial dielectric layer 908 may be a grown layer formed using a controlled growth process such as oxidation or deposition, may be a native oxide, or a combination thereof. In some cases, a thickness of the interfacial dielectric layer 908 can be as small as 2 atoms of an oxide material. In some, examples, the thickness of the interfacial dielectric layer 908 may be determined based on a desired gain for the corresponding L-BJT. In some other examples, the thickness of the interfacial dielectric layer can be optimized for providing a maximum level of gain within constraints imposed by the other parameter and features of the L-BJT.

FIGS. 12D-12F schematically illustrate selected fabrication steps for an L-BJT comprising a vertical emitter section and having isolating dielectric layers 1100 disposed in trenches (instead of thermally grown field oxide). In some cases, the fabrication steps shown in FIGS. 12D-12F are identical to the fabrication steps shown in FIGS. 12A-12C, respectively.

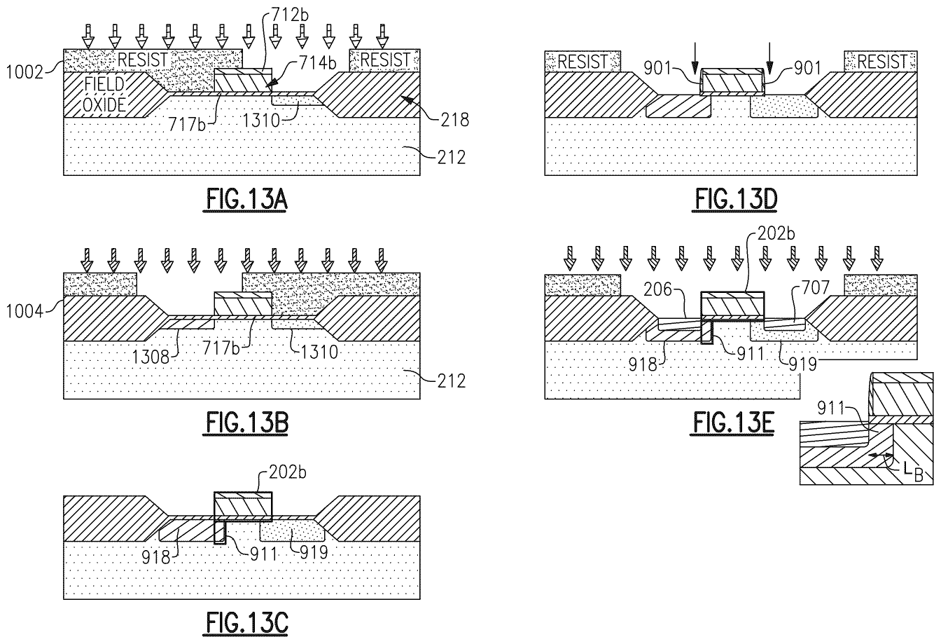

As described above in some embodiments, the base region of a BJT can be a thermally defined base region (instead of being defined by the base width of a spacer). FIG. 13-13C schematically illustrate the fabrication process of the thermally defined base region 901 and the corresponding base well 918 and HD collector region 919. FIG. 13A shows a cross-sectional view of a partially fabricated L-BJT structure during formation of the HD collector region 919 and before fabricating the base well 918. In some cases, the isolating oxide layers 218, the RESURF oxide layer 717b, the RESURF contact layer 712b, and the RESURF layer 714b, may have been fabricated using standard CMOS fabrication processes. In some examples, these features may have been co-fabricated with the corresponding features of one or more MOS transistors.

The fabrication step shown in FIG. 13A may comprise depositing a photoresist layer and lithographically patterning the photoresist layer to generate a patterned photoresist layer 1002 covering portions of the isolating dielectric layers 218 and the RESURF contact layer 712b leaving an edge of the layer stack 202b near the collector region uncovered. After patterning the photoresist layer, an initial LD collector region 1310 may be formed in the common well 212, e.g., by implanting an n-type dopant (for an NPN L-BJT) or a p-type (e.g., for PNP L-BJT). The dopant selectively penetrate to a region of the common well 212 covered by the unprotected portion of the RESURF oxide layer 717b and form the initial LD collector region 1310.

The fabrication step shown in FIG. 13B may comprise removing the patterned photoresist 1002 and depositing a second photoresist layer and lithographically patterning the second photoresist layer to generate a second patterned photoresist layer 1004 covering the portions of the isolating dielectric layers 218 and the RESURF contact layer 712b leaving an edge of the layer stack 202b near the emitter/base region uncovered. After patterning the second photoresist layer, an initial LD base well 1308 may be formed in the common well 212, e.g., by implanting a p-type dopant (for an NPN L-BJT) or an n-type (e.g., for PNP L-BJT).

The depths of the initial base well 1308 and the initial collector well 1310 along a lateral direction (e.g., along the y-axis), may be determined based on a desired depth of the base well 918 and a length (L_{B}) of the thermally diffused base region 901. The length of the initial base well 1308 and the initial collector well 1310 along a vertical direction (e.g., along the z-axis), may be determined based on a desired length of the base well 918 and a length (L_{B}) of the thermally diffused base region 901.

The fabrication step shown in FIG. 13C comprises removing the patterned photoresist 1004 and elevating the temperature of the structure to form the base well 918, the thermally diffused base region 901, and the HD collector region 919, by thermally diffusing the dopants away from the initial base well 1308 and the initial collector well 1310. As a result of the lateral diffusion of the dopant from the initial base well 1308, the base length (L_{B}) and base depth are determined by the doping profile of the initial base well 1308 and the temperature elevation process. In some cases, a temperature elevation process used for diffusing the initial base well 1308 and LD collector region 1310, may comprise elevating the temperature of the structure from an initial temperature to a final temperature. In some examples, the temperature may be increased continuously in a linear fashion, nonlinear fashion, or a combination of both. In some examples, the temperature may be increased step wise were during each step the temperature is kept constant or nearly constant to allow for diffusion of the dopant before next temperature increment. In some cases, a length of the thermally diffused base region 901 along the lateral direction (e.g., a lateral diffusion length of the dopants under the layer stack 202b), can be from 50 nm to 100, from 100 nm to 150 nm, from 150 nm to 200 nm, or any range formed by these ranges, or larger or smaller ranges.

In some cases, the doping profile of the initial base well 1308 may be engineered such when the thermal diffusion process is complete, a doping profile of the resulting base well 918 matches with or is substantially identical to a target doping profile along both the lateral and the vertical directions. In these cases, the thermal diffusion process may simultaneously define L_{B} and a location of the peak dopant concentration along the vertical axis.

After fabricating the base well 918 and the LD collector region 919, a dielectric layer 1006 (e.g., a layer comprising TEOS) may be deposited on the L-BJT structure using the fabrication step described above with respect to FIG. 10C. The fabrication step shown in FIG. 13D may comprise a dedicated etching step for etching the dielectric layer 1006 and portions of the RESURF dielectric layer 717b on the base well 918 and LD collector region 919. In some cases a very thin spacer 901 may be left after the etching process (e.g., a vertical etching process). In some cases, the base width of the spacer 901 can be from 1 nm to 5 nm, from 5 nm to 10 nm, from 10 nm to 20 nm, from 20 nm to 30 nm, from 30 nm to 40 nm, or from 40 nm to 50. The final fabrication step shown in FIG. 13E can be similar to the final fabrication step described above with respect to FIG. 10E where the HD emitter region 206 and the HD collector region 707 are fabricated by implanting an n-type dopant (for an NPN L-BJT) or a p-type dopant (e.g., for PNP L-BJT). The layer stack 202b and the thin spacers 901 of the L-BJT act as a mask for defining the HD emitter region 206 and the HD collector region 707. While an L-BJT having a thermally diffused base region 911 can be fabricated without the need for fabricating spacers on the side walls of the layer stack 202b, in some cases, to maintain the synergy between the fabrication process for the L-BJT and the MOS transistors and to reduce a number of fabrication steps, the dielectric layer 1004 may be still disposed on eth L-BJT structure (after thermal diffusion of the base region). In such cases, the L-BJT is co-fabricated (at least partially) with MOS transistors on a common substrate. However, in some cases (e.g., when the L-BJT is not co-fabricated with MOS transistors), when the deposition of the dielectric layer 1004 after fabricating the thermally defused base region 911 can be skipped. In such cases, the etching process (FIG. 13D) removes the portions of RESURF dielectric 717b layer disposed on the base well 918 and LD collector region 919 but no spacer structure is formed. Subsequently in the final fabrication step (FIG. 13E), the layer stack 202b acts as a mask for defining the HD emitter region 206 and the HD collector region 707.

The edge of the layer stack 202b self-aligns the edge of the initial base well 1308 and edge of the spacer 901 self-aligns the emitter region 206. As result the emitter the base-junction is self-alighted with respect to the edge of the spacer 901 or the edge of the layer stack 202b (in eth absence of the spacer). The base length and the position of the base-collector junction are determined by the thermal diffusion process. So the doping profile and the length of the thermally diffused base region 901 can be precisely tailored by controlling the doping profile of the initial base well 1308 and a temperature elevation process.

The doping profile of the thermally diffused base region 901 may comprise a spatially varying dopant concentration that decreases (linearly or nonlinearly) from the edge of the layer stack 202b along a lateral direction toward the LD collector region 919. In contrast, the doping profile of a base region defined by spacers (e.g., the base region 201 in the process shown in FIG. 10A-10E), may comprise a nearly constant or slowly varying dopant concentration along the lateral direction, from the edge of the layer stack 202b toward the LD collector region 919 (compared to a variation of dopant concentration in the thermally diffused base region 901). Advantageously, the doping profile of the thermally diffused base region 901 increases an operational speed of the corresponding L-BJT compared to an L-BJT having base region with nearly constant or slowly varying dopant concentration.

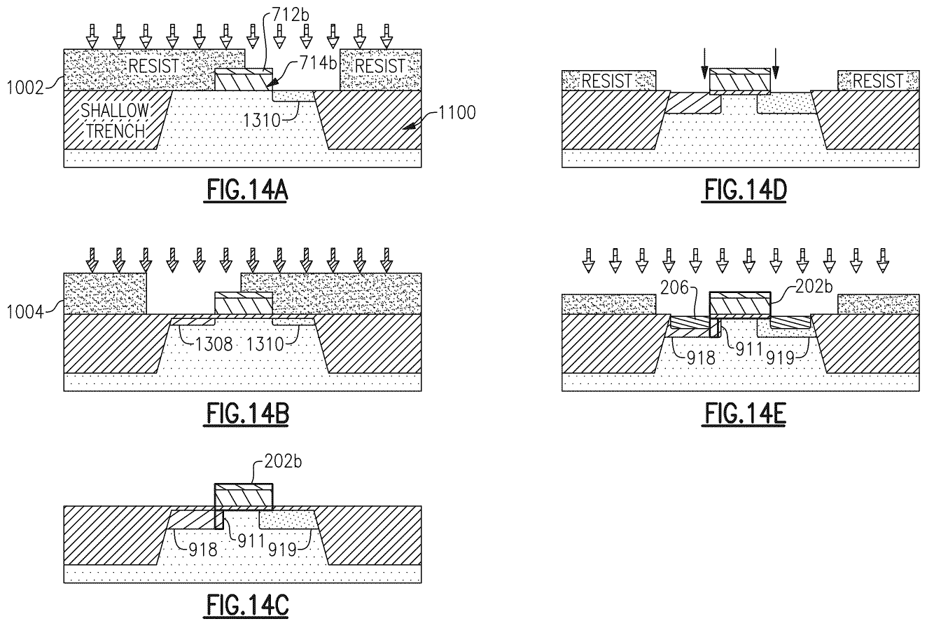

FIGS. 14A-14D schematically illustrate selected fabrication steps for an L-BJT having isolating dielectric layers 1100 disposed in trenches. In some cases, the RESURF dielectric layer 717b may be fabricated as part of dielectric deposition process used to fabricate the isolating dielectric layers 1100. In some cases, the fabrication steps shown in FIGS. 14A-14E are similar to the fabrication steps shown in FIGS. 13A-13E, respectively.

Lateral Bipolar Junction Transistors with Extended Collector Drift Region

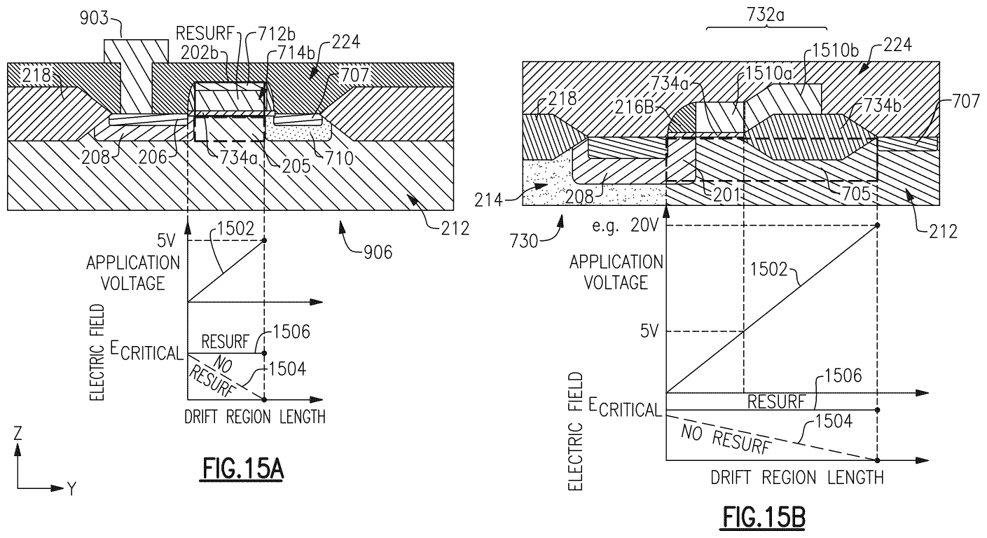

FIG. 15A schematically illustrates a cross-sectional view of the L-BJT 906 shown in FIG. 9D and variation of the voltage 1502 and electric field 1506 along the drift and base regions, 201, 205 of the L-BJT 906. The drift region 205 of the L-BJT 906 is extended along the lateral direction from a vertical boundary of the base well 208, which is aligned with a first edge of the layer stack 202b, to a vertical boundary of the LD collector region 710, which is aligned with a second edge of the layer stack 202b opposite to the first edge. The layer stack 202b includes a RESURF connector layer 712b, a RESURF layer 714b, and a RESURF dielectric layer 734a. The RESURF connector layer 712b is disposed on and is in electric contact with the RESURF layer 714b, and the RESURF layer 714b is disposed on the RESURF dielectric layer 734a that electrically isolates the RESURF layer 714b from the drift region 205. The RESURF layer 714b can alter the electric field (E-field) in the drift region 205 by supporting vertical E-field components, e.g., to maintain a magnitude of a lateral E-field component substantially constant or nearly constant along the drift region 205. In some cases, e.g., when the RESURF connector layer 712b is electrically biased to a voltage having a lower magnitude than a voltage provided to the HD collector region 707, the magnitude of a lateral component of an electric field 1506 generated by applying a voltage between the HD collector region 707 and HD emitter region 206 (also referred to as emitter region), may stay substantially constant or nearly constant along the drift region 205 and base region 201. In some examples, the constant magnitude of the E-field 1506 (e.g., the lateral component of the E-filed) can be substantially equal to a critical E-field magnitude (E_{critical}) than can cause one or both of a reverse-bias junction break down in the emitter-base junction and a dielectric breakdown of the RESURF dielectric layer 734a.

As one example, when the potential difference between the HD collector region 707 and HD emitter region 206 is about 5 volts, the voltage 1502 may monotonically, e.g., substantially linearly, decrease from 5 volts at the HD collector region 707 to near zero at the base-emitter junction. As such, the L-BJT 906 can control (e.g., switch) signals comprising a voltage of magnitude of 5 volts. In some cases, an omission of the RESURF layer 714b and RESURF contact 712b, in the L-BJT 906 may cause the magnitude of the electric field 1504 to monotonically, e.g., substantially linearly increase, along the base region 201 and the drift region 205. As a result, in the absence of the RESURF layer 714b and RESURF contact 7121b, a voltage difference of about 5 volts between the HD collector region 707 and HD emitter region 206 may result in a breakdown of one or both of the reverse-biased collector-base junction and the collector-base junction RESURF dielectric layer 734a.

In some cases, the role of the RESURF layer of the L-BJTs 908, 910, 902, 904, 240 described above with respect to FIGS. 9E, 9F, 9B, 9C and 7A, respectively, can be similar or identical to that of the RESURF layer 714b of the L-BJT 906, e.g., maintaining a magnitude of a lateral E-field component constant or nearly constant along the corresponding drift regions. Similarly the variation of E-field and the corresponding voltage along the drift regions of L-BJTs 908, 910, 902, 904, 240, and 235 can be similar to those of the L-BJT 906 shown in FIG. 15A.

FIG. 15B schematically illustrates a cross-sectional view of the L-BJT 730 shown in FIG. 7C and variation of the voltage 1506 and electric field 1506 along the drift and base regions, 201, 705 of the L-BJT 730. The drift region 705 of the L-BJT 730 is extended along the lateral direction from a vertical boundary of the base well 208, which is aligned with an edge of the RESURF layer 732a, to a vertical boundary of the HD collector region 707, which is aligned with an end of the thick isolating dielectric layer 734b. When the thick isolating dielectric layer 734b is a LOCOS layer, the end can correspond to a “bird's beak” thereof. The RESURF layer 732a comprises a first section 1510a on the RESURF dielectric layer 734a and a second section disposed on the thick isolating dielectric layer 734b. The RESURF dielectric layer 734a and the thick isolating dielectric layer 734b electrically isolate the RESURF layer 732a from the drift region 705. In some cases, the first and the second sections 1510a, 1510b, of the RESURF layer 732a are referred to as first and second RESURF plates or field plates of the L-BJT 730. The RESURF layer 732a (the first and the second field plates) can alter the electric field (E-field) in the drift region 705 by supporting a vertical E-field component, e.g., to keep a magnitude of a lateral E-field component substantially constant or nearly constant along the drift region 705. The RESURF layer 732a is generally formed of a conductive material and may have a conductivity larger than 10 Ω/sq, larger than 30 Ω/sq, larger than 50 Ω/sq, or larger than 70 Ω/sq. For example, the RESURF layer 732a may comprise polysilicon (e.g., n-doped or p-doped polysilicon). However, embodiments are not so limited and the RESURF layer 732a may be formed of a metal.

In some cases, a RESURF connector layer (not shown) may be disposed on the RESURF layer 732a to provide an electric contact to the RESURF layer 732a. In some cases, e.g., when the RESURF layer 732a is electrically biased (e.g., via the RESURF contact layer) to a voltage having a magnitude smaller than the magnitude of a voltage provided to the HD collector region 707, the magnitude of a lateral component of an electric field 1506 generated in the drift region 705 and the base region 201 (resulting from a voltage applied between the HD collector region 707 and HD emitter region 206), may stay substantially constant along the drift region 705 and base region 201. As such, the corresponding voltage may monotonically, e.g., substantially linearly, decrease along the drift region 705 and the base region 201 toward the emitter-base junction. In some examples, the constant magnitude of the lateral component of the E-field 1506 can be substantially equal to the critical E-field magnitude (E_{critical}) corresponding to a reverse junction breakdown. A length of the drift region 705 of the L-BJT 730 in the lateral direction can be greater than a length of the drift region 205 of the L-BJT 240 (FIG. 27A. As a result, the drift region 705 and the field plates 1510a and 1510b of the L-BJT 730 can support a larger voltage drop from the HD collector region 707 to the HD emitter region 206 compared to of the drift region 205 and the RESURF layer (field plate) 714b of the L-BJT 906 (FIG. 15A).

As one example, when the potential difference between the HD collector region 707 and HD emitter region 206 is about 20 volts, the voltage 1502 may monotonically, e.g., substantially linearly, decrease from 20 volts at the HD collector region 707 to near zero at the base-emitter junction. As such, L-BJT 730 can control (e.g., switch) signals comprising a voltage of magnitude of 20 volts. In some examples by elongating the drift region 705 and one or both field pates 1510a, 1510b, the voltage drop along the drift region 705 and the base region 201 may be increased up to 80 volts, thereby allowing the L-BJT 730 to control (e.g., switch) signals comprising a voltage having a magnitude of 80 volts.

With reference to FIG. 15B, in some cases, omitting the RESURF layer 732a, in the L-BJT 730, may cause the magnitude of the electric field 1504 to monotonically, e.g., substantially linearly, increase along the drift region 705 and the base region 201 of the L-BJT 730. As a result, in the absence of the RESURF layer 732a, a voltage different of 20 volts between the HD collector region 707 and HD emitter region 206 may result in a breakdown of the emitter-base junction of the L-BJT 730.

Still referring to FIGS. 15A and 15B, in some cases, the L-BJT 906 (FIG. 15A), which can operate between 0 and 5 volts, may be referred to as a low voltage (LV) L-BJT, and the L-BJT 730, which can operate between 0 and 80 volts (e.g., depending on the length of its drift region), may be referred to herein as a medium voltage (MV) L-BJT. A comparison between voltage drop across the drift regions of the L-BJT 730 and the L-BJT 906 shows that elongating a length of the drift region in the lateral direction and providing a field plate above the elongated drift region can increase the magnitude of the voltage drop across the drift and base regions. As such, the layer stack and the corresponding drift region of an L-BJT not only self-align the emitter region, the base well, and the collector region of the L-BJT, but also define a drift region of the L-BJT below a conductive layer (the RESURF LAYER) that may be tailored for increasing an upper limit for the operating voltage of the L-BJT. Advantageously, both L-BJT designs described above can be synergistically co-fabricated with MOS devices having common structural features by using CMOS co-fabrication techniques described herein. For example, the L-BJT 906 can be co-fabricated with, e.g., the low voltage MOS transistor 240 (FIG. 2), and L-BJT 730 can be co-fabricated with, e.g., the high voltage MOS transistor 740. In some examples, the base well 208 and the HD collector region 707 of the L-BJT 730 and the LD source region 709 and the HD drain region 721 of the MOS transistor 740 may have at least one common physical dimensions and/or common doping profiles, and can be co-fabricated on a common substrate or a common well in the common substrate. In some examples, the spacer 216b, the RESURF layer 732a, the RESURF dielectric layer 734a, and the thick isolating dielectric layer 734b of the L-BJT 730 and the spacer 216a, the gate layer 732b, the gate 734c, and the thick drain dielectric layer 734d of the MOS transistor 740 may have at least one common physical dimensions and can be co-fabricated on a common substrate.

In some examples, the upper limit for the operating voltage (Vₘ) of an L-BJT can be a voltage above which at least one junction and/or at least one dielectric layer within the L-BJT electrically breaks down by an electric field generated across the dielectric layer or a junction, e.g., a reverse biased PN junction.

In some embodiments, a collector region of an L-BJT can be tailored to increase its Vₘ without substantially changing the dimensions and/or configurations of its emitter and base regions. For example, the collector region of the L-BJT 730 may be further extended by increasing the length of the drift region 705 in the lateral direction (e.g., y-direction), elongating the thick isolating dielectric layer 734b, and adding an additional field plate above the elongated section of the thick isolating dielectric layer 734b.

Advantageously, by not having to change the emitter and base regions, the fabrication of an L-BJT operating at higher voltages can benefit from the accurate control over the length of the base region (L_{B}) and co-fabrication of the spacer, RESURF dielectric layer, as well as the emitter, base, and HD collector regions, with the corresponding regions and layers of MOS transistors on a common substrate (as described above with respect to L-BJT 240 (FIG. 2)). An example of a high voltage (HV) L-BJT 350 having an extended drift region was described above with respect to FIG. 3B. More details about L-BJT 350 and related L-BJT designs capable of operating at higher voltages (e.g., larger than 80 volts) are described below. In some cases, an L-BJT having an extended drift region and a field plate (e.g., a metallic field plate) in addition to the RESURF layer 732a, may be referred to herein as an HV L-BJT. In some examples, an HV L-BJT may have a Vₘ greater than 80 volts, greater than 90 volts, greater than 100 volts, greater than 150 volts, greater than 200 volts, greater than 250 volts, greater than 300 volts, or a value in a range defined by any of these values.

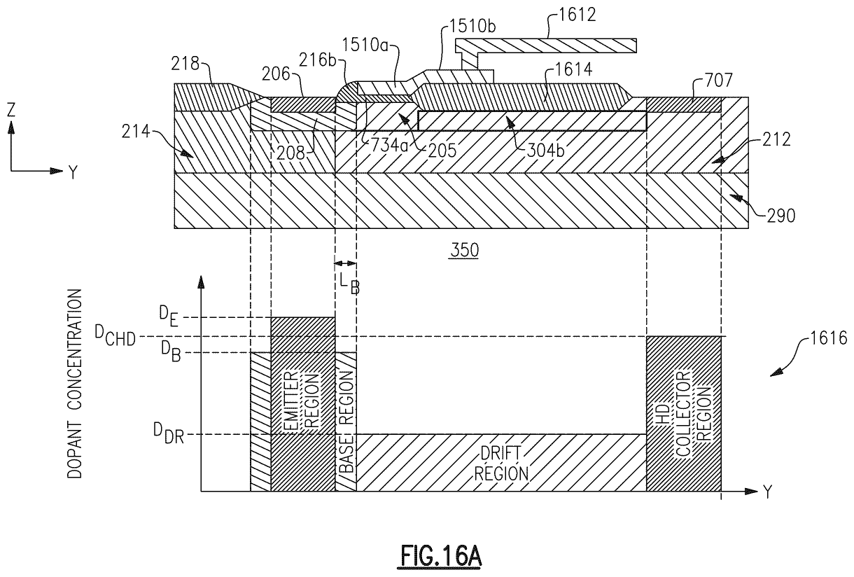

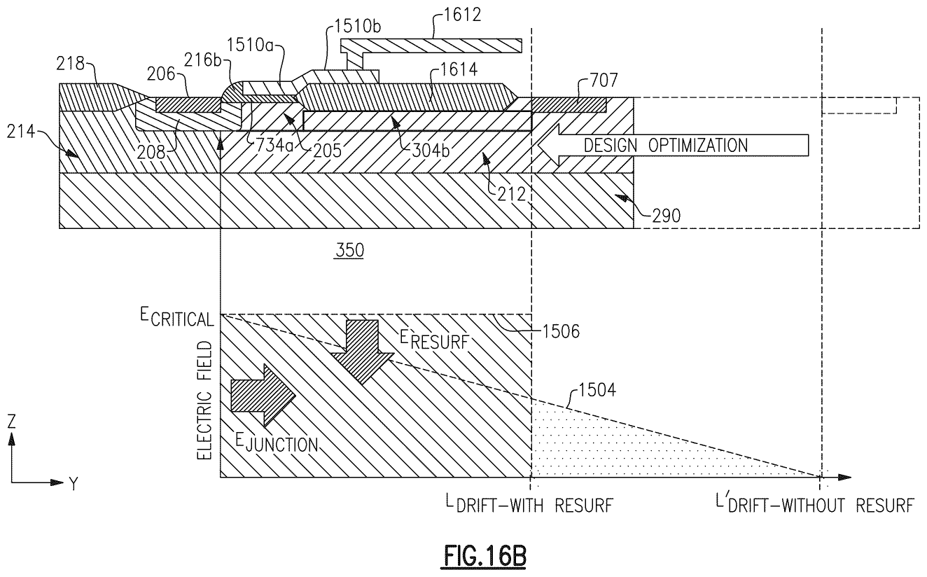

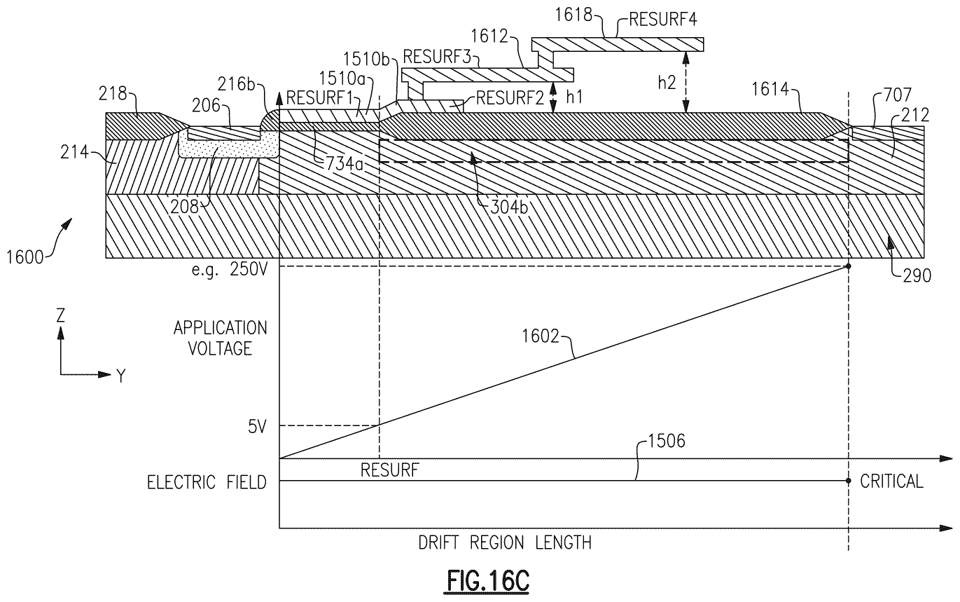

FIG. 16A schematically illustrates a cross-sectional view of an example L-BJT 350 having an elongated drift region, herein referred to as an extended drift region, comprising the drift region 205 and a drift region extension 304b. In some cases, the elongated drift region extending between the HD collector region 707 and the base well 206 may be referred to as the drift region of the L-BJT 350. The L-BJT 350 further comprises a layer stack, and one or more field plates above the drift region extension. The drift region 205 extends in the lateral direction from a first end to a second end, and the drift region extension 304b extends in the lateral direction from the second end of the drift region 205 to a third end. The extended drift region extends from the first end of the drift region 205 to the third end of the drift region extension 304b. A length of the extended drift region in the lateral direction can be from 0.5 to 2.0 microns, or from 2.0 to 5.0 microns, from 5.0 to 15.0 microns, from 15.0 to 25.0 microns, or a value in a range defined by any of these values or smaller or larger. A length of the drift region 205 in the lateral direction can be from 0.18 to 0.6 microns, or a value in a range defined by any of these values or smaller or larger. A length of the extended drift region 304b can be from 0.5 to 25.0 microns, or a value in a range defined by any of these values or smaller or larger.

Similar to L-BJT 240, the HV L-BJT 350 includes an emitter region 206 and a base region 201 at one end of the extended drift region, and an HD collector region 707 at the other end of the extended drift region.

Still referring to FIG. 16A, the layer stack of the HV L-BJT 350 comprises a RESURF dielectric layer 734a over the drift region 205, and a RESURF layer herein referred to as first field plate 1510a disposed on the RESURF dielectric layer 734a. In some cases, a RESURF connection layer may be disposed on the first field plate 1510a. In some cases, a thick isolating dielectric layer 1614 may be disposed above the drift region extension 304b. The thick isolating dielectric layer 1614 can extend from an edge of the RESURF dielectric layer 734a toward the HD collector region 707. A thickness of a thick isolating dielectric layer 1614 along the vertical direction (e.g., along z-axis) can be larger than a thickness of the RESURF dielectric layer 734 along the vertical direction. In various implementations, a difference between a thickness of the thick isolating dielectric layer 1614 and RESURF dielectric layer 734 along can be from 0.01 to 0.015 microns. In some examples, thickness of the thick isolating dielectric layer 1614 can be from 0.3 to 0.5 microns, a value in a range defined by any of these values or smaller or larger. In various implementations, a length of the thick dielectric layer 1614 can be larger than 20%, 30%, 40%, 50%, or 60% of the length the extended drift region or a lateral distance between the base well 208 and the HD collector region 707.

A second field plate 1510b may be disposed above a portion of the thick isolating dielectric layer 1614. In some cases, the second field plate 1510b may be in contact with atop surface of the thick isolating dielectric layer 1614. In some cases, the first and the second field plates 1510a, 1510b may comprise the same material (e.g., a conductive material such as n-doped polysilicon). In some cases, the first and the second field plates 1510a, 1510b can be two sections of a single RESURF layer disposed (e.g., conformally) on the RESURF dielectric layer and at least a portion of the thick isolating dielectric layer 1614.

The extended drift region can be laterally extended from a vertical boundary of the base well 208 below the first field plate 734a to a vertical boundary of the HD collector region 707). In some cases the vertical boundary of the base well 208 can be aligned with an edge of the first field plate 734a.

In some cases, the emitter region 206 (also referred to as HD emitter region) of the L-BJT 350 may be aligned with an edge of a spacer 216b formed on a sidewall of the first field plate 1510a (similar to L-BJT 240). As such, during a fabrication process, the length of a base region of the L-BJT 350 may be defined by a width of a bottom portion of the spacer 216b. In some cases, at least the base well 208, the emitter region 206, the spacer 216b, the first field plate 1510a, and the RESURF dielectric layer 734a of the L-BJT 350 may be co-fabricated with the corresponding regions and features of a MOS transistor (e.g., the MOS transistor 300 (FIG. 3A) or the MOS transistor 280 (FIG. 2). In some cases, the L-BJT 350 can be co-fabricated with the MOS transistor 300 (e.g., a DMOS) on a common substrate (e.g., in a common well 212 formed in the substrate 290). For example, a gate layer in the gate stack 202a of the MOS transistor 300 may serve as a gate contact (corresponding to the first field plate 1510a), and its gate stack extension 302a may include a first drain plate (corresponding to the second field plate 1510b) disposed on a thick drain dielectric layer 1614 (corresponding to the thick isolating dielectric layer), and a second drain plate (corresponding to the third field plate) extended over the thick channel dielectric layer. In some cases, the first, second, and third field plates 1510a, 1510b, 1612, the thick isolating dielectric layer 1614, of the L-BJT 350 and the corresponding plates and layers of the MOS transistor 300 may have at least one common physical dimension and/or material and can be co-fabricated (e.g., during the same fabrication steps) on a common substrate (e.g., over common well in the common substrate).

The dopant concentration distribution 1616 shows the variation of average doping concentration level in the L-BJT 350 along the lateral direction (e.g., y-axis). A dopant concentration (D_{E}) in the emitter region can be larger than a dopant concentration (D_{B}) in the base region. A dopant concentration (D_{DR}) in the extended drift region can be smaller than D_{B} and D_{DR}. A dopant concentration (D_{CHD}) in the HD collector region can be from 10²⁰ to 10²¹ cm⁻³. A dopant concentration (D_{E}) in the emitter region 206 can be from 10²⁰ to 10²¹ cm⁻³. A dopant concentration (D_{B}) in the base well can be from 10¹⁸ to 10¹⁹ cm⁻³. In some cases, a dopant profile of the base region can have a peak near or at the lateral boundary between the emitter region 206 and the base well 208.

In some cases, the dielectric layers and field plates in the extended layer stack of the L-BJT 350 may allow for increasing D_{DR} compared to that of an L-BJT having an extended drift region without the field plates reduce the resistance of the drift region.

In some cases, in addition to altering the E-field in the extended drift region, the field plates may dissipate heat generated by the L-BJT 350 and thereby improve the performance of the L-BJT 350 by allowing larger currents to follow across different region of the L-BJT 350 before the onset of current limiting thermal effects.

FIG. 16B schematically illustrates a cross-sectional view of the L-BJT 350 shown in FIG. 16A and variation of the electric field along the extended drift region of the L-BJT. As described above, the field plates 1510a, 1510b, 1612, produce a vertical E-field component (E_{RESURF}) in the extended drift region. The total E-field (Eₜₒₜ) at any point along the extended drift region can correspond to a vector sum of the emitter-base junction E-field and the E_{RESURF}. In some cases, at least the magnitude of the lateral component of the Eₜₒₜ(E_{tot-L}) 1506 remains constant or nearly constant along the extended drift region from the base-emitter junction to the HD collector region (in the lateral direction). In some examples, the lateral component of the Eₜₒₜ along the extended drift region, from HD collector region 707 to the base well 208, may change less than 2%, less than 4%, less than 6%, less than 8%, or less than 10% of its vale at the boundary of the base well 208. In some examples, the lateral component of the Eₜₒₜ along the extended drift region, from HD collector region 707 to the base well 208, may remain less than threshold value (e.g., E_{critical}) that may cause break down in a oxide layer (e.g., RESURF dielectric layer 734a) or a junction (e.g., base-collector junction), of an L-BJT (e.g., an L-BJT having an extended drift region).

The voltage drop from the HD collector region 707 to HD emitter region 206 is equal to the area under the curve 1506 or |E_{tot-L}|×L_{drift}, where L_{drift} is the length of the extended drift region in the lateral direction. In some cases, Vₘ for the L-BJT 350 can be substantially equal to |E_{critical}|×L_{drift}, where E_{critical} is an E-field magnitude that can cause electrical break down in the emitter-base junction or the RESURF dielectric layer 734a. In other words, the minimum length of the extended drift region for a desired Vₘ, or the Vₘ for a given L_{drift} are constrained by E_{critical} that depends on the material and thickness of the RESURF dielectric layer, and the material and doping characteristics of the emitter-base junction. In the absence of the field plates, 1510a, 1510b, and 1612, the magnitude of the E_{tot-L} 1504 could monotonically decrease, e.g., substantially linearly decrease, along the extended drift region from the base-emitter junction to the HD collector region (in the lateral direction). As such, to for the E_{tot-L} to stay below or close to E_{critical} near the base-emitter junction, the length of the drift region should be longer in the absence of the field plates. In the absence of the field plates, Vₘ can be correspond to or approximated as |E_{critical}|×(L′_{drift}/2), or the area below E_{tot-L} 1504 line. So for a given Vₘ and E_{critical} the length of the extended drift region (L′_{drift}) in the absence of the field plates can be about two times larger than the length (L_{drift}) of the extended drift region in the presence of the field plates for the L-BJT 350.

In some embodiments, Vₘ can be further increased by elongating the extended drift region and adding yet an additional (e.g., a fourth) field plate extended over at least a portion of the elongated section of the extended drift region. In some cases, the thick isolating dielectric layer 1614 may be elongated to provide isolation between the additional field plate and the elongated section of the extended drift region. FIG. 16C schematically illustrates a side cross-sectional view of an HV L-BJT 1600 having a yet longer drift region extension 304b and thick isolating dielectric layer 1614 compared to HV L-BJT 350. The HV L-BJT 1600 also includes a fourth field plate 1618 that is laterally extended from a distal end of the third field plate 1612, with respect to the second field plate 1510b, toward the HD collector region 707. In some cases, the third and fourth field plates 1612, 1618, are substantially parallel to the top surface of the substrate or the top surface of the thick isolating dielectric layer 1614. A vertical distance h₁ (e.g., along z-axis) between the third field plate 1612 and the top surface of the thick isolating layer 1614 can be larger than a vertical distance h₂ (e.g., along z-axis) between the fourth field plate 1618 and the top surface the thick isolating layer 1614. In some cases, the third and fourth field plates 1612, 1618, can be fabricated in two different metallization layers (e.g., adjacent metallization layers of an IC), where one metallization layer is above the other. In various implementations, a difference between h₁ and h₂ can be from 0.5 to 1.0 microns. In some examples, h₁ and h₂ can be from 0.5 to 2.5 microns, or a value in any range defined by these values or smaller or larger.

In various implementations, the third and the fourth field plates 1612, 1618, may cover at least 20%, 30%, 40%, 50%, or 60% of a lateral length of the thick isolating dielectric layer 1614. In various implementations, the third field plate 1612 may cover at least 20%, 30%, 40%, 50%, or 60% of the lateral length thick isolating dielectric layer 1614. In various implementations, the third and the fourth field plates 1612, 1618, may cover at least 20%, 30%, 40%, 50%, or 60% of a lateral length of the extended drift region. In various implementations, the third field plate 1612 may cover at least 20%, 30%, 40%, 50%, or 60% of the lateral length of the extended drift region.

In some cases, a doping profile of the L-BJT 1600 can be similar to the doping profile 1616 described with respect to L-BJT 350. The placement of the HD base regions of the L-BJT 350 and L-BJT 1600, with respect to the corresponding HD emitter regions 206, is similar to the placement of the HD base regions 802a/802b in the L-BJT 800 (FIGS. 8A and 8B).

The variations of the voltage 1602 and electric field 1506 along the extended drift region are shown below the corresponding drift region and drift region extension 304b. As shown in FIG. 16C, the isolating dielectric layers and field plates can maintain the lateral component of the E-field 1506 constant or nearly constant along the drift region. As such the voltage 1602 monotonically, e.g., substantially linearly, drops from the HD collector region 707 toward the HD emitter region 206. Similar to the L-BJT 350 (FIG. 3B), Vₘ for the L-BJT 1600 is equal to |E_{critical}|×L_{drift}. Given that L_{drift} is longer for the L-BJT 1600, Vₘ can be larger for the L-BJT 1600 compared to the L-BJT 350. In the example, shown the Vₘ for the L-BJT 1600 is about 250 V.

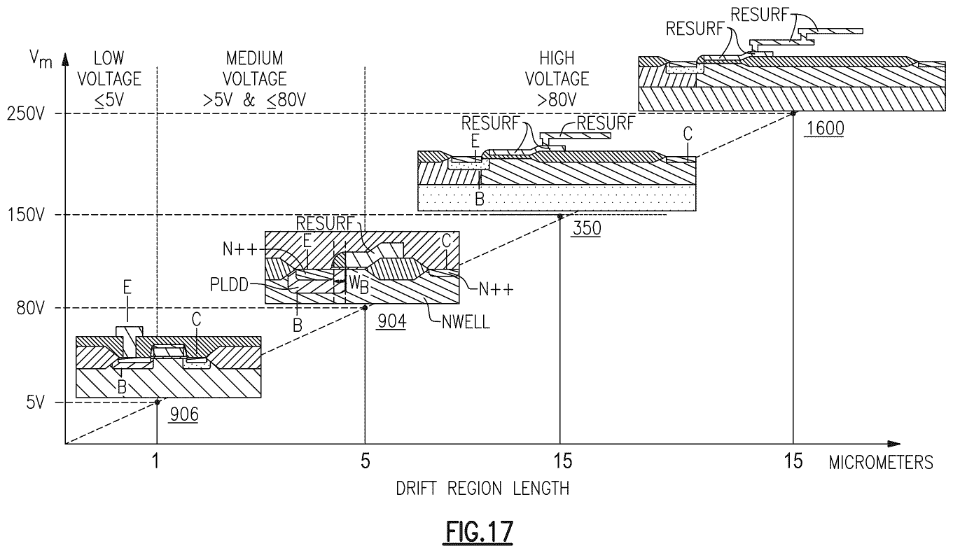

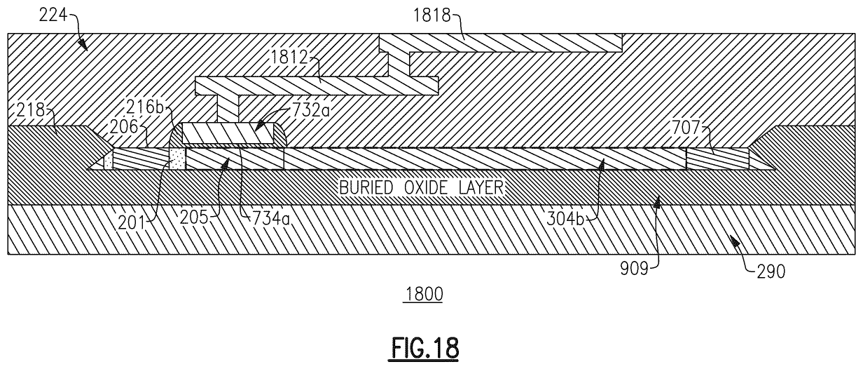

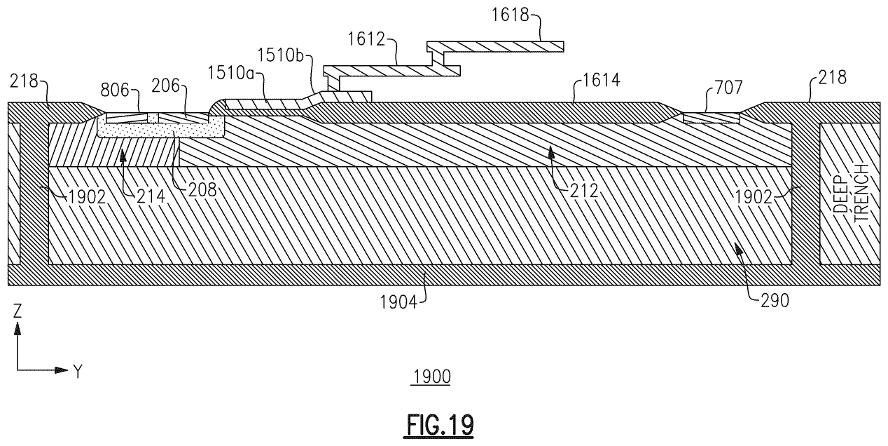

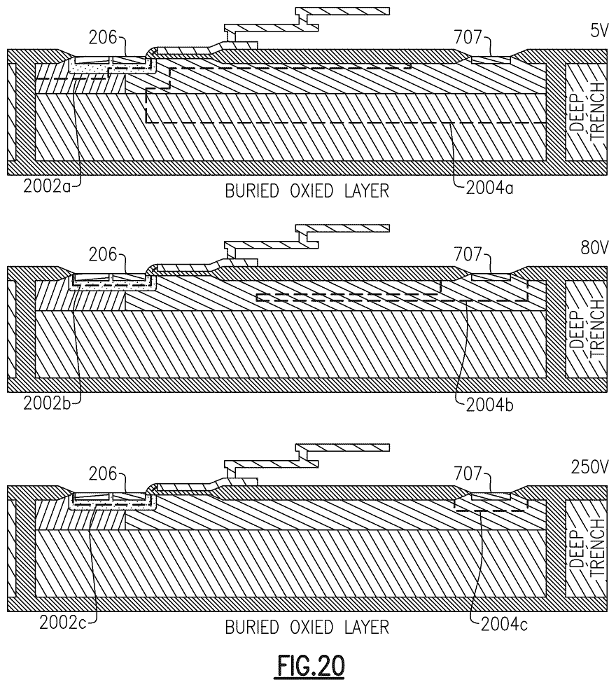

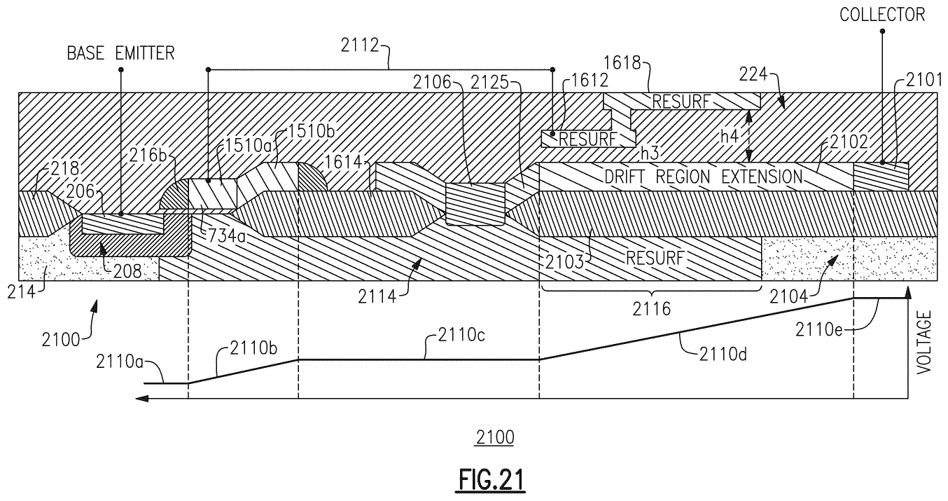

FIG. 17 schematically illustrates Vₘ (the upper limit for the operating voltage) plotted against the length of the drift region for four different L-BJT designs and structures described herein. The low voltage (LV) L-BJT 906 and similar L-BJT designs (e.g., L-BJT 908, 910, 902, 904, 240, or 235) that include a single field plate over a thin dielectric layer (RESURF dielectric layer) and/or have drift region length less than 1.0 microns, may have a Vₘ smaller or equal to 5 volts. The medium voltage (MV) L-BJT 904 and similar L-BJT designs that include two field plates, one disposed on a thin dielectric layer and the other on a thick dielectric layer, and/or have a drift region length greater than 1.0 microns but smaller than 5.0 microns, may have a Vₘ larger than 5 volts but smaller than or equal to 80 volts. The High Voltage (HV) L-BJT 350 and similar L-BJT designs that include three field plates, one over a thin dielectric layer and two over a thick dielectric layer and/or have a drift region length greater than 5.0 microns but smaller than 15.0 microns, may have a Vₘ larger than 80 volts but smaller than or equal to 150 volts. The HV L-BJT 1600 and similar L-BJT designs that include four field plates, one over a thin dielectric layer and three over a thick dielectric layer, and/or have a drift region length greater than 15.0 microns, may have a Vₘ larger than 150 volts.

In some cases, an L-BJT having a drift region length less than 1.0 microns can be an LV L-BJT with a Vₘ less than 5 volts, an L-BJT having a drift region larger than 1.0 and smaller than 5.0 microns can be an MV L-BJT with a Vₘ greater than 5 volts and less than 80 volts, an L-BJT having a drift region length larger than 5.0 microns and smaller than 15.0 microns can be an HV L-BJT with a Vₘ greater than 80 volts and less than 150 volts, and an L-BJT having a drift region length larger than 15.0 microns can be an HV L-BJT with a Vₘ up to 150 volts or greater.

In some cases, a length of the extended drift region of the L-BJT 350 or the L-BJT 1600, in the lateral direction, can be substantially equal to a length of the first field plate 1510a in the lateral direction. In some cases, a length of the drift region extension 304b of the L-BJT 350 or the L-BJT 1600 can be substantially equal to the length of the thick isolating dielectric layer 1614.

In various implementations, all the field plates of an L-BJT are electrically connected to each other. In some examples, the third field plate 1612 can be electrically connected to the second field plate 1510b via a first vertical conductive line (e.g., a first conductive via), and the fourth field plate 1618 can be electrically connected to the second field plate 1612 via a second vertical conductive line (e.g., a second conductive via). In some embodiments, the first and the second field plates 1510a, 1510b, may comprise polysilicon. In some embodiments, the third and fourth field plates 1612, 1618, may comprise metal (e.g., copper, gold, aluminum, chromium, or an alloy made of two or more metals). In various examples, one or more field plates may comprise a doped semiconductor (e.g., doped polysilicon). In various examples, one or more field plates may comprise a metal or metallic alloy.

In some examples, the field plates 1510a, 1510b, 1612, and 1618, may be electrically connected to a potential (referred to as RESURF potential) having a magnitude less than the magnitude of a potential applied to the HD collector region 707. For example, the field plates 1510a, 1510b, 1612, and 1618, may be electrically connected to the emitter region 206 or potential provided to the emitter region 206. In some example, the field plates 1510a, 1510b, 1612, and 1618, may be electrically connected to a ground potential. In various implementations, a potential of the field plates 1510a, 1510b, 1612, and 1618, may remain constant or nearly constant during the operation of the corresponding L-BJT.

In some embodiments, the extended drift region can be further elongated and more field plates may be added over of the elongated section of the extended drift region to further increase Vₘ of an HV L-BJT. A vertical distance between a field plate and the top surface of the thick dielectric layer 1614 (or a top surface of the drift region extension 304b) may be smaller than a vertical distance between a subsequent field plate and the top surface of the thick dielectric layer 1614. In some cases, the increasing vertical distances of the subsequent field plates from a surface can contribute in maintaining a lateral component of the E-field substantially constant along the extended drift region and thereby increasing Vₘ.

In some examples, the field plates 1510a, 1510b, 1612, and 1618, and any additional field plate(s), may be fabricated on different metallization layers (e.g., metallization layers of an IC).

In various embodiments, an HV L-BJT, having an extended drift region and field plates, may be electrically isolated from low or medium voltage electronic devices (e.g., LV and MV L-BJTs and MOS transistors) fabricated on the same substrate, to avoid perturbation or damage to those devices due to unintended coupling of a high level voltage from the HV L-BJT. In some cases, electrical isolation may comprise complete isolation of the HV L-BJT both in the lateral and vertical directions to block carrier transport or E-field coupling through nearly all regions of the HV L-BJT to a region of the substrate comprising low or medium voltage devices. In some cases, a complete isolation may be achieved using a combination of a buried dielectric layer (e.g., a buried oxide layer) and deep trenches filled with a dielectric material (e.g., deep trench oxides), or isolating dielectric layers near the top surface of the device (e.g., LOCOS field oxide layers or shallow trenches filled with a dielectric material).

FIG. 18 schematically illustrates a side cross-sectional view of an HV L-BJT 1800 with extended drift region, which is fully isolated. In some cases, L-BJT 1800 can be laterally isolated by the isolation dielectric layers 218 (e.g., field oxide or shallow trench isolation (STI) layers), and vertically isolated by a buried dielectric layer 909 (e.g., buried oxide layer). In some cases, the L-BJT 1800 can be laterally isolated by the shallow dielectric filled trenches (e.g., shallow trench oxide also referred to as STI) similar to the isolation dielectric layers 1100, described above with respect to FIGS. 11A-11F. L-BJT 1800 may comprise one or more features described above with respect to the L-BJT 350 or L-BJT 1600.

In some examples, the buried dielectric layer 909 may be in contact with the dielectric layers 218. In some examples, a vertical gap or distance (e.g., along z-axis) between a bottom surface of the dielectric layer 218 and a top surface of the buried dielectric layer 909 can be less than 5 nm, less than 10 nm, or less than 20 nm. In some cases, the extended drift region of the L-BJT 1800 may comprise a drift region 205 below a layer stack and a drift region extension 304b. The layer stack may comprise a RESURF dielectric layer 734a, and a RESURF layer (or a first field plate) 732a disposed on RESURF dielectric layer 734a. The base well of the L-BJT 1800 can be vertically extended from a top surface of the buried dielectric layer 909 to a cladding dielectric layer 224, e.g., a passivation layer, disposed on the L-BJT 1800 along its entire length. A thickness of the emitter region 206 and a thickness of the HD collector region 707 can be substantially equal to the thickness of the base well along the vertical direction.

The drift region 205 of the L-BJT 1800 is extended in the vertical direction from a top surface of the buried dielectric layer 909 to a bottom surface of the RESURF dielectric layer 734a. The drift region extension 304b of the L-BJT 1800 is bound in the vertical direction by the cladding dielectric layer 224, and the top surface of the buried dielectric layer 909. In some embodiments, the fully isolated L-BJT 1800 may not include a thick isolating dielectric layer above its drift region extension 304b. The field plates of the L-BJT 1800 include the first field plate (RESURF layer) 732a, a second field plate 1812, and a second field plate 1818. In some cases, the second field plate 1812 may be extended in the lateral direction from a first end approximately aligned with a middle region of the first field plate 732a to a second end above the drift region extension 304b. The third field plate 1818 may be extended in the lateral direction from a point near the second end of the first field plate 1812 away from the first field plate 1812.

In some cases, the field plates 1812, 1818 of the L-BJT 1800 may maintain a magnitude of the lateral E-field component in the drift region 304b constant or nearly constant from the emitter-base junction to the HD collector region 707 of the L-BJT 1800. As such the L-BJT 1800 may have a Vₘ larger than 80 volts.

In some implementations, the length of the extended drift region of the L-BJT 1800 can be further increased by increasing the lateral distance between the base well and the HD collector region 707 and adding a fourth field plate above the third field plate 1818.

In some cases, a doping profile of the L-BJT 1800 can be similar to the doping profile 1616 described with respect to L-BJT 350.

In some embodiments any of the L-BJT's (e.g., L-BJT 240, 730, 350, or 1600) described above can be isolated in the lateral direction using deep trenches filled with a dielectric material (e.g., an oxide). These deep trenches may be extended from the isolating dielectric layers 218 to a buried dielectric layer that vertically isolates (electrically) an upper region of the substrate 290 below the doped wells, in which the L-BJT is formed, from a lower region of the substrate 290. FIG. 19 schematically illustrates an example HV L-BJT 1900 having an extended drift region, which is fully isolated using deep dielectric trenches 1902 and a buried dielectric layer 1904. The fully isolated L-BJT 1900 comprises one or more features described above with respect to L-BJT 1600. The placement of the HD base region 806 with respect to the HD emitter region 206 for L-BJT 1900 is similar to the placement of the HD base region 806 of the L-BJT 804. In some examples, a height of a deep dielectric trench 1902 along the vertical direction (z-axis), can be from 1 to 5 microns, from 5 to 10 microns, from 10 to 15 microns, from 15 to 20 microns, or larger values.

FIG. 20 schematically illustrates the depletion regions of the L-BJT 2000 at three different magnitudes of bias or input voltages (e.g., voltages applied between the HD collector region 707 and the HD emitter region 206. The evolution of the depletion regions of the L-BJT 350, 1600, 1800 and similar L-BJT designs having an extended drift region can be at least qualitatively similar to the evolution of the depletion regions of the L-BJT under the same biasing conditions.

In some cases, the depletion regions of the L-BJT 2000 may be formed by two boundaries, including a first boundary near the emitter-base junction and the base well, and a second boundary surrounding the HD collector region 707 and extending into the collector region and sometimes a portion of the substrate below the collector region.

As one example, at a relatively low bias voltage of about 5 volts, the first boundary 2102a may extend from the base region to a region below the base well, and the second boundary 2104a may extend along the entire drift region including a portion of the substrate below the collector region.

As another example, at a medium bias voltage of about 80 volts, the first boundary 2102b may become confined in the well and surround the HD emitter region 206 and HD base region 806, and the second boundary 2104b may be contracted back toward the HD collector region and may entirely be in the drift region extension.

As yet another example, at a relatively high bias voltage of about 250 volts, the first boundary 2102c may remain substantially unchanged compared to the first boundary 2102b under 80 volt bias, while the second boundary 2104c may further contracted and be confined around the HD collector region.

While fully isolating an HV L-BJT using shallow or deep dielectric filled trenches and a buried dielectric layer based on the architectures described above may highly effectively prevent current and/or voltage coupling to low or medium voltage devices fabricated on the same substrate, implementation of these isolation structures can be costly, and significantly increases the complexity and cycle time of the fabrication process. Fabricating deep trenches and filling them with dielectric material requires additional process steps that are longer and more complicated compared to local oxidation of silicon (LOCOS) and fabrication of shallow trench isolation (STI) layers. The buried dielectric layer is typically embedded in the wafer or the substrate on which the HV L-BJT is fabricated. An example, of such wafer is silicon-on-oxide (SOI) wafer that is significantly more expensive than a regular silicon wafer.

To reduce cost, complexity, and cycle time for fabricating HV L-BJT properly isolated from the low or medium voltage devices fabricated on the same substrate, in some cases, the high voltage region of the device may be isolated from the other regions by thick isolating dielectric layers (e.g., fabricated by LOCOS) on the surface of the device. As described above, in an HV L-BJT the high voltage provided to HD collector region drops along the extended drift region. As such, electrically isolating the HD collector region and the extended drift region from the base region, and the emitter region can decouple the high voltage from the substrate on which other electronic devices are fabricated.

FIG. 21 schematically illustrates a cross-sectional view of an HV L-BJT 2100 with an isolated drift region extension 2102 and four field plates 1510a, 150b, 1612, 1618. The architecture of the HV L-BJT 2100 has been modified with respect to the HV L-BJT 1600 (FIG. 16C) to allow for vertical isolation of the HD collector region 2101 and the drift region extension 2102 from the rest of the device, which operates at a low or medium voltage level, using a second thick dielectric layer (e.g., a second field oxide layer) 2103. The HD collector region 2101 and the drift region extension 2102 have the same polarity but the drift region extension 2102 can be an LD region having a smaller dopant concentration.

The HV-LBJT 2100 may include an emitter region 206, a base well 208, spacers 216b, a first field plate 1510a, a second field plate 1510b, a RESURF dielectric layer 734a, and a thick isolating dielectric layer 1614. In some implementations, doping profiles, physical dimensions, configuration, and relative alignment of the emitter region 206, the base well 208, the spacer 216b, the first field plate 1510a, the second field plate 1510b, a RESURF dielectric layer 734a, and the thick isolating dielectric layer 1614 of the HV L-BJT 2100 may be identical or similar to those of the HV L-BJT 1600 (FIG. 16C) or 350 (FIGS. 16A and 16B), the detailed description of which are not repeated herein for brevity.

The RESURF dielectric layer 734a, the thick isolating dielectric layer 1614, and the base well 208 may be formed in or disposed on a main well (e.g., a common well) 2114 having a polarity opposite to the polarity of the drift region extension 2102. In some cases, the base well 208 may be partially formed in the main well 2114 and a second well 214 having a polarity opposite to that of the base well 208. In some cases, a vertical boundary between the second well 214 and the main well 2114, below the base well 208, can be aligned with a vertical boundary between the emitter region and base well, below the spacer 216b.

In some cases, the second thick isolating dielectric layer 2103 is partially disposed or grown on the main well 2114 and a third well 2104 having the same polarity as the drift region extension 2102 (opposite to the polarity of the main well 2114).

The HV L-BJT 2100 also includes a third and a fourth field plate 1612, 1618 that are laterally extended above a portion of the drift region extension 2102. In some cases, the third and fourth field plates 1612, 1618, are parallel to the top surface drift region extension 2102. A vertical distance h₃ (e.g., along z-axis) between the third field plate 1612 and the top surface of the drift region extension 2102 can be larger than a vertical distance h₄ (e.g., along z-axis) between the fourth field plate 1618 and the top surface the drift region extension 2102. In various implementations, a difference between h₃ and h₄ can be from 0.5 to 1.0 microns. In some examples, h₁ and h₂ can be from 0.5 to 2.5 microns, or any value in a range defined by any of these values or smaller or larger. In some cases, the third and fourth field plates 1612, 1618, can be fabricated in two different metallization layers (e.g., metallization layers of an IC) and can be electrically connected via a vertical conductive line.

Similar to HV L-BJT 1600, the third and the fourth field plates 1612, 1618, may maintain a lateral component of the E-field in the drift region extension 2102, constant along drift region extension 2102. A section 2116 of the main well 2114 below the drift region extension 2102 may function as an auxiliary field plate further reducing the variation of the lateral component of the E-field in the drift region extension 2102.

The third and fourth field plates 1612, 1618, are electrically connected to the first and second field plates 1510a, 1510b, e.g., via a conductive line 2112 having at least one lateral section and one vertical section.

In some cases, the drift region extension 2102 of the IV L-BJT 2100 may be electrically connected to the main well 2114 via an LD connecting layer 2125 and an HD connecting region 2106.

When the HV L-BJT 2100 is biased, e.g., a potential difference is generated between the HD collector region 2101 and the emitter region 206, the voltage variation the device may have a piecewise behavior. For example, the illustrated voltage curve in FIG. 21 shows relatively constant voltage curve portions 2110a, 2110c and 2110e, and monotonically varying voltage curve portions 2110b, 2110d. As illustrated, the voltage remains relatively or nearly constant along the HD collector region 2101 as shown by the voltage curve portion 2110e, varies (e.g., monotonically, e.g., substantially linearly) along the drift extension region 2102 as shown by the voltage curve portion 2110d, remains relatively or nearly constant along the region extending from a boundary of the drift region extension 2102 to an edge of the second field plate 1510b as shown by the voltage curve portion 2110c, varies (e.g., monotonically, e.g., substantially linearly) along the drift region under the first and the second field plates 1510a and 1510b as shown by the voltage curve portion 2110b, and remains relatively or nearly constant in the base region as shown by the voltage curve portion 2110a. As such the voltage drops from an input voltage (Vᵢₙ) level applied to the HD collector region to an intermediate voltage (V_{Mid}) along the drift region extension 2102, which is electrically isolated from the substrate along the vertical direction, and from the first voltage to a final voltage (V_{Fin}) along the drift region. In some cases, the first voltage can be equal less than 5 volts. In some cases, the ratio between the intermediate voltage and the input voltage (V_{Mid}/Vᵢₙ) can be less than 50%, less than 40%, less than 30%, less than 20%, or less than 10%. In some cases, the voltage drop in the drift region extension (2102) may be increased or the ratio V_{Mid}/Vᵢₙ can be decreases by elongating the drift region extension 2102. To support a monotonic or substantially linear voltage drop along the drift region extension 2102, more field plates may be added above the drift region extension 2102. A vertical distance of each field plate from the top surface of the drift region extension 2102 can be smaller than a vertical distance of a subsequent field plate from the top surface of the drift region extension 2102.

In some cases, the emitter region 206, the base well 208, the spacer 216b, the first field plate 1510a, the second field plate 1510b, and the thick isolating dielectric layer 1614 of the HIV L-BJT 2100 and corresponding features of a MOS transistor (e.g., MOS transistor 280), an MV MOS or DMOS transistor (e.g., the MOS transistor 740), or an HV MOS or DMOS transistor (e.g., the MOS transistor 300) may be co-fabricated and have a common physical dimension.

In some embodiments, a length of the thick isolating dielectric layer 1614 in the lateral direction, can be from 0.5 to 5.0 micrometers, or any value in a range defined by any of these values or larger or smaller.

In some embodiments, a length of the first field plate 1510a (RESURF layer) can be from 0.18 to 1.0 micrometers, or any value in a range defined by any of these values or larger or smaller.

In some embodiments, a length of the second field plate 1510b (RESURF layer) can be from 0.5 to 5.0 micrometers, or any value in a range defined by any of these values or larger or smaller.

In some embodiments, a length of the third or fourth field plates 1612, 1618, can be from 1 to 15 micrometers, or any value in a range defined by any of these values or larger or smaller.

In some examples, a lateral length of the third field plate 1612 can be from 1-5 μm, and the lateral length of the fourth field plate can be from 1-15μ. Their vertical distance from the top surface of the drift region extension 2102 can be 0.5 and 2.5 μm, respectively.

In some embodiments, the third and fourth field plates 1612, 1618, may cover 50% to 60%, 60% to 70%, 70% to 80%, 80% to 90%, or 90% to 100%, or any percentage in a range defined by any of these values or larger or smaller, of the length of the thick isolating dielectric layer 1614.

While the region below the base well of the L-BJTs 350, 1600, and 2100 comprises two regions having opposite polarities, in some cases, the region below these base wells may not comprise two regions having opposite polarities. As described above, splitting the region below the base well into two regions with opposite polarities and aligning a vertical interface between the two regions with the emitter-base junction may improve the performance of the L-BJT.

In various implementations, the L-BJTs having extended drift regions (e.g., L-BJT 350 (FIG. 16A, 16B), 1600 (FIG. 18), 1800 (FIG. 18)), can be NPN or PNP bipolar transistors. For example, an n-type emitter region, a p-type base well 208, n-type extended drift region, and an n-type HD collector region may form an NPN bipolar transistor, and a p-type emitter region, an n-type base well 208, p-type extended drift region, and an p-type HD collector region may form a PNP bipolar transistor. In some embodiments, an L-BJT having extended drift region (e.g., L-BJT 350, 1600, 1800), can be at least partially co-fabricated with a HV MOS transistor (e.g., a DMOS) having an extended channel region or an LV MOS transistor. In some embodiments, one or more features of the HV L-BJT and the HV MOS transistor (or an LV MOS transistor) may have common physical dimensions. For example, a bottom width of a spacer, a length of the RESURF layer and the RESURF dielectric layer, a length of the emitter region, a length of the base well, or a length of the HD collector region of the HV L-BJT, can be substantially equal to a bottom width of a spacer, a length of the gate layer and the gate dielectric layer, a length of the HD source region, a length of the LD source region, or a length of the HD drain region of the HV MOS transistor.

In some implementations, and the corresponding features of the HV MOS transistor and the HV L-BJT, e.g., those features having common physical dimensions, may be synergistically co-fabricated during the same fabrication step(s) on a common substrate. Unlike the HD and LD source regions of the HV MOS transistor, the emitter region and the base well of the HV-LBJT do not have same polarity, in both cases the boundary of the LD and HD regions are defined by the RESURF dielectric layers and the spacers.

As mentioned above, the structure and configuration of the base well, base region, emitter region, RESURF layer, and the RESURF layer stack in an HV L-BJT having an extended drift region (e.g., the HV L-BJT 350 or HV L-BJT 1600) can be identical to an LV L-BJT (e.g., the L-BJT 240). As such fabrication steps described above with respect to co-fabrication of the L-BJT 240 with the MOST transistor 280 on a common substrate may be used to co-fabricate at least the base well, base region, emitter region, RESURF layer, and the RESURF layer stack of the HV L-BJT 350 (or L-BJT 1600) and the respective regions of the MOS transistor 280.

### Depletion Field Effect Potential Divider

As described above, with respect to FIGS. 4A and 4B, an inventive aspect relates to structures for dividing low voltage (5V or less) regions from voltage drop regions, e.g., in HV L-BJT 350 and HV MOS transistor 300. By physically separating a collector region along which the potential drops from a voltage greater than 5 volts to a voltage equal or less than 5 volts, a broad range of voltages can be supported on a single chip that includes a first region on which LV MOS or LV BJT (e.g., L-BJT) devices are monolithically fabricated (e.g., co-fabricated or at least partially co-fabricated) and a second region in which a potential divider (PD) is fabricated. In some cases, the first and the second regions can be electrically isolated and the devices in the first region can be electrically connected to the PD via conductive lines comprising vertical sections connected to the PD and the devices receiving voltage from the PD, and lateral sections fabricated in metallization layers above the first and second regions, connecting the vertical sections. The PD can be a silicon based device and include features similar to the drift region extension of an HV L-BJT (e.g., HV L-BJTs 350, 1600). A PD may be designed to monotonic or substantially linearly scale a high voltage (e.g., a voltage greater than 5 volts, 10 volts, 50 volts, 80 volts, 100 volts, 200 volts, or greater) applied on an input port (or input node) to a low voltage (e.g., less than or equal to 5 volts) at an output port (or output node).

In some cases, the PD can be fabricated using the same low cost and fast cycle time bipolar-CMOS (BiCMOS) core process used for fabrication of LV MOS and BJT transistors. This approach has the advantage of enabling higher voltage signals to be monotonic or substantially linear scaled to the voltage node of any host process platform to enable a range of different design applications. Accordingly, superior analog signal translation between process platforms can be achieved.

In certain embodiments disclosed herein, the potential divider (PD) can be a semiconductor device configured to operate based on the principles of a depletion field effect (DFE). As such, the disclosed PD may be referred to as a depletion filed effect PD or DFE-PD. The DFE-PD monotonic or substantially linearly scales a higher input voltage at a first node (an input node) to a lower voltage at a second node (an output node). Thus, the DFE-PD is advantageous adapted for analog signal translation. In some embodiments, DFE-PD is a semiconductor device comprising a plurality of individually doped silicon regions (for example, four regions, or in certain implementations five or more regions) arranged to form a first semiconductor junction at the input node and a second semiconductor junctions at the output node. Upon biasing the DFE-PD (e.g., applying a voltage to input node) according to embodiments, both the first and second junctions (e.g., PN junctions) can be reverse biased. When a voltage is applied to the input node a portion of the charge induced in the input node can be coupled from the first junction to the second junction generating an output potential in the output node thus serving as a potential divider (PD). A ratio of the voltage scaling can be defined by the ratio of charge coupled from the first junction to the second junction. By electrically connecting the DFE-PD in series with an LV BJT, an LV MOS transistor, or any suitable LV device, the voltage scaling operation can be electrically and physically separated from the a low voltage BiCMOS platform.

In certain implementations, the full extent of the voltage scaling can range from a direct one-to-one voltage translation to a situation in which the output voltage is independent of the input voltage and fixed to be substantially constant. In some embodiments, the construction and operation of a depletion field device can exist between two extreme operation regions or device classes. At one extreme, a punch-through device is provided where charge applied to a first depletion region of the first junction is directly coupled onto a second depletion region of the second junction such that the input voltage is substantially equal to the output voltage. At the other extreme, charge provided to the input node is substantially completely coupled onto one or more gate regions that shield the output node from any charge coupling from the input node. This results in a device having a substantially fixed output voltage that is relatively independent of an input voltage.

It is desirable to create a DFE-PD device that operates between these two extremes in order to monotonic or substantially linearly transform an input voltage signal into a scaled down output signal at least within an input voltage range (e.g., a voltage range having a lower bound of zero volt). To achieve this, an architecture similar to a junction field effect transistor (JFET) or a modified JFET structure can be used in which an inter-gate region has a shortened length, and a light doping concentration, and the same polarity as the gate regions (cf. an inter-gate region of a JFET, having a polarity opposite to the gate regions). In some cases, the inter-gate region on a DFE-PD electrically connects the gate regions.

In some cases, shortening the length of an inter-gate region eliminates voltage saturation at a pinch-off output voltage, and the reverse polarity and low doping concentration of the channel region (compared to a JFET) generates continuous voltage translation curve having a linear or substantially linear region and shifts a punch-through voltage of the device down (e.g., to zero voltage). In certain implementations, the length of the inter-gate region is balanced against the doping concentration such that the depletion regions of the input junction (first junction) and the depletion region of the output junction (the second junction) are coupled at zero input voltage. This results in a device that monotonically or substantially linearly translates an input voltage to a scaled down output voltage, where the magnitude of the scaling factor proportional by the ratio of the charge coupling. As such, the DFE-PD monotonically or substantially linearly scales an input voltage (Vᵢₙ) to a reduced output voltage (Vₒᵤₜ), where a scaling ratio (slope of the Vᵢₙ-Vₒᵤₜ curve) can be adjusted to a suitable value by carefully tailoring the length of the inter-gate region doping concentration.

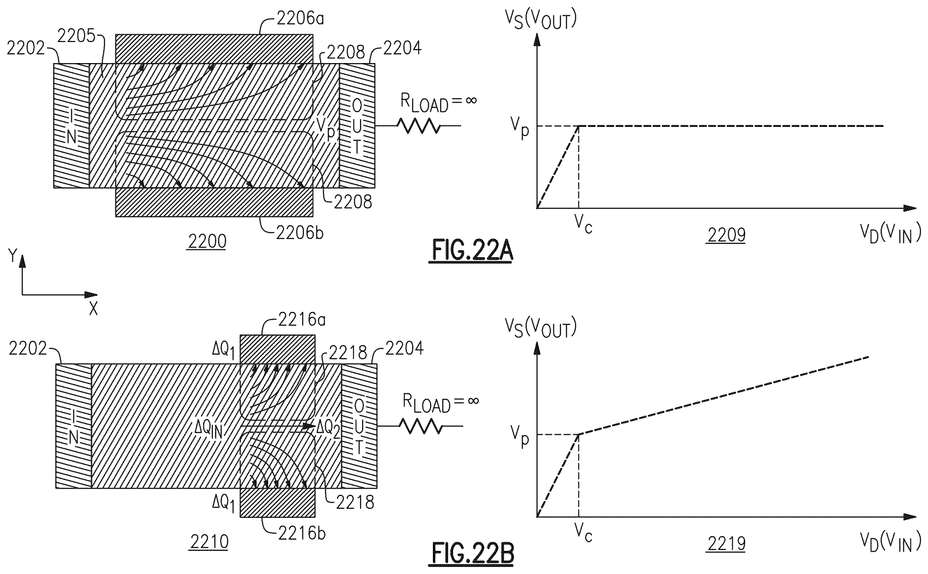

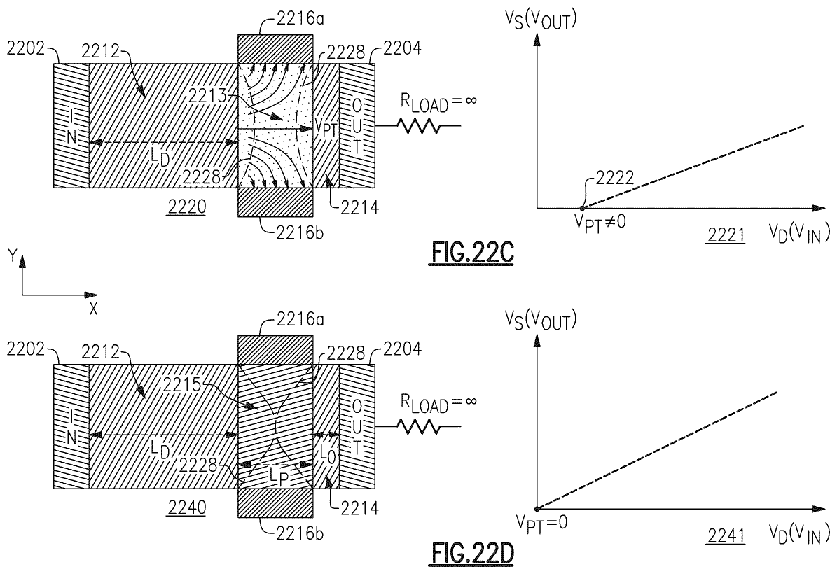

FIG. 22A schematically illustrates a cross-sectional view of a semiconductor device 2200 for voltage reduction with output saturation, and the corresponding voltage transfer function in an open ended output configuration. The semiconductor device 2200 can monotonically or substantially linearly scale an input voltage until the output voltage reaches saturation voltage (Vₚ). In some cases, the semiconductor device 2200 can be configured to be similar to a JFET. The semiconductor device 2200 includes an LD channel region 2205 extended from an input region 2202 to an output region 2204 along a first lateral or longitudinal direction (e.g., along the x-axis), and two highly doped (HD) gate regions 2206a, 2206b, disposed on opposite sides of the LD channel region 2205 in a second lateral or transverse direction (e.g., y-axis) perpendicular to the longitudinal direction. The input region 2202, the output region 2204, and the channel region 2205 have a same polarity opposite to a polarity of the gate regions 2206a, 2206b. For example, the gate regions 2206a, 2206b may comprise p-type semiconductors and the input region 2202, the output region 2204, and the channel region 2205 may comprise n-type semiconductor. The first gate region 2206a and the second gate region 2206b can have the same nominal potential (e.g., can be electrically shorted). The first and second gate regions 2206a, 2206b form PN-junctions 2208 with the channel region 2202.

Carrier transport and E-field distribution in the inter-gate region of the channel region 2205 are controlled by the electrical characteristics of the gate regions 2206a, 2206b and a potential applied across these gate regions. The Vᵢₙ-Vₒᵤₜ plot 2209 shows the potential of the output region 2204 as a function of the potential of the input region 2202 for a given voltage difference between output region 2202 and the HD gate regions 2206a, 2206b, and when the output region 2204 is open ended (e.g., R_{LOAD}>1MΩ). As Vᵢₙ is increased, Vₒᵤₜ increases monotonically or substantially linearly and a gap between the depletion regions 2208 becomes progressively smaller. At Vᵢₙ=V_{c} the gap between the two depletion regions 2208 is closed and the electrical connection between the input regions 2202 and the output region 2204 is pinched off by the depletion regions, resulting in saturation and clamping of Vₒᵤₜ at Vₚ (pinch-off voltage).

While the Vᵢₙ-Vₒᵤₜ behavior of the semiconductor device 2200 can be useful for reducing and limiting the voltage provided to a low voltage device, e.g., for protection from high voltage damage, for applications where a high voltage signal (e.g., a time varying signal) has to be controlled, processed by a circuit comprising LV devices, the saturation of the output voltage can distort the signal by chopping a portion of the signal having a voltage larger than a voltage (V_{c}) at which Vₒᵤₜ becomes saturated. For such applications, the PD may be configured to monotonically or substantially linearly scale Vᵢₙ to Vₒᵤₜ with a scaling factor across a voltage range that is equal or larger than a peak voltage of the high voltage signal that should be processed by the LV device.

The monotonic or substantially linear scaling from Vᵢₙ to Vₒᵤₜ can be achieved by modifying the structure of the semiconductor device 2200. As a first step, the length of the inter-gate region of the semiconductor device 2200 may be reduced to increase the slope of the saturated portion (Vᵢₙ>V_{c}) of the Vᵢₙ-Vₒᵤₜ curve 2209 from zero to a positive value. FIG. 22B schematically illustrates a cross-sectional view of another semiconductor device 2210 configured for voltage reduction, without output saturation, and the corresponding voltage transfer function (Vᵢₙ-Vₒᵤₜ curve) 2219 in an open ended output configuration. The structure of the semiconductor device 2210 can be arranged to the same as the structure of the semiconductor device 2210, except for the length of the inter-gate region, which is reduced compared to that of the device 2200, to allow for some charge coupling from the input region 2202 to the output region 2204 even when Vᵢₙ is larger than Vₒᵤₜ. In some cases, length of the inter-gate region of the semiconductor device 2200 can be from 3.0 to 10 microns. As shown in curve 2219, when Vₒᵤₜ is smaller than V_{c}, Vₒᵤₜ increases monotonically or substantially linearly with Vᵢₙ at a first slope and when Vᵢₙ is equal or larger than V_{c}, Vₒᵤₜ increases linearly or substantially linearly with Vᵢₙ at a second slope smaller than the first slope. So because the inter-gate region is short even after pinch-off (Vᵢₙ>V_{c}), a portion (ΔQₒᵤₜ) of the charge input to the inter-gate region (ΔQᵢₙ) is coupled to the output region 2204. While at Vᵢₙ=V_{c} the gap between the two depletion regions 2218 is closed, still some electrical connection between the input region 2202 and the output region 2204 can be supported by charge tunnelling through the pinched off region. Given the probability of charge tunnelling is proportional to the length of the inter-gate region, the second slope can be adjusted by adjusting the length of the inter-gate region.

As a second step toward substantially linearizing the Vᵢₙ-Vₒᵤₜ relation, the polarity of the inter-gate region of the semiconductor device 2210 can be configured to have the same polarity as the polarity of the first and the second gate regions 2216a, 2216b, to electrically couple connect the first gate region 2216a to the second gate region 2216b, thereby effectively resulting in a pinch-off between the input region 2202 and the output region 2204 at Vᵢₙ=0. This can reduce or eliminates the first portion (Vᵢₙ<V_{c}) of the Vᵢₙ-Vₒᵤₜ curve 2219 (FIG. 22B).

FIG. 22C schematically illustrates a cross-sectional view of another semiconductor device 2220 for monotonic or substantially linear voltage reduction with non-zero punch-through voltage (VPT≠0), and the corresponding voltage transfer function 2221 in an open ended output configuration. The inter-gate region 2213 of the semiconductor device 2220 has the first and the second gate regions 2216a, 2216b (e.g., they can be all p-type regions). Thus, the first and the second gate regions 2216a, 2216b are electrically connected and the charge coupling between the input region 2202 and the output region 2204 is pinched off at Vᵢₙ=0. However, due to formation of new depletion regions between the inter-gate region 2213 and the input and the output drift regions 2212, 2214, the electric charge cannot be coupled from the input region 2202 to the output region 2204 until Vᵢₙ is large enough to close a gap (e.g., the smallest gap along the longitudinal direction), between the two new depletion region boundaries 2228 and allow charge coupling through the inter gate region 2213 via a punch-through mechanism. As shown in the Vᵢₙ-Vₒᵤₜ plot 2221, at a pinch-off voltage (V_{PT}) 2222, the charge is coupled through the inter-gate region 2213 and Vₒᵤₜ linearly or substantially linearly scales with Vₒᵤₜ similar to the second region (Vᵢₙ>V_{c}) of the Vᵢₙ-Vₒᵤₜ plot 2219 (FIG. 22B), and the slope of Vᵢₙ-Vₒᵤₜ line is primarily determined by the length of the inter-gate region.

The third step toward linearizing the Vᵢₙ-Vₒᵤₜ relation is to reduce a dopant concentration of the inter-gate region of the semiconductor device 2220 such that the gap between the two depletion region boundaries 2228 is eliminated or otherwise significantly reduced to allow charge coupling through the inter-gate region at Vᵢₙ=0 (or zero bias) via punch-through mechanism.

FIG. 22D schematically illustrates a cross-sectional view of an example DFE-PD device 2240 that can monotonically or substantially linearly scale Vᵢₙ to Vₒᵤₜ, and the corresponding voltage transfer function 2241 in an open ended output configuration. The structure of the DFE-PD 2240 is identical to the structure of the semiconductor device 2220 (FIG. 22C), except that the concentration of majority carriers in its inter-gate region 2215 is reduced (e.g., by reducing the doping concentration), compared to that of the device 2200, to charge couple the input region 2202 to the output region 2204 even when Vᵢₙ is zero. As shown in the Vᵢₙ-Vₒᵤₜ plot 2241, an input voltage (Vᵢₙ) applied to the input region 2202 of the DFE-PD 2240 may be linearly or substantially linearly scaled to an output voltage (Vₒᵤₜ) generated in its output region 2204 from Vᵢₙ=Vₒᵤₜ. Similar to the semiconductor device 2220 (FIG. 22C), the Vᵢₙ-Vₒᵤₜ slope is primarily determined by the length of the inter-gate region 2215. In some cases, a maximum voltage drop from the input region 2202 to the output region 2204 may be limited by the breakdown voltage of one of the junctions. In some cases, increasing the length (L_{D}) of the as input drift region 2212 may increase the maximum input voltage that can be scaled down by the DFE-PD according to its Vᵢₙ-Vₒᵤₜ slope. In some cases, increasing the length (L_{O}) of the output drift region 2214 may increase the maximum voltage that can be output by the DFE-PD.

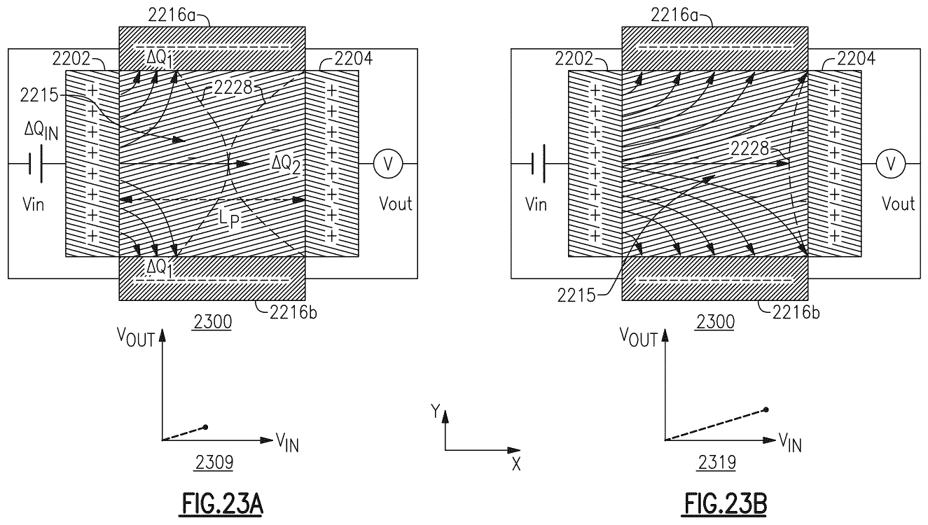

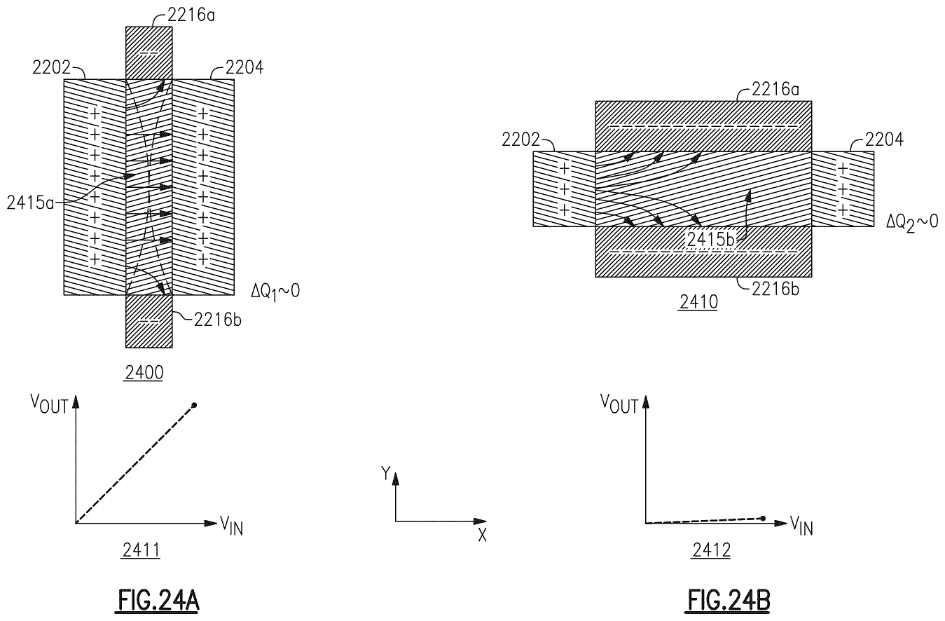

FIGS. 23A-23B schematically qualitatively illustrate the evolution of E-field and charge coupling through inter-gate region 2215 of an example DFE-PD 2300, and the resulting voltage transformation. In the DFE-PD 2300, input and output regions are eliminated and the input region 2202 and the output region 2204 are directly in contact with the inter-gate region 2215. The concentration of the majority carrier in the inter-gate region 2215 and the length (Lₚ) of the inter-gate region 2215 are adjusted such that the depletion region boundaries 2228 are in contact or separated by a small gap therebetween along the longitudinal direction (e.g., along x-axis), where the gap can be smaller than 150 nanometer, 500 nanometer, 1000 nanometer, or a value in a range between any of these values. When an input voltage (Vᵢₙ) is applied between the input region 2202 and the first and second gate regions 2216a, 2216b, a first portion (ΔQ₁) of the charge (ΔQᵢₙ) generated in the input region 2202 couples to the first and second gate regions 2216a, 2216b (that are at or substantially at equipotential), and a second portion (ΔQ₂) of ΔQᵢₙ couples to the output region 2204, resulting in an output voltage Vₒᵤₜ between the first and second gate regions 2216a, 2216b, at the output region 2204. Accordingly, a first portion of the E-field associated with ΔQᵢₙ is coupled to the first and second gate regions 2216a, 2216b (that are at or substantially at equipotential), and a second portion of the E-field associated with ΔQᵢₙ is coupled to the output region 2204, resulting in an output voltage Vₒᵤₜ between the first and second gate regions 2216a, 2216b, at the output region 2204. As Vᵢₙ is increased, ΔQ₁ and ΔQ₂ increase proportionally to ΔQᵢₙ such that the ratio ΔQ₂/ΔQᵢₙ and the corresponding voltage ratio ΔVₒᵤₜ/ΔVᵢₙ stay constant or nearly constant. The E-fields couple to the first and second gate regions 2216a, 2216b, such that the output region 2204 change in the same manner as ΔQ₁ and ΔQ₂. As shown in the Vᵢₙ-Vₒᵤₜ plot 2309, as Vᵢₙ is gradually increased from 0 volt, Vₒᵤₜ increases with a slope smaller than 45 degrees (indicating voltage reduction). The Vᵢₙ-Vₒᵤₜ shows that increasing the Vᵢₙ does not change the slope of the Vᵢₙ-Vₒᵤₜ indicating that the E-field coupling and charge coupling ratios are not significantly affected by the magnitude of Vᵢₙ. At low voltage regimes, a contact point between the depletion region boundaries 2228 (or a lateral position at which the gap between them is reduced or minimized) moves toward the output region 2204 and eventually the two boundaries merge near the output region 2204.

While the configuration of the DFE-PD 2300 simplifies visualization of the evolution of E-field and charge coupling, at least qualitatively, the evolution of E-field and charge coupling in the inter-gate region of the DFE-PD 2240 (FIG. 22D) will be similar to that of the DFE-PD 2300.

FIGS. 24A-24B schematically illustrate two DFE-PDs 2400, 2410, respectively, having inter-gate regions with different geometries. The DFE-PD 2400 has a short inter-gate region 2415a having a length (along x-axis) substantially smaller than a width (along y-axis). In the example shown, the length of the inter-gate region 2415a is sufficiently short such that nearly all the E-filed lines and the charge generated in the input region 2202 are coupled to the output region 2204. As a result, the slope of the Vᵢₙ-Vₒᵤₜ line (in the plot 2411) is near 45 degrees indicating that voltage scaling ratio is near 1 and the DFE-PD 2400 does not reduce the voltage. In some examples, the length of the inter-gate region 2415a can be than less than 5 microns, depending on, among other things, the doping concentrations of the input and output regions 2202, 2204, relatively to that of the inter-gate region 2415a.

DFE-PD 2410 has a long inter-gate region 2415b having a length (along x-axis) substantially greater than a width (along y-axis). In the example shown, the length of the inter-gate region 2415a is sufficiently long such that nearly all the E-field lines and the charge generated in the input region 2202 are coupled to the first and second gate regions 2216a, 2216b. As a result, the slope of the Vᵢₙ-Vₒᵤₜ line (in the plot 2412) is near 0 degrees indicating that the DFE-PD 2410 generates a constant (near zero) Vₒᵤₜ independent of Vᵢₙ. In some examples, the length of the inter-gate region 2415b is longer than 5.0 microns but less than 20.0, depending on, among other things, the doping concentrations of the input and output regions 2202, 2204, relatively to that of the inter-gate region 2415b.

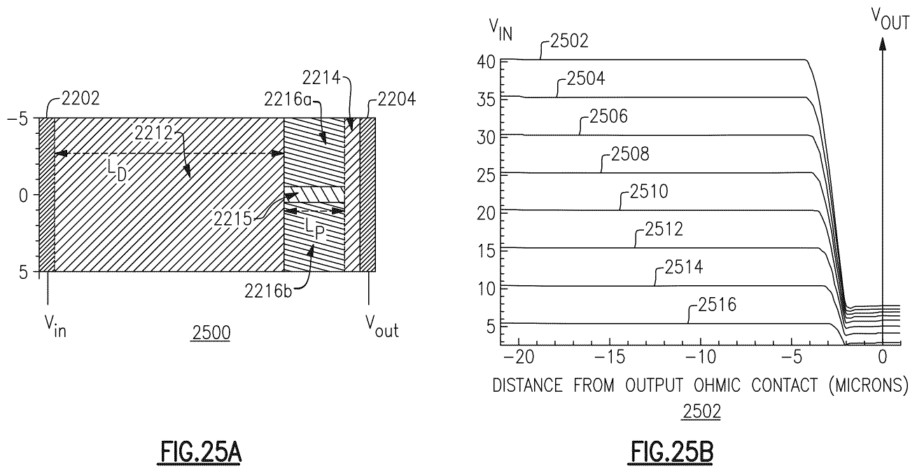

FIG. 25A schematically illustrates a cross-sectional view of a DFE-PD 2500 with an extended drift region. Similar to DFE-PD 2240 (FIG. 22D), DFE-PD 2500 comprises an input region 2202, an output region 2204, an inter-gate region 2215 extending in the longitudinal (e.g., x) direction from the first end to the second end, an input drift region 2212 extending from the input region 2202 to a first end of the inter-gate region 2215, and an output drift region 2214 extending from the second end of the inter-gate region 2215 to the output region 2204. The DFE-PD 2500 further comprises a first and second gate regions 2216a, 2216b, disposed above and below the inter-gate region 2215 respectively. The inter-gate region 2215 is laterally bound by the first and second gate regions 2216a, 2216b that extend from the first end to the second end of the inter-gate region 2215.

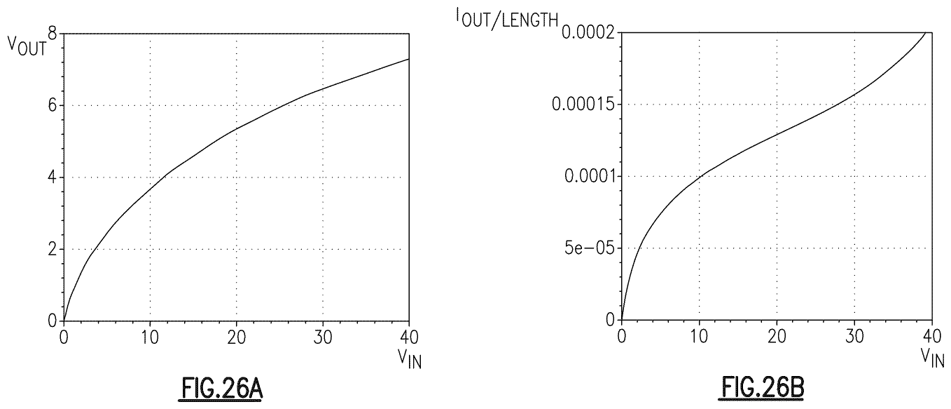

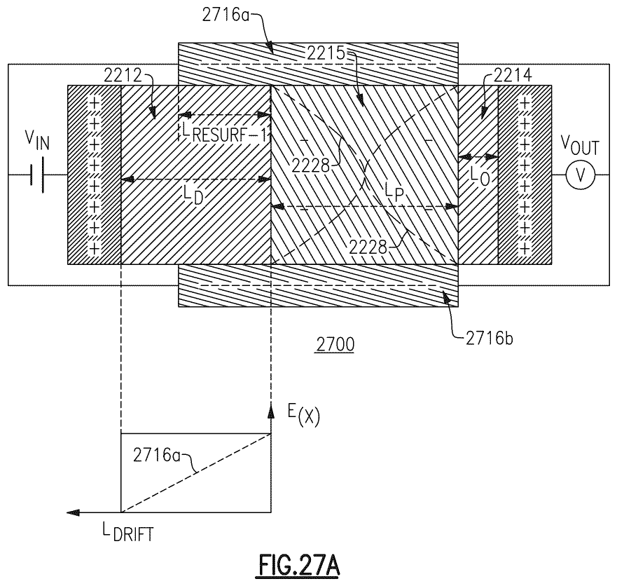

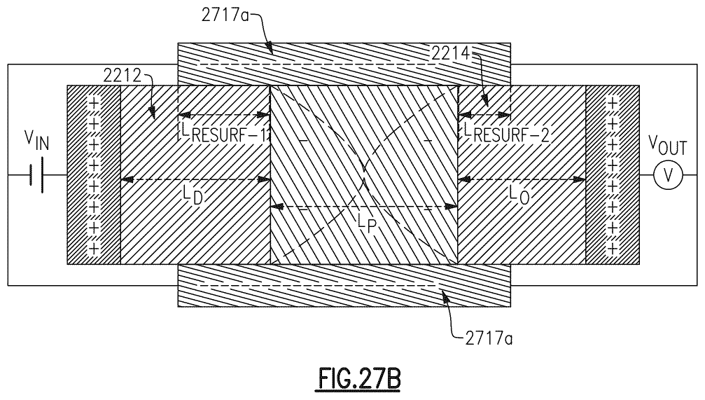

FIG. 25B shows calculated voltage variation plotted against a longitudinal distance from the output region 2204 (where 0 corresponds to the location output region 2204) of the DFE-PD 2500, for eight different values of the input voltage (Vᵢₙ) including Vᵢₙ=40.5 volts (curve 2502), Vᵢₙ=35.5 volts (curve 2504), Vᵢₙ=30.5 volts (curve 2506), Vᵢₙ=25.5 volts (curve 2508), Vᵢₙ=20.5 volts (curve 2510), Vᵢₙ=15.5 volts (curve 2512), Vᵢₙ=10.5 volts (curve 2514), Vᵢₙ=5.5 volts (curve 2516). Voltage at the x-axis value of −21 microns corresponds to Vᵢₙ (left vertical axis) and the voltage at the x-axis value of 0 corresponds to Vₒᵤₜ (right vertical axis). As shown in the plot 2502, the voltage is nearly constant along the input drift region 2212, drops across the inter-gate region 2215 and is nearly constant along the output drift region 2214. While the length (Lₚ) of the input drift region 2212 and the length (Lₒ) of the output drift region 2214 do not significantly contribute to the voltage drop along the DFE-PD 2500, the maximum Vᵢₙ that can be applied to the input region 2202 and the maximum Vₒᵤₜ that can be output by DFE-PD 2500, without causing damage to any junctions or oxide layers, can depend on Lₚ and Lₒ respectively. FIG. 26A shows calculated Vₒᵤₜ plotted against Vᵢₙ, when Vᵢₙ varies from 0 to 40 volts for the DFE-PD 2500. The Vₒᵤₜ-Vᵢₙ is not perfectly linear but an average voltage scaling factor (Vₒᵤₜ/Vᵢₙ) for this device is about 5. FIG. 26B shows output current per unit length of the DFE-PD 2500 plotted against Vᵢₙ. In some cases, the linearity of the Vₒᵤₜ-Vᵢₙ transfer curve is controlled by the geometry and doping profile of the inter-gate region 2215 relative to the doping profiles of the input drift region 2212 and the output drift region 2214. Optimizing those doping profiles and coupling geometry can improve the linearity. For calculating the curves shown in FIGS. 26A and 26B, box-shape doping profile have been used to simplify the calculations. Using, graded doping profiles (along x-axis, y-axis, or both) and carefully tailoring the doping profiles may improve the linearity Vₒᵤₜ-Vᵢₙ curve (e.g., extend the linear region to larger voltage ranges).

In some cases, increasing the length (Lₚ) of the input drift region and the length (Lₒ) of the output drift region and adding RESURF plates, herein referred to as “field plates,” above them may increase the maximum magnitude of the Vᵢₙ and Vₒᵤₜ that can be supported by a DFE-PD, respectively. These field plates can function similar to the field plates 1510a, 1510b, 1612, 1618 above the drift region extension 304b of the HV L-BJTs 350, 1600 (FIG. 16). These field plates can keep a lateral component of the E-field in the input drift region 2212 and/or the output drift region 2214 substantially constant to cause a voltage drop along the input drift region 2212 and/or output drift region 2214. FIG. 27A schematically illustrates a side cross-sectional view of a DFE-PD 2700 with gate regions 2716a, 2716b, extending over the input drift region 2212. The portion of the gate regions 2716a, 2716b, extended over the input drift region 2212 can function as field plates and cause a linear or substantially linear voltage drop 2702 along the input drift region 2212. In some cases, the length (L_{resurf-1}) of the portion of gate regions 2716a, 2716b, extending over the input drift region 2212 can be less than the length (L_{D}) of the input drift region 2212. In various implementations, a portion of the first gate region 2716a that extends over the input drift region 2212 may comprise one or more electrically connected field plates (e.g., metallic and/or polysilicon field plates) placed above each other and above the input drift region 2212. These field plates can be connected to the portion of the gate region 2716a over the inter-gate region 2215. Similar to the field plates 1510a, 1510b, 1612, 1618 of the HV L-BJTs 350, 1600, a vertical distance between these filed plates and a top surface of the input drift region 2212 can increase from an interface between the integrate region 2215 toward the input region 2202. In some examples, a portion of a well region or a substrate in which DFE-PD 2700 is formed may be electrically connected to the first gate region (e.g., via an ohmic contact) and serve as the second gate region 2716b and one or more field plates.

In some cases, the largest input voltage magnitude that can be scaled down by the DFE-PD 2700 can be limited by a resulting reduced voltage that can damage the junctions and/or isolating dielectric layers near the interface between the inter-gate region 2215 or within the output region 2204 (e.g., 5 volts). By way of illustration, if the voltage scaling factor of a DFE-PD 2700 is 40, the upper limit for Vᵢₙ can be 200 volts because scaling down any voltage above 200 volts by a factor of 40 can generate a voltage above 5 volts near the interface between the inter-gate region 2215 or within the output region 2204 (e.g., 5 volts). In some embodiments, an upper limit for Vₒᵤₜ can be increased (e.g., above 5 volts), by extending the output drift region 2214 and providing one or move field plates above it. FIG. 27B schematically illustrates a side cross-sectional view of a DFE-PD 2704 with gate regions 2717a, 2717b, extending over the output drift region 2214. The portion of the gate regions 2717a, 2717b, extending over the output drift region 2214 can function as field plates and cause a linear or near linear voltage drop along the output drift region 2214. In some cases, the length (L_{resurf-2}) of the portion of gate regions 2717a, 2717b, extending over the output drift region 2214 can be less than the length (Lₒ) of the output drift region 2214. In various implementations, a portion of the first gate region 2717a that extends over the output drift region 2214, may comprise one or more electrically connected field plates (e.g., metallic and/or polysilicon field plates) placed above each other and above the output drift region 2214. These field plates can be connected to the portion of the first gate region 2717a over the integrate region 2215. Similar to the field plates 1510a, 1510b, 1612, 1618 of the HV L-BJT 350, 1600 described above, a vertical distance between these filed plates and a top surface of the output drift region 2214 can increase from an interface between the integrate region 2215 toward the output region 2214. In some examples, a portion of a well region or a substrate in which DFE-PD 2704 is formed may be electrically connected to the first gate region 2717a (e.g., via an ohmic contact) and serve as the second gate region 2717b and one or more field plates.

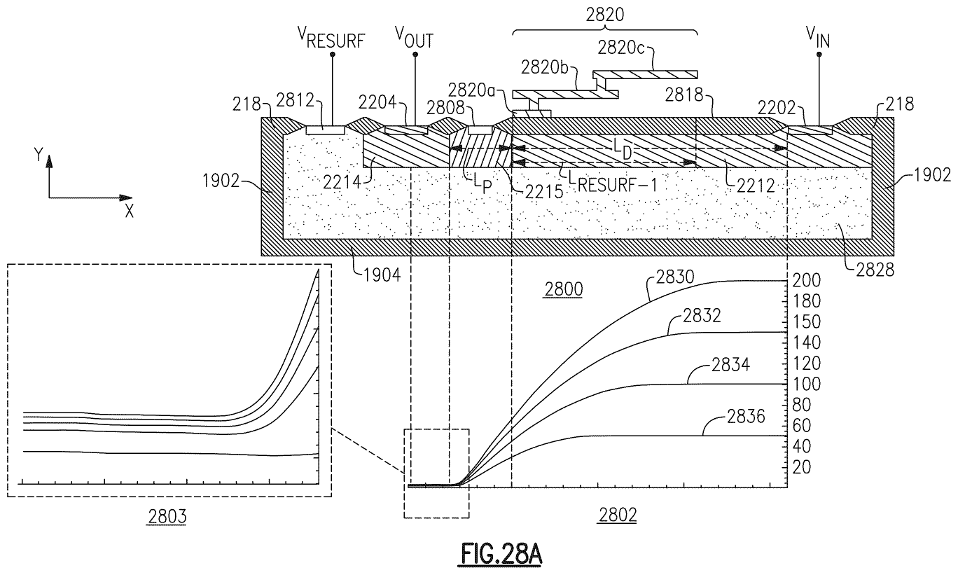

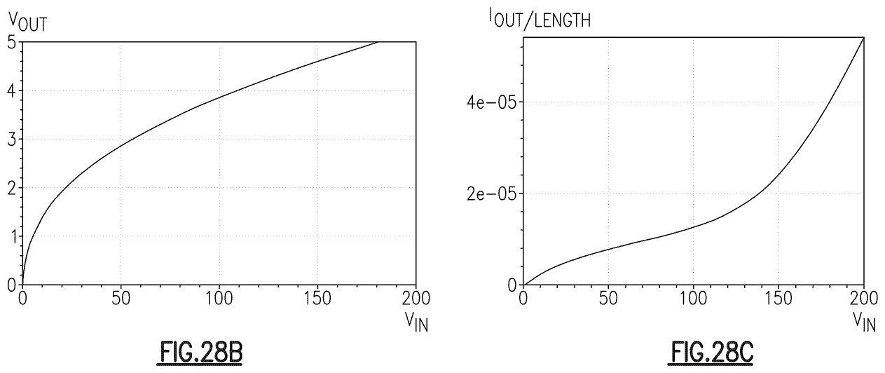

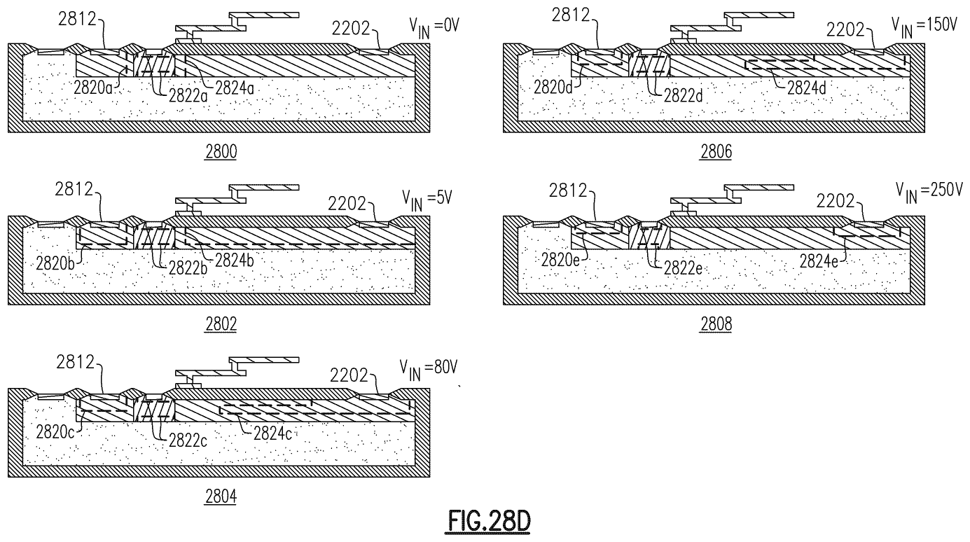

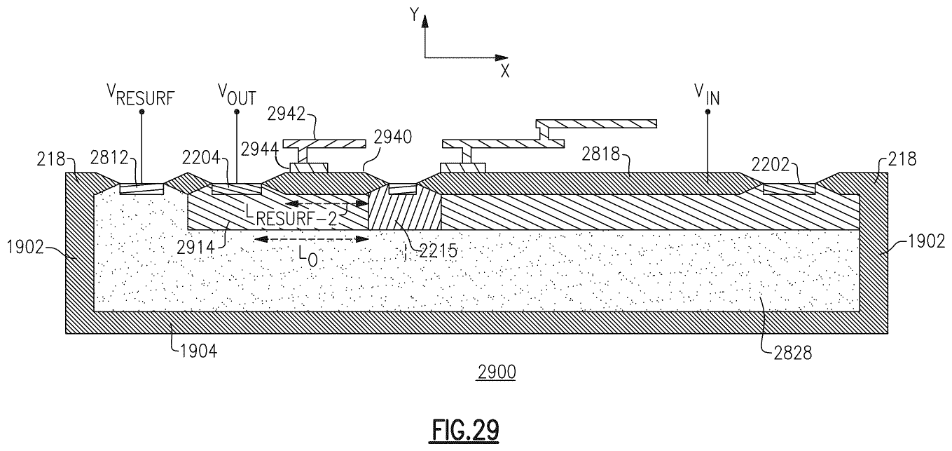

FIG. 28A schematically illustrates a cross-sectional view of a practical implementation of an DFE-PD that can be fabricated to have input/output regions, gate regions and/or field plates at the same major surface of a substrate (e.g. a front side of a silicon substrate). The illustrated DVE-PD comprises HD regions (2202, 2808, 2204, and 2812), and LD regions (2212, 2215, 2214) formed in a well 2828. The DFE-PD 2800 may further comprise isolating dielectric layers (e.g., an isolating dielectric layer 2818), and one or more field plates 2820 above the LD and HD regions. The process architecture of the DFE-PD 2800 is analogous to that of the DFE-PD 2700 (FIG. 27A) having analogous electrical configuration of LD and HD regions, but a different physical geometry. The input drift region 2212 of the DFE-PD 2800 extends in a lateral direction (e.g., along x-axis) from an input region 2022, to a first vertical interface with an inter-gate region 2215. The inter-gate region 2215 is extended from the first vertical interface to a second interface with an output drift region 2214. The first and second vertical interfaces electrically correspond to the first and second junctions and the resulting depletion regions 2228 of the DFE-PD 2700 (FIG. 27A). The DFE-PD 2800 further comprises an output region 2204, a first gate region 2808, and a gate contact region 2812 that provides electrical contact to the well (second gate region) 2828. A region of the well 2828 below the input drift region 2212, the inter-gate region 2215, and the output drift region 2214, serve as the second gate region analogous to the second gate region 2717b of the DFE-PD 2704 described above with respect to FIG. 27B.

In some cases, the input drift region 2212, the inter-gate region 2215, and the output drift region 2214 are doped regions formed in the well 2828 using suitable doping methods (e.g., thermal diffusion or implantation) used in MOS fabrication processes described herein. Similarly, the input region 2202, the output region 2204, the first gate region 2808, and the gate contact region 2812 are formed in the input drift region 2212, the inter-gate region 2215, and the output drift region 2214, respectively. In some cases, the input drift region 2212, the inter-gate region 2215, and the output drift region 2214 are LD regions having a low doping concentration or a low majority carrier concentration (e.g., lower than HD regions). In some cases, the input region 2202, the first gate region 2808, the output region 2204, and the gate contact region 2812 are HD regions having a high doping concentration or a high majority carrier concentration and can serve as ohmic contacts.

The input region 2202, the input drift region 2212, the output drift region 2214, and the output region 2204 can have the same polarities. In some cases, a doping concentration or carrier concentration of the input region 2202 can be similar or substantially identical to that of the output region 2204. In some cases, a doping concentration or carrier concentration of the input drift region 2212 can be similar or substantially identical to that of the output drift region 2214.

The first gate region 2808, the inter-gate region 2215, and the gate contact 2812, and the well 2828 can have the same dopant polarity type. In some cases, a doping concentration and/or majority carrier concentration of the first gate region 2808 can be identical to that of the gate contact 2812.

Still referring to FIG. 28A, the DFE-PD 2800 further includes a thick isolating dielectric layer 2818 (e.g., an oxide layer such as a LOCOS or STI layer) above the first drift region 2212, and three field plates 2820 disposed above the thick isolating dielectric layer 2818. The field plates 2820 may comprise a first field plate 2820a disposed on top of the thick isolating dielectric layer 2818, a second field plate 2820b placed above the first field plate 2820a and extended in the lateral direction towards the input region 2202, and a third field plate 2820c above the second field plate 2820b and extended in the lateral direction towards the input region 2202. In some cases, the first, second, and third field plates 2820a, 2820b, 2820c may cover a portion (L_{resurf-1}) of the length (L_{D}) the input drift region 2212. In some examples, L_{D} can be larger than L_{resurf-1} by a factor of 1.2, 1.4, 1.6, 1.7, 2 or larger or smaller values.

In some cases, the arrangement of the first, second, and third field plates 2820a, 2820b, 2820c can be similar to that of the second, third, and fourth field plates 1510a, 1612, 1618 described above with respect to the HV L-BJT 1600. In some cases, the first, second, and third field plates 2820a, 2820b, 2820c may comprise features (e.g., geometrical and material characteristics) similar to those of the second, third, and fourth field plates 1510a, 1612, 1618 respectively. For example, the first field plate 2820a may comprise polysilicon and the second and third field plates, 2820b, 2820c, may comprise a metal or metal alloy. Similar to the second, third, and fourth field plates 1510a, 1612, 1618 of the HV L-BJT 1600, the first, second, and third field plates 2820a, 2820b, 2820c can maintain at least a lateral component of the E-field in the input drift region 2212 constant or nearly constant, e.g., by introducing vertical E-field components (e.g., along y-axis) along the input drift region 2212. As a result, the presence of the field plates may result in a voltage drop (ΔV_{drift}) along the first drift region 2212 in addition to the voltage drop (ΔV_{dep}) in the inter-gate region 2215. The resulting voltage scaling factor of the DFE-PD 2800 can be larger than that of the DFE-PD 2500 (FIG. 25A).

In various implementations, the ΔV_{drift} can be adjusted by changing the length (L_{D}) of the input drift region 2212 and the ΔV_{dep} can be adjusted by changing the length (Lₚ) of the inter-gate region 2808, and majority carrier concentration (or doping concentration) in the inter-gate region 2808. In various implementations ΔV_{dep} can be from 0 to 5 volts, and ΔV_{drift} can be from 0 to 300 volts.

In various implementations, Lₚ can be from 0.1 to 5.0 microns, L_{D} can be from 0.5 to 25 microns, majority carrier concentration (or doping concentration) in the inter-gate region 2808 can be from 10¹⁵ to 10¹⁷ cm⁻³. In some examples, the majority carrier concentration (or doping concentration) in the inter-gate region 2808 is lower than those of the first gate region 2808 and well (the second gate region) 2828. In some implementations, a difference between the majority carrier concentration (or doping concentration) in the inter-gate region 2808 and the first gate region 2808 can be from 10¹⁶ to 10¹⁷ cm⁻³. In some examples, a difference between the majority carrier concentration (or doping concentration) in the inter-gate region 2808 and the well (the second gate region) 2828 can be from 10¹⁶ to 10¹⁷ cm³.

In some cases, the field plates 2820 and the gate contact 2812 may be substantially at equipotential. For example, they can be connected to an ohmic region or electrode having a stable and constant potential (e.g., a ground plane), during the operation of the DFE-PD 2800.

The plot 2802 shows calculated variation of voltage in a lateral direction (e.g., along x-axis) along the DFE-PD 2800, plotted against a distance from the input region 2202 for four different values of the input voltage (Vᵢₙ) including Vᵢₙ=200 volts (curve 2830), Vᵢₙ=144 volts (curve 2832), Vᵢₙ=100 volts (curve 2834), and Vᵢₙ=2836 volts (curve 2836). The plot 2803 is a close-up view of a portion of the plot 2802 near the interface between the inter-gate region 2215 and within the output region 2204.

In some implementations, fabrication of the DFE-PD 2800 may comprise forming the doped substrate region 2828 by implanting a top layer of a silicon-on-insulator (SOI) wafer and thermally driving down dopant below toward the buried oxide layer 1904. Next, an epitaxial layer is grown on top of the silicon layer and single well would be implanted for the entire length extending from regions 2214 to 2212. Next, a second well of opposite dopant is implanted to form the inter-gate region 2215. In some cases, the dopant concentration of this well would exceed the dopant of well regions 2214 and 2212. These wells would be thermally driven until they merge with the buried dopant layer 2828. The excessive dopant of 2215 would counter dope 2214 and 2212 to form a more lightly net doped region 2215. Next, the dielectric layers are formed and the heavily doped regions (ohmic contacts), 2202, 2208, 2204, and 2812 are be implanted. Finally, the metallic interconnects are formed.

FIG. 28B shows an example calculation of Vₒᵤₜ plotted against Vᵢₙ, when Vᵢₙ varies from 0 to 200 volts for DFE-PD 2800. The Vₒᵤₜ-Vᵢₙ is not perfectly linear but an average voltage scaling factor (Vₒᵤₜ/Vᵢₙ) for this device is about 40. FIG. 28C shows an example calculation of the output current per unit length of the DFE-PD 2800 plotted against Vᵢₙ.

FIG. 28D schematically illustrates snapshots of the depletion regions of the DFE-PD 2800 at five different magnitudes of bias or input voltages (e.g., voltages applied between the input region 2202 and the first gate region 2808). Associated with every junction are two depletion boundaries that push into either side of the opposing junction dopant. In FIG. 28D, the depletion boundaries 2820a-2820e and 2824a-2824e represent one side of eth depletion regions of two junctions. The depletion region on the other side of the junctions in the inter-gate region are merged. In some cases, the depletion boundaries represented by 2822a-2822e show how the merged depletions within inter-gate cannot merge around the higher doped regions.

As mentioned above, in some applications, a high input voltage can be scaled down to a lower voltage, but can still be too high for junctions and dielectric layers near the interface between the inter-gate region 2215 or within the output region 2204 (e.g., 5 volts). For example, a region or a device in an IC may be designed to operate at 50 volts, while an available source may generate an output voltage of 200 volts (a voltage scaling factor of 4). While by reducing Lₚ and/or L_{D} the voltage scaling factor of DFE-PD 2800 can be reduced to 4, the output region 2204 may be damaged by the resulting scaled down voltage (50 volts). This limitation can be removed by employing a longer output drift region 2204 and adding one or more field plates (RESURF plates) above the output drift region 2204 (the same design used for the input drift region 2212).

FIG. 29 schematically illustrates a cross-sectional view of a DFE-PD 2900 having an extended output region 2914 and two field plates 2944, 2942 placed above the extended output region 2914. In some examples, the input region, the output drift region, the dielectric layer on the input region, the inter-gate layer, the gate layer, of and the DFE-PD 2900 and the well in which DFE-PD 2900 is formed be analogous to the corresponding features of the DFE-PD 2800.

Unlike the DFE-PD 2800, the DFE-PD 2900 comprises an extended output region 2914, and a thick dielectric layer 2940 disposed thereover. In some cases, the field plates 2944, 2942 may cover a portion (L_{resurf-2}) of the length (Lₒ) of the extended output drift region 2914. In some examples, Lₒ can be larger than L_{resurf-2} by a factor of 1.2, 1.4, 1.6, 1.7, 2 or have a value in range defined by any of these values or larger or smaller values. The extended output region 2914 and the field plates 2944, 2942, may allow the DFE-PD 2900 to support output voltages above 5 volts. An upper limit for the magnitude of the output voltage for DFE-PD 2900 may be increased by increasing Lₒ and L_{resurf-2}.

In some cases, the field plates 2944, 2942 and the gate contact 2812 may substantially be at equipotential. For example, they can be connected to an ohmic region or an electrode having a stable and constant potential (e.g., a ground plane), during the operation of the DFE-PD 2900.

The thick dielectric layers 2818 and 2940 may comprise one or more features described above with respect to the thick dielectric layer 1614 of the HV L-BJT 350 (FIGS. 16A, 16B).

To support a voltage drop (e.g., a substantially linear voltage drop) along the input drift region 2112 and/or the output drift region 2214, more field plates may be added above each drift region. A vertical distance of each field plate from the top surface of the corresponding drift region can be smaller than that of a subsequent field plate. The length of each field plate and its relative vertical distance with a respect to adjacent field plates may be determined based on input voltage or voltage range to the PD and a desired output voltage or voltage range provided by the PD.

In some embodiments, the DFE-PD 2800 or the DFE-PD 2900 can be isolated in the lateral direction using deep trenches 1902 filled with a dielectric material (e.g., an oxide). These deep trenches may be extended from the isolating dielectric layers 218 to a buried dielectric layer 1904 that vertically isolates (electrically) an upper region of a substrate on which the well 2828 is formed (e.g., below the well 2828), from a lower region of the substrate.

MOS Devices Coupled with High Voltage Potential Divider

As discussed above, another second inventive aspect allows the low voltage BiCMOS platform to be elevated to a higher voltage node using a high voltage potential divider that is connected in series with the lower voltage devices to create high voltage devices.

In some embodiments the DFE-PDs described above can be electrically connected (e.g., in series) to a low or medium voltage bipolar junction device (e.g., an L-BJT), or a low voltage MOS device (e.g., a MOSFET). In some cases, DFE-PDs, the bipolar devices, and the MOS devices can be fabricated on a common substrate using MOS fabrication techniques and libraries similar to those described above. In some such cases, at least a portion of a DFE-PD can be co-fabricated with a bipolar and/or MOS device. The DFE-PDs can be laterally separated or isolated from the bipolar devices, and the MOS devices, and/or vertically separated or isolated from the common substrate.

In some cases, the DFE-PDs can be fabricated on integrated circuit (IC) comprising bipolar junction devices and MOS devices. In some cases, the DFE-PDs can be fabricated on a high-voltage region of the IC that is electrically isolated from a low-voltage region of the IC (e.g., by deep dielectric filled trenches). In some examples, the DFE-PDs can be connected to the devices in the low voltage regions via vertical conductive lines (vias) connected to a common lateral conductive line fabricated, e.g., in a metallization layer of the IC above the substrate. In some embodiments, a DFE-PD may be electrically connected to a multiple low voltage devices that receive a reduced voltage from the DFE-PD. In various implementations, the DFE-PD may have a voltage scaling factor of 2 to 5, 5 to 10, 10 to 20, 20 to 30, 30 to 40, 40 to 50, or a value in a range defined by any of these values or larger values. The DFE-PD may be configured to scale down a high voltage level to a voltage level safe for a low voltage device (e.g., equal or less than 5 volts), or a medium voltage device (e.g., equal or less than 80 volts).

In some embodiments, the DFE-PD and a low voltage device (e.g., an L-BJT or a MOS transistor) may have at least one layer having a common material or physical dimension, or at least one doped region having a common doping profile.

The input region, output region and the drift regions of a DFE-PD may have the same polarity as the drain region of a MOS transistor or a collector region of an L-BJT to which it is connected.

In a similar manner to the synergistic processing advantages of HV L-BJTs described above, various synergistic parallel processing of DFE-PDs with L-BJTs and MOS transistors can be performed, including definition of one or more of respectively thick dielectric layers, field plates, extended drift regions, and HD and LD doped regions. The details of the synergistic processing have been described above, and the details are not repeated herein for brevity.

In some cases, a DFE-PD and a low voltage (LV) MOS transistor that receives a reduced voltage from the DFE-PD can electrically behave similar to a single HV MOS transistor, e.g., a LDMOS transistor. A channel region of such LDMOS transistor can be laterally interposed between the HD input region 2202 of the DFE-PD serving as a drain of eth LDMOS and the HD source region of the LV MOS having the same polarity as the HD input region 2202. The HD output region 2204 of the DFE-PD is physically separated by the inter-gate structure from, while being electrically connected to, the HD drain region of the LV MOS. The LDMOS transistor may further comprises a backgate contact electrically connected to the field plate 2820 formed over the extended input drift region serving as a reduced surface field (RESURF) plate. The LDMOS transistor may comprise a backgate contact electrically connected to the gate region 2802 of the DFE-PD.

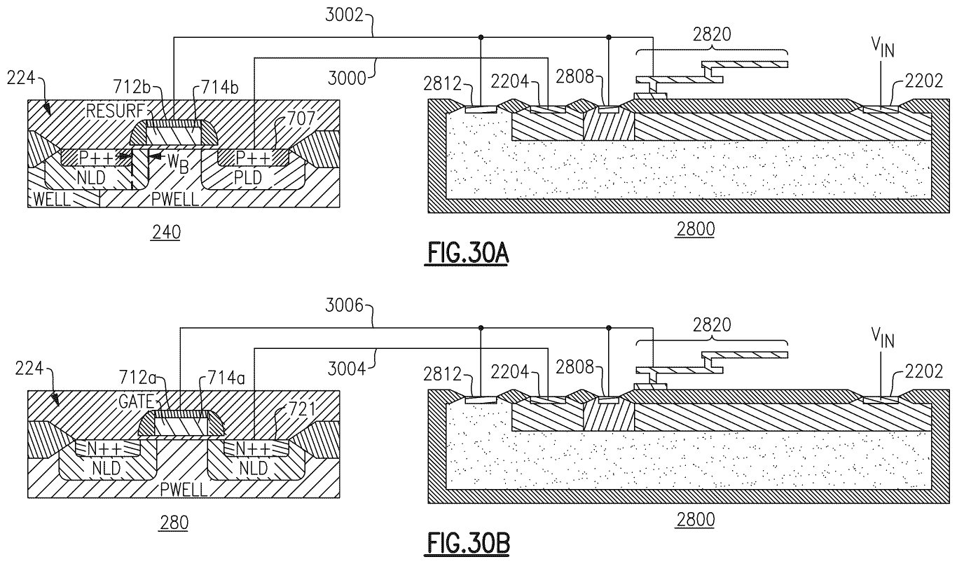

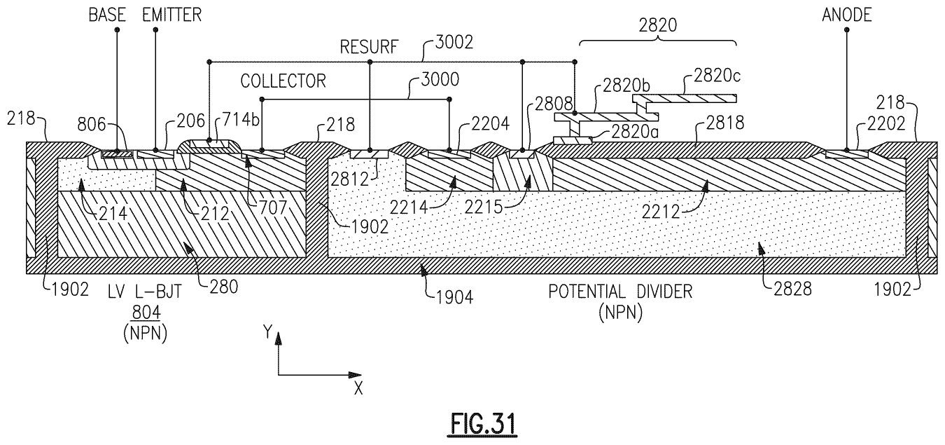

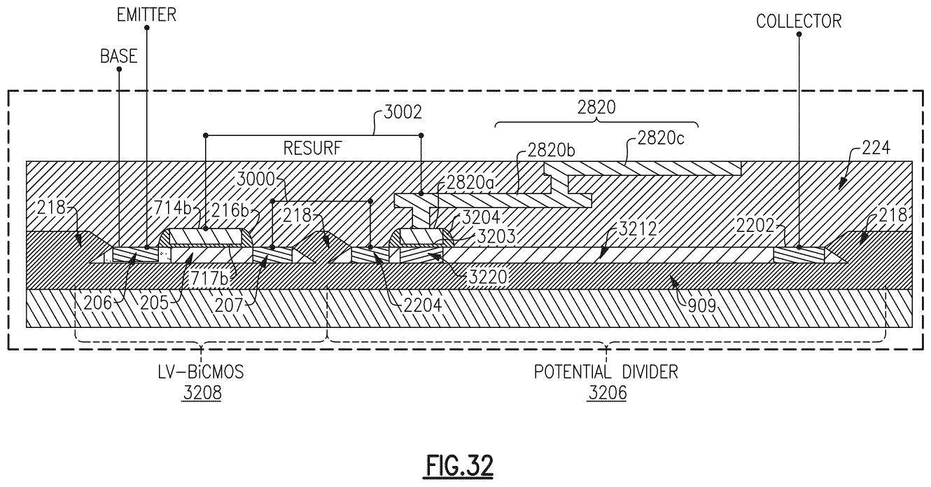

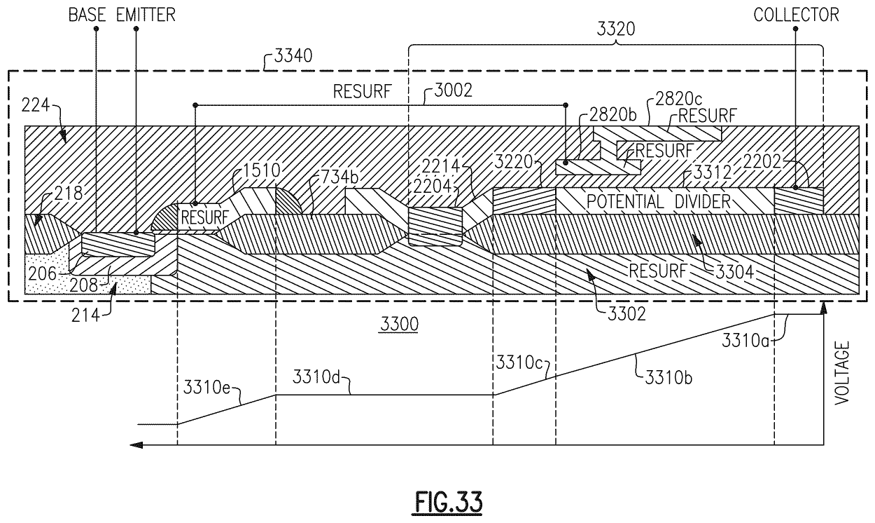

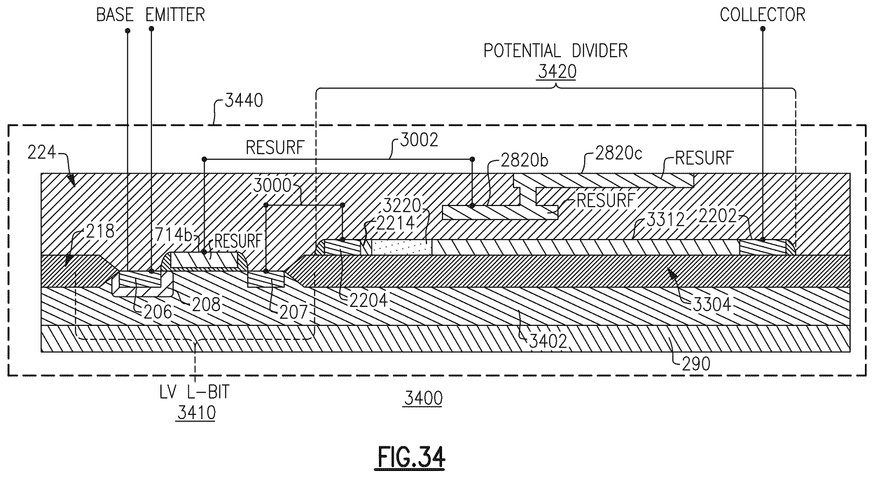

FIG. 30A schematically illustrates a cross-sectional view of a DFE-PD 2800 laterally isolated and/or separated from and electrically connected to a lateral BJT similar to, e.g., the L-BJT 240 described above (FIG. 2). The output region 2204 of the DFE-PD 2800 is connected to the HD collector region 707 of the L-BJT 240 via a first conductive line 3000. The conductive line 3002 can be a conductive line patterned in a metallization layer above a substrate on which the DFE-PD 2800 and L-BJT 240 are fabricated and the output region 2204 and the HD collector region 707 can be electrically connected to the first conductive line 3000 through two individual vertical conductive lines (vias).

The first gate region 2808, field plates 2820 and the gate contact 2812 of the DFE-PD 2800 are connected to the RESURF contact 712b and the RESURF layer 714b of the L-BJT 240 via a second conductive line 3002. The second conductive line 3002 can be a conductive line in a metallization layer above a substrate on which the DFE-PD 2800 and L-BJT 240 are fabricated and the first gate region 2808, field plates 2820, the gate contact 2812, and the RESURF contact 712b can be electrically connected to the second conductive line 3002 through two individual vertical conductive lines (e.g., vias). In various embodiments, the first and the second conductive lines 3000, 3002 can be fabricated on the same or different metallization layers.

FIG. 30B schematically illustrates a side cross-sectional view of a DFE-PD 2800 laterally isolated and/or separated from and electrically connected to a low voltage MOS transistor similar to, e.g., the MOS transistor 280 described above (FIG. 2). The output region 2204 of the DFE-PD 2800 is connected to the HD drain region 721 of the MOS transistor 280 via a third conductive line 3004. The third conductive line 3004 can be a conductive line patterned in a metallization layer above a substrate on which the DFE-PD 2800 and the MOS transistor 280 are fabricated, and the output region 2204 and the HD drain region 721 can be electrically connected to the third conductive line 3004 through two individual vertical conductive lines (e.g., vias).

The first gate region 2808, field plates 2820 and the gate contact 2812 of the DFE-PD 2800 are connected to the gate contact 712a and the gate layer 714b of the MOS transistor 280 via a fourth conductive line 3006. The fourth conductive line 3006 can be a conductive line patterned in a metallization layer above a substrate on which the DFE-PD 2800 and the MOS transistor 280 are fabricated and the first gate region 2808, field plates 2820, the gate contact 2812, and the gate contact 712a can be electrically connected to the fourth conductive line 3006 through two individual vertical conductive lines (e.g., vias). In various embodiments, the first, second, third and fourth conductive lines 3000, 3002, 3004, 3006 can be fabricated on the same or different metallization layers.

In some cases, one or both of the MOS transistor 280 and the L-BJT 240 can be fabricated on a common substrate with the DFE-PD 2800. For example, the MOS transistor 280 and the L-BJT 240 can be fabricated on a low voltage region of an IC that is electrically isolated from a high voltage region of the IC, on which the DFE-PD 2800 is fabricated. As shown in FIGS. 30A-30B, in some cases, the electrical isolation can be provided by deep dielectric filled trenches disposed between a low voltage device (e.g., the MOS transistor 280, the L-BJT 240) and the DFE-PD 2800 and/or between the low and high voltage regions of the IC.

In some cases, the HD gate region 721, the HD source region of the MOS transistor 280, and collector region 707 of the L-BJT 240, can be co-fabricated with output regions 2202, 2204 of the DFE-PD 2800.

High Voltage Devices Including Potential Divider Physically Separated from Low Voltage Devices

In some embodiments, a DFE-PD (e.g., DFE-PDs 2900 (FIG. 29) or 2800 (FIG. 28A)) described above, may be physically separated and/or electrically isolated from one or more low or medium voltage devices that that receive a scaled down voltage from the DFE-PD to avoid any damage to the low or medium voltage device by a high voltage signal. In various embodiments, the physical and/or electrical isolation may comprise lateral and/or vertical separation from the low or medium voltage devices via one or more dielectric layers. In some cases, lateral isolation may comprise isolation by a shallow or deep dielectric filled trench formed in the substrate or an oxide layer thermally grown (e.g., LOCOS) on a top (major) surface of the substrate. In some cases, the vertical isolation may be provided by a buried oxide layer, e.g., of a silicon-on-insulator substrate. In some other cases, the vertical isolation may be provided by a thick dielectric layer formed on or over the substrate (e.g., thermally grown or deposited oxide layer), and/or by a portion of one or more interlayer dielectric layers (ILDs) or intermetal dielectric layers (IMDs) deposited above the substrate. In some cases, the cladding layer 224 may comprise one of more ILD or IMD layers.

FIG. 31 schematically illustrates a cross-sectional view of an example high voltage device including electrical connections between the DFE-PD 2800 and a low voltage device such as the LV L-BJT 804, fabricated on a common substrate, for controlling (e.g., switching, modulation, and the like) high voltage signals provided to the DFE-PD 2800 using the low voltage device, e.g., the LV L-BJT 804. The DFE-PD 2800 and L-BJT 804e are laterally separated or isolated from each other using a deep dielectric filled trench 1902 and a buried dielectric layer 1904. In some cases, the substrate may comprise a silicon-on-insulator (SOI) wafer where DFE-PD 2800 and the LV L-BJT 804 are fabricated on the top silicon layer above the insulating layer (e.g., a buried oxide layer of a silicon-on-insulator (SOI) substrate). The buried dielectric layer 1904 can provide advantages including, e.g., enabling reduction of the depth of the trench 1904 by blocking carrier flow between the two devices through an unblocked region of the substrate below the trench 1902. As shown in FIG. 31, similar dielectric trenches may be used to electrically isolate the DFE-PD 2800 and LV L-BJT 804 from other devices fabricated on the common substrate. The deep trenches 1902 may extend from the isolating dielectric layers 218 to the buried dielectric layer 1904. In some cases, the deep trenches 1902 may in contact with the buried dielectric layer 1904. In some cases, a vertical gap between a deep trench 1902 and the buried dielectric layer 1904 can be less than 50 nm, or less than 10 nm.

The output region 2204 and the HD collector region 707 of the LV BJT 804 are electrically connected via a first conductive line 3000 fabricated in a metallization layer connected above the top surface of the common substrate. The field plates 2820, the first gate region 2808, the gate contact region 2812, and the RESURF layer 714b are electrically connected via a second conductive line 3002 fabricated in a metallization layer above the top surface of the common substrate. The first and the second conductive lines 3000, 3002 can be fabricated on the same or different metallization layers.

In various implementations, the inter-gate region of an DFE-PD can control a coupling ratio between an input voltage and the corresponding output voltage in two configurations; the first configuration, described above includes one or more interfaces or junctions with a HD gate region on top or bottom, or both sides of the inter-gate region and electric field coupling to these gate regions controls the voltage drop across the inter-gate region. In a second configuration, the DFE-PD may control the voltage drop across the inter-gate region based on electric field coupling to one or more adjacent HD regions of electrodes that are not in contact with the inter-gate region. The electric field coupling to such electrically isolated HD regions or electrodes may have the same effect as the HD gate regions 2216a and 2216b, on voltage drop across the inter-gate region and controlling the ratio between the input and output voltages.

In some embodiments, the architecture of the DFE-PD 2800 can be modified by removing one or both of the gate regions 2216a, 2216b and relying on the dynamics of the depletion region boundaries 2228 for voltage scaling. In some cases, the second gate region 2216b may be eliminated and first gate region 2216a may be separated from the inter-gate region 2215. In these examples, the region where the dielectric regions reside, also referred to herein to as the inter-gate region 2215, may be referred to as a depletion control region.

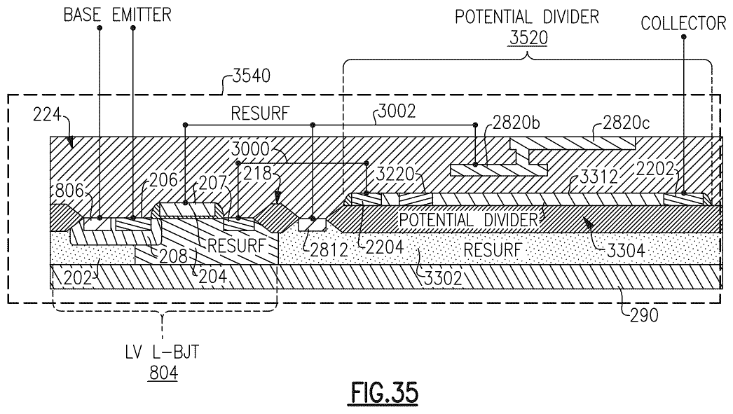

FIG. 32 schematically illustrates a cross-sectional view of an example high voltage device including electrical connections between a DFE-PD 3206 and an L-BJT 3208, fabricated on a common substrate, where the DFE-PD 3206 and L-BJT 3208 (that is similar to the L-BJT 800) are laterally separated or isolated from each other by a dielectric layer 218, and vertically separated or isolated from a lower region of the common substrate by a buried dielectric layer 909. The dielectric layer 218 can be a shallow dielectric field trench (e.g., shallow trench oxide), or thermally grown oxide layer. In some examples, the buried dielectric layer 909 may be in contact or merged with the dielectric layer 218. In some cases, a thickness of the dielectric layer 218 in the vertical direction can be from 0.3 to 0.5 microns. In some examples, a vertical gap or distance (e.g., along z-axis) between a bottom surface of the dielectric layer 218 and a top surface of the buried dielectric layer 909 can be less than 5 nm, or less than 10 nm. The DFE-PD 3206 may comprise an input region 2202, an input drift region 3212, a depletion control region 3220, and an output region 2204. The polarity and relative majority carrier concentrations (or doping concentrations) in these regions may be similar to those of the input region 2202, the input drift region 2212, the inter-gate region 2215, and the output region 2204 region of the DFE-PD 2800 (FIG. 28A), respectively. The DFE-PD 3206 may further comprise a thin dielectric layer 3203 above the depletion control region 3220, a first field plate layer 2820a, spacers 3204 formed on the side walls of the first field plate 2820a, a second field plate 2820b above the first field plate 2820a, and a third field plate 2820c above the second field plate 2820b. The input drift region 3212 is bound in the vertical direction by one or more intermetal dielectric layers 224, and the top surface of the buried dielectric layer 909. In some embodiments, the DFE-PD 3206 may not include a thick isolating dielectric layer above its input drift region 3212. In some cases, the second field plate 2820b may be connected to the first field plate 2820a through a vertical connector, e.g., a via, and extend in the lateral direction from a first end approximately aligned with a middle point of the first field plate 2820a to a second end above the input drift region 3212. The third field plate 2820c may be connected to the second field plate through a vertical connector, e.g., via and extend in the lateral direction from a region near the second end of the second field plate 2820b. The field plates 2820 of the DFE-PD 3206 are configured to maintain a magnitude of the lateral E-field component in the input drift region 33212 relatively or nearly constant from input region 2202 to the output region 2204. The output region 2204 and the HD collector region 207 of the LV BJT 3208 are electrically connected via a first conductive line 3000 fabricated in a metallization layer above the top surface of the common substrate. The field plates 2820 are electrically connected to the RESURF layer 714b via a second conductive line 3002 fabricated in a metallization layer above the top surface of the common substrate. The first and the second conductive lines 3000, 3002 can be fabricated as part of the same or different metallization layers.

FIG. 33 schematically illustrates a cross-sectional view of an example high voltage device including a DFE-PD that is vertically separated from the substrate and directly connected to an L-BJT. The device 3300 includes a DFE-PD 3320 that is directly connected to the L-BJT 730 while being vertically raised or separated from a substrate on which the L-BJT 730 is fabricated. The DFE-PD 3320 and L-BJT 730 are fabricated on a common substrate, thereby forming an integrated device effectively functioning as a HV L-BJT. The DFE-PD 3320 includes an input region 2202, an input drift region 3312, and a depletion control region 3220 that are disposed on a top surface of a thick dielectric layer 3304 disposed on the common substrate. In some cases, advantageously, the input region 2202, the input drift region 3312, and the depletion control region 3220 may be formed from the same layer, e.g., a polysilicon layer. In these embodiments, the thicknesses of these layers along the vertical direction (along y-axis), can be substantially equal. In some other cases, the base layer, e.g., a polysilicon layer, from which the input region 2202, the input drift region 3312, and the depletion control region 3220 may be formed may be co-deposited and co-patterned to have the same thickness with the RESURF layer 1510, such that the thicknesses of all of these regions, along the vertical direction, are substantially equal. Furthermore, in some cases, one or more of the input region 2202, the input drift region 3312 and the depletion control region 3220 may be co-doped to have the same dopant type and/or concentration as the RESURF layer 1510. In various embodiments, the thicknesses of the input region 2202, the input drift region 3312, and the depletion control region 3220, can be from 0.15 to 0.5 μm.

The DFE-PD 3320 includes an output drift region 2214 and an output region 2204. The input drift region 3312 extends in the lateral direction from the input region 2202 to the depletion control region 3220. The output drift region extends from the depletion control region 3220 to the output region 2204. The output region 2204 is formed on or partially formed in a first substrate region 3302. The first region of the substrate 3302, the output region 2204, the input drift region 3312 and the input region 2202 of the DFE-PD 3320, and the emitter region 206 of the L-BJT 730 can have the same polarity opposite to a polarity of the depletion control region 3220 of the DFE-PD 3320 and the base region 208 L-BJT 730. The output region 2204 of the DFE-PD 3320 can be laterally extended from the thick dielectric layer 3304 and a thick dielectric layer 734b that disposed over the drift region of the L-BJT 730. In some examples, the output region 2204 of the DFE-PD 3320 may serve as the HD collector region of the L-BJT 730. As such, the output region 2204 serves as a common electrical contact between the DFE-PD 3320 and L-BJT 730 arranged in electrical series. In some cases, the combination of DFE-PD 3320 and L-BJT 730 (the device within the dashed box 3340) may electrically behave as an HV L-BJT with the input region 2202 serving as an effective collector region of the HV L-BJT.

The DFE-PD 3320 may further include two electrically connected field plates 2820b, 2820c over the input drift region 3312, extending from an interface between the input drift region 3312 and the depletion control region 3220 toward the input region 2202. Each field of the plates 2820b, 2820c can be fabricate as part of a different metallization layer, where a vertical distance of the field plate 2820 that is closer to the depletion control region 3220 from a top surface of the input drift region 3312 is smaller than that of the other field plate that is closer to the input region 2202.

The common substrate may include a second substrate region 214 having a polarity opposite to a polarity of the first substrate region 3302. The base well 208 of the L-BJT 730 may have portions formed in each of the first and second substrate regions 3302 and 214 and extend across a boundary therebetween.

In some cases, the first substrate region 3302 below the thick dielectric layer 3304 serves as a bottom field plate for the DFE-PD 3320 and contributes in maintaining the lateral component of the E-field within the input drift region 3312 relatively constant or near constant (a condition that results in monotonic or substantially linear reduction of voltage along the input drift region 3312).

The field plates 2820b, 2820c and the RESURF layer 1510b can be electrically connected via conductive line 3002 fabricated in a metallization layer above the top surface of the common substrate. The conductive lines 3002 may be fabricated on the same metallization layer on which the field plate 2820b or field plate 2820c is fabricated, or on a different metallization layer.

Referring to the voltage versus distance curve shown at the lower half of FIG. 33, when an input voltage (Vᵢₙ) is provided to the DFE-PD 3320, the voltage variation along the device may have a piecewise behavior, and the voltage versus distance curve may include substantially constant segments 3310a and 3310d, and drop segments 3310b, 3310c and 3310e. For example, the voltage may remain constant or nearly constant within the segment 3310a along the input region 2202, drop (e.g., monotonically or substantially linearly) within the segment 3310b along the input drift region 3312, drop (e.g., monotonically or substantially linearly) within the segment 3310c with the same or different slope as the segment 3310b along the depletion control region 3220, remain constant or nearly constant within the segment 3310d along the output region 2204 and along a first portion of a drift region of the L-BJT 730, drop (e.g., monotonically or substantially linearly) within the segment 3310e along a second portion of the drift region below the RESURF layer 1510, and remain constant 3310e along the base region of the L-BJT 730. As such, the voltage drops from an input voltage (Vᵢₙ) level applied to the input region 2202 to an intermediate voltage (V_{Mid}) along a first portion of the drift region, and from the intermediate voltage to a final voltage (Vᵢₙ) along the second portion of the drift region. In some cases, V_{Fin} can be equal or less than 5 volts. In some cases, the ratio between the intermediate voltage and the input voltage (V_{Mid}/Vᵢₙ) can be less than 50%, less than 40%, less than 30%, less than 20%, or less than 10%. In some cases, the slopes of the voltage drop segments 3310b, 3310c, 3310e, may be different and individually tailored by adjusting a length of the input drift region 3312, a length and/or doping of the depletion control region 3220, and a length of drift region of the L-BJT 730, respectively.

FIG. 34 schematically illustrates a cross-sectional view of an example high voltage device including a DFE-PD that is vertically separated from the substrate and is electrically connected to an L-BJT via conductive lines. The device 3400 includes a DFE-PD 3420 that is electrically connected to an LV L-BJT 3410 while being vertically isolated and/or separated from a substrate on which the LV L-3410 is fabricated. The DFE-PD 3420 and LV L-BJT 3410 are fabricated on a common substrate 290, thereby forming the integrated device 3400 that effectively functions as an HV L-BJT. The DFE-PD 3420 includes an input region 2202, an input drift region 3312, a depletion control region 3220, an output drift region 2204, and an output region 2204 that are disposed on a top surface of a thick dielectric layer 3304 disposed on the common substrate 290. The input drift region 3312 extends in the lateral direction from the input region 2202 to the depletion control region 3220, and the output drift region 2214 is laterally extended from the depletion control region 3220 to the output region 2204.

The DFE-PD 3420 may further include two electrically connected field plates 2820b, 2820c over the input drift region 3312, extended from an interface between the input drift region 3312 and depletion control region 3220 toward the input region 2202. Each field of the plates 2820b, 2820c can be patterned on a different metallization layer where a vertical distance of the field plate 2820 that is closer to the depletion control region 3220 from a top surface of the input drift region 3312 is smaller than that of the other field plate that is closer to the input region 2202.

The output region 2204 of the DFE-PD 3420 and the HD collector region of the LV L-BJT 3410 can be electrically connected via a first conductive line 3000 fabricated in a metallization layer above the top surface of the common substrate. The RESURF layer 714b of the LV L-BJT 3410 can be electrically connected to the field plate 2820b via a second conductive line 3002 fabricated in a metallization layer above the top surface of the common substrate. The first and the second conductive lines 3000, 3002 can be fabricated on the same or different metallization layers.

In some cases, the DFE-PD 3320 and L-BJT 730 may be fabricated in a well 3402 formed in the common substrate 290. The well 3402, the input region 2202, the output region 2204, the input drift region 3312, the HD collector region 207, and the emitter region 206 may have the same polarity that is opposite to a polarity of the base well 208 and the depletion control region 3220. In some cases, the majority carrier concentration in the depletion control region 3220 can be smaller than that of the input and put drift regions 3312, 2214.

In some cases, the combination of DFE-PD 3320 and L-BJT 730 (the device within the dashed box 3440) may electrically behave as an HV L-BJT with the input region 2202 serving as the effective collector region of the HV L-BJT.

FIG. 35 schematically illustrates a cross-sectional view of an example high voltage device including a DFE-PD that is laterally and vertically separated and/or isolated from the substrate and is electrically connected to an L-BJT via conductive lines. The device includes a DFE-PD 3520 that is laterally and vertically separated and/or isolated from the substrate and is electrically connected to the LV L-BJT 804 via conductive lines. The DFE-PD 3520 may comprise one or more features described above with respect to DFE-PD 3420. In some examples, the dielectric layer 3304, the input and output regions 2202, 2204 and the regions between them, and the field plates 2820b, 2820c can be analogous and similar to those of the DFE-PD 3420. In the device in FIG. 35, however, a first substrate region 3302 below the dielectric layer 3304 (on which the DFE-PD 3520 is formed) may include a gate contact 2812 (an HD region or ohmic contact) that allows the first substrate region 3302 to be electrically connected to the field plates 2820b, 2820c and thereby serve as a bottom field plate as part of the RESURF mechanism for the DFE-PD 3520. The L-BJT 804 may have portions formed in each of the second and third substrate regions 204, 202, e.g., well regions that are doped oppositely, and extend across a boundary therebetween, where the second substrate region 204 forms a first vertical interface with the first substrate region 3302. A dielectric layer 218 disposed above the first interface electrically isolates the gate contact 2812 of the DFE-PD 3520 from the HD collector region 207 of the LV L-BJT 804. The second substrate region 204 may form a second vertical interface with the third substrate region 202. In some cases, the third substrate interface can be aligned with an edge of the base region of the LV L-BJT 804.

The output region 2204 of the DFE-PD 3520 and the HD collector region of the LV L-BJT 804 can be electrically connected via a first conductive line 3000 fabricated in a metallization layer above the top surface of the common substrate. The field plates 2820b, 2820c, the gate contact 2812, and the RESURF layer 207 can be electrically connected via a second conductive line 3002 fabricated in a metallization layer above the top surface of the common substrate. The conductive lines 3002, 3000 may be patterned as part of the same or different metallization layers.

Advantageously, as a result of the electrical connection between the first substrate region 3302 and the field plates 2820b, 2820c, the first substrate region 3302 serves as a bottom field plate and contributes to the RESURF mechanism of the DFE-PD 3520.

In some embodiments, the input and output regions 2202, 2204, the input and output drift regions 3312, 2214, and the second substrate region 204 can have the same polarity that is opposite to a polarity of the first and the third substrate regions 3302, 202, and the depletion control region 3220.

In some cases, the first, second, and the third substrate regions 3302, 204, 202 can be doped wells formed in the common substrate 290.

In some cases, the combination of the DFE-PD 3520 and the L-BJT 804 (the device within the dashed box 3540) may electrically behave as an HV L-BJT with the input region 2202 serving as the effective collector region of the HV L-BJT.

As discussed above, inventive aspects which enable the low voltage BiCMOS platform to be elevated to a suitably high voltage node relates to the use of a DFE-PD in series with the lower voltage devices to create high voltage DMOS and BJT devices. In the above, the high voltage potential divider region was formed in the common substrate as the BiCMOS devices. The inventors have discovered that, by forming the DFE-PD in the back-end-of-line (BEOL) above the front-end-of-line (FEOL), further degree of freedom in monolithic integration of different devices may be achieved.

According to various aspects, an integrated circuit (IC) device comprises a metal-oxide-semiconductor (MOS) transistor and one or both of a bipolar junction transistor (e.g., an L-BJT) and a lateral double-diffused metal-oxide-semiconductor (LDMOS) transistor formed in a common silicon substrate. The IC device additionally comprises a DFE-PD or a PD region formed above a major surface of the common semiconductor substrate and integrated in a back-end-of-line (BEOL) of the IC device. In some embodiments, the high voltage potential divider region is formed of a wide bandgap semiconductor material. In some other embodiments, the high voltage potential divider region comprises a major portion comprising a lightly doped semiconductor region. In some other embodiments, in operation, the high voltage potential divider region is configured to drop a higher voltage relative to at least the MOS transistor.

According to various embodiments, the high voltage potential divider region is separated from the major surface of the common semiconductor substrate by at least one intermetal dielectric layer. Similar to the in-substrate high voltage potential divider region described above, the high voltage potential divider region formed in the BEOL also comprises a major portion comprising a lightly (N− or P−) doped semiconductor region laterally extending between heavily doped regions. One of the heavily doped regions is connected to the one or both of the BJT and the LDMOS transistor and the other one of the heavily doped regions is configured as a high voltage input configured to be biased at 5-400V. In addition, the high voltage potential divider region comprises a conductive field plate formed thereover to serve as a reduced surface field (RESURF) plate. The high voltage potential divider region is formed of a wide band gap semiconductor comprising one or more of SiC, GaN and Ga₂O₃.

Advantageously, by isolating silicon substrate in which low voltage devices are formed using the backend dielectric layers, the high voltage nodes are effectively separated from the low voltage substrate. The interlayer dielectric isolation can provide vertical high voltage isolation, high voltage latch-up immunity and reduction in parasitic capacitances, among other advantages.

In a similar manner as described above, various synergistic processing advantages may be realized for fabricating a metal-oxide-semiconductor (MOS) transistor and one or both of a bipolar junction transistor (BJT) and a lateral double-diffused metal-oxide-semiconductor (LDMOS) transistor formed in a common silicon substrate. The details of the synergistic processing have been described above, and the details are not repeated herein for brevity.

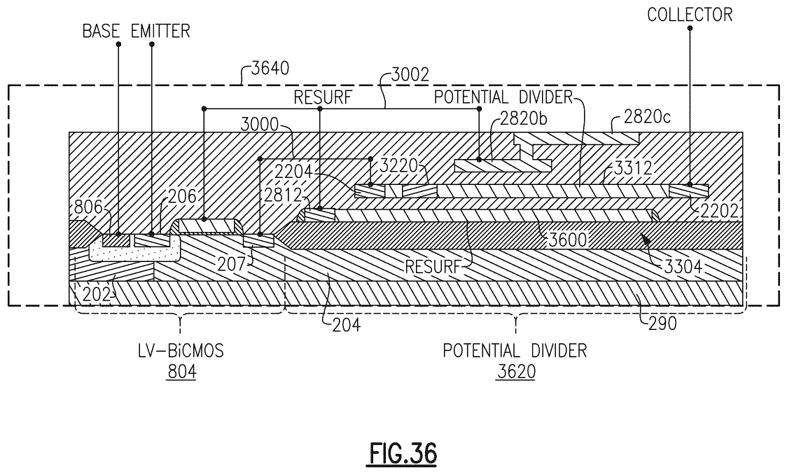

FIG. 36 schematically illustrates a cross-sectional view of another example high voltage device including a DFE-PD that is vertically separated and/or isolated from the substrate and is electrically connected to an L-BJT via conductive lines. An example DFE-PD 3620 is electrically connected to an LV L-BJT 804 via conductive lines and is vertically separated from the major surface (top surface) of the a substrate 290 on which the LV L-BJT 804 is fabricated. In some implementations, the DFE-PD 3620 may comprise one or more features described above with respect to the DFE-PD 3520 (FIG. 35). The DFE-PD 3620 is fabricated above the top surface of a thick dielectric layer 3304 disposed on the top surface of the substrate 290. In some cases, a vertical distance of a bottom surface of the DFE-PD 3620 from the top surface of a thick dielectric layer 3304 can be greater than 0.5 microns, greater than 1.0 microns, greater than 1.5 microns, greater than 2.0 microns, or be a distance in a range defined by any of these value.

In some cases, the DFE-PD 3620 may further comprise a bottom field plate 3600 disposed on the top surface of the thick dielectric layer 3304. The bottom field plate 3600 may have a thickness (in the vertical direction), from 0.1 to 0.5 microns, or have a thickness in a range defined by any of these values.

The output region 2204 of the DFE-PD 3620 and the HD collector region of the LV L-BJT 804 can be electrically connected via a first conductive line 3000 fabricated in a metallization layer above the top surface of the substrate 290. The field plates 2820b, 2820c, the bottom field plate 3600 and the RESURF layer 207 can be electrically connected via a second conductive line 3002 fabricated in a metallization layer above the top surface of the common substrate. In some examples, the bottom field plate 3600 may comprise a HD region serving as an ohmic contact between the field plate 3600 and the second conductive line 3002.

The conductive lines 3002, 3000 may be fabricated on the same or different metallization layers. The electrical connection between the bottom field plate 3600 and the field plates 2820b, 2820c results in an enhanced RESURF mechanism of the DFE-PD 3620.

In some cases, the LV L-BJT 804 have portions formed in each of the first and a second regions 204, 202 of the substrate 290 having opposite polarities, and extend across a boundary therebetween. In some cases, a vertical interface between the two regions of the substrate 290 may be aligned with a vertical interface between the emitter and base regions of the L-BJT 804. The thick oxide layer 3304 may be disposed on the first region 204 of the substrate 290. In some cases, the first and the second regions 204, 202 can be doped wells formed in the substrate 290, e.g., using thermal diffusion of dopants or ion implantation.

In some embodiments, the input and output regions 2202, 2204, the input and output drift regions 3312, 2214, the first substrate region 204, the collector 207 and the emitter 206 regions of the L-BJT 803, and the HD region 3602 of the bottom field plate 3600 can have the same polarity, which is opposite to a polarity of the second substrate region 202, the base well, and the depletion control region 3220.

In some cases, the combination of the DFE-PD 3620 and the L-BJT 804 (the device within the dashed box 3640) may electrically behave as an HV L-BJT with the input region 2202 serving as the effective collector region of the HV L-BJT.

The LV L-BJT 804 in FIGS. 35 and 36 may have the same arrangement of the base well, base region, emitter region, RESURF layer, and RESURF dielectric layer, and HD collector region as the L-BJT 804 described above with respect to FIG. 8, except for omission of the L_{D} collector region.

Advantageously, physically separating the DFE-PD 3620 from the substrate in which the LV L-BJT 804 is fabricated provides a more reliable electrical isolation between the DFE-PD 3620 and LV the L-BJT 804 (and other low voltage devices fabricated on the substrate 290). However, placing the bottom field plate 3600 on the thick dielectric layer 3304 can reduce the substrate area that may otherwise be available for fabricating transistors and other active devices for performing logic, switching, and analog operations. In some embodiment, moving the DFE-PD further up (e.g., increasing its vertical distance from the substrate) and separating the bottom field plate from the substrate can free up the corresponding substrate area and allow fabrication of more devices (e.g., BiCMOS devices) within a given substrate and connecting them to the DFE-PD for high voltage operation. In addition to freeing the surface area available for device fabrication, this approach can allow replacement of polysilicon with variety of wide bandgap materials (e.g., having bandgaps larger than 1.5 eV), e.g., compound semiconductors such as III-V and II-VI compound semiconductors, as the structural material of DFE-PD to improve the quality of the junctions formed between the depletion control region and the input/output drift regions. In some implementations, when a vertical distance between DFE-PD and substrate 290 is sufficiently large, the DFE-PD structure may be formed using advanced material growth and deposition techniques (e.g., for disposing large bandgap materials) that may not be used closer to eth substrate. Moreover, placing the DFE-PD at a higher level, e.g., above one or more metallization levels, facilitates enables electrical connection between a DFE-PD and multiple low voltage devices via a network of vias and lateral conductive lines.

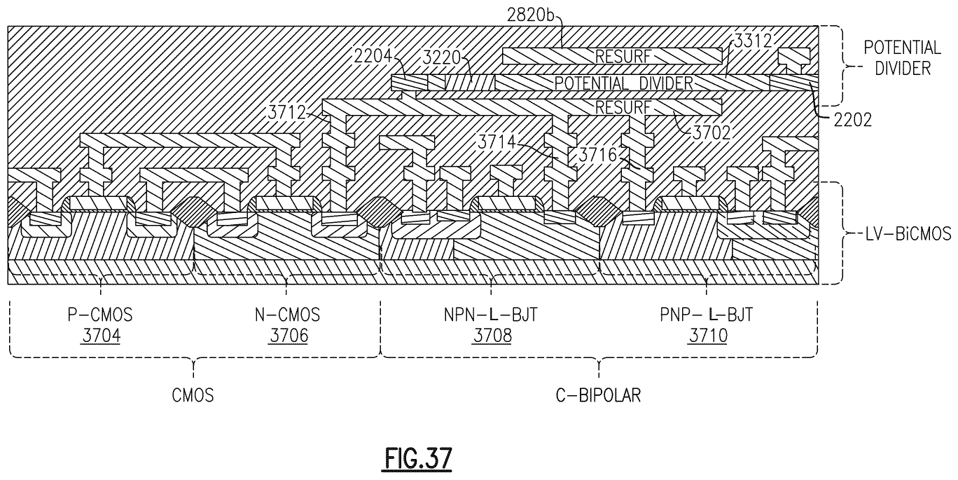

FIG. 37 schematically illustrates a cross-sectional view of another example high voltage device including a DFE-PD 3270 that is vertically separated and/or isolated from the substrate and is electrically connected to one or more MOS transistors and BJTs. An example DFE-PD 3720 has top and bottom field plates 2820b, 3702, fabricated above one or more metallization layers (e.g., two metallization layers) above a common substrate in which a plurality of MOS and/or bipolar devices are fabricated. By way of example, in the illustrated example, the DFE-PD 3720 is connected to an N-MOS 3702, a PNP L-BJT 3710 and an NPN L-BJT 3708 by the bottom field plate 3702 and parallel vertical electrical connections including vias between the output region 2204 and the drain and collector regions of the N-MOS 3702, the L-BJT 3710 and the L-BJT 3708.

Advantageously, the conductive line that laterally extends to connect the vias to the output region 2204, also serves as the bottom field plate 3702 of the DFE-PD 3720.

In some implementations, a vertical distance H between the input drift region 3312 of the DFE-PD 3720 and the top surface of the substrate on which the MOS and L-BJT transistor are fabricated can be greater than 0.15, greater than 0.3, greater than 0.5, greater than 1.0, or a distance in a range defined by any of these values.

In some cases, at least a region of the DFE-PD 3720 may comprise a wide band gap material such as SiC, GaN, or Ga₂O₃.

In some cases, a thickness of the input region 2202, the input drift region 3312, and the depletion control region 3220 (of the DFE-PD 3320, 3420, 3520, 3620), along the vertical direction (along y-axis), can be substantially equal due to being formed from the same layer. In various embodiments, the thickness of the input region 2202, the input drift region 3312, and the depletion control region 3220, can be from 0.15 to 0.5 microns. In some cases, the thickness of the dielectric layer 3304 (of the DFE-PD 3320, 3420, 3520, 3620), can be from be from 0.15 to 0.5 microns.

In various implementations, the input region 2202, the input drift region 3312, the output drift region 2204, and the output region 2204 of the DFE-PDs 3320, 3420 (FIG. 34), 3520 (FIG. 35), 3620 (FIG. 36), and 3720 (FIG. 37) may comprise a polysilicon layer or a wide band gap material layer disposed on a the thick dielectric layer 3304 or on portion of the dielectric cladding later 214 disposed above the thick dielectric layer 3304 or the top surface of the substrate 290.

In various embodiments the thickness of the polysilicon layer can be from 0.1 to 0.15 microns, from 0.1 to 0.3 microns, from 0.1 to 1.0 microns, but smaller than 2.0 microns, or a thickness in a range defined by any of these values.

In some examples, the input region 2202, the input drift region 3312, the output drift region 224, and the output region 2204 of the DFE-PDs 3320, 3420, 3520, 3620, and 3720 may formed in the polysilicon or wide band gap semiconductor using suitable doping techniques such as thermal diffusion, ion implantation or in-situ doping. In some examples, the thicknesses of the input region 2202, the input drift region 3312, the output drift region 224, and the output region 2204 of the DFE-PDs 3320, 3420, 3520, 3620, and 3720 may vertically extend across the entire thickness of the polysilicon or wide band gap semiconductor layer. In some cases, the thermal diffusion or activation of dopants in the polysilicon layer may be achieved using a suitable technique such as rapid thermal anneal (RTA) process that does not affect the wells and doped regions already formed in the substrate 290.

In some embodiments, the L-BJTs in any of the configurations shown in FIGS. 31-36, may be replaced with a MOS transistor (e.g., MOS transistors 280 or 740 shown in FIGS. 7B and 7D). In the se embodiments, the output region 2204 of the corresponding DFE-PDs (e.g., DFE-PD 3206, 3320, 3420, 3520, and 3620) can be electrically connected to the HD drain region 720 of the MOS transistor where the HD drain region 720 and the output region 2204 have the same polarities. Accordingly, the combination of a DFE-PD and the MOS transistor (the device within the dashed boxes 3240, 3340, 3440, 3540, and 3640) may electrically behave as an HV MOS or DMOS transistor with the input region 2202 serving as an effective drain region of the DMOS.

In any one of the embodiments described above with respect to FIGS. 32-38, thicknesses of the depletion control region 3220, the input drift region 3312, and the output drift region 3220 along the vertical direction can be substantially equal. In various implementations, the thickness of the depletion control region 3220, the input drift region 3312, or the output drift region 3220, along the vertical direction can be from 0.1 micron to 0.2 microns, from 0.2 microns to 0.3 microns, from 0.3 microns to 0.4 microns, from 0.4 microns to 0.5 microns, or any values in a range formed by these values. In various implementations, a common thickness of the depletion control region 3220, the input drift region 3312, or the output drift region 3220, along the vertical direction can be smaller than 2 micrometers.

In any one of the embodiments described above with respect to FIGS. 23-37, a majority carrier concentration or a doping concentration in the inter-gate region 2215 and depletion control region 3220 is smaller than those of the input drift regions 2212, 3212, 3312, and the output drift region 2214 (or output drift regions of potential dividers 3420, 3520, 3620, 3720, or 3820), and/or the well 2828, by a factor of 5, 10, 20, 30, 40, 50, 10², 10³, or larger values.

In any one of the embodiments described above with respect to FIGS. 23-37, a majority carrier concentration or a doping concentration in the inter-gate region 2215 and depletion control region 3220 is smaller than those of the input drift regions 2212, 3212, 3312 and the output drift region 2214 (or output drift regions of potential dividers 3420, 3520, 3620, 3720, or 3820), and/or the well 2828, by at least a factor of 10.

### Equivalent Circuit Model

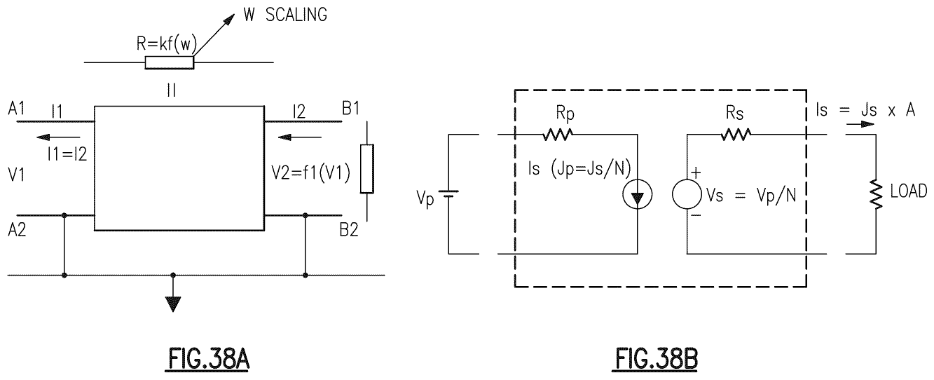

FIG. 38A-38B illustrates, without being bound to any theory, an equivalent circuit to the DFE-PD described above. The secondary voltage source (V2, Vs) is a scaled function of the applied primary voltage (V1, Vp) and the primary current (I1) is determined by the secondary current (I2), where the current densities for optimum performance are inversely ratioed by the same scaling design parameters.

The represented voltage transformer is represented as a non-magnetic, no active circuitry, or a single component that scales the applied higher DC and AC voltage levels (primary, Vₚ) to lower voltages (secondary, Vₛ). The ratio of the two voltage nodes is a design controlled parameter that can be represented by the integer N>1.

$$\frac{{V}_{p}}{{V}_{s}} = N$$

The represented voltage transformer can be adjustable to target any voltage node, where the maximum planned voltage scaling transforms 0-400V into a 0-5V range. The output of the secondary terminal is directly connected to the low voltage (LV)-BiCMOS silicon substrate. The current that flows through the LV secondary side of the voltage transformer, iₛ, is controlled by the operation of the LV circuitry. This can be translated to a current concentration according to the conduction area represented by a width, Wₛ, and height, h:

$${i}_{s} = {W}_{s} \times h \times {J}_{s}$$

No current flows through the higher voltage primary side, iₚ, until a current flows through the lower voltage secondary, where the ratio of the current concentration between the two sides is similarly scaled according to the design ratio, N.

$$\frac{{J}_{s}}{{J}_{p}} = N$$

The primary current concentration is related to the primary conduction area according to a representative width, Wₚ, and height, h.

$${i}_{p} = {W}_{p} \times h \times {J}_{p}$$

For the optimum translation of the performance achieved at the lower voltage nodes to the higher voltage nodes, the higher voltage must be capable of supporting the same current conducted by the secondary:

iₚ=iₛ

This implies the conduction width of the higher voltage node must be, N, times the width of the lower voltage secondary:

$$\begin{matrix}{W}_{p} \times h \times {J}_{p} = {W}_{s} \times h \times {J}_{s} \\ \frac{{W}_{p}}{{W}_{s}} = N\end{matrix}$$

This makes the area of the primary high voltage node, N, times larger than the lower voltage conduction area. The lower voltage area is limited by the width of the MOS channel, or the width of the emitter terminal for the bipolar. When the voltage transformer is conducting, it can be similar to a resistive element. In the illustrated model, the combination of the LV BiCMOS components together with the vertically stacked voltage transformer are drawn as a standalone device

Some additional nonlimiting examples of embodiments discussed above are provided below. These should not be read as limiting the breadth of the disclosure in any way.

### EXAMPLE EMBODIMENTS I

1. An integrated circuit (IC) device, comprising:
a metal-oxide-semiconductor (MOS) transistor comprising a gate stack formed over a channel region thereof; and
a bipolar junction transistor (BJT) comprising a layer stack formed over a collector region thereof,
wherein the gate stack and the layer stack have one or more corresponding layers having a common physical dimension.

2. An integrated circuit (IC) device, comprising:
a metal-oxide-semiconductor (MOS) transistor comprising a gate stack formed over a channel region thereof; and
a bipolar junction transistor (BJT) comprising a layer stack formed over a collector region thereof,
wherein the gate stack and the layer stack have corresponding spacer structures formed on sidewalls thereof and having a common physical dimension.

3. An integrated circuit (IC) device, comprising:
a metal-oxide-semiconductor (MOS) transistor comprising a gate stack formed over a channel region thereof; and
a bipolar junction transistor (BJT) comprising a layer stack formed over a collector region thereof,
wherein the MOS transistor and the BJT have corresponding implanted diffusion regions having a common implanted dopant profile.

4. The IC device of Embodiment 1, wherein the gate stack and the layer stack have corresponding spacer structures formed on sidewalls thereof having a common physical dimension.

5. The IC device of Embodiment 1, wherein the MOS transistor and the BJT have corresponding implanted diffusion regions having a common implanted dopant profile.

6. The IC device of Embodiment 2, wherein the gate stack and the layer stack have one or more corresponding layers having a common physical dimension.

7. The IC device of Embodiment 2, wherein the MOS transistor and the BJT have corresponding implanted diffusion regions having a common implanted dopant profile.

8. The IC device of Embodiment 3, wherein the gate stack and the layer stack have corresponding spacer structures formed on sidewalls thereof having a common physical dimension.

9. The IC device of Embodiment 8, wherein the corresponding implanted diffusion regions include source and drain regions of the MOS transistor and one of an emitter region or a collector region of the BJT.

10. The IC device of Embodiment 1, wherein the common physical dimension is caused by one or more of co-oxidation, co-deposition, co-etch and co-patterning of the gate stack and the layer stack.

11. The IC device of Embodiment 2, wherein the common physical dimension is caused by one or more of co-deposition, co-etch and co-patterning of the corresponding spacer structures.

12. The IC device of Embodiment 3, wherein the common implanted dopant profile is caused by one or more of co-implantation and co-dopant activation of the corresponding implanted diffusion regions.

13. The IC device of any one of the above Embodiments, wherein the MOS transistor and the BJT are monolithically integrated on a common substrate.

14. The IC device of any one of the above Embodiments, wherein the BJT is a lateral BJT having an emitter region, a base region within a base well and a collector region within a common well, wherein the emitter region, the base region, and the collector region are arranged in a lateral direction to support lateral bipolar currents, and where in the lateral direction is parallel to a main surface of a common substrate on which the BJT and MOS transistor are fabricated.

15. The IC device of any one of the above Embodiments, wherein a base length of the BJT is laterally extended from a first end at a vertical interface between the base region and the emitter region to a second end below an edge of the layer stack.

16. The IC device of any one of the above Embodiments, wherein the layer stack of the BJT has a first RESURF dielectric layer that is co-deposited or co-oxidized with and has a same thickness as a first gate dielectric layer of the MOS transistor.

17. The IC device of any one of the above Embodiments, wherein the layer stack of the BJT has a RESURF layer on the first RESURF dielectric layer that is co-deposited with and has a same thickness as a gate electrode on the first gate dielectric layer of the MOS transistor.

18. The IC device of any one of the above Embodiments, wherein at least a portion of the RESURF layer is disposed on a second RESURF dielectric layer that is co-deposited with and has a same thickness as a gate layer on a second gate dielectric layer of the MOS transistor.

19. The IC device of any one of the above Embodiments, wherein a thickness of the second RESURF dielectric layer and the second gate dielectric layers along a vertical direction is larger than a thickness of the first RESURF dielectric layer and the first gate dielectric layers, respectively, wherein the vertical direction is perpendicular to a main surface of a common substrate on which the BJT and MOS transistor are fabricated.

20. The IC device of any one of the above Embodiments, wherein the second RESURF dielectric layer and the second gate dielectric layer comprise thermally grown oxide layers.

21. The IC device of any one of the above Embodiments, wherein a lateral dimension of the layer stack in a first direction defines a drift region or a collector length of the BJT, and wherein a lateral dimension of the gate stack in a second direction defines a channel length of the MOS transistor in the first direction.

22. The IC device of any one of the above Embodiments, wherein the first direction is parallel to the second direction.

23. The IC device of any one of the above Embodiments, wherein a length of the layer stack in the lateral direction is substantially equal to a distance from an interface between the base region and the collector region to a vertical boundary of a lightly doped collector region.

24. The IC device of any one of the above Embodiments, wherein the layer stack of the BJT serves as a first reduced surface field (RESURF) plate extending across a collector region of the BJT.

25. The IC device of any one of the above Embodiments, wherein each of the layer stack of the BJT and the gate stack of the MOS transistor has formed on opposing sidewall surfaces thereof a pair of spacers that are co-deposited, co-patterned and co-etched such that each of the pair of spacers of the BJT and the pair of spacers of the MOS transistor has substantially a same lateral dimension.

26. The IC device of any one of the above Embodiments, wherein substantially the same lateral dimension is a width at a bottom portion of the spacers.

27. The IC device of any one of the above Embodiments, wherein the width at the bottom portion of the spacers defines a base length (LB) of the BJT and a width of a lightly-doped (L_{D}) drain region of the MOS transistor.

28. The IC device of any one of the above Embodiments, wherein each of the layer stack of the BJT and the gate stack of the MOS transistor has formed on opposing sidewall surfaces thereof a pair of spacers that are co-deposited, co-patterned, and etched separately such that the pair of spacers of the BJT has a first lateral dimension and the pair of spacers of the MOS transistor has a second lateral dimension.

29. The IC device of any one of the above Embodiments, wherein the first and second lateral dimensions are first and second widths at a bottom portion of the corresponding spacers.

30. The IC device of any one of the above Embodiments, wherein the first width defines a base length (LB) of the BJT and the second width defines a width of a lightly-doped (LD) drain region of the MOS transistor.

31. The IC device of any one of the above Embodiments, wherein the layer stack of the BJT and the gate stack of the MOS transistor have a same lateral dimension and define one or more implanted diffusion regions for the BJT and the MOS transistor.

32. The IC device of any one of the above Embodiments, wherein at least one implanted diffusion region of the BJT is co-implanted with an implanted diffusion region of MOS transistor with the same implanted dopant profile.

33. The IC device of any one of the above Embodiments, wherein the least one implanted diffusion region of the BJT comprises an LD or HD collector region of the BJT.

34. The IC device of any one of the above Embodiments, wherein the layer stack and the gate stack respectively define a first end of a base region of the BJT and a first end of a lightly-doped (LD) drain region of the MOS transistor that are co-implanted.

35. The IC device of any one of the above Embodiments, wherein a second end of a base region of the BJT and a second end of the lightly-doped (LD) drain region of the MOS transistor are defined by a spacer structure formed on respective sidewalls of the layer stack and the gate stack.

36. The IC device of any one of the above Embodiments, wherein a first end of the base region of the BJT is defined by a spacer structure formed on a sidewall of the layer stack and the second end of the base region of the BJT is defined by a diffusion length of dopants diffused from an initial base well from which the base well is formed.

37. The IC device of any one of the above Embodiments, wherein a doping profile of the base region comprises a gradient of the doping concentration in the lateral direction.

38. The IC device of any one of the above Embodiments, wherein the LD drain region is an n-doped LD (NLD) region of an n-channel MOS transistor (NMOS) that is co-implanted with an n-type base region of a PNP BJT.

39. The IC device of any one of the above Embodiments, wherein the LD drain region is a p-doped LD (PLD) region of a p-channel MOS transistor (PMOS) that is co-implanted with a p-type base region of an NPN BJT.

40. The IC device of any one of the above Embodiments, wherein a spacer of the BJT and a spacer of the MOS transistor have a same lateral dimension and define one or more implanted diffusion regions for the BJT and the MOS transistor.

41. The IC device of any one of the above Embodiments, wherein at least one implanted diffusion region of the BJT is co-implanted with an implanted diffusion region of the MOS transistor with the same implanted dopant profile.

42. The IC device of any one of the above Embodiments, wherein the spacer of the BJT and the spacer of the MOS transistor respectively define one end of an emitter region of the BJT and one end of a source/drain (S/D) region of the MOS transistor that are co-implanted.

43. The IC device of any one of the above Embodiments, wherein at least one implanted diffusion region of the BJT has a different implanted dopant profile compared to the corresponding implanted diffusion region of the MOS transistor.

45. The IC device of any one of the above Embodiments wherein the S/D region is an n-doped S/D region of an n-channel MOS transistor (NMOS) that is co-implanted with an n-type emitter region of an NPN BJT.

46. The IC device of any one of the above Embodiments, wherein the S/D region is a p-doped S/D region of a p-channel MOS transistor (PMOS) that is co-implanted with a p-type emitter region of PNP BJT.

47. The IC device of any one of the above Embodiments, wherein a collector region of the BJT and channel region of the MOS transistor are co-implanted.

48. The IC device of any one of the above Embodiments, wherein the channel region is an n-doped well region of a p-channel MOS transistor (PMOS) that is co-implanted with an n-type collector region of an NPN BJT.

49. The IC device of any one of the above Embodiments, wherein the n-type collector region comprises a lightly doped region that is co-implanted with an n-doped LD (NLD) region of an n-channel MOS transistor (NMOS) and an n-type base region of a PNP BJT.

50. The IC device of any one of the above Embodiments, wherein the n-type collector region comprises a heavily doped region that is co-implanted with an n-doped S/D region of an n-channel MOS transistor (NMOS) and an n-type emitter region of an NPN BJT.

51. The IC device of any one of the above Embodiments, wherein the channel region is a p-doped well region of an n-channel MOS transistor (NMOS) that is co-implanted with a p-type collector region of PNP BJT.

52. The IC device of any one of the above Embodiments, wherein the p-type collector region comprises a lightly doped region that is co-implanted with a p-doped LD (PLD) region of a p-channel MOS transistor (PMOS) and a p-type base region of an NPN BJT.

53. The IC device of any one of the above Embodiments, wherein the p-type collector region comprises a heavily doped region that is co-implanted with a p-doped S/D region of a p-channel MOS transistor (PMOS) and a p-type emitter region of a PNP BJT.

54. The IC device of any one of the above Embodiments, wherein the base well is formed in the common well.

55. The IC device of any one of Embodiments above the above, wherein the base well comprises a lightly doped (LD) region and at least one highly doped (HD) region.

56. The IC device of any one of the above Embodiments, wherein the at least one HD region is adjacent to the layer stack and the emitter region.

57. The IC device of any one of the above Embodiments, wherein the base well is partially formed in the common well and a second region having an opposite polarity compared to that of the common well, the second region having an interface with the common well, the interface being perpendicular to a main surface of a substrate on which the BJT and MOS transistor are fabricated.

58. The IC device of any one of the above Embodiments, wherein the emitter region is disposed between the HD region of the base well and the layer stack.

59. The IC device of any one of the above Embodiments, wherein a length of the base well along a lateral direction parallel to a substrate and extended from an edge of the layer stack to an isolating dielectric structure, is larger than a length of an LD collector region along the same lateral direction and extended from the opposing edge of the layer stack to another isolating dielectric structure, by at least 1 micrometer.

60. The IC device of any one of the above Embodiments, wherein a length of the base well along a lateral direction parallel to a substrate and extended from an edge of the layer stack to an isolating dielectric structure, is substantially equal to a length of an LD collector region along the same lateral direction and extended from the opposing edge of the layer stack to another isolating dielectric structure.

61. The IC device of any one of the above Embodiments, further comprising an interfacial dielectric layer on the emitter region and a vertical emitter region disposed on the interfacial dielectric layer, the vertical emitter extended in a vertical direction to a major surface of a substrate on which the BJT and the MOS transistor are formed.

62. The IC device of any one of the above Embodiments, wherein the vertical emitter region disposed on the emitter region comprises polysilicon.

63. The IC device of any one of the above Embodiments, wherein a thickness of the interfacial dielectric layer is less than 0.3 nm.

64. The IC device of any of the above Embodiments, wherein the BJT is electrically isolated in a vertical direction by a buried dielectric layer, and at least one lateral direction by isolating dielectric structures, wherein the vertical direction is perpendicular to a main surface of a substrate on which the BJT and the MOS transistor are fabricated.

65. The IC device of any one of the above Embodiments, wherein a base well and an LD collector region of the BJT are extended in the vertical direction to a top surface of the buried dielectric layer, wherein a vertical distance between the top surface of the buried dielectric layer and base well or the LD collector region is less than 10 nm.

66. The IC device of any one of the above Embodiments, wherein the isolating dielectric structures that laterally bound the base well and the LD collector region are in contact with the buried dielectric layer.

67. The IC device of any one of the above Embodiments, wherein a distance between a lower boundary of the dielectric structures that laterally bound the base well and the LD collector region and a top boundary of the buried dielectric layer is less than 10 nm.

68. The IC device of any one of the above Embodiments, wherein the buried dielectric layer comprises a buried oxide layer.

69. The IC device of any one of the above Embodiments, wherein the isolating dielectric structures comprise trench oxide.

70. The IC device of any one of the above Embodiments, wherein the isolating dielectric structures comprise thermally grown oxide (TGO).

71. The IC device of any one of the above Embodiments, wherein the base length is less than 500 nm.

72. The IC device of any one of the above Embodiments, wherein the metal-oxide-semiconductor (MOS) transistor further a comprises a first field plate extended in the lateral direction over a portion of the second gate dielectric layer, and the BJT comprises a second field plate extended in the lateral direction over a portion of the second RESURF dielectric layer, wherein the first field plate and the second field plate are fabricated in a first common metallization layer above the gate stack and the layer stack respectively.

73. The IC device of any one of the above Embodiments, wherein the first field plate and the second field plate are co-fabricated and have the same thickness along a vertical direction perpendicular to the lateral direction.

74. The IC device of any one of the above Embodiments, wherein the first field plate is electrically connected to the gate layer and the second filed plate is connected to RESURF layer.

75. The IC device of any one of the above Embodiments, wherein the metal-oxide-semiconductor (MOS) transistor further a comprises a third field plate extended in the lateral direction over a portion of the second gate dielectric layer, and the BJT comprises a fourth field plate extended in the lateral direction over a portion of the second RESURF dielectric layer, wherein the third field plate and the fourth field plate are fabricated in a second common metallization layer above the first common metallization layer.

76. The IC device of any one of the above Embodiments, wherein the third field plate and the fourth field plate co-fabricated and have the same thickness along a vertical direction perpendicular to the lateral direction.

78. The IC device of any one of the above Embodiments, wherein a base length of the BJT extends in a lateral direction along a major surface of the common substrate from a first end at a vertical interface between a base well and an emitter region formed in the base well, to a second end below an edge of the layer stack.

79. The IC device of any one of the above Embodiments, wherein the spacer structure of the BJT and the spacer structure of the MOS transistor have a same lateral dimension and partly define one or more implanted diffusion regions for the BJT and the MOS transistor.

80. The IC device of any one of the above Embodiments, wherein a width of a bottom portion of the spacer structure of the BJT defines a base length of the BJT and a width of the spacer structure of the MOS transistor defines on end of a lightly-doped drain region of the MOS transistor.

81. The IC device of any one of the above Embodiments, wherein the base length of the BJT and the width of the lightly-doped drain region of the MOS transistor are substantially equal.

84. The IC device of any one of the above Embodiments, wherein the common implanted dopant profile is caused by co-implantation that is self-aligned by the gate stack and the layer stack after forming the spacer structures.

85. The IC device of any one of the above Embodiments, wherein the corresponding implanted diffusion regions include lightly doped regions surrounding source and drain regions of the MOS transistor and one of an emitter region or a collector region of the BJT.

86. The IC device of Embodiment 19, wherein the common implanted dopant profile is caused by co-implantation that is self-aligned by the gate stack and the layer stack, prior to forming spacer structures on sidewalls of the gate stack and the layer stack.

### EXAMPLE EMBODIMENTS II

1. A lateral bipolar junction transistor (BJT), comprising:
an emitter region formed in a base well;
a lightly doped collector region separated in a lateral direction from the base well by a drift region doped with a dopant of a same type at a lower dopant concentration relative to the lightly doped collector region; and
a layer stack formed on the drift region;
wherein a boundary of the base well or the emitter region is aligned, in a vertical direction crossing the lateral direction, with an edge of the layer stack.

2. A lateral bipolar junction transistor (BJT), comprising:
an emitter region formed in a base well;
a lightly doped collector region separated in a lateral direction from the base well by a drift region doped with a dopant of a same type at a lower dopant concentration relative to the lightly doped collector region; and
a layer stack formed on the drift region having a spacer formed on a sidewall thereof;
wherein a base length of the lateral BJT, extending in the lateral direction between the emitter region and the drift region, is defined by a lateral width of a bottom portion of the spacer formed on a sidewall of the layer stack.

3. A lateral bipolar junction transistor (BJT), comprising:
an emitter region formed in a base well;
a heavily doped collector region separated in a lateral direction from the base well by a drift region doped with a dopant of a same type at a lower dopant concentration relative to the heavily doped collector region;
a layer stack formed at least on a first lateral section of the drift region, the layer stack including a conductive reduced surface field (RESURF) layer.

4. The lateral BJT of Embodiment 1, wherein a base length of the lateral BJT, extending between the emitter region and drift region, is defined by a lateral width of a bottom portion of a spacer formed on a sidewall of the layer stack.

5. The lateral BJT of Embodiment 1, wherein the layer stack comprises:
a dielectric layer formed on the drift region, and
a conductive reduced surface field (RESURF) layer formed on the dielectric layer.

6. The lateral BJT of Embodiment 2, wherein a vertical boundary between the base well and the emitter region is aligned, in a vertical direction crossing the lateral direction, with an edge of the layer stack.

7. The lateral BJT of Embodiment 2, wherein the layer stack of the lateral BJT comprises a dielectric layer vertically interposed between the drift region and a conductive reduced surface field (RESURF) layer.

8. The lateral BJT of Embodiment 3, wherein the layer stack further comprises a thin dielectric layer vertically interposed between the RESURF layer and the drift region.

9. The lateral BJT of Embodiment 8, further comprising a thick dielectric layer formed on a second lateral section of the drift region extending from the layer stack to the heavily doped collector region.

10. The lateral BJT of any one of the above Embodiments, wherein a vertical boundary of the base well or the emitter region is aligned with an edge of the layer stack

11. The lateral BJT of any one of the above Embodiments, wherein the base well comprises a base region extended in the lateral direction from a first end to a second end, wherein one of the first and second ends is aligned with an edge of the layer stack.

13. The lateral BJT of any one of the above Embodiments, wherein a length of the layer stack in the lateral direction is substantially equal to a length of the drift region in the lateral direction.

14. The lateral BJT of any one of the above Embodiments, wherein a base length (LB) of the L-BJT is a lateral distance from the first end aligned with an edge of the layer stack to the second end, and the base length is defined by a thermal diffusion length.

15. The lateral BJT of any one of the above Embodiments, wherein the base length (LB) is less than 500 nm.

16. The lateral BJT of any one of the above Embodiments, wherein the emitter region, the base region, and the collector region are arranged in the lateral direction to support bipolar current in the lateral direction.

17. The lateral BJT of any one of the above Embodiments, wherein the layer stack of the BJT comprises a RESURF dielectric layer, and a conductive RESURF layer disposed on the RESURF dielectric layer.

18. The lateral BJT of any one of the above Embodiments, wherein the second RESURF dielectric layer comprises a thermally grown oxide layer.

19. The lateral BJT of any one of the above Embodiments, wherein the second RESURF layer is configured to reduce a lateral component of an electric field in the drift region.

20. The lateral BJT of any one of the above Embodiments, wherein a vertical boundary of the HD collector region is aligned with a spacer formed on a sidewall of the layer stack.

21. The lateral BJT of any one of the above Embodiments, wherein a vertical boundary of the HD collector region is aligned another edge of the layer stack.

22. The lateral BJT of any one of the above Embodiments, further comprising a lightly doped (LD) collector region in which the HD collector region is formed on a second sidewall of the layer stack opposite to the first sidewall.

23. The lateral BJT of any one of the above Embodiments, wherein a peak of an implanted dopant profile of the base well of the BJT in the vertical direction is substantially positioned at a lateral interface between the base well and the emitter region.

24. The lateral BJT of any one of the above Embodiments, wherein the base well is partially formed in the common well and a second region having an opposite polarity compared to that of the common well, the second region having a vertical interface with the common well.

25. The lateral BJT of any one of the above Embodiments, wherein a length of the emitter region in the lateral direction, is larger than a length of the LD collector region along the same lateral direction by at least 0.3 micrometer.

29. The lateral BJT of any one of the above Embodiments, wherein a thickness of the interfacial dielectric layer is less than 0.3 nm.

30. The lateral BJT of any one of the above Embodiments, wherein interfacial dielectric layer comprises an oxide layer.

31. The lateral BJT of any one of the above Embodiments, wherein the BJT is electrically isolated in a vertical direction by a buried dielectric layer, and at least in one lateral direction by isolating dielectric structures.

32. The lateral BJT of any one of the above Embodiments, wherein the base well and the LD collector region are extended in the vertical direction to a top surface of the buried dielectric layer, wherein a vertical distance between the top surface of the buried dielectric layer and base well or the LD collector region is less than 500 nm.

33. The lateral BJT of any one of the above Embodiments, wherein the isolating dielectric structures that laterally bound the base well and the LD collector region are in contact with the buried dielectric layer.

34. The lateral BJT of any one of the above Embodiments, wherein a distance between a lower boundary of the dielectric structures that laterally bound the base well and the LD collector region and a top boundary of the buried dielectric layer is less than 10 nm.

35. The lateral BJT of any one of the above Embodiments, wherein the buried dielectric layer comprises a buried oxide layer.

36. The lateral BJT of any one of the above Embodiments, wherein the isolating dielectric structures comprise trench oxide.

37. The lateral BJT of any one of the above Embodiments, wherein the isolating dielectric structures comprise thermally grown oxide (TGO).

38. The lateral BJT of any one of the above Embodiments, wherein the RESURF layer is configured to provide a substantially constant lateral electric field component along the drift region.

40. The lateral BJT of any one of the above Embodiments, wherein the emitter region comprises a vertical emitter portion extending in the vertical direction above a surface of a substrate having the base well formed therein.

41. The lateral BJT of any one of the above Embodiments, wherein the vertical emitter portion comprises polysilicon.

42. The lateral BJT of any one of the above Embodiments, further comprising an interfacial dielectric layer formed between the vertical emitter portion and the top surface of the substrate.

45. The lateral BJT of any one of the above Embodiments, wherein the emitter region, a base region, and the collector region of the lateral BJT are arranged in the lateral direction, and wherein the base region comprises a region of the of the base well extending in the lateral direction between the emitter region and the drift region.

46. The lateral BJT of any one of the above Embodiments, wherein the RESURF layer laterally extends from a vertical interface between the base well and the drift region towards the heavily doped collector region to cover a portion of the thick dielectric layer.

### EXAMPLE EMBODIMENTS III

1. An integrated circuit (IC) device, comprising:
a metal-oxide-semiconductor (MOS) transistor comprising a heavily doped (HD) drain region, a gate stack, a drain region extension extending in a lateral direction from the HD drain region to an edge of the gate stack, and at least one drain field plate extending over at least 20% of a length of the drain region extension; and
a bipolar junction transistor (BJT) comprising a heavily doped (HD) collector region, a layer stack, a drift region extension extending in the lateral direction from the HD collector region to an edge of the layer stack, and at least one field plate extending over at least 20% of the drift region extension;
wherein at least one drain field plate and at least one field plate have at least one common physical dimension.

2. An integrated circuit (IC) device, comprising:
a metal-oxide-semiconductor (MOS) transistor comprising a heavily doped (HD) drain region, a gate stack, a drain region extension extending in a lateral direction from the HD drain region to an edge of the gate stack, and a thick dielectric layer extending over the drain region extension; and
a bipolar junction transistor (BJT) comprising a heavily doped (HD) collector region, a layer stack, a drift region extension extending in the lateral direction from the HD collector region to an edge of the layer stack, and a thick isolating dielectric layer extending over the drift region extension,
wherein the thick dielectric layer and the thick isolating dielectric layer have at least one common physical dimension.

3. An integrated circuit (IC) device, comprising:
a metal-oxide-semiconductor (MOS) transistor comprising a heavily doped (HD) drain region, a gate stack and a drain region extension extending in a lateral direction from the HD drain region to an edge of the gate stack, the gate stack comprising a gate layer extending over a gate dielectric layer and a portion of the drain region extension; and
a bipolar junction transistor (BJT) comprising a heavily doped (HD) collector region, a layer stack and a drift region extension extending in the lateral direction from the HD collector region to an edge of the layer stack, and a reduced surface field (RESURF) layer extending over a RESURF dielectric layer and a portion of the drift region extension,
wherein the gate layer and the RESURF layer have least one common physical dimension.

4. The IC device of Embodiment 1, wherein the at least one common physical dimension is caused by one or more of co-deposition, co-etch, and co-patterning of the drain field plate and the field plate.

5. The IC device of Embodiment 1, wherein the MOS transistor further comprises a gate layer extending over a gate dielectric layer and further over a portion of the drain region extension, and the BJT further comprises a reduced surface field (RESURF) layer extending over a RESURF dielectric layer and further over a portion of the drift region extension, and wherein the gate layer and the RESURF layer, have least one common physical dimension.

6. The IC device of Embodiment 1, wherein the MOS transistor further comprises a thick dielectric layer extending over the drain region extension, and wherein the BJT further comprises a thick isolating dielectric layer extending over the drift region extension, and wherein the thick dielectric layer and thick isolating dielectric layer have at least one common physical dimension.

7. The IC device of Embodiment 2, wherein the at least one common physical dimension is caused by one or more of co-oxidation, co-deposition, co-etch, and co-patterning of the thick dielectric layer and thick isolating dielectric layer.

8. The IC device of Embodiment 2, wherein the MOS transistor further comprises a gate layer extending over a gate dielectric layer and further over a portion of the drain region extension, and the BJT further comprises a reduced surface field (RESURF) layer extending over a RESURF dielectric layer and further over a portion of the drift region extension, and wherein the gate layer and the RESURF layer, have least one common physical dimension.

9. The IC device of Embodiment 2, wherein the MOS transistor further comprises at least one drain field plate extending over at least 20% of the drain region extension, wherein the BJT further comprises at least one field plate extending over at least 20% of the drift region extension, and wherein the at least drain field plate and the at least one field plate have at least one common physical dimension.

10. The IC device of Embodiment 3, wherein the common physical dimension is caused by one or more of co-deposition, co-etch, and co-patterning of the gate layer and the RESURF layer.

11. The IC device of Embodiment 3, wherein the MOS transistor further comprises at least one drain field plate extending over at least 20% of the drain region extension, wherein the BJT further comprises at least one field plate extending over at least 20% of the drift region extension, and wherein the at least one drain field plate and the at least one field plate have at least one common physical dimension.

12. The IC device of Embodiment 3, wherein the MOS transistor further comprises a thick dielectric layer extending over the drain region extension, wherein the BJT further comprises a thick isolating dielectric layer of the drift region extension, and wherein the thick dielectric layer and thick isolating dielectric layer, have at least one common physical dimension.

13. An integrated circuit (IC) device of any one of the above Embodiments, wherein:
the gate stack is formed over a channel region; and
the layer stack is formed over a first section of the drift region,
wherein the gate stack and the layer stack have corresponding spacer structures formed on sidewalls thereof having a common physical dimension.

14. The IC device of any one of the above Embodiments, wherein the MOS transistor and the BJT have at least one corresponding implanted diffusion region having a common implanted dopant profile.

15. The IC device of any one of the above Embodiments, wherein the common physical dimension is caused by one or more of co-oxidation, co-deposition, co-etch and co-patterning of the gate stack and the layer stack.

16. The IC device of Embodiment 2, wherein the common physical dimension is caused by one or more of co-deposition, co-etch and co-patterning of the corresponding spacer structures.

17. The IC device of Embodiment 3, wherein the common implanted dopant profile is caused by one or more of co-implantation and co-dopant activation of the corresponding implanted diffusion regions.

18. The IC device of any one of the above Embodiments, wherein the MOS transistor and the BJT are monolithically integrated on a common substrate.

19. The IC device of any one of the above Embodiments, wherein the BJT is a lateral BJT having an emitter region formed in the base well, and a base region within a base well, wherein the emitter region, the base region, and the HD collector region are arranged in a lateral direction to support lateral bipolar currents.

20. The IC device of any one of the above Embodiments, wherein at least one of the drain plates and at least one of the field plates comprise a metal.

21. The IC device of the Embodiment 9, wherein at least two drain plates are separated in the vertical direction by at least 0.5 micrometers and at least two field plates are separated in the vertical direction by at least 0.5 micrometers.

22. The IC device of any one of the above Embodiments, wherein the drain plate and at least one of the field plates comprise polysilicon.

23. The IC device of any one of the above Embodiments, wherein a base length of the BJT is laterally extended from a first end at a vertical interface between the base region and the emitter region to a second end below an edge of the layer stack.

24. The IC device of any one of the above Embodiments, wherein the layer stack of the BJT comprises a first field plate on a RESURF dielectric layer and the MOS transistor comprises a gate layer on a gate dielectric layer, wherein the first field plate and the RESURF dielectric layer, are co-deposited with and have same thickness as the gate layer and the gate dielectric layer, respectively.

25. The IC device of any one of the above Embodiments, wherein the BJT comprises a thick isolating dielectric layer that is co-deposited with and has a same thickness as a thick drain dielectric layer of the MOS transistor.

26. The IC device of any one of the above Embodiments, wherein a thickness of the thick isolating dielectric layer and the thick channel dielectric layers along the vertical direction are larger than a thickness of the RESURF dielectric layer and the gate dielectric layer, respectively.

27. The IC device of any one of the above Embodiments, wherein the second RESURF dielectric layer and the second gate dielectric layer comprise thermally grown oxide layers.

28. The IC device of any one of the above Embodiments, wherein a lateral dimension of the RESURF dielectric layer and the thick isolating dielectric layer define a length of the drift region on the BJT.

29. The IC device of any one of the above Embodiments, wherein a second field plate of the BJT and the drain plate of the MOS transistor are disposed on the thick isolating dielectric layer and the thick drain dielectric layer respectively.

30. The IC device of any one of the above Embodiments, wherein a base length (LB) of the BJT and a width of a lightly-doped (LD) drain region of the MOS transistor, are defined by the corresponding spacer structures having a common physical dimension.

31. The IC device of any one of the above Embodiments, wherein the layer stack of the BJT and the gate stack of the MOS transistor have a same lateral dimension and define boundaries of the base well of the BJT and the LD source region of the MOS transistor, respectively.

32. The IC device of any of the Embodiments above, wherein lengths of the extended drift region and the drift region extension in the lateral direction are larger than 0.5 micrometers.

33. The IC device of any one of the above Embodiments, wherein a length of the base region in the lateral direction is defined by thermal diffusion of dopants.

34. The IC device of any one of the above Embodiments, wherein a peak of doping profile of the base well along the vertical direction is at or near a lateral boundary of emitter region therein.

35. The IC device of any one of the above Embodiments, wherein the base well is an n-doped LD region of an PNP BJT that is co-implanted with an LD source region of an n-channel DMOS transistor (NDMOS).

36. The IC device of any one of the above Embodiments, wherein the base well is an p-doped LD region of an NPN BJT that is co-implanted with an LD source region of a p-channel DMOS transistor (NDMOS).

37. The IC device of any one of the above Embodiments, wherein the HD collector region is an n-doped LD region of an NPN BJT that is co-implanted with an HD drain region of an n-channel DMOS transistor (NDMOS).

38. The IC device of any one of the above Embodiments, wherein the HD collector region is an p-doped LD region of an PNP BJT that is co-implanted with an HD drain region of a p-channel DMOS transistor (NDMOS).

39. The IC device of any one of the above Embodiments, wherein at least one implanted region of the BJT has a different implanted dopant profile compared to the corresponding implanted diffusion region of the MOS transistor.

40. The IC device of any one of the above Embodiments, wherein at least a portion of the base well and the HD drain region are formed in a common well in the common substrate.

41. The IC device of any one of the above Embodiments, wherein the base well is partially formed in the common well and a second region having an opposite polarity compared to that of the common well, the second region having an interface with the common well, the interface being perpendicular to the lateral direction.

42. The IC device of any one of the above Embodiments, a length of the emitter region along the lateral direction, is larger than a length of an LD collector region along the lateral direction by at least 0.3 micrometer.

43. The IC device of any one of the above Embodiments, further comprising an interfacial dielectric layer on the emitter region and a vertical emitter region disposed on the interfacial dielectric layer, the vertical emitter extended in a vertical direction perpendicular to the lateral direction.

44. The IC device of any one of the above Embodiments, wherein the vertical emitter region disposed on the emitter region comprises polysilicon.

45. The IC device of any one of the above Embodiments, wherein a thickness of the interfacial dielectric layer is less than 0.3 nm.

46. The IC device of any one of the above Embodiments, wherein the BJT is electrically isolated in a vertical direction by a buried dielectric layer, and at least one lateral direction by isolating dielectric structures, wherein the vertical direction is perpendicular to eth lateral direction.

47. The IC device of any one of the above Embodiments, wherein the base well and the HD collector region of the BJT are extended in the vertical direction to a top surface of the buried dielectric layer, wherein a vertical distance between the top surface of the buried dielectric layer and base well or the HD collector region is less than 10 nm.

48. The IC device of any one of the above Embodiments, wherein the isolating dielectric structures that laterally bound the base well and the HD collector region are in contact with the buried dielectric layer.

49. The IC device of any one of the above Embodiments, wherein a distance between a lower boundary of the dielectric structures that laterally bound the base well and the HD collector region and a top boundary of the buried dielectric layer is less than 5 nm.

50. The IC device of any one of the above Embodiments, wherein the buried dielectric layer comprises a buried oxide layer.

51. The IC device of any one of the above Embodiments, wherein the isolating dielectric structures comprise trench oxide.

52. The IC device of any one of the above Embodiments, wherein the isolating dielectric structures comprise thermally grown oxide (TGO).

53. The IC device of any one of the above Embodiments, wherein the base length is less than 500 nm.

54. The IC device of any one of the above Embodiments, wherein thicknesses of the isolating dielectric layer and the thick isolating dielectric layer are greater than the thicknesses of the RESURF dielectric layer and the gate dielectric layer.

55. The IC device of any one of the above Embodiments, wherein the layer stack of the BJT and the gate stack of the MOS transistor have a same lateral dimension and respectively define boundaries of a base well of the BJT and a low doped source or drain region of the MOS transistor.

56. The IC device of any one of the above Embodiments, wherein the RESURF layer and the gate layer comprise polysilicon.

58. The IC device of any one of the above Embodiments, wherein the gate stack and the layer stack have corresponding spacer structures formed on sidewalls thereof and having a common physical dimension, and wherein a boundary of a heavily-doped source region of the MOS transistor and a boundary of an emitter region of the BJT are defined by the corresponding spacer structures.

61. The IC device of any one of the above Embodiments, wherein at least one drain field plate and at least one field plate comprise metal.

### EXAMPLE EMBODIMENTS IV

1. A bipolar junction transistor (BJT) formed in a substrate, the BJT comprising:
a base well;
an emitter region formed in the base well;
a heavily doped (HD) collector region separated in a lateral direction from the base well by a drift region,
a first conductive field plate disposed over a first lateral section of the drift region spanning greater than 20% of a length of the drift region in the lateral direction,
wherein the emitter region, the drift region, and the HD collector region have a same polarity that is opposite to a polarity of the base well.

2. A bipolar junction transistor (BJT) formed in a substrate, the BJT comprising:
a base well;
an emitter region formed in the base well; and
a heavily doped (HD) collector region separated in a lateral direction from the base well by a drift region having the HD collector region formed therein;
wherein the drift region has a lower dopant concentration relative to that of the HD collector region and of the base well; and
wherein the emitter region, the drift region, and the HD collector region have a same polarity that is opposite to a polarity of the base well.

3. A bipolar junction transistor (BJT) formed in a substrate, the BJT comprising:
a base well;
an emitter formed in the base well;
a heavily doped (HD) collector region separated in a lateral direction from the base well by a drift region; and
a thick dielectric layer disposed on a first lateral section of the drift region,
wherein the first lateral section is longer than 20% of a length of the drift region in the lateral direction, and
wherein the emitter region, drift region, and the HD collector region have a same polarity opposite to a polarity of the base well.

4. The BJT of Embodiment 1, wherein a dopant concentration in the drift region is less than dopant concentrations in the HD collector region and the base well.

5. The BJT of Embodiment 1, further comprising a thick dielectric layer disposed on the first lateral section of the drift region.

6. The BJT of Embodiment 5, further comprising a second conductive field plate disposed over a second lateral section of the drift region extending from the base well to the first lateral section of the drift region.

7. The BJT of Embodiment 2, further comprising a thick dielectric layer disposed on a first lateral section of the drift region, wherein the first lateral section is longer than 20% of a length of the drift region in the lateral direction.

8. The BJT of Embodiment 7, further comprising a thin dielectric layer laterally extending from an edge of the thick dielectric region to the base well, the thin dielectric layer having a thickness less than a thickness of the thick dielectric layer.

9. The BJT of Embodiment 7, further comprising first conductive field plate disposed above a first lateral section of the drift region, wherein the first lateral section is longer than 20% of a length of the drift region in the lateral direction.

10. The BJT of Claim 2, wherein a base region of the base well, the emitter region, the drift region, and the HD collector region are arranged in the lateral direction, the base region having a base length defined by a spacer structure formed above the substrate.

11. The BJT of Embodiment 3, wherein a dopant concentration in the drift region is less than dopant concentrations in the HD collector region and the base well,

12. The BJT of Embodiment 3, further comprising a first conductive field plate disposed above the thick dielectric layer.

13. The BJT of the any one of the above Embodiments, wherein the second conductive field plate is disposed on a RESURF dielectric layer, the RESURF dielectric layer being above the second lateral section of the drift region.

14. The BJT of the any one of the above Embodiments, wherein a thickness of the thick isolating dielectric layer along the vertical direction is at least 0.1 nanometer thicker than that of the RESURF dielectric layer.

15. The BJT of the any one of the above Embodiments, wherein the first, second, and the third conductive field plates are electrically connected to each other.

16. The BJT of the any one of the above Embodiments, wherein the third conductive field plate is electrically connected to the conductive first field plate via a vertical conductive line.

17. The BJT of the any one of the above Embodiments, wherein a vertical distance between the third conductive field plate and the first conductive field plate is least 0.5 micrometer.

18. The BJT of the any one of the above Embodiments, wherein the thick isolating dielectric layer is laterally extended from an edge of the RESURF dielectric layer to the HD collector region.

19. The BJT of the any one of the above Embodiments, wherein the second conductive field plate is electrically connected to the first conductive field plate via at least one vertical conductive line.

20. The BJT of the any one of the above Embodiments, wherein the vertical boundary of the base well is aligned with the edge of the second conductive field plate.

21. The BJT of the any one of the above Embodiments, further comprising a spacer formed on a sidewall of the second conductive field plate, wherein a vertical boundary of the emitter region is aligned with an edge of the spacer, and a length of a base region (L_{B}) of the BJT in the lateral direction is defined by a length of a bottom portion of the space in the lateral direction.

28. The BJT of the any one of the above Embodiments, wherein when the BJT is biased a lateral component of a lateral electric field in the drift region is substantially constant along the drift region.

22. The BJT of the any one of the above Embodiments, wherein when the BJT is biased, a voltage drop along the drift region is larger than 80 Volts.

23. The BJT of the any one of the above Embodiments, wherein when the BJT is biased, a voltage drop along the drift region is larger than 100 Volts.

24. The BJT of the any one of the above Embodiments, wherein when the BJT is biased, a voltage drop along the drift region is larger than 150 Volts.

25. The BJT of the any one of the above Embodiments, wherein when the BJT is biased, a voltage drop along the second lateral section of the drift region is larger than a voltage drop along the first section of the drift region.

26. The IC device of the any one of the above Embodiments, wherein (LB) is less than 500 nm.

27. The BJT of the any one of the above Embodiments, further comprising a third conductive field plate disposed over a third lateral section of the drift region that is non-overlapping with the first and the second lateral sections of the drift region.

28. The BJT of the any one of the above Embodiments, wherein the first conductive field plate comprises metal and the second conductive field plate comprises polysilicon.

29. The BJT of the any one of the above Embodiments, wherein a vertical boundary of the base well is defined by an edge of a layer stack disposed on the second lateral section of the drift region.

30. The BJT of the any one of the above Embodiments, wherein the drift region has a lower dopant concentration relative to that of the HD collector region and of the base well.

31. The BJT of the any one of the above Embodiments, wherein a vertical boundary of the base well is defined by an edge of a layer stack disposed on a second lateral section of the drift region extending from the base well to the first lateral section of the drift region.

32. The BJT of the any one of the above Embodiments, wherein the layer stack is disposed on the thin dielectric layer having a thickness less than a thickness of the thick dielectric layer.

33. The BJT of the any one of the above Embodiments, further comprising a fourth conductive field plate above the drift region, the fourth conductive field plate electrically connected to the first, second, and the third conductive field plates.

34. The BJT of the any one of the above Embodiments, wherein the third and further conductive field plate comprise metal.

35. The BJT of the any one of the above Embodiments, wherein the first, second, third field, and fourth conductive field plates are configured to provide a substantially constant lateral electric field component along the drift region.

### EXAMPLE EMBODIMENTS V

1. A depletion field effect potential divider (DFE-PD) comprising:
a semiconductor substrate;
a first junction formed over the semiconductor substrate and including a reverse-biased depletion region connected to an input node;
a second junction formed over the semiconductor substrate and connected to an output node,
wherein the first junction and the second junction are coupled to substantially linearly scale a high voltage input signal at the input node to a low voltage output signal at the output node.

2. The depletion field effect potential divider of Embodiment 1, wherein the high voltage input signal provides a charge at the input node that is directly coupled from the first junction onto a depletion region of the second junction.

3. The depletion field effect potential divider of Embodiment 1, wherein the low voltage output signal scales substantially linearly with the high voltage input signal with a DC offset.

4. The depletion field effect potential divider of Embodiment 1, further comprising a gate diffusion region formed between the first junction and the second junction.

5. The depletion field effect potential divider of Embodiment 4, further comprising a first gate region, a second gate region, and a lightly doped region connecting the first gate region to the second gate region, wherein a polarity of the lightly doped region and a polarity of the gate diffusion region are the same.

6. The depletion field effect potential divider of Embodiment 4, wherein the first junction includes an n-type region, the second junction includes an n-type region, and the gate diffusion region includes a p-type region.

7. The depletion field effect potential divider of Embodiment 4, further comprising a metal field plate connected to the gate diffusion region and extending over a region between the first junction and the second junction.

8. The depletion field effect potential divider of Embodiment 1, wherein the first junction has a bias of about zero volts.

9. The depletion field effect potential divider of Embodiment 1, wherein the second junction has a bias of about zero volts.

10. The depletion field effect potential divider of Embodiment 1, wherein a magnitude of the scaling factor between the low voltage output signal and the high voltage input signal is adjustable by a ratio of charge coupling between the first junction and the second junction.

11. The depletion field effect potential divider of Embodiment 1, further comprising an oxide layer formed over the semiconductor substrate, wherein the first junction and the second junction are formed in the oxide layer.

12. The depletion field effect potential divider of Embodiment 11, wherein the oxide layer includes an intermetal dielectric (IMD) oxide layer.

13. The depletion field effect potential divider of Embodiment 1, wherein the high voltage input signal is over 100 volts and the low voltage output signal is less than 10 volts.

14. The depletion field effect potential divider of Embodiment 1, wherein the input node includes a first metal contact connected to the first junction, and the output node includes a second metal contact connected to the second junction.

15. A method of analog signal translation by a depletion field effect potential divider, the method comprising:
providing a high voltage input signal to a reverse-biased depletion region of a first junction formed over a semiconductor substrate;
outputting a low voltage output signal from a second junction formed over the semiconductor substrate; and
coupling charge from the first junction to the second junction to substantially linearly scale the low voltage output signal in relation to the high voltage input signal.

16. The method of Embodiment 15, further comprising any of the features of Embodiments 2 through 14.

17. A method of forming a depletion field effect potential divider, the method comprising:
forming a first junction over a semiconductor substrate, the first junction including a reverse-biased depletion region;
contacting the first junction using a first metal contact to form an input node;
forming a second junction over the semiconductor substrate; and
contacting the second junction using a second metal contact to form an output node;
wherein the first junction and the second junction are charge coupled to provide linear scaling between the input node and the output node.

18. The method of Embodiment 17, further comprising forming a gate diffusion region over the semiconductor substrate and between the first junction and the second junction.

19. The method of Embodiment 18, further comprising forming a first gate region, forming a second gate region, and forming a lightly doped region connection the first gate region and the second gate region, wherein a polarity of the lightly doped region and a polarity of the gate diffusion region are the same.

20. The method of Embodiment 18, wherein the first junction includes an n-type region, the second junction includes an n-type region, and the gate diffusion region includes a p-type region.

21. The method of Embodiment 18, further comprising forming a metal field plate connected to the gate diffusion region and extending over a region between the first junction and the second junction.

22. The method of Embodiment 17, further comprising forming an oxide layer over the semiconductor substrate, wherein the first junction and the second junction are formed in the oxide layer.

23. The method of Embodiment 22, wherein the oxide layer includes an intermetal dielectric (IMD) oxide layer.

### EXAMPLE EMBODIMENTS VI

1. An integrated circuit (IC) device configured for voltage reduction between an input and an output, the IC device comprising;
an isolated substrate region formed in a semiconductor substrate while being electrically isolated therefrom in vertical and lateral directions, the isolated substrate region having formed therein a plurality of alternatingly doped regions arranged laterally in a lateral direction and alternatingly doped with dopants of opposite types, the alternatingly doped regions comprising:
   an input drift region and an output drift region each doped with a dopant of a first type, wherein the input drift region is connected to the input and the output drift region is connected to the output,
   an inter-gate region and a substrate region of the isolated substrate region each doped with a dopant of a second type, wherein the inter-gate region is laterally interposed between the input and output drift regions, and
   a heavily doped first gate region formed within the inter-gate region
   wherein the input drift region is elongated to have a first lateral length along the lateral direction that is longer than a second lateral length of the inter-gate region by at least a factor of two.

2. An integrated circuit (IC) device configured for voltage reduction between an input and an output, the IC device comprising:
an isolated substrate region formed in a substrate while being electrically isolated therefrom in vertical and lateral directions, the isolated substrate region having formed therein a plurality of alternatingly doped regions arranged laterally in a lateral direction and alternatingly doped with dopants of opposite types, the alternatingly doped regions comprising:
   an input drift region and an output drift region each doped with a dopant of a first type, wherein the input drift region is connected to the input and the output drift region is connected to the output, and
   an inter-gate region and a substrate region of the isolated substrate region each doped with a dopant of a second type, wherein the inter-gate region is laterally interposed between the input and output drift regions,
   wherein the inter-gate region has a dopant concentration that is lower than that of the input drift region, the output drift region and the substrate region, and
   a heavily doped first gate region formed within the inter-gate region.

3. An integrated circuit (IC) device configured for voltage reduction between an input and an output, the IC device comprising:
an isolated substrate region formed in a substrate while being electrically isolated therefrom in vertical and lateral directions, the isolated substrate region having formed therein a plurality of alternatingly doped regions arranged laterally in a lateral direction and alternatingly doped with dopants of opposite types, the alternatingly doped regions comprising:
   an input drift region and an output drift region each doped with a dopant of a first type, wherein the input drift region is connected to the input and the output drift region is connected to the output,
   an inter-gate region and a substrate region of the isolated substrate region each doped with a dopant of a second type, wherein the inter-gate region is laterally interposed between the input and output drift regions,
   a dielectric layer covering the input drift region and at least one conductive field plate extending above the dielectric layer along the lateral direction, and
   a heavily doped (HD) first gate region formed within the inter-gate region.

4. The IC device of Embodiment 1, further comprising a dielectric layer covering the input drift region, and at least one conductive field plate extending above the dielectric layer along the lateral direction.

5. The IC device of Embodiment 1, wherein the inter-gate region has a concentration of the dopant of the second type that is lower than that of the input drift region, the output drift region and the substrate region of the isolated substrate region outside of the alternatingly doped regions.

6. The IC device of Embodiment 2, further comprising a dielectric layer covering the input drift region, and one or more conductive field plates extending above the dielectric layer along the lateral direction.

7. The IC device of Embodiment 2, wherein the input drift region has a first lateral length along the lateral direction that is longer than a second lateral length of the second doped region by at least a factor of two.

8. The IC device of Embodiment 3, wherein the inter-gate region has a concentration of the dopant of the second type that is lower than that of the input drift region, output drift region and of a remaining portion of the isolated substrate region outside of the alternatingly doped regions.

9. The IC device of Embodiment 3, wherein the input drift region has a first lateral length along the lateral direction that is longer than a second lateral length of the second doped region by at least a factor of two.

10. The IC device of any one of the above Embodiments, wherein the at least one of the conductive field plates is electrically connected to the first gate region.

11. The IC device of any one of the above Embodiments, wherein the at least one of the conductive field plates is electrically connected to the first gate region.

12. The IC device of any one of the above Embodiments, further comprising a highly doped (HD) gate contact region formed in the isolated substrate region, the (HD) gate contact region having the same polarity as the first gate region, wherein the substrate region is electrically connected to the first gate region via the gate contact region to serve as a second gate region.

13. The IC device of any one of the above Embodiments, wherein the IC device is configured to provide an output voltage greater than one microvolt to the output in response to receiving an input voltage greater than 0.5 volts from the input.

14. The IC device of any one of the above Embodiments, wherein the isolated substrate region first and the second junctions are reversed biased.

15. The IC device of any one of the above Embodiments, wherein the IC device scales a high voltage input signal provided to the input substantially linearly to a low voltage output signal at least for high voltage input signals within a voltage range determined at least by a doping concentration in the inter-gate region and a lateral length of the integrate region.

16. The IC device of any one of the above Embodiments, wherein the substrate comprises silicon.

17. The IC device of any one of the above Embodiments, wherein an amplitude or minimum-to-maximum magnitude of the high voltage signal is larger than 80 volts.

18. The IC device of any one of the above Embodiments, wherein an amplitude or minimum-to-maximum magnitude of the low voltage signal is smaller than 10 volts.

19. The IC device of any one of the above Embodiments, wherein a voltage scaling factor of the IC device is at least 2.

20. The IC device of any one of the above Embodiments, wherein the output is electrically connected to an active low voltage device formed on a semiconductor substrate on which the isolated substrate region is formed.

21. The IC device of any one of the above Embodiments, wherein at least a region of IC device is co-fabricated with a region of the active low voltage device and during the same fabrication step.

22. The IC device of any one of the above Embodiments, wherein the first lateral length (LD) is longer than 0.5 micro meters.

23. The IC device of any one of the above Embodiments 1, wherein a voltage drop along the IC device comprises a first voltage drop along the input drift region and a second voltage drop along the inter-gate region, wherein the first voltage drop is determined at least partially by the first length (LD).

24. The IC device of any one of the above Embodiments, wherein the second voltage drop along the inter-gate region is determined at least partially by the second length (Lp).

25. The IC device of any one of the above Embodiments, wherein the second length (Lp) is determined based at least in part on a majority carrier concentration in the inter-gate region.

26. The IC device of any one of the above Embodiments, wherein the at least one conductive field plate comprises doped polysilicon.

27. The IC device of any one of the above Embodiments, further comprising a second conductive field plate comprising metal.

28. The IC device of any one of the above Embodiments 1, further comprising a thick dielectric layer formed over the input drift region forming an interface with the input drift region.

29. The IC device of any one of the above Embodiments, wherein the thick dielectric layer comprises an oxide.

30. The IC device of any one of the above Embodiments, the input comprises a highly doped (HD) input region formed in the input drift region, the HD input region having the same polarity as the input drift region.

31. The IC device of any one of the above Embodiments, the input comprises a highly doped (HD) output region formed in the output drift region, the HD output region having the same polarity as the output drift region.

33. The IC device of any one of the above Embodiments, wherein a majority carrier concentration or a doping concentration in the inter-gate region is smaller than those of the gate region by at least a factor of 10.

34. The IC device of any one of the above Embodiments, further comprising a heavily doped gate contact region formed at a surface of the substrate region of the isolated substrate region, the heavily doped gate contact region configured to be at the same polarity as the heavily doped first gate region, wherein the substrate region is electrically connected to the heavily doped first gate and the heavily doped gate contact region to serve as a second gate region.

35. The IC device of any one of the above Embodiments, wherein a voltage reduction factor between the input and the output is at least 2.

38. The IC device of any one of the above Embodiments, wherein the isolated substrate region is electrically isolated from other substrate regions by at least one dielectric filled trench and a buried dielectric layer.

39. A method of forming a depletion field effect potential divider (DFE-PD) in a semiconductor substrate, wherein the (DFE-PD) is configured to scale a high voltage input signal received from a high voltage node to a low voltage output signal provided to at least one low voltage device, the method comprising:
forming an input drift region extended from a first end to a second end along a lateral direction parallel to a main surface of the substrate, the input drift region having a first length (L_{D}) along the lateral direction and a first depth along a vertical direction perpendicular to the lateral direction;
forming an inter-gate region extended from the second end to third end along the lateral direction, the inter-gate region having a second length (Lₚ) along the lateral direction and a second depth along the vertical direction;
forming an output drift region extended from the third end to a fourth end along the lateral direction; and
forming highly doped first gate region formed within the inter-gate region;
electrically connecting the input drift region to the high voltage node and the output drift region is electrically connected to the low voltage device;
wherein the input drift region, the output drift region, the first gate region and the inter-gate region are doped regions, the first input drift region and the output drift regions having the same polarity opposite to a polarity of the inter-gate region and the first gate region; and
wherein a majority carrier concentration or a doping concentration in the inter-gate region is smaller than those of the gate region by at least a factor of 10².

40. The method of Embodiment 39, further comprising forming at least one conductive field plate extended above the input drift region along the lateral direction.

41. The method of any one of the above Embodiments, wherein the field plate is electrically connected to the first gate region.

42. he method of any one of the above Embodiments, wherein forming the input drift region, the output drift region, and the inter-gate region comprises forming the input drift region, the output drift region, and the inter-gate region in a first region of the substrate having the same polarity as the inter-gate region.

43. The method of any one of the above Embodiments, further comprising electrically connecting the first to the first gate region.

44. The method of any one of the above Embodiments, further comprising forming a highly doped gate contact region having the same polarity as the first gate region, in the first region, wherein the first region of the substrate is electrically connected to the first gate region via the gate contact region.

45. The method of any one of the above Embodiments, wherein depletion field effect potential divider (DFE-PD) is configured to provide an output voltage greater than one microvolt to the low voltage active device in response to receiving an input voltage greater than 0.5 volts from the high voltage node.

46. The method of any one of the above Embodiments, wherein the substrates comprises silicon.

47. The method of any one of the above Embodiments, wherein at least a region of the low voltage device and the DFE-PD are formed during the same fabrication step.

48. The method of any one of the above Embodiments, wherein the first length (L_{D}) is longer than 0.5 micrometers.

49. The method of any one of the above Embodiments, wherein the first length is longer than the first depth at least by a factor 2.

50. The method of any one of the above Embodiments, further comprising determining the second length (Lₚ) based at least in part on the majority carrier concentration in the inter-gate region.

51. The method of any one of the above Embodiments, wherein the conductive field plate comprises doped polysilicon.

52. The method of any one of the above Embodiments, further comprising forming a second conductive field plate above the conductive field plate wherein the second conductive field plate comprises metal.

53. The method of any one of the above Embodiments, further comprising forming a thick dielectric layer formed on the input drift region.

54. The method of any one of the above Embodiments, wherein the thick dielectric layer comprises an oxide.

55. The method of any one of the above Embodiments, further comprising forming a highly doped input region in the input drift region and electrically connecting the highly doped input region to the high voltage node.

56. The method of any one of the above Embodiments, further comprising forming a highly doped output region in the input drift region and electrically connecting the highly doped output region to the low voltage device.

57. The method of any one of the above Embodiments, further comprising electrically isolating the low voltage device from the DFE-PD.

58. The method of any one of the above Embodiments, further comprising forming at least one dielectric filled trench to electrically isolate first region of the substrate from other regions of the substrate.

### EXAMPLE EMBODIMENTS VII

1. An integrated circuit (IC) device, comprising:
a metal-oxide-semiconductor (MOS) transistor and a bipolar junction transistor (BJT) formed in a common semiconductor substrate;
the BJT comprising a collector region electrically connected to a high voltage potential divider substrate region in series and physically separated therefrom by an isolation structure; and
the BJT further comprising a layer stack comprising a conductive field plate formed over the collector region.

2. An integrated circuit (IC) device, comprising:
a metal-oxide-semiconductor (MOS) transistor and a bipolar junction transistor (BJT) formed in a common semiconductor substrate; and
the BJT comprising a collector region electrically connected to a high voltage potential divider substrate region in series and physically separated therefrom by an isolation structure,
wherein the collector region and the high voltage potential divider substrate region are electrically connected through one or more metallization levels formed above a major surface of the common semiconductor substrate.

3. An integrated circuit (IC) device, comprising:
a metal-oxide-semiconductor (MOS) transistor and a bipolar junction transistor (BJT) formed in a common semiconductor substrate; and
the BJT comprising a collector region electrically connected to a high voltage potential divider substrate region in series and physically separated therefrom by an isolation structure,
wherein the high voltage potential divider substrate region is configured to drop>50% of a combined voltage applied across the BJT and the high voltage potential divider substrate region.

4. The IC device of any one of the above Embodiments, wherein in operation, each of the MOS transistor and the BJT is configured to drop 5V or less while the high potential divider substrate region is configured to drop 5-400V.

5. The IC device of any one of the above Embodiments, wherein the high voltage potential divider substrate region comprises a major portion that is lightly (N− or P−) doped with a same dopant type as the collector region of the BJT.

6. The IC device of any one of the above Embodiments, wherein the isolation structure comprises a shallow trench isolation.

7. The IC device of any one of the above Embodiments, wherein a gate stack of the MOS transistor and a layer stack of the BJT comprising a conductive field plate formed over the collector region thereof have one or more corresponding layers having a common physical dimension.

8. The IC device of any one of the above Embodiments, wherein a gate stack of the MOS transistor and a layer stack of the BJT comprising a conductive field plate formed over the collector region thereof have corresponding spacer structures formed on sidewalls thereof having a common physical dimension.

9. The IC device of any one of the above Embodiments, wherein the MOS transistor and the BJT have implanted diffusion regions having a common implanted dopant profile.

10. The IC device of any one of the above Embodiments, wherein the BJT is a lateral BJT having an emitter region, a base region and a collector region that are arranged in a lateral direction parallel to a main surface of a common substrate.

11. The IC device of any one of the above Embodiments, wherein a layer stack formed over the collector region of the BJT has a dielectric layer that is co-deposited or co-oxidized with and has a same thickness as a gate dielectric of the MOS transistor.

12. The IC device of any one of the above Embodiments, wherein a layer stack formed over the collector region of the BJT has a conducting layer on a dielectric that is co-deposited with and has a same thickness as a gate electrode on a gate dielectric of the MOS transistor.

13. The IC device of any one of the above Embodiments, wherein a layer stack formed over the collector region of the BJT extends over the isolation structure.

14. The IC device of any one of the above Embodiments, wherein a layer stack formed over the collector region of the BJT in a first direction defines a length of the collector region of the BJT, and wherein a lateral dimension of the gate stack defines a channel length of the MOS transistor in the first direction.

15. The IC device of any one of the above Embodiments, wherein a layer stack formed over the collector region of the BJT serves as a reduced surface field (RESURF) plate.

16. The IC device of any one of the above Embodiments, wherein a layer stack formed over the collector region of the BJT and a gate stack of the MOS transistor have formed on sidewall surfaces thereof spacers that are co-deposited, co-patterned and co-etched such that the spacer of the BJT and spacer of the MOS transistor have substantially a same lateral dimension.

17. The IC device of Embodiment 16, wherein substantially the same lateral dimension is a width at a base region of the spacers.

18. The IC device of Embodiment 17, wherein the width at the base region of the spacers define a base length of the BJT and a width of a lightly-doped drain of the MOS transistor.

19. The IC device of any one of the above Embodiments, wherein the layer stack of the BJT and the gate stack of the MOS transistor have a same lateral dimension and define one or more implanted diffusion regions for the BJT and the MOS transistor that have a co-implanted dopant profile.

20. The IC device of Embodiment 19, wherein the layer stack and the gate stack respectively define one end of a base region of the BJT and one end of a lightly-doped drain (LDD) region of the MOS transistor that are co-implanted.

21. The IC device of Embodiment 20, wherein the other end of the base region of the BJT and the other end of the lightly-doped drain (LDD) region of the MOS transistor are defined by a spacer formed on respective sidewalls of the layer stack and the gate stack.

22. The IC device of Embodiment 20, wherein the LDD region is an n-doped LDD (NLDD) region of an n-channel MOS transistor (NMOS) that is co-implanted with an n-type base region of a PNP BJT.

23. The IC device of Embodiment 20, wherein the LDD region is a p-doped LDD (PLDD) region of a p-channel MOS transistor (PMOS) that is co-implanted with a p-type base region of an NPN BJT.

24. The IC device of any one of the above Embodiments, wherein a spacer of the BJT and a spacer of the MOS transistor have a same lateral dimension and define one or more implanted diffusion regions for the BJT and the MOS transistor that have a common implanted dopant profile.

25. The IC device of Embodiment 24, wherein the spacer of the BJT and the spacer of the MOS transistor respectively define one end of an emitter region of the BJT and one end of a source/drain (S/D) region of the MOS transistor that are co-implanted.

26. The IC device of Embodiment 25, wherein the S/D region is an n-doped S/D of an n-channel MOS transistor (NMOS) that is co-implanted with an n-type emitter region of an NPN BJT.

27. The IC device of Embodiment 25, wherein the S/D region is a p-doped S/D of a p-channel MOS transistor (PMOS) that is co-implanted with a p-type emitter region of PNP BJT.

28. The IC device of any one of the above Embodiments, wherein a collector region of the BJT and channel region of the MOS transistor are co-implanted.

29. The IC device of Embodiment 28, wherein the channel region is an n-doped well region of a p-channel MOS transistor (PMOS) that is co-implanted with an n-type collector region of an NPN BJT.

30. The IC device of Embodiment 29, wherein the n-type collector region comprises a lightly doped region that is co-implanted with an n-doped LDD (NLDD) region of an n-channel MOS transistor (NMOS) and an n-type base region of a PNP BJT.

31. The IC device of Embodiment 29, wherein the n-type collector region comprises a heavily doped region that is co-implanted with an n-doped S/D region of an n-channel MOS transistor (NMOS) and an n-type emitter region of an NPN BJT.

32. The IC device of Embodiment 28, wherein the channel region is a p-doped well region of an n-channel MOS transistor (NMOS) that is co-implanted with a p-type collector region of PNP BJT.

33. The IC device of Embodiment 32, wherein the p-type collector region comprises a lightly doped region that is co-implanted with a p-doped LDD (PLDD) region of a p-channel MOS transistor (PMOS) and a p-type base region of an NPN BJT.

34. The IC device of Embodiment 32, wherein the p-type collector region comprises a heavily doped region that is co-implanted with a p-doped S/D region of a p-channel MOS transistor (PMOS) and a p-type emitter region of an PNP BJT.

35. An integrated circuit (IC) device, comprising:
a metal-oxide-semiconductor (MOS) transistor and a lateral double-diffused metal-oxide-semiconductor (LDMOS) transistor formed in a common semiconductor substrate; and
the LDMOS transistor comprising an extended drain drift region that is physically separated from a channel region of the LDMOS transistor by an isolation structure,
wherein a gate stack of the MOS transistor and a gate stack of the LDMOS transistor have one or more corresponding layers having a common physical dimension.

36. An integrated circuit (IC) device, comprising:
a metal-oxide-semiconductor (MOS) transistor and a lateral double-diffused metal-oxide-semiconductor (LDMOS) transistor formed in a common semiconductor substrate; and
the LDMOS transistor comprising an extended drain drift region that is physically separated from a channel region of the LDMOS transistor by an isolation structure,
   wherein the MOS transistor and the LDMOS transistor have implanted diffusion regions having a common implanted dopant profile.

37. An integrated circuit (IC) device, comprising:
a metal-oxide-semiconductor (MOS) transistor and a lateral double-diffused metal-oxide-semiconductor (LDMOS) transistor formed in a common semiconductor substrate; and
the LDMOS transistor comprising an extended drain drift region that is physically separated from a channel region of the LDMOS transistor by an isolation structure,
wherein the extended drain drift region comprises a conductive field plate formed thereover.

38. The IC device of any one of the Embodiments 35-37, wherein in operation, the MOS transistor is configured to drop 5V or less while the extended drain drift region is configured to drop 5-400V.

39. The IC device of any one of the Embodiment 35-38, wherein the isolation structure comprises a shallow trench isolation.

40. The IC device of any one of the Embodiment 35-39, wherein the channel region of the LDMOS transistor and the extended drain drift region are electrically connected through one or more metallization levels formed above a major surface of the common semiconductor substrate.

41. IC device of any one of the Embodiment 35-40, wherein the extended drain drift region comprises a major portion that is lightly (N− or P−) doped with a same dopant type as the a source region of the LDMOS transistor.

42. IC device of any one of the Embodiment 35-41, wherein the channel of the LDMOS transistor is laterally interposed between a first heavily (N++ or P++) doped region serving as a source and a second heavily (N++ or P++) doped region doped with the same dopant type as the first heavily doped region.

43. IC device of any one of the Embodiment 35-42, wherein the second heavily (N++ or P++) doped region is physically separated by the isolation structure from, while being electrically connected to, a third heavily (N++ or P++) doped region formed in the extended drain drift region and doped with the same dopant type as the first and second heavily doped regions.

44. IC device of any one of the Embodiment 35-43, wherein the extended drain drift region comprises a conductive field plate formed thereover to serve as a reduced surface field (RESURF) plate.

45. IC device of any one of the Embodiment 35-44, wherein the LDMOS transistor comprises a backgate contact electrically connected to a conductive field plate formed over the extended drain drift region serving as a reduced surface field (RESURF) plate.

46. IC device of any one of the Embodiment 35-45, wherein the LDMOS transistor comprises a backgate contact electrically connected to a heavily (N++ or P++) doped region formed in and oppositely doped as a major portion of the extended drain drift region that is lightly (N− or P−) doped.

47. IC device of any one of the Embodiment 35-46, wherein a gate dielectric of the LDMOS transistor is co-deposited or co-oxidized with and has a same thickness as a gate dielectric of the MOS transistor.

48. IC device of any one of the Embodiment 35-47, wherein a gate electrode of the LDMOS is co-deposited and co-patterned with and has a same thickness as a gate electrode of the MOS transistor.

49. IC device of any one of the Embodiment 35-48, wherein the extended drain drift region comprises a conductive field plate formed thereover to serve as a reduced surface field (RESURF) plate that is co-deposited with and has a same thickness as a gate electrode of one or both of the MOS transistor and the LDMOS transistor.

50. IC device of any one of the Embodiment 35-49, wherein a gate stack of the LDMOS transistor and a gate stack of the MOS transistor are co-patterned to have a same lateral dimension in at least one direction.

51. IC device of any one of the Embodiment 35-50, wherein a lateral dimension of a gate stack defines a channel length of one or both of the MOS transistor and the LDMOS transistor.

### EXAMPLE EMBODIMENTS VIII

1. An integrated circuit (IC) device, comprising:
at least one low voltage active semiconductor device formed in a first substrate region of a semiconductor substrate; and
a depletion field effect potential divider (DFE-PD) formed in a second substrate region of the semiconductor substrate and configured to reduce a high voltage input signal received from a high voltage node to generate a low voltage output signal, and to provide the low voltage output signal to the low voltage active semiconductor device as an input signal thereto,
wherein the low voltage active semiconductor device and the DFE-PD are physically separated while being electrically connected in series, and
wherein the first and the second substrate regions are electrically separated by an isolation structure.

2. An integrated circuit (IC) device, comprising:
at least one low voltage active semiconductor device formed in a first substrate region of a semiconductor substrate; and
a depletion field effect potential divider (DFE-PD) formed in a second substrate region of the semiconductor substrate and configured to reduce a high voltage input signal received from a high voltage node to generate a low voltage output signal, and to provide the low voltage output signal to the low voltage active semiconductor device as an input signal thereto,
wherein the DFE-PD comprises a plurality of alternatingly doped regions arranged laterally in a lateral direction and alternatingly doped with dopants of opposite types, the alternatingly doped regions comprising:
an input drift region and an output drift region each doped with a dopant of a first type, wherein the input drift region is connected to the input and the output drift region is connected to the output,
an inter-gate region laterally interposed between the input and output drift regions, wherein the inter-gate region and the second substrate region are doped with a dopant of a second type, and
a heavily doped first gate region formed within the inter-gate region.

3. The integrated circuit (IC) device of any one of the above Embodiments, wherein the at least one low voltage active semiconductor device comprises a bipolar junction transistor (BJT).

4. The integrated circuit (IC) device of any one of the above Embodiments, wherein the BJT is a lateral BJT having an emitter region, a base region and a collector region that are arranged in a lateral direction parallel to a major surface of a common substrate.

5. The integrated circuit (IC) device of any one of the above Embodiments, wherein the BJT is a lateral BJT having a layer stack comprising a reduced surface field (RESURF) layer formed over a collector region.

6. The integrated circuit (IC) device of any one of the above Embodiments, wherein the at least one low voltage active semiconductor device comprises a metal oxide semiconductor (MOS) transistor having a gate stack comprising a gate layer formed over a channel region.

7. The integrated circuit (IC) device of any one of the above Embodiments, wherein the at least one low voltage active semiconductor further comprises a lateral BJT having an emitter region, a base region and a collector region that are arranged in a lateral direction parallel to a main surface of a common substrate.

8. The integrated circuit (IC) device of any one of the above Embodiments, wherein the gate stack of the MOS transistor and the layer stack of the lateral BJT have one or more corresponding layers having a common physical dimension.

9. The integrated circuit (IC) device of any one of the above Embodiments, wherein the gate stack of the MOS transistor and the layer stack of the lateral BJT comprise corresponding spacer structures formed on sidewalls thereof, the corresponding spacer structures having a common physical dimension.

10. The integrated circuit (IC) device of any one of the above Embodiments, wherein a width of a base portion of the spacers define a base length of the lateral BJT and a width of a lightly-doped drain of the MOS transistor.

11. The integrated circuit (IC) device of any one of the above Embodiments, wherein the lateral BJT further comprises a layer stack comprising a dielectric layer between a reduced surface field (RESURF) layer and the base region that is co-deposited or co-oxidized with and has a same thickness as a gate dielectric layer of the MOS transistor.

12. The integrated circuit (IC) device of any one of the above Embodiments, wherein the at least one low voltage semiconductor active device and the DFE-PD are electrically connected through one or more metallization levels formed above a major surface of the semiconductor substrate.

13. The integrated circuit (IC) device of any one of the above Embodiments, wherein in operation, the at least one low voltage semiconductor active device is configured to drop 5V or less while the DFE-PD is configured to drop 5-400V.

14. The integrated circuit (IC) device of any one of the above Embodiments, wherein the isolation structure comprises a shallow or deep dielectric filed trench.

15. The integrated circuit (IC) device of any one of the above Embodiments, wherein the isolation structure further comprises a buried dielectric layer.

16. The integrated circuit (IC) device of any one of the above Embodiments, wherein the DFE-PD is configured to reduce the high voltage input signal by at least 50%.

17. The integrated circuit (IC) device of any one of the above Embodiments, wherein the input drift region is elongated to have a first lateral length along the lateral direction that is longer than a second lateral length of the inter-gate region by at least a factor of two.

18. The integrated circuit (IC) device of any one of the above Embodiments, wherein the inter-gate region has a dopant concentration that is lower than that of the input drift region, the output drift region and the second substrate region.

19. The integrated circuit (IC) device of any one of the above Embodiments, further comprising at least one conductive field plate extending above the input drift region along the lateral direction.

20. The integrated circuit (IC) device of any one of the above Embodiments, wherein the at least one low voltage active semiconductor device comprises one or both of a metal oxide semiconductor transistor or a bipoloar junction transistor.

23. The integrated circuit (IC) device of any one of the above Embodiments, wherein the BJT is a lateral BJT (L-BJT) having a layer stack comprising a RESURF layer formed over a collector region.

24. The integrated circuit (IC) device of any one of the above Embodiments, wherein the at least one low voltage active semiconductor device comprises a MOS transistor having a gate stack comprising a gate layer formed over a channel region.

25. The integrated circuit (IC) device of any one of the above Embodiments, wherein the at least one low voltage active semiconductor device comprises a MOS transistor having a gate stack comprising a gate layer formed over a channel region, and a lateral BJT (L-BJT) having a layer stack comprising a RESURF layer formed over a collector region, the L-BJT having an emitter region, a base region and a collector region that are arranged in a lateral direction parallel to a main surface of a common substrate.

26. The integrated circuit (IC) device of any one of the above Embodiments, wherein the gate stack of the MOS transistor and the layer stack of the L-BJT have one or more corresponding layers having a common physical dimension.

27. The integrated circuit (IC) device of any one of the above Embodiments, wherein the gate stack of the MOS transistor and the layer stack of the L-BJT comprise spacer structures formed on sidewalls of the layer stack and the gate stack, the spacer structures having a common physical dimension.

28. The integrated circuit (IC) device of any one of the above Embodiments, wherein the width at the base region of the spacers define a base length of the BJT and a width of a lightly-doped drain of the MOS transistor.

29. The integrated circuit (IC) device of any one of the above Embodiments 8, wherein the MOS transistor and the L-BJT have implanted diffusion regions having a common implanted dopant profile.

30. The integrated circuit (IC) device of any one of the above Embodiments, wherein the layer stack formed has a RESURF dielectric layer that is co-deposited or co-oxidized with and has a same thickness as a gate dielectric layer of the MOS transistor.

31. The integrated circuit (IC) device of any one of the above Embodiments, wherein the layer stack and the gate stack respectively define one end of a base region of the BJT and one end of a lightly-doped drain region of the MOS transistor that are co-implanted.

34. The integrated circuit (IC) device of any one of the above Embodiments, wherein the isolation structure comprises a shallow dielectric filed trench.

35. The integrated circuit (IC) device of any one of the above Embodiments, wherein the isolation structure comprises a deep dielectric filed trench.

36. The integrated circuit (IC) device of any one of the above Embodiments, wherein the isolation structure comprises a buried dielectric layer.

37. The integrated circuit (IC) device of any one of the above Embodiments, wherein the DFE-PD is configured to reduce the high voltage input signal by at least 50%.

38. The integrated circuit (IC) device of any one of the above Embodiments, wherein the DFE-PD comprises a major portion that is lightly (N− or P−) doped with a same dopant type as the collector region of the BJT or a drain region of the MOS transistor.

39. The integrated circuit (IC) device of any one of the above Embodiments, wherein the DFE-PD comprises:
an input drift region extended from a first end to a second end along a lateral direction parallel to the main surface of the substrate, the input drift region having a first length (L_{D}) along the lateral direction;
an inter-gate region extended from the second end to third end along the lateral direction, the inter-gate region having a second length (Lₚ) along the lateral direction;
an output drift region extended from the third end to a fourth end along the lateral direction; and
a highly doped first gate region formed within the inter-gate region;
wherein the first length is larger than the second length and the first depth;
wherein the first input drift region and the second drift regions have the same polarity opposite to a polarity of the inter-gate region and the first gate region; and
wherein a majority carrier concentration or a doping concentration in the inter-gate region is smaller than those of the gate region by at least a factor of 10.

40. The integrated circuit (IC) device of any one of the above Embodiments, further comprising at least one conductive field plate extended above the input drift region along the lateral direction.

41. The integrated circuit (IC) device of any one of the above Embodiments, wherein the field plate is electrically connected to the first gate region.

42. The integrated circuit (IC) device of any one of the above Embodiments, wherein the first region of the substrate having the same polarity as the inter-gate region.

43. The integrated circuit (IC) device of any one of the above Embodiments, wherein the second substrate region is electrically connected to the first gate region and at least a portion of the second substrate region serves as a second gate region for the DFE-PD.

44. The integrated circuit (IC) device of any one of the above Embodiments, wherein the first length (LD) is longer than 0.5 micrometers.

45. The integrated circuit (IC) device of any one of the above Embodiments, wherein the second length (Lp) is shorter than 5.0 micrometers.

46. The integrated circuit (IC) device of any one of the above Embodiments, wherein the first length (LD) is longer than the second length (Lp) at least by a factor 2.

### EXAMPLE EMBODIMENTS IX

1. An integrated circuit (IC) device, comprising:
a metal-oxide-semiconductor (MOS) transistor and one or both of a bipolar junction transistor (BJT) and a lateral double-diffused metal-oxide-semiconductor (LDMOS) transistor formed in a common silicon substrate; and
a high voltage potential divider region formed above a major surface of the common semiconductor substrate and integrated in a back-end-of-line (BEOL) of the IC device,
wherein the high voltage potential divider region is formed of a wide bandgap semiconductor material.

2. An integrated circuit (IC) device, comprising:
a metal-oxide-semiconductor (MOS) transistor and one or both of a bipolar junction transistor (BJT) and a lateral double-diffused metal-oxide-semiconductor (LDMOS) transistor formed in a common silicon substrate; and
a high voltage potential divider region formed above a major surface of the common semiconductor substrate and integrated in a back-end-of-line (BEOL) of the IC device,
wherein the high voltage potential divider region comprises a major portion comprising a lightly doped semiconductor region.

3. An integrated circuit (IC) device, comprising:
a metal-oxide-semiconductor (MOS) transistor and one or both of a bipolar junction transistor (BJT) and a lateral double-diffused metal-oxide-semiconductor (LDMOS) transistor formed in a common silicon substrate; and
a high voltage potential divider region formed above a major surface of the common semiconductor substrate and integrated in a back-end-of-line (BEOL) of the IC device,
wherein in operation, the high voltage potential divider region is configured to drop a higher voltage relative to at least the MOS transistor.

4. The IC device of any one of the above Embodiments, wherein in operation, each of the MOS transistor and the BJT is configured to drop 5V or less while the high voltage potential divider region is configured to drop 5-400V.

5. The IC device of any one of the above Embodiments, wherein the high voltage potential divider region is separated from the major surface of the common semiconductor substrate by at least one intermetal dielectric layer.

6. The IC device of any one of the above Embodiments, wherein the high voltage potential divider region is embedded in an intermetal dielectric layer.

7. The IC device of any one of the above Embodiments, wherein the high voltage potential divider region comprises a major portion comprising a lightly (N− or P−) doped semiconductor region laterally extending between heavily doped regions, wherein one of the heavily doped regions is connected to the one or both of the BJT and the LDMOS transistor and the other one of the heavily doped regions is configured as a high voltage input configured to be biased at 5-400V.

8. The IC device of any one of the above Embodiments, wherein the high voltage potential divider region comprises a conductive field plate formed thereover to serve as a reduced surface field (RESURF) plate.

9. The IC device of any one of the above Embodiments, wherein the high voltage potential divider region is formed of a wide band gap semiconductor comprising one or more of SiC, GaN and Ga₂O₃.

10. The IC device of any one of the above Embodiments, wherein the IC device comprises the BJT, and wherein a collector region of the BJT is electrically connected to the high voltage potential divider region in series.

11. The IC device of Embodiment 10, wherein the BJT is a lateral BJT and comprises a layer stack formed over a collector region thereof.

12. The IC device of Embodiment 11, wherein a gate stack of the MOS transistor and the layer stack of the BJT have at least one layer having a common physical dimension.

13. The IC device of Embodiment 11, wherein a gate stack of the MOS transistor and the layer stack of the BJT each have spacer structures formed on respective sidewalls thereof and having a common physical dimension.

14. The IC device of Embodiment 11, wherein the MOS transistor and the BJT have implanted diffusion regions having a common implanted dopant profile.

15. The IC device of any one of the above Embodiments, wherein the IC device comprises the LDMOS, and wherein a channel region of the LDMOS is electrically connected to the high voltage potential divider region in series.

16. The IC device of Embodiment 15, wherein the high voltage potential divider region serves as an extended drain drift region of the LDMOS that is physically separated from a channel region of the LDMOS.

17. The IC device of Embodiment 15, wherein a gate stack of the MOS transistor and a gate stack of the LDMOS transistor have at least one layer having a common physical dimension.

18. The IC device of Embodiment 13, wherein the MOS transistor and the LDMOS transistor have implanted diffusion regions having a common implanted dopant profile.

### EXAMPLE EMBODIMENTS X

1. An integrated circuit (IC) device, comprising:
at least one low voltage active device formed in a semiconductor substrate; and
a depletion field effect potential divider (DFE-PD) formed above a major surface of the semiconductor substrate and separated therefrom by a dielectric layer, the DFE-PD configured to scale a high voltage input signal received from a high voltage node to a low voltage output signal, and to provide a low voltage signal to the low voltage active device as an input signal thereto, the DFE-PD comprising:
a doped semiconductor region extending along a lateral direction parallel to the major surface of the substrate between a heavily doped (HD) input region and a heavily doped (HD) output region, and
a depletion control region formed within the doped semiconductor region and oppositely doped relatively to a remainder of the doped semiconductor region;
wherein the DFE-PD and the low voltage active device are electrically connected by an electrical connection.

2. An integrated circuit (IC) device, comprising:
at least one low voltage active device formed in a semiconductor substrate; and
a depletion field effect potential divider (DFE-PD) formed above a major surface of the semiconductor substrate and separated therefrom by a dielectric layer, the DFE-PD configured to scale a high voltage input signal received from a high voltage node to a low voltage output signal, and to provide a low voltage signal to the low voltage active device as an input signal thereto, the DFE-PD comprising:
a doped semiconductor region laterally extending along a lateral direction parallel to the major surface of the substrate between a heavily doped (HD) input region that receives the low voltage output signal and a heavily doped (HD) output region that outputs the low voltage signal,
a depletion control region formed within the doped semiconductor region and oppositely doped relatively to a remainder of the doped semiconductor region, and
at least one conductive field plate laterally extending over the doped semiconductor region and electrically connected to the low voltage active device by an electrical connection formed at least partly above the semiconductor substrate.

3. The IC device of Embodiment 1, wherein the DFE-PD further comprises at least one conductive field plate laterally extending over the doped semiconductor region and electrically connected to the low voltage active device by an electrical connection formed above the semiconductor substrate by one or more common metallization levels of the low voltage active device and the DFE-PD.

4. The IC device of Embodiment 2, wherein the DFE-PD and the low voltage active device are electrically connected by an electrical connection formed by one or more common metallization levels of the low voltage active device and the DFE-PD.

5. The integrated circuit (IC) device of an one of the above Embodiments, wherein DFE-PD further comprises an input drift region extending between the HD input region and the depletion control region, and an output drift region extending between the depletion control region and the output drift region.

6. The integrated circuit (IC) device of any one of the above Embodiments, a thicknesses of the depletion control region, the input drift region, and the output drift region along a vertical direction are substantially equal, and are smaller than 2 micrometers, wherein vertical direction is perpendicular to the lateral direction.

7. The integrated circuit (IC) device of any one of the above Embodiments, further comprising a second conductive field plate laterally extended above the at least one field plate and electrically connected to the first field plate.

8. The integrated circuit (IC) device of any one of the above Embodiments, wherein depletion field effect potential divider (DFE-PD) is configured to provide an output voltage greater than one microvolt to the low voltage active device in response to receiving an input voltage greater than 0.5 volts from the high voltage node.

9. The integrated circuit (IC) device of any one of the above Embodiments, wherein a length of the input drift region along the lateral direction is at least 2 times larger than a length of the depletion control region.

10. The integrated circuit (IC) device of any one of the above Embodiments, wherein the dielectric layer comprises a buried dielectric layer within the substrate.

11. The integrated circuit (IC) device of any one of the above Embodiments, wherein the dielectric layer is formed on the semiconductor substrate.

12. The integrated circuit (IC) device of any one of the above Embodiments, wherein a region of the semiconductor substrate below the dielectric layer is electrically connected to the HD output region and serves as a field plate for the DFE-PD, and wherein the region of the semiconductor substrate has the same polarity as the HD output region.

13. The integrated circuit (IC) device of any one of the above Embodiments, wherein a region of the semiconductor substrate below the dielectric layer is electrically connected to the at least one conductive field plate via an HD contact region and serves as a second field plate for the DFE-PD, and wherein the region of the semiconductor substrate and the HD contact region have the same polarity as the depletion control region.

14. The integrated circuit (IC) device of any one of the above Embodiments, wherein a pn junction and a dielectric layer are formed between the region of the semiconductor substrate and a region of the substrate on which the low voltage device is formed.

15. The integrated circuit (IC) device of any one of the above Embodiments, wherein the dielectric layer comprises a cladding dielectric layer disposed on the semiconductor substrate.

16. The integrated circuit (IC) device of any one of the above Embodiments, wherein the dielectric layer comprises an intermetal dielectric layer (IDL).

17. The integrated circuit (IC) device of any one of the above Embodiments, wherein the dielectric layer comprises a cladding dielectric layer disposed on the semiconductor substrate and the DFE-PD is integrated in a back-end-of-line (BEOL) of the IC device,

18. The integrated circuit (IC) device of any one of the above Embodiments, wherein the dielectric layer comprises a cladding dielectric layer disposed on the semiconductor substrate, wherein the high voltage potential divider region is embedded in an intermetal dielectric layer (IMD).

19. The integrated circuit (IC) device of any one of the above Embodiments, wherein the IC device further comprises a second field plate disposed on a second dielectric layer formed on the semiconductor substrate, the second field plate electrically connected to the low voltage device and eth at least one field plate.

20. The integrated circuit (IC) device of any one of the above Embodiments, wherein an amplitude or minimum-to-maximum magnitude of the high voltage input signal is larger than 80 volts.

21. The integrated circuit (IC) device of any one of the above Embodiments, wherein an amplitude or minimum-to-maximum magnitude of the low voltage output signal is less than 5 volts.

22. The integrated circuit (IC) device of any one of the above Embodiments, wherein the at least one low voltage active device comprises a lateral BJT or a MOS transistor.

23. The integrated circuit (IC) device of any one of the above Embodiments, comprising a second low voltage active device, wherein the at least one of the low voltage active device comprises a BJT and the second low voltage active device comprises a MOS transistor.

24. The integrated circuit (IC) device of any one of the above Embodiments, wherein the BJT comprises an L-BJT and a layer stack of the L-BJT and a gate stack of the MOS transistor have at least one layer having a common physical dimension.

25. The integrated circuit (IC) device of any one of the above Embodiments, wherein the L-BJT comprises a laterally extended base region having a length defined by a spacer disposed on a side wall of the layer stack.

26. The integrated circuit (IC) device of any one of the above Embodiments, wherein the spacer has the same physical dimensions and is co-fabricated with another spacer dispose on a side wall of the gate stack.

27. The integrated circuit (IC) device of any one of the above Embodiments, wherein the L-BJT and the MOS transistor have at least one implanted region having a common implanted dopant profile.

28. The integrated circuit (IC) device of any one of the above Embodiments, wherein in operation, the low voltage active device is configured to drop 5V or less while the DFE-PD is configured to drop 5-400V.

29. The integrated circuit (IC) device of any one of the above Embodiments, wherein the doped semiconductor region comprises at least one wide bandgap semiconductor material.

30. The integrated circuit (IC) device of any one of the above Embodiments, wherein the DFE-PD comprises at least one of SiC, GaN and Ga₂O₃.

31. The integrated circuit (IC) device of any one of the above Embodiments, wherein a majority carrier concentration or a doping concentration in the inter-gate region is smaller than those of the gate region by at least a factor of 10.

32. The integrated circuit (IC) device of any one of the above Embodiments, wherein DFE-PD further comprises an input drift region extending between the HD input region and the depletion control region, and an output drift region extending between the depletion control region and the HD output region, the input and output drift regions having a doping concentration less than that of the HD input and output regions.

35. The integrated circuit (IC) device of any one of the above Embodiments, wherein the HD output region is electrically connected to the low voltage active device by a common metallization levels of the low voltage active device and the DFE-PD.

37. The integrated circuit (IC) device of any one of the above Embodiments, wherein a region of the semiconductor substrate below the dielectric layer is electrically connected to the at least one conductive field plate via a heavily doped contact region, formed in the semiconductor substrate, and serves as a second field plate for the DFE-PD, and wherein the region of the semiconductor substrate and the HD contact region have the same polarity as the depletion control region.

38. A method of fabricating an integrated circuit (IC) device, the method comprising:
forming at least one low voltage device on a semiconductor substrate; and
forming a depletion field effect potential divider (DFE-PD) above a major surface of substrate and on a dielectric layer, the DFE-PD configured to scale a high voltage input signal received from a high voltage node to a low voltage output signal provided the low voltage device, forming the DFE-PD comprising:
   forming a doped semiconductor region laterally extended in a lateral direction parallel to the main surface of the substrate between a highly doped (HD) input region and a highly doped (HD) output region, the doped semiconductor region comprising a depletion control region laterally extended from an input doped region to an output doped region of the doped semiconductor region; and
   electrically connecting the HD input region to the high voltage node and the HD output region to the low voltage device;
wherein the input drift region, the output drift region, the HD input region, and the HD output region have the same polarity opposite to a polarity of the depletion control region; and
wherein a majority carrier concentration or a doping concentration in the depletion control region is smaller than those of the input and output drift regions by at least a factor of 10.

39. The method of Embodiment 38, wherein a thicknesses of the depletion control region, the input drift region, and the output drift region along a vertical direction are substantially equal and smaller than 2.0 micrometers, wherein vertical direction is perpendicular to the lateral direction.

40. The method of any one of the above Embodiments, further comprising forming a first conductive field plate extended above the input drift region along the lateral direction and electrically connecting it to a reduced surface field (RESURF) layer or a gate layer of the low voltage device, the field plate serving as a RESURF plate for the DFE-PD.

41. The method of any one of the above Embodiments, further comprising forming a second conductive field plate laterally extended above the first field plate and electrically connected to the first field plate.

42. The method of any one of the above Embodiments, wherein depletion field effect potential divider (DFE-PD) is configured to provide an output voltage greater than one microvolt to the low voltage active device in response to receiving an input voltage greater than 0.5 volts from the high voltage node.

43. The method of any one of the above Embodiments, wherein a length of the input drift region along the lateral direction is at least 2 times larger than a length of the depletion control region. Valid

44. The method of any one of the above Embodiments, wherein the dielectric layer comprises a buried dielectric layer within the substrate.

45. The method of any one of the above Embodiments, wherein the dielectric layer is formed on the semiconductor substrate.

46. The method of any one of the above Embodiments, further comprising electrically connecting a region of the semiconductor substrate below the dielectric layer to the HD output region, wherein the region of the semiconductor substrate has the same polarity as the HD output region.

47. The method of any one of the above Embodiments, further comprising electrically connecting a region of the semiconductor substrate below the dielectric layer to a first field plate above the input drift region via an HD contact region, and wherein the region of the semiconductor substrate and the HD contact region have the same polarity as the depletion control region.

48. The method of any one of the above Embodiments, further comprising forming a PN junction and a dielectric layer between the region of the semiconductor substrate and a region of the substrate on which the low voltage device is formed.

49. The method of any one of the above Embodiments, wherein the dielectric layer comprises a cladding dielectric layer disposed on the semiconductor substrate.

50. The method of any one of the above Embodiments, wherein forming the DFE-PD comprises forming the DFE-PD above a major surface of the semiconductor substrate and integrating in a back-end-of-line (BEOL) of the IC device.

51. The method of any one of the above Embodiments, wherein the DFE-PD is separated from the major surface of the semiconductor substrate by at least one intermetal dielectric layer.

52. The method of any one of the above Embodiments, wherein forming the DFE-PD comprises embedding the DFE-PD in an intermetal dielectric layer.

53. The method of any one of the above Embodiments, further comprising forming first field plate on a second dielectric layer formed on the semiconductor substrate, and electrically connecting the first field plate to the low voltage device and a second field plate over the input drift region.

54. The method of any one of the above Embodiments, wherein an amplitude or minimum-to-maximum magnitude of the high voltage input signal is larger than 100 volts.

55. The method of any one of the above Embodiments, wherein an amplitude or minimum-to-maximum magnitude of the low voltage output signal is less than 5 volts. Perfect

56. The method of any one of the above Embodiments, wherein the low voltage device comprises a lateral BJT or a MOS transistor.

57. The method of any one of the above Embodiments, further comprising forming a second low voltage device on the semiconductor substrate, wherein the at least one low voltage device comprises a BJT and the second low voltage device comprises a MOS transistor.

58. The method of any one of the above Embodiments, wherein the BJT comprises an L-BJT and a layer stack of the L-BJT and a gate stack of the MOS transistor have at least one layer having a common physical dimension.

59. The method of any one of the above Embodiments, wherein the L-BJT comprises a laterally extended base region having a length defined by a spacer disposed on a side wall of the layer stack.

60. The method of any one of the above Embodiments, wherein the spacer has the same physical dimensions and is co-fabricated with another spacer dispose on a side wall of the gate stack.

61. The method of any one of the above Embodiments, wherein the L-BJT and the MOS transistor have at least one implanted region having a common implanted dopant profile.

62. The method of any one of the above Embodiments, wherein in operation, the low voltage device is configured to drop 5V or less while the high voltage potential divider region is configured to drop 5-400V.

63. The method of any one of the above Embodiments, wherein forming the DFE-PD comprises forming the DFE-PD by deposing or growing at least one wide bandgap semiconductor material.

64. The method of any one of the above Embodiments, wherein the at least one wide bandgap semiconductor material region comprises SiC, GaN and Ga₂O₃.

### Terminology

In the foregoing, it will be appreciated that any feature of any one of the embodiments can be combined or substituted with any other feature of any other one of the embodiments.

Aspects of this disclosure can be implemented in various electronic devices. Examples of the electronic devices can include, but are not limited to, consumer electronic products, parts of the consumer electronic products, electronic test equipment, cellular communications infrastructure such as a base station, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, peripheral device, a clock, etc. Further, the electronic devices can include unfinished products.

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

As used herein, unless expressly stated otherwise, “similar” or “substantially identical means”, depending on the variability of the process, can be +/−5%, +/−10%, etc.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A lateral bipolar junction transistor (BJT), comprising:
an emitter region formed in a base well;
a lightly doped collector region separated in a lateral direction from the base well by a drift region doped with a dopant of a same type at a lower dopant concentration relative to the lightly doped collector region; and
a layer stack formed on the drift region,
wherein a boundary of the base well or the emitter region is aligned, in a vertical direction crossing the lateral direction, with an edge of the layer stack.

2. The lateral BJT of claim 1, wherein a base length of the lateral BJT, extending between the emitter region and the drift region, is defined by a lateral width of a bottom portion of a spacer formed on a sidewall of the layer stack.

3. The lateral BJT of claim 1, wherein the layer stack comprises:
a dielectric layer formed on the drift region, and
a conductive reduced surface field (RESURF) layer formed on the dielectric layer.

4. The lateral BJT of claim 3, wherein the RESURF layer is configured to provide a substantially constant lateral electric field component along the drift region.

5. The lateral BJT of claim 1, wherein a peak of an implanted dopant profile of the base well along the vertical direction is substantially positioned at a lateral interface between the base well and the emitter region.

6. The lateral BJT of claim 1, wherein the emitter region comprises a vertical emitter portion extending in the vertical direction above a surface of a substrate having the base well formed therein.

7. The lateral BJT of claim 6, wherein the vertical emitter portion comprises polysilicon.

8. The lateral BJT of claim 7, further comprising an interfacial dielectric layer formed between the vertical emitter portion and a top surface of the substrate.

9. The lateral BJT of claim 1, wherein a base length of the lateral BJT is a lateral distance from a first end aligned with an edge of the layer stack to a second end defined by a diffusion length of a dopant used to form the base well.

10. A lateral bipolar junction transistor (BJT), comprising:
an emitter region formed in a base well;
a lightly doped collector region separated in a lateral direction from the base well by a drift region doped with a dopant of a same type at a lower dopant concentration relative to the lightly doped collector region; and
a layer stack formed on the drift region having a spacer formed on a sidewall thereof,
wherein a base length of the lateral BJT, extending in the lateral direction between the emitter region and the drift region, is defined by a lateral width of a bottom portion of the spacer formed on the sidewall of the layer stack.

11. The lateral BJT of claim 10, wherein a vertical boundary between the base well and the emitter region is aligned, in a vertical direction crossing the lateral direction, with an edge of the layer stack.

12. The lateral BJT of claim 10, wherein the layer stack of the lateral BJT comprises a dielectric layer vertically interposed between the drift region and a conductive reduced surface field (RESURF) layer.

13. The lateral BJT of claim 12, wherein the RESURF layer is configured to provide a substantially constant lateral electric field component along the drift region.

14. The lateral BJT of claim 10, wherein the emitter region, a base region, and the collector region of the lateral BJT are arranged in the lateral direction, and wherein the base region comprises a region of the base well extending in the lateral direction between the emitter region and the drift region.

15. A lateral bipolar junction transistor (BJT), comprising:
an emitter region formed in a base well;
a heavily doped collector region separated in a lateral direction from the base well by a drift region doped with a dopant of a same type at a lower dopant concentration relative to the heavily doped collector region; and
a layer stack formed at least on a first lateral section of the drift region, the layer stack including a conductive reduced surface field (RESURF) layer.

16. The lateral BJT of claim 15, wherein the layer stack further comprises a thin dielectric layer vertically interposed between the conductive RESURF layer and the drift region.

17. The lateral BJT of claim 16, further comprising a thick dielectric layer formed on a second lateral section of the drift region extending from the layer stack to the heavily doped collector region.

18. The lateral BJT of claim 17, wherein the conductive RESURF layer laterally extends from a vertical interface between the base well and the drift region towards the heavily doped collector region to cover a portion of the thick dielectric layer.

19. The lateral BJT of claim 15, further comprising a spacer structure formed on a sidewall of the layer stack and vertically over a base region of the lateral BJT.

20. The lateral BJT of claim 19, wherein a base length of the lateral BJT, extending between the emitter region and drift region, is defined by a lateral width of a bottom portion of the spacer structure.

21. The lateral BJT of claim 1, wherein a base length of the lateral BJT comprises a lateral distance between an edge of the emitter region and the edge of the layer stack.
